(19) United States
(12) Patent Application Publication
(10) Pub. No.: US 2024/0228515 A1
(43) Pub. Date: Jul. 11, 2024

(54) BORON-CONTAINING TRIPHENYLENE COMPOUNDS, COMPOSITIONS, AND ORGANIC ELECTRONIC DEVICES USING THE SAME

(71) Applicant: SHENZHEN CHINA STAR OPTOELECTRONICS SEMICONDUCTOR DISPLAY TECHNOLOGY CO., LTD., Shenzhen (CN)

(72) Inventors: Xinlong SONG, Shenzhen (CN); Zhihua XIAO, Shenzhen (CN); Ruifeng HE, Shenzhen (CN); Jingyao SONG, Shenzhen (CN)

(21) Appl. No.: 18/236,422

(22) Filed: Aug. 22, 2023

(30) Foreign Application Priority Data
Dec. 13, 2022 (CN) 202211604608.6

(51) Int. Cl. C07F 5/02; H10K 85/60

(52) U.S. Cl. CPC C07F 5/027; H10K 85/615; H10K 85/633; H10K 85/636; H10K 85/6572; H10K 85/6574; H10K 85/6576; H10K 85/658; C07B 2200/05

(57) ABSTRACT

A boron-containing triphenylene compound has a structure represented by formula (1). In the formula (1), Ar₁ and Ar₂ are each independently selected from any one of formula (A-1) to formula (A-5); X is selected from O, S, CR₅R₆, or NR₇; and n1-n4 are each independently selected from 0, 1, 2, or 3.

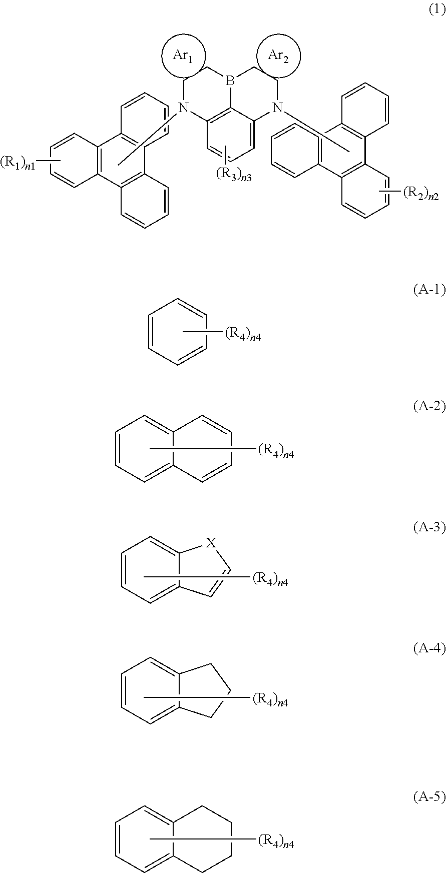

### CROSS-REFERENCE TO RELATED APPLICATION

The present disclosure claims priority to and the benefit of Chinese Patent Application No. 202211604608.6, filed on Dec. 13, 2022, the present disclosure of which is incorporated herein by reference in its entirety.

### TECHNICAL FIELD

The present disclosure relates to the field of display, in particular to boron-containing triphenylene compounds, compositions, and organic electronic devices using the same.

### BACKGROUND

In order to improve the luminescence efficiency of organic light-emitting diode (OLED), various luminescence material systems based on fluorescence and phosphorescence have been developed. The OLED using a fluorescence material has the characteristic of high reliability, but its internal electroluminescence quantum efficiency is limited to 25% under electrical excitation due to the fact that the branch ratio of exciton in a singlet excited-state and a triplet excited-state is 1:3. The OLED using a phosphorescence material has achieved almost 100% internal electroluminescence quantum efficiency, but it arises a roll-off effect, that is, the luminescence efficiency rapidly decreases with an increase of current or brightness, which is particularly unfavorable for high brightness application.

So far, traditional phosphorescence materials with practical application value are metal complexes containing iridium and platinum. However, the metal complexes containing iridium and platinum used as raw materials are rare and expensive, and the synthesis of the metal complexes is complex, resulting in high cost. In order to solve the above-mentioned problems, the concept of reverse internal conversion is proposed, which refers to the use of organic compounds as luminescence materials to achieve high luminescence efficiency comparable to phosphorescence. This concept has been achieved through various combinations of materials, such as composite excited-state materials, thermally activated delayed fluorescence (TADF) materials, and the like.

For traditional blue light TADF materials, the way of connecting an electron donor group and an electron acceptor group is mostly used in the connection between groups in the chemical formula. However, the above-mentioned connection way causes the complete separation of the electron cloud distribution of the highest occupied molecular orbital (HOMO) and the lowest unoccupied molecular orbital (LUMO), decreasing the difference (ΔEST) between the singlet state (S1) and the triplet state (T1) of the TADF compounds, thus reducing the luminescence efficiency and lifespan of the device.

Therefore, the traditional blue light TADF materials still have certain disparity in performances compared to phosphorescence luminescence materials in terms of efficiency and lifespan.

### SUMMARY

The present disclosure provides a boron-containing triphenylene compound, which has a structure represented by the following formula (1):

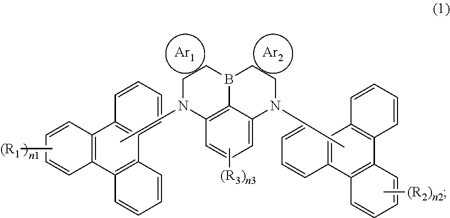

In the formula (1), Ar₁ and Ar₂ are each independently selected from any one of formula (A-1) to formula (A-5):

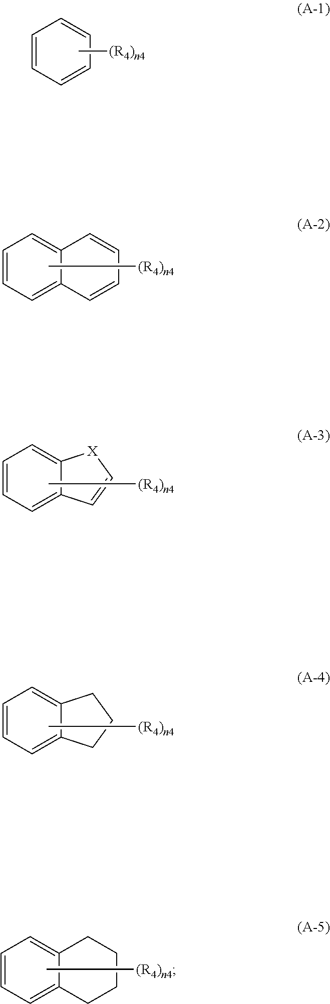

X is selected from O, S, CR₅R₆, or NR₇;
R₁-R₇ are each independently selected from H, D, a C₁₋₂₀ linear alkyl group, a C₁₋₂₀ linear alkoxyl group, a C₁₋₂₀ linear thioalkoxyl group, a C₃₋₂₀ branched alkyl group, a C₃₋₂₀ cyclic alkyl group, a C₃₋₂₀ branched alkoxyl group, a C₃₋₂₀ cyclic alkoxyl group, a C₃₋₂₀ branched thioalkoxyl group, a C₃₋₂₀ cyclic thioalkoxyl group, silyl, a ketone group containing 1-20 carbon atoms, an alkoxycarbonyl group containing 2-20 carbon atoms, an aryloxycarbonyl group containing 7-20 carbon atoms, an alkenyl group containing 1-20 carbon atoms, a cyanoyl group, a carbamoyl group, a haloformyl group, a formyl group, an isocyanoyl group, an isocyanate group, a thiocyanate group, an isothiocyanate group, a hydroxyl group, a nitro group, CF₃, Cl, Br, F, a substituted or unsubstituted aromatic group containing 6-30 ring atoms, a substituted or unsubstituted heteroaromatic group containing 5-30 ring atoms, a substituted or unsubstituted aryloxy group containing 6-30 ring atoms, a substituted or unsubstituted heteroaryloxy group containing 5-30 ring atoms, or combinations thereof at each occurrence; and
n1-n4 are each independently selected from 0, 1, 2, or 3.

Accordingly, the present disclosure further provides a composition, which includes the above-mentioned boron-containing triphenylene compound and an organic solvent.

Accordingly, the present disclosure further provides an organic electronic device, which includes an organic functional layer, and the organic functional layer includes the above-mentioned boron-containing triphenylene compound.

### BRIEF DESCRIPTION OF THE DRAWINGS

In order to illustrate technical solutions in embodiments of the present disclosure more clearly, the following briefly introduces drawings needed to be used in description of the embodiments. Apparently, the drawings in the following description are only some embodiments of the present disclosure. For those skilled in the art, other drawings can be obtained from these drawings without paying creative effort.

FIG. 1 is a schematic structural diagram of an organic electronic device according to some embodiments of the present disclosure.

### DETAILED DESCRIPTION

The following provides a clear and complete description of the technical solution in the embodiments of the present disclosure, in conjunction with the accompanying drawings. It is apparent that the described embodiments are only some of the embodiments of the present disclosure, not all of them. Based on the embodiments of the present disclosure, other embodiments obtained by those skilled in the art without creative effort belong to a scope of the present disclosure. In addition, it should be understood that specific embodiments described herein are only used to explain and illustrate the present disclosure and are not used to limit the present disclosure. In the present disclosure, location terms used, such as “up” and “down”, generally indicate up and down in actual using or working state of devices, in particular drawing directions in the drawings, unless otherwise described. In addition, in the description of the present disclosure, a term “include” refers to “include but not limited to”, and a term “more” refers to “two or more than two”. Various embodiments of the present disclosure may exist in a form of a scope. It should be understood that description in a form of the scope is only for convenience and conciseness, and should not be understood as a rigid restriction on the scope of the present disclosure. Therefore, it should be considered that the description of ranges has specifically disclosed all possible sub-ranges and single values within the sub-ranges. For example, it should be considered that the description of a range “from 1 to 6” has specifically disclosed a sub-range, such as from 1 to 3, from 1 to 4, from 1 to 5, from 2 to 4, from 2 to 6, from 3 to 6, and a single number within the sub-range, such as 1, 2, 3, 4, 5, or 6, which is applicable regardless of the ranges/scopes. In addition, whenever a numerical range is indicated in this article, it refers to a number (fraction or integer) including any reference within the range.

The selection scope of terms “and/or” used in this context includes any one of two or more related listed items, and any and all combinations of related listed items. The above-mentioned any and all combinations include combinations of any two related listed items, any more related listed items, or all related listed items.

In the present disclosure, a composition, printing ink, and ink have the same meaning and may be interchanged.

In the present disclosure, an aromatic group, an aromatic ring, and an aromatic ring system have the same meaning and may be interchanged.

In the present disclosure, a heteroaromatic group, a heteroaromatic ring, and a heteroaromatic ring system have the same meaning and may be interchanged.

In the present disclosure, “substituted” means that one or more hydrogen atoms in one substituted group are substituted by a substituent group.

In the present disclosure, a same substituent group at different substituent site may be independently selected from different groups. If a formula includes a plurality of R₁ groups, each of the R₁ groups may be independently selected from different groups. For example, in formula

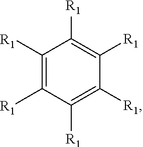

six R₁ groups of a benzene ring may be same or different.

In the present disclosure, “substituted or unsubstituted” means that a defined group may be substituted or not be substituted. When the defined group is substituted, it can be understood that the defined group may be substituted by at least one substituent R. The substituent R is selected from, but not limited thereto: D, a cyanoyl group, an isocyanoyl group, a nitro group, a halogen group, a C₁-C₂₀ alkyl group, a heterocyclic group containing 3-20 ring atoms, an aromatic group containing 6-20 ring atoms, a heteroaromatic group containing 5-20 ring atoms, —NR′R″, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, or a trifluoromethyl group. The above-mentioned groups may further be substituted by acceptable substituent groups in the art. Understandably, R′ and R″ in the —NR′R″ are each independently selected from, but not limited thereto: H, D, a cyanoyl group, an isocyanoyl group, a nitro group, a halogen group, a C₁-C₁₀ alkyl group, a heterocyclic group containing 3-20 ring atoms, an aromatic group containing 6-20 ring atoms, or a heteroaromatic group containing 5-20 ring atoms. Preferably, R′ and R″ are each independently selected from, but not limited thereto: D, a cyanoyl group, an isocyanoyl group, a nitro group, a halogen group, a C₁-C₁₀ alkyl group, a heterocyclic group containing 3-10 ring atoms, an aromatic group containing 6-20 ring atoms, a heteroaromatic group containing 5-20 ring atoms, a silane group, a carbonyl group, an alkoxycarbonyl group, an aryloxycarbonyl group, a carbamoyl group, a haloformyl group, a formyl group, an isocyanate group, a thiocyanate group, an isothiocyanate group, a hydroxyl group, or a trifluoromethyl group, and the above-mentioned groups may further be substituted by acceptable substituent groups in the art.

In the present disclosure, “a ring atom number” refers to a number of atoms constituting a ring of a structural compound (such as a monocyclic compound, a fused ring compound, a cross-linked compound, a carbon ring compound, or a heterocyclic compound) obtained by atomic bonding. In a ring substituted by a substituent group, atoms contained in the substituent group are not included in the atoms forming the ring. The same applies to the “number of ring atoms” described below unless otherwise specified. For example, a ring atom number of a benzene ring is 6, a ring atom number of a naphthalene ring is 10, and a ring atom number of a thiophene group is 5. Furthermore, unless otherwise specified, the ring atom is carbon atom, and the “heteroatom” is selected from N, S, or O.

In the present disclosure, “an aryl group or an aromatic group” refers to an aromatic hydrocarbon group derived from a basis of an aromatic ring compound removing H. The aromatic ring compound may be an aromatic group with a single ring, a fused ring aromatic group, or a polycyclic aromatic group. For a polycyclic ring type, at least one ring is an aromatic ring system. For example, “a substituted or unsubstituted aryl group containing 6 to 40 ring atoms” refers to an aryl group containing 6 to 40 ring atoms, preferably a substituted or unsubstituted aryl group containing 6 to 30 ring atoms, a substituted or unsubstituted aryl group containing 6 to 18 ring atoms, or a substituted or unsubstituted aryl group containing 6 to 14 ring atoms, and the aryl group is optionally further substituted. Suitable examples include, but are not limited thereto: a phenyl group, a biphenyl group, a triphenyl group, a naphthyl group, an anthracyl group, a phenanthryl group, a fluoranthenyl group, a triphenylene group, a pyrenyl group, a perylene group, a tetraphenyl group, a fluorenyl group, a diphenyl group, an acenaphthenyl group, and derivatives thereof. Understandably, multiple aryl groups may further be disconnected by short non-aromatic units (for example, a non-hydrogenium atom contenting less than 10%, such as C, N, or O). In particular, an acenaphthene group, a fluorene group such as a 9,9-diarylfluorene group, a triarylamine group, and a diaryl ether system may be further included in a definition of the aryl group.

In the present disclosure, “a heteroaryl group or a heteroaromatic group” refers to a basis of an aryl group with at least one carbon atom substituted by a non-carbon atom, and the non-carbon atom may be N, O, S, or the like. For example, “a substituted or unsubstituted heteroaryl group containing 5 to 40 ring atoms” refers to a heteroaryl group containing 5 to 40 ring atoms, preferably a substituted or unsubstituted heteroaryl group containing 6 to 30 ring atoms, a substituted or unsubstituted heteroaryl group containing 6 to 18 ring atoms, or a substituted or unsubstituted heteroaryl group containing 6 to 14 ring atoms, and the heteroaryl group is optionally further substituted. Suitable examples include, but are not limited thereto: a thiophene group, a furan group, a pyrrolyl group, a diazo group, a triazole group, an imidazolyl group, a pyridinyl group, a bipyridyl group, a pyrimidinyl group, a triazinyl group, an acridine group, a pyridazinyl group, a pyrazinyl group, a quinolinyl group, an isoquinolinyl group, a quinazolinyl group, a quinoxalinyl group, a phthalazinyl group, a pyridino pyrimidinyl group, a pyridino pyrazinyl group, a benzo thienyl group, a benzofuranyl group, an indolyl group, a pyrrolo imidazolyl group, a pyrrolo pyrrolyl group, a thiophenopyrrolyl group, a thiophenothiophenyl group, a furanopyrrolyl group, a furanofuranyl group, a thiophenofuranyl group, a benzoisoxazolyl group, a benzoisothiazolyl group, a benzimidazolyl group, an o-diaznaphthyl group, a phenanthryl group, a pyridinyl group, a quinazolinketone group, a dibenzothiophenyl group, a dibenzofuranyl group, a carbazolyl group, and derivatives thereof.

In the present disclosure, “an alkyl group” refers to a linear alkyl group, a branched alkyl group, or a cyclic alkyl group. A number of carbon atoms in the alkyl group may range from 1 to 50, 1 to 30, 1 to 20, 1 to 10, or 1 to 6. The term “a C₁₋₉ alkyl group” refers to the alkyl group containing 1 to 9 carbon atoms. For example, “the C₁₋₉ alkyl group” may be a C₁ alkyl group, a C₂ alkyl group, a C₃ alkyl group, a C₄ alkyl group, a C₅ alkyl group, a C₆ alkyl group, a C₇ alkyl group, a C₈ alkyl group, or a C₉ alkyl group at each occurrence. Examples of the alkyl group include, but are not limited thereto: methyl, ethyl, n-propyl, isopropyl, n-butyl, sec-butyl, tert-butyl, isobutyl, 2-ethylbutyl, 3,3-dimethylbutyl, n-pentyl, isopentyl, neopentyl, tert-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butyl hexyl, cyclohexyl, 4-methylcyclohexyl 4-tert butylcyclohexyl, n-heptyl, 1-methylheptyl, 2,2-dimethylheptyl, 2-ethylheptyl, 2-butyl heptyl, n-octyl, tertoctyl, 2-ethyloctyl, 2-butyl octyl, 2-hexyloctyl, 3,7-dimethyloctyl, cyclooctyl, n-nonyl, n-decyl, adamantine, 2-ethyldecyl, 2-butyl decyl, 2-hexyldecyl, 2-octyldecyl, n-undecyl, n-dodecyl, 2-ethyldodecyl 2-butyl dodecyl, 2-hexyl dodecyl, 2-octyl dodecyl, n-tridecyl, n-tetradecyl, n-pentadecyl, n-hexadecyl, 2-ethyl hexadecyl, 2-butyl hexadecyl, 2-hexyl hexadecyl, 2-octyl hexadecyl, n-heptadecyl, n-octadecyl, n-octadecyl, n-eicosyl, 2-ethyl eicosyl, 2-butyl eicosyl, 2-hexyl eicosyl, 2-octyl twenty one alkyl, twenty two alkyl, twenty three alkyl, twenty four alkyl, twenty five alkyl, twenty six alkyl, twenty seven alkyl, twenty eight alkyl, twenty nine alkyl, thirty alkyl, or the like.

In the present disclosure, abbreviations of substituent groups are as follows: normal (n), secondary (sec), iso (i), tertiary (tert), ortho (o), meta (m), para (p), methyl (Me), ethyl (Et), propyl (Pr), butyl (Bu), n-amyl (Am), hexyl (Hx), cyclohexyl (Cy).

In the present disclosure, “an amino group” refers to a derivative of the amine, has a feature of a group represented by formula —N(X)₂. X is independently selected from H, a substituted or unsubstituted alkyl group, a substituted or unsubstituted cycloalkyl group, a substituted or unsubstituted heterocyclic group, or the like. Examples of amino groups include, but are not limited thereto: —NH₂, —N(alkyl)₂, —NH(alkyl), —N(cycloalkyl)₂, —NH(cycloalkyl), —N(heterocyclic)₂, —NH(heterocyclic), —N(aryl)₂, —NH(aryl), —N(alkyl)(aryl), —N(alkyl)(heterocyclic), —N(cycloalkyl)(heterocyclic), —N(aryl)(heteroaryl), —N(alkyl)(heteroaryl), or the like.

In the present disclosure, unless otherwise specially defined, a hydroxyl group refers to —OH, a carbonyl group refers to —C(═O)—, an amino group refers to —NH₂, a formyl group refers to —C(═O)H, a haloformyl group refers to —C(═O)Z (Z refers to halogen), a carbamoyl group refers to —C(═O)NH₂, an isocyanate group refers to —NCO, and an isothiocyanate group refers to —NCS.

In the present disclosure, “an alkoxyl group” refers to a group having a structure of “—O-alkyl”, that is, the alkyl group as defined above is connected to other groups through an oxygen atom. Suitable examples of phrases containing the above-mentioned term include, but are not limited thereto: a methoxyl group (—O—CH₃ or —OMe), an ethoxyl group (—O—CH₂CH₃ or -OEt), and a tert-butoxy group (—O—C(CH₃)₃ or -OtBu).

In the present disclosure, the “*” connected to a single bond indicates a linking site or a fused site.

In the present disclosure, when a linking site in a group is not specified, it means that any of connectable sites in the group may be selected as the linking site.

In the present disclosure, when a fused site in a group is not specified, it means that any of fusible sites in the group may be selected as the fused site. Preferably, two or more adjacent sites in the group are fused sites.

In the disclosure, a single bond connected to a substituent group and penetrated a corresponding ring indicates that the substituent group may be connected to any site of the ring. For example,

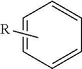

means that R may be connected to any substituent site of the benzene ring, and

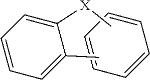

means that

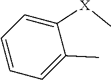

may be connected to any substituent site of the benzene ring to form a union ring.

In the present disclosure, a cyclic alkyl group and a cycloalkyl group have the same meaning and may be interchanged.

In the present disclosure, “adjacent groups” means the absence of a substituent site between two substituent groups.

In the present disclosure, “two adjacent R₁ groups, two adjacent R₃ groups, or two adjacent R₅ groups forming a ring with each other” indicates that a ring system is formed by connecting two adjacent R₁ groups, two adjacent R₃ groups, or two adjacent R₅ groups, and the ring system may be selected from an aliphatic hydrocarbon ring, an aliphatic heterocyclic ring, an aromatic hydrocarbon ring, or an aromatic heterocyclic ring. Preferably, the ring system may be

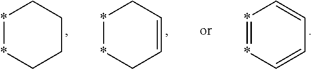

In the present disclosure, terms “combination thereof” used include all suitable combinations of any two or more of the listed items.

In the present disclosure, terms “further”, “special”, “specially”, or the like, are used to describe the purpose, indicating the differences in content, but should not be understood as limitations on the scope of the protection of the present disclosure.

In the present disclosure, the term “optionally” indicates that any one of the two parallel options of “yes” and “no” can be selected. If there are multiple “options” in a technical solution, unless otherwise specified, if there is no contradiction or mutual constraint, each “option” is independent.

Technical solutions of the present disclosure will be described in detail in the following.

The present disclosure provides a boron-containing triphenylene compound, which has a structure represented by the following formula (1):

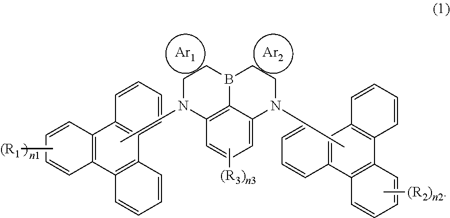

In the formula (1), Ar₁ and Ar₂ are each independently selected from any one of the following formula (A-1) to formula (A-5):

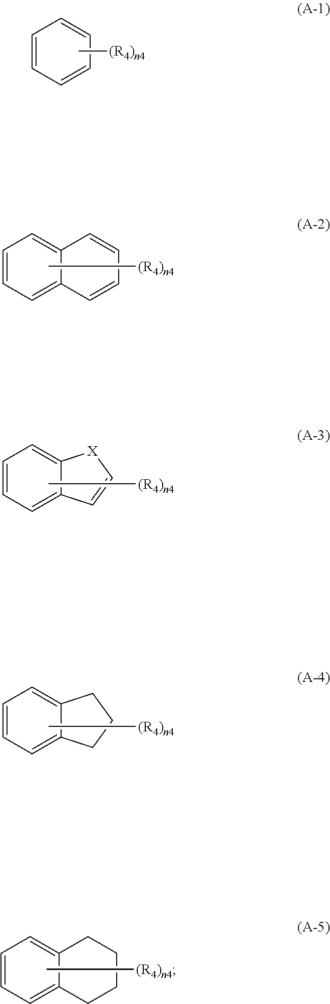

X is selected from O, S, CR₅R₆, or NR₇;
R₁-R₇ are each independently selected from H, D, a C₁₋₂₀ linear alkyl group, a C₁₋₂₀ linear alkoxyl group, a C₁₋₂₀ linear thioalkoxyl group, a C₃₋₂₀ branched alkyl group, a C₃₋₂₀ cyclic alkyl group, a C₃₋₂₀ branched alkoxyl group, a C₃₋₂₀ cyclic alkoxyl group, a C₃₋₂₀ branched thioalkoxyl group, a C₃₋₂₀ cyclic thioalkoxyl group, silyl, a ketone group containing 1-20 carbon atoms, an alkoxycarbonyl group containing 2-20 carbon atoms, an aryloxycarbonyl group containing 7-20 carbon atoms, an alkenyl group containing 1-20 carbon atoms, a cyanoyl group, a carbamoyl group, a haloformyl group, a formyl group, an isocyanoyl group, an isocyanate group, a thiocyanate group, an isothiocyanate group, a hydroxyl group, a nitro group, CF₃, Cl, Br, F, a substituted or unsubstituted aromatic group containing 6-30 ring atoms, a substituted or unsubstituted heteroaromatic group containing 5-30 ring atoms, a substituted or unsubstituted aryloxy group containing 6-30 ring atoms, a substituted or unsubstituted heteroaryloxy group containing 5-30 ring atoms, or combinations thereof at each occurrence; and
n1-n4 are each independently selected from 0, 1, 2, or 3.

In the present disclosure, two adjacent R₁ groups form a ring or do not form a ring with each other, two adjacent R₂ groups form a ring or do not form a ring with each other, two adjacent R₃ groups form a ring or do not form a ring with each other, and two adjacent R₄ groups form a ring or do not form a ring with each other.

In some embodiments, the boron-containing triphenylene compound is selected from any one of the following formula (2-1) to formula (2-8):

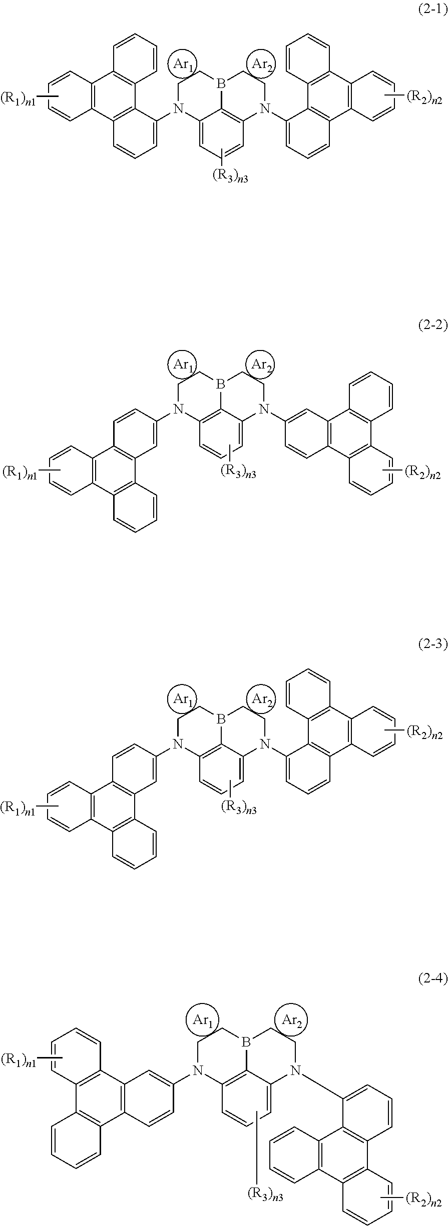

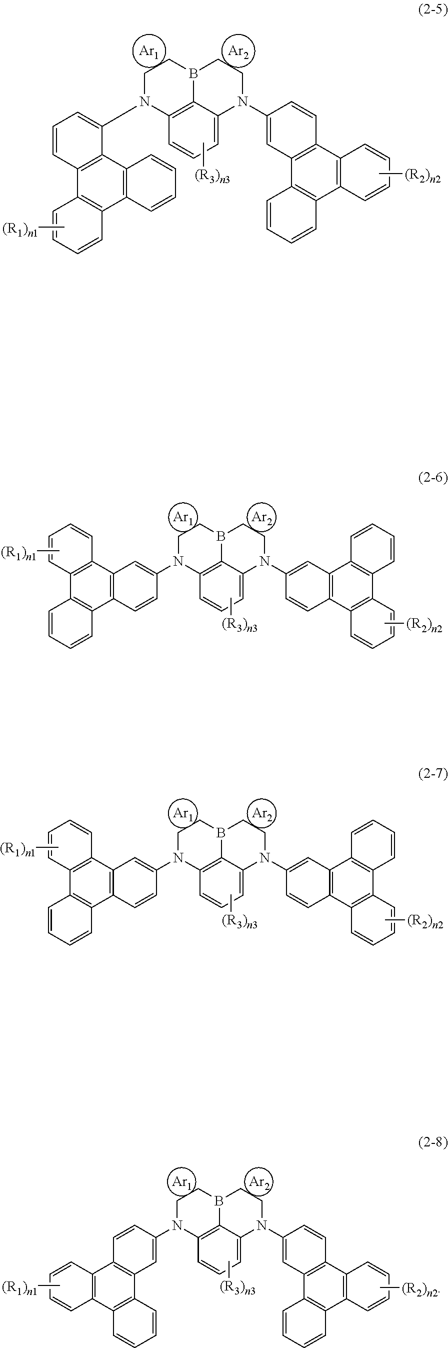

In some embodiments, the boron-containing triphenylene compound is selected from any one of the following formula (3-1) to formula (3-22):

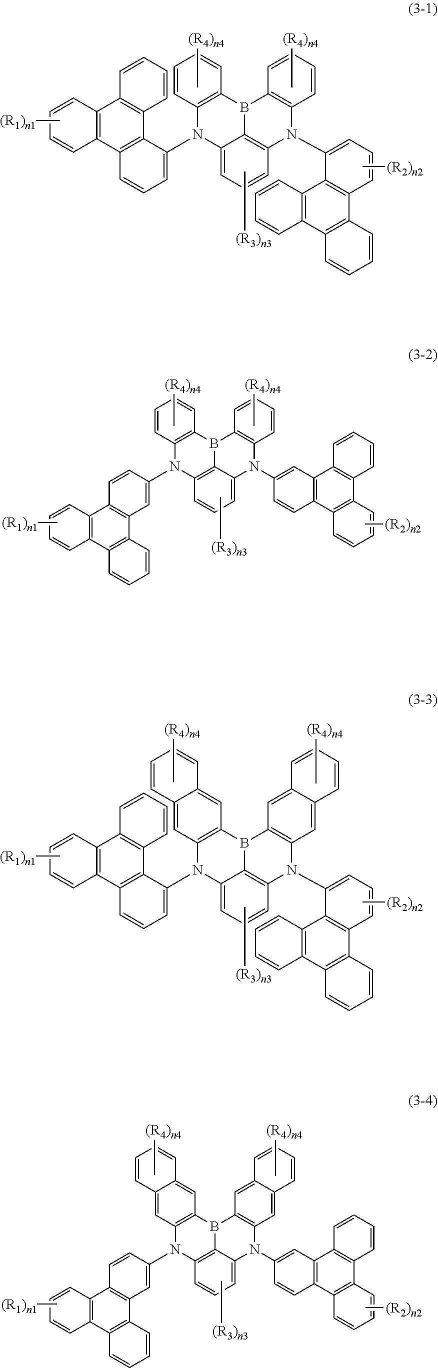

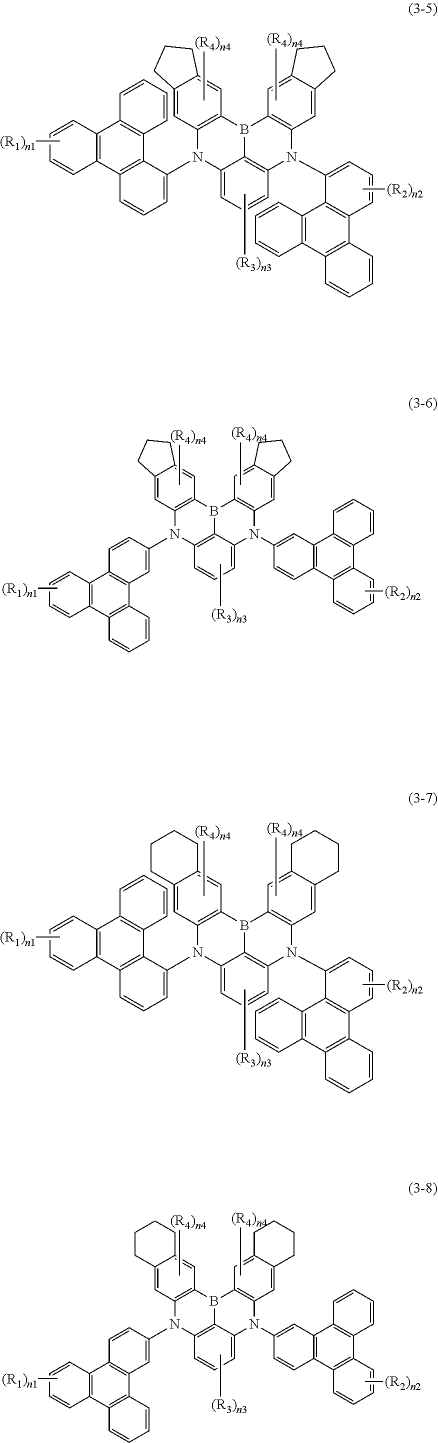

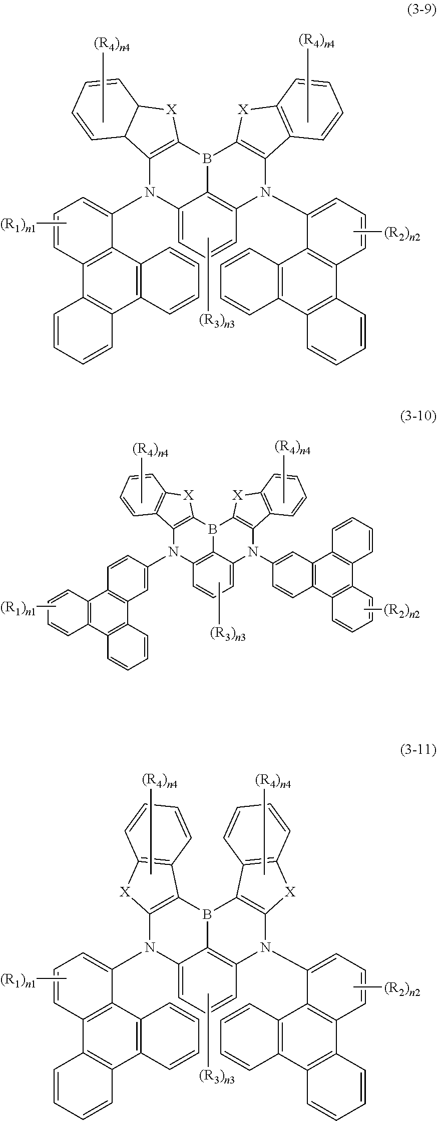

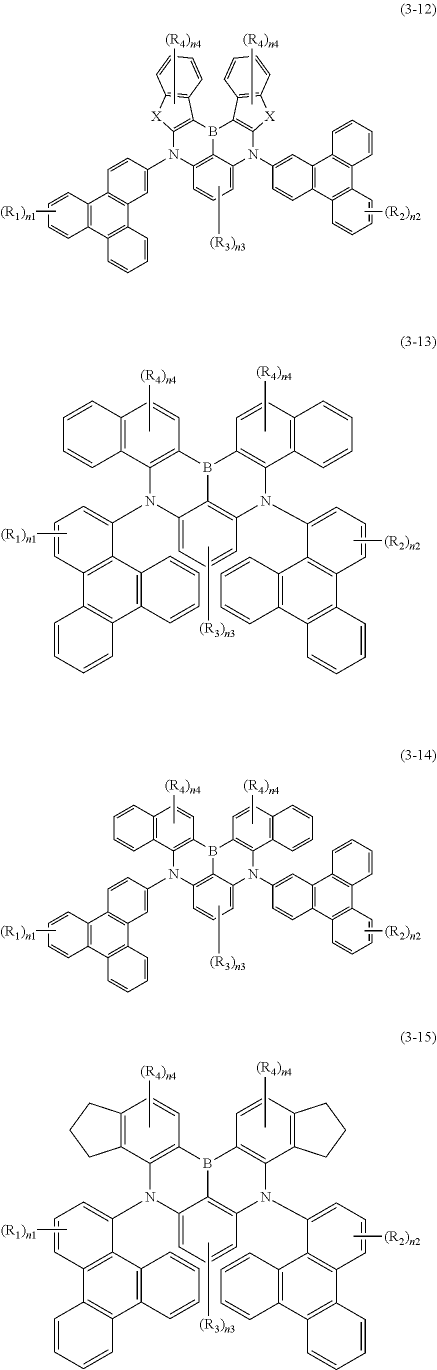

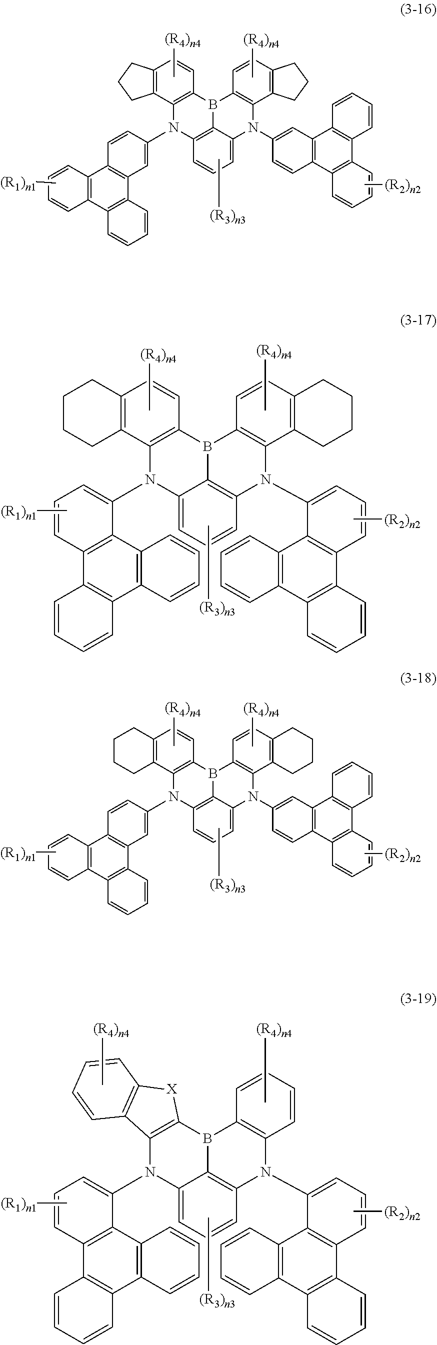

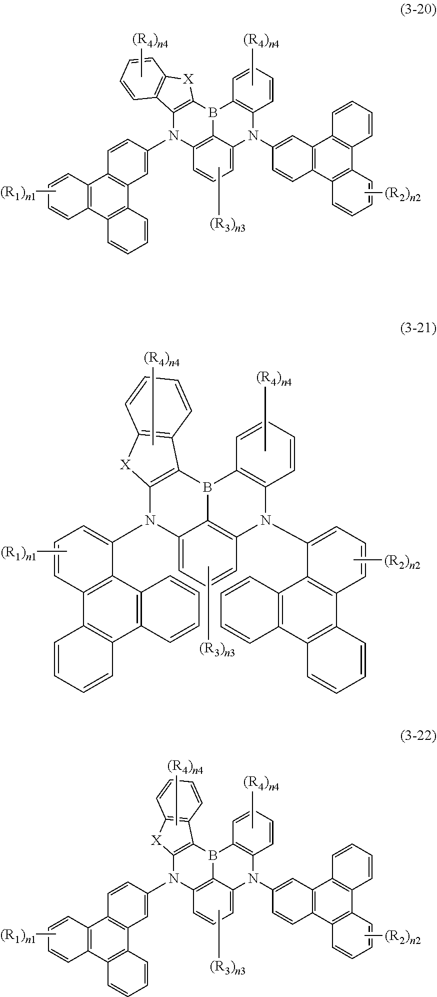

In some embodiments, Ar₁ and Ar₂ are each independently selected from any one of the following formula (B-1) to formula (B-8):

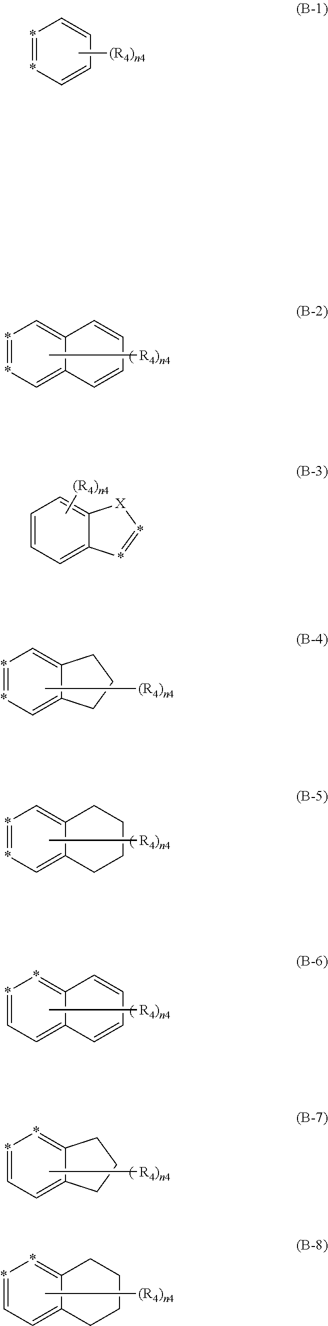

In the formula (B-1) to formula (B-8), “*” indicates a fused site.

In some embodiments, R₆ and R₇ are each independently selected from H, D, a C₁₋₁₀ linear alkyl group, a C₃₋₁₀ branched alkyl group, a C₃₋₁₀ cyclic alkyl group, or combinations thereof at each occurrence. Further, R₆ and R₇ are each independently selected from H, D, a C₁₋₄ linear alkyl group, a C₃₋₅ branched alkyl group, or combinations thereof at each occurrence.

In some embodiments, R₁ is independently selected from H, D, a C₁₋₁₀ linear alkyl group, a C₃₋₁₀ branched alkyl group, a C₃₋₁₀ cyclic alkyl group, or combinations thereof at each occurrence. Further, R₁ is independently selected from H, D, a C₁₋₄ linear alkyl group, a C₃₋₅ branched alkyl group, or combinations thereof at each occurrence.

In some embodiments, two adjacent R₁ groups do not form a ring with each other.

In some embodiments, two adjacent R₁ groups form a ring with each other. Further, two adjacent R₁ groups form an aromatic ring containing six ring atoms or an aliphatic ring with each other. Furthermore, two adjacent R₁ groups form

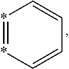 [SMILES: *1:*cccc1]

in which the “*” indicates a linking site.

In some embodiments, R₂ is independently selected from H, D, a C₁₋₁₀ linear alkyl group, a C₃₋₁₀ branched alkyl group, a C₃₋₁₀ cyclic alkyl group, or combinations thereof at each occurrence. Further, R₂ is independently selected from H, D, a C₁₋₄ linear alkyl group, a C₃₋₅ branched alkyl group, or combinations thereof at each occurrence.

In some embodiments, two adjacent R₂ groups do not form a ring with each other.

In some embodiments, two adjacent R₂ groups form a ring with each other. Further, two adjacent R₂ groups form an aromatic ring containing six ring atoms or an aliphatic ring with each other. Furthermore, two adjacent R₂ groups form

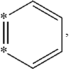 [SMILES: *1:*cccc1]

in which the “*” indicates a linking site.

In some embodiments, R₃ is independently selected from H, D, a C₁₋₁₀ linear alkyl group, a C₃₋₁₀ branched alkyl group, a C₃₋₁₀ cyclic alkyl group, or combinations thereof at each occurrence. Further, R₃ is independently selected from H, D, a C₁₋₄ linear alkyl group, a C₃₋₅ branched alkyl group, or combinations thereof at each occurrence.

In some embodiments, two adjacent R₃ groups do not form a ring with each other.

In some embodiments, two adjacent R₃ groups form a ring with each other. Further, two adjacent R₃ groups form an aromatic ring containing six ring atoms or an aliphatic ring with each other. Furthermore, two adjacent R₃ groups form

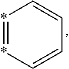 [SMILES: *1:*cccc1]

in which the “*” indicates a linking site.

In some embodiments, R₄ is independently selected from H, D, a C₁₋₁₀ linear alkyl group, a C₃₋₁₀ branched alkyl group, a C₃₋₁₀ cyclic alkyl group, or combinations thereof at each occurrence. Further, R₄ is independently selected from H, D, a C₁₋₄ linear alkyl group, a C₃₋₅ branched alkyl group, or combinations thereof at each occurrence.

In some embodiments, X is selected from O, S, N—CH₃, N-Ph, or C(CH₃)₂, in which Ph indicates benzene.

In some embodiments, the boron-containing triphenylene compound may be selected from, but not limited to, any one of the following structures:

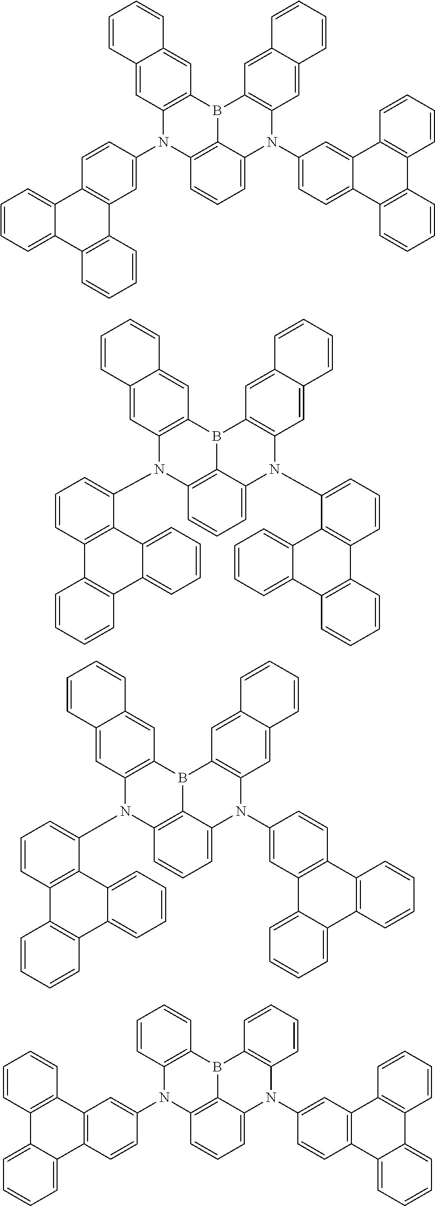

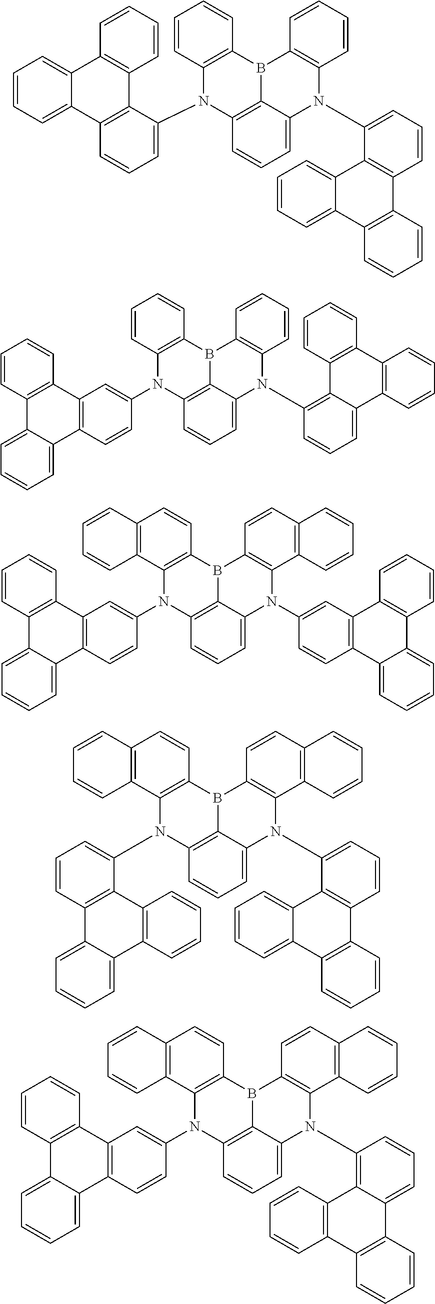

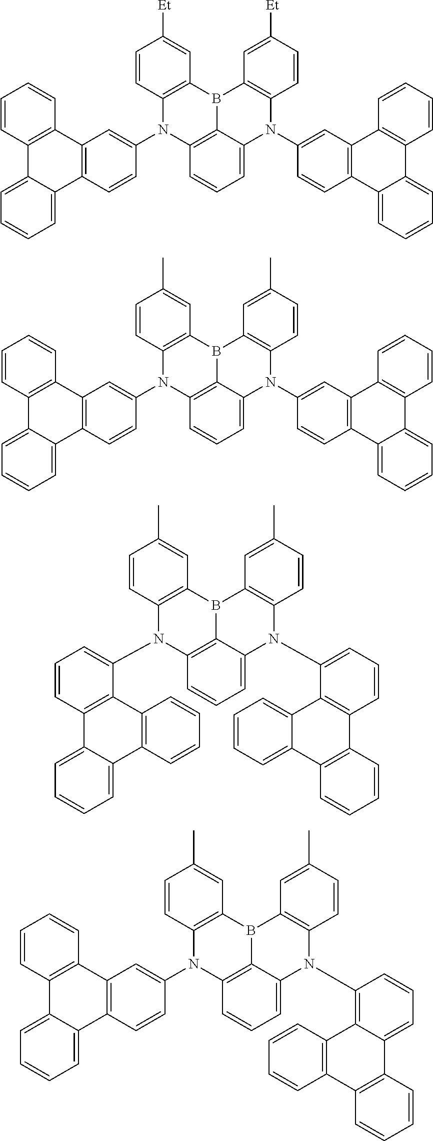

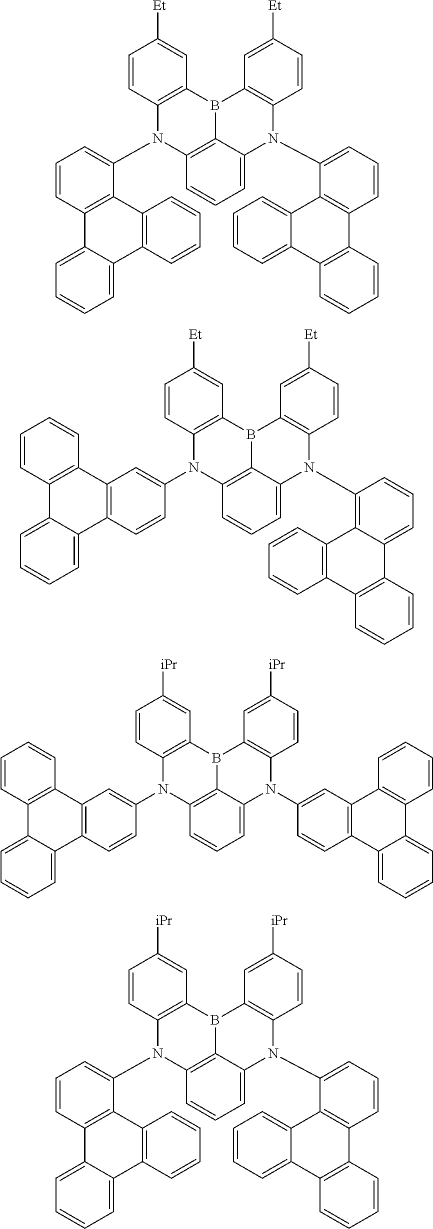

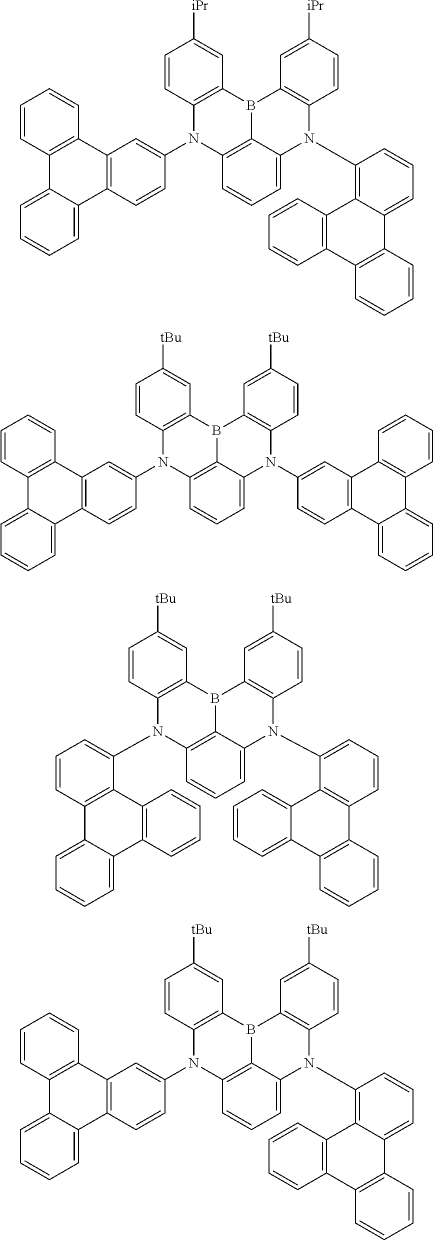

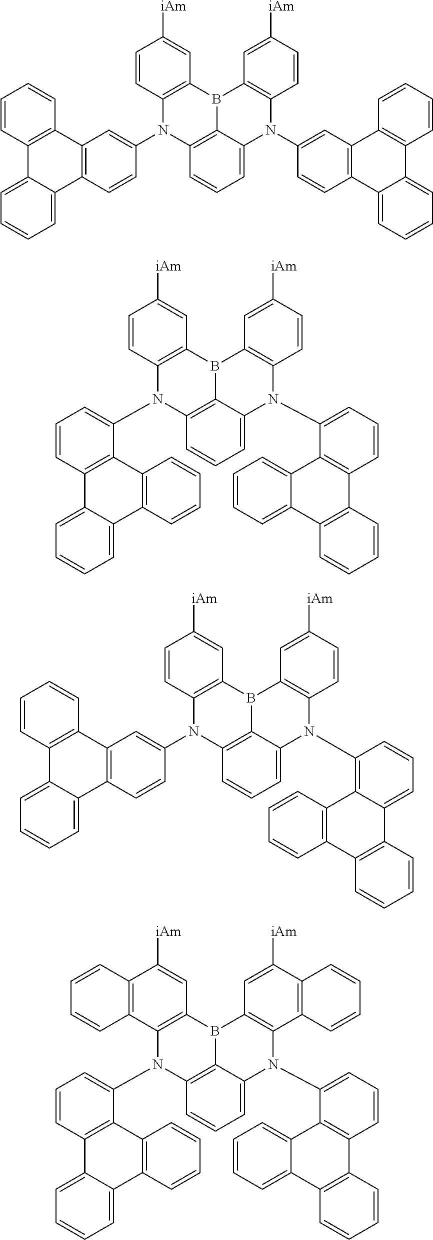

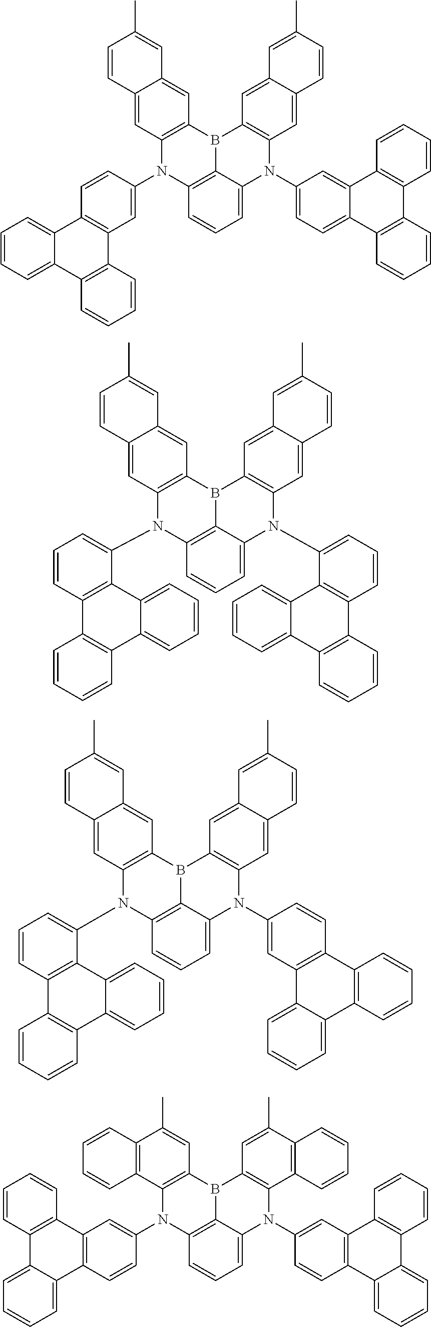

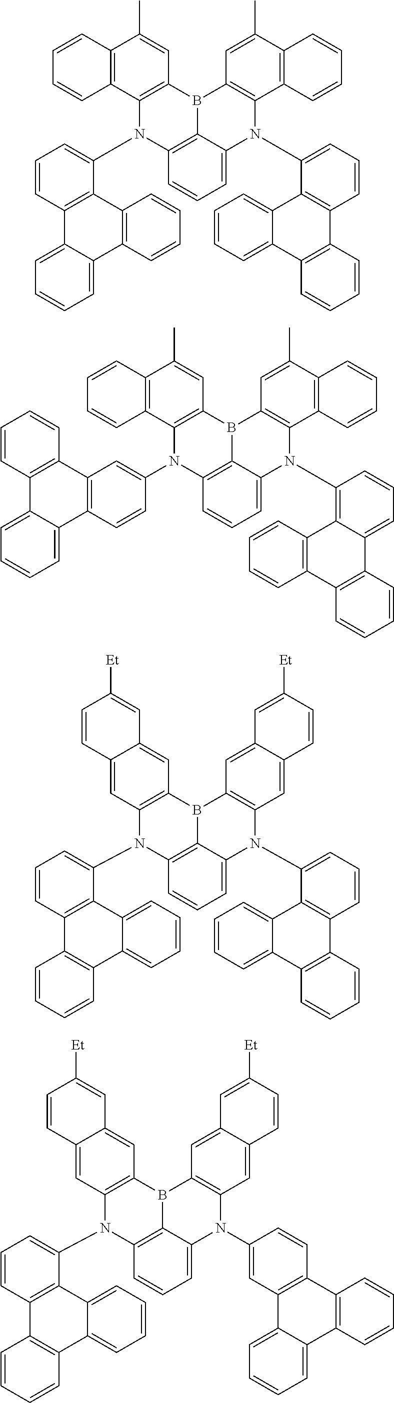

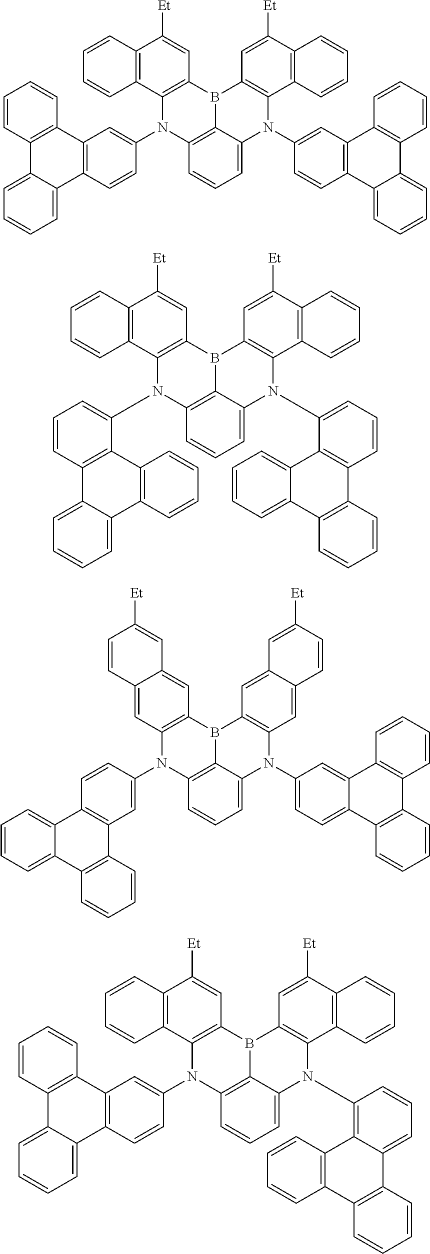 [SMILES: CCc1cc2c(c3ccccc13)N(c1ccc3c4ccccc4c4ccccc4c3c1)c1cccc3c1B2c1cc(CC)c2ccccc2c1N3c1ccc2c3ccccc3c3ccccc3c2c1 ; CCc1cc2c(c3ccccc13)N(c1cccc3c4ccccc4c4ccccc4c13)c1cccc3c1B2c1cc(CC)c2ccccc2c1N3c1cccc2c3ccccc3c3ccccc3c12 ; CCc1ccc2cc3c(cc2c1)B1c2cc4cc(CC)ccc4cc2N(c2ccc4c5ccccc5c5ccccc5c4c2)c2cccc(c21)N3c1ccc2c3ccccc3c3ccccc3c2c1 ; CCc1cc2c(c3ccccc13)N(c1ccc3c4ccccc4c4ccccc4c3c1)c1cccc3c1B2c1cc(CC)c2ccccc2c1N3c1cccc2c3ccccc3c3ccccc3c12]

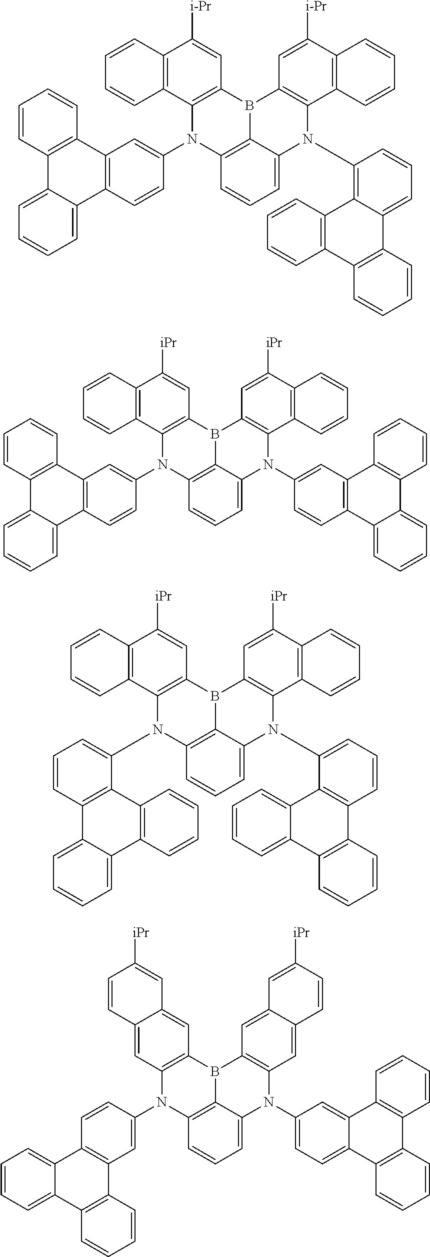 [SMILES: CC(C)c1cc2c(c3ccccc13)N(c1ccc3c4ccccc4c4ccccc4c3c1)c1cccc3c1B2c1cc(C(C)C)c2ccccc2c1N3c1cccc2c3ccccc3c3ccccc3c12 ; CC(C)c1cc2c(c3ccccc13)N(c1ccc3c4ccccc4c4ccccc4c3c1)c1cccc3c1B2c1cc(C(C)C)c2ccccc2c1N3c1ccc2c3ccccc3c3ccccc3c2c1 ; CC(C)c1cc2c(c3ccccc13)N(c1cccc3c4ccccc4c4ccccc4c13)c1cccc3c1B2c1cc(C(C)C)c2ccccc2c1N3c1cccc2c3ccccc3c3ccccc3c12 ; CC(C)c1ccc2cc3c(cc2c1)B1c2cc4cc(C(C)C)ccc4cc2N(c2ccc4c5ccccc5c5ccccc5c4c2)c2cccc(c21)N3c1ccc2c3ccccc3c3ccccc3c2c1]

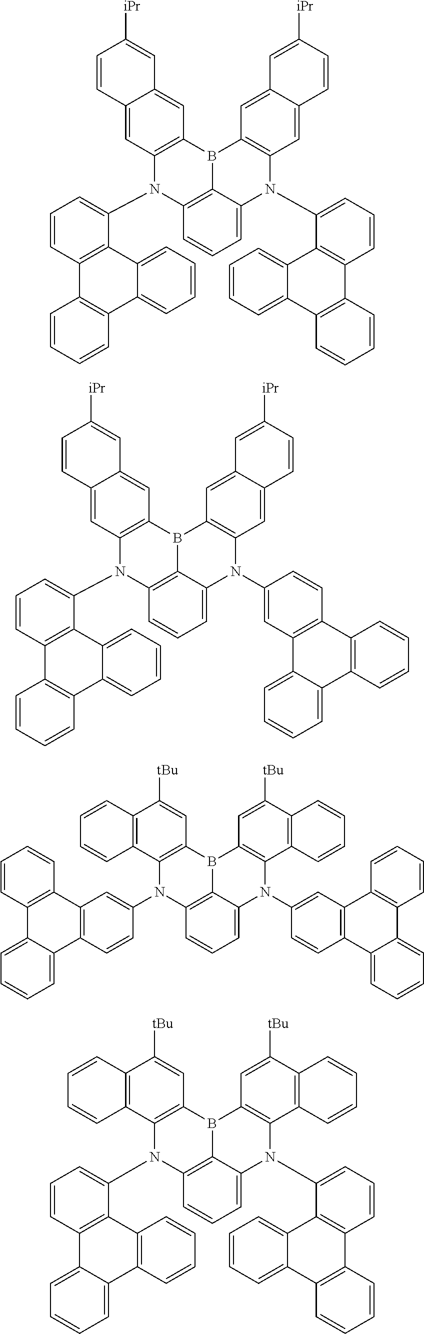

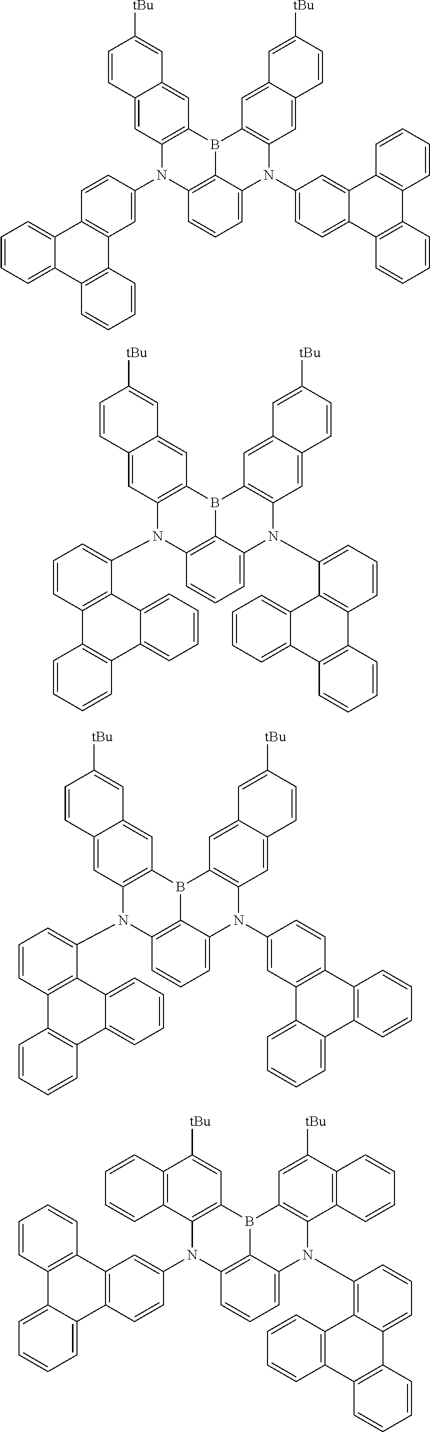

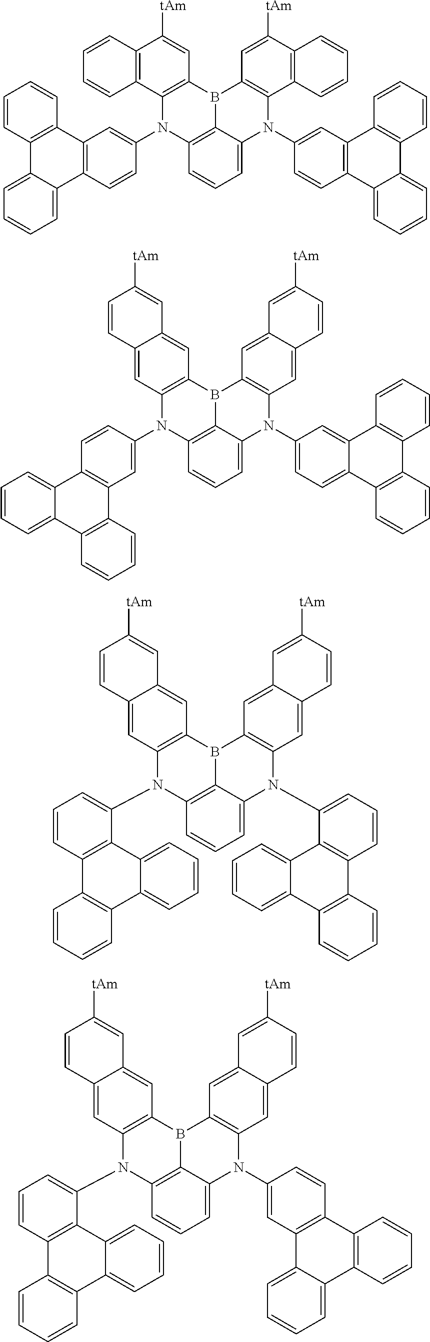

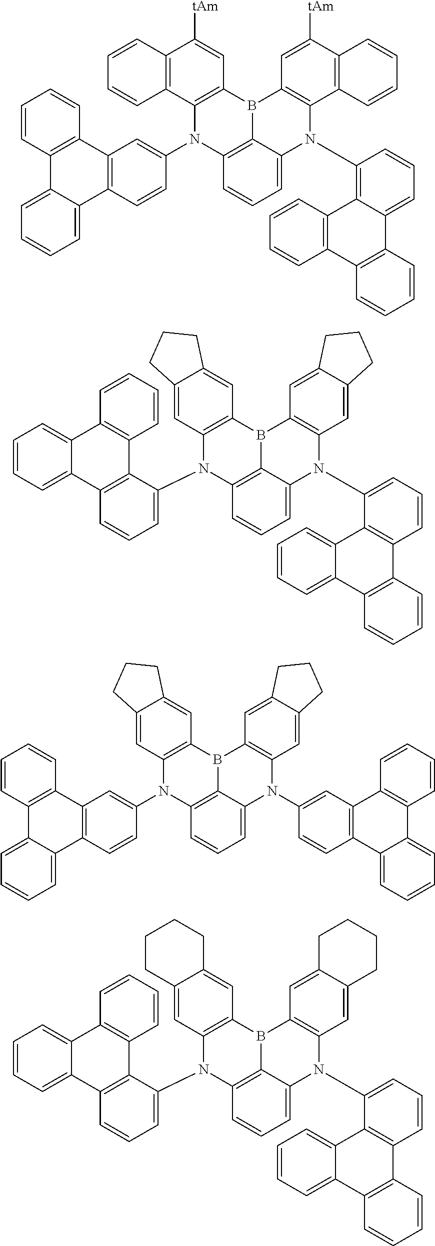

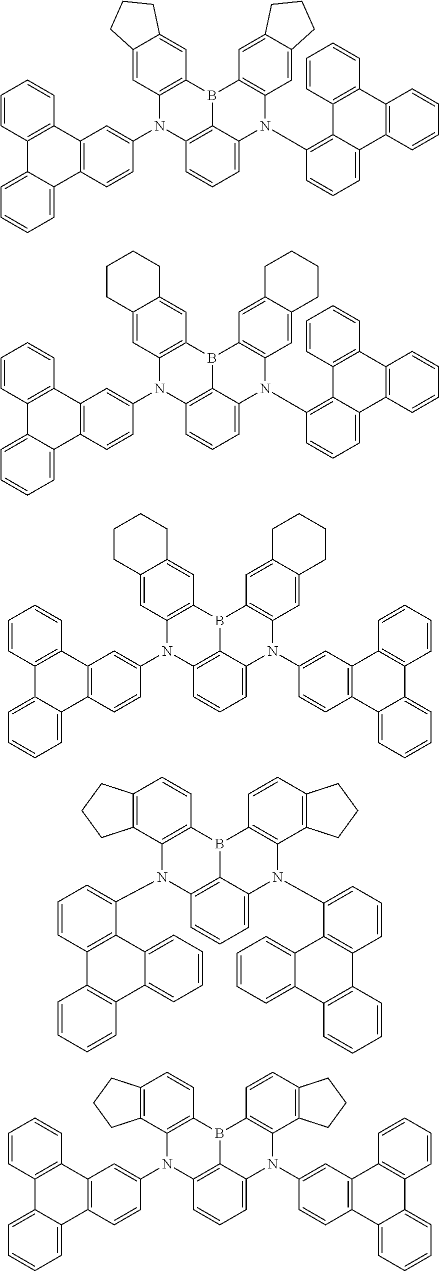

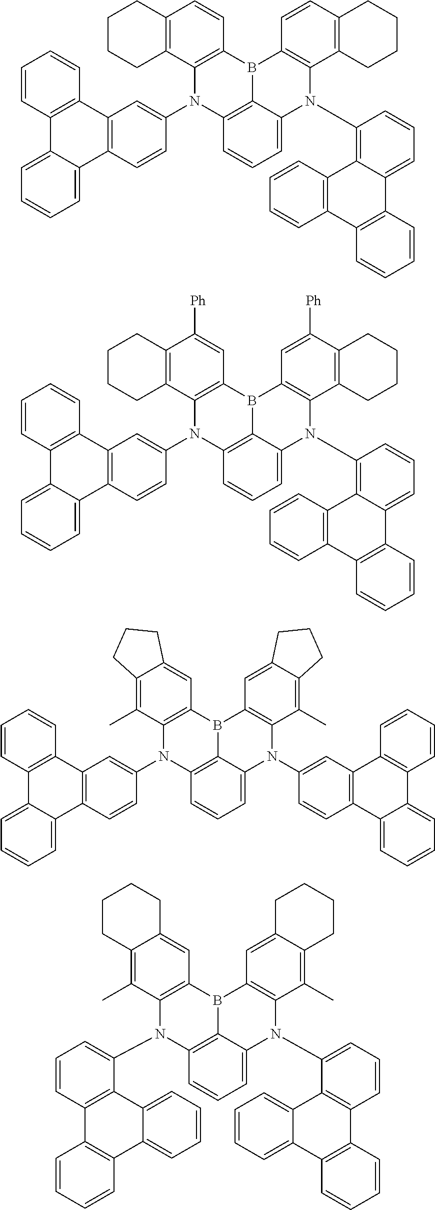 [SMILES: c1cc2c3c(c1)N(c1cccc4c5ccccc5c5ccccc5c14)c1c(ccc4c1CCCC4)B3c1ccc3c(c1N2c1ccc2c4ccccc4c4ccccc4c2c1)CCCC3 ; c1ccc(-c2cc3c(c4c2CCCC4)N(c2ccc4c5ccccc5c5ccccc5c4c2)c2cccc4c2B3c2cc(-c3ccccc3)c3c(c2N4c2cccc4c5ccccc5c5ccccc5c24)CCCC3)cc1 ; Cc1c2c(cc3c1N(c1ccc4c5ccccc5c5ccccc5c4c1)c1cccc4c1B3c1cc3c(c(C)c1N4c1ccc4c5ccccc5c5ccccc5c4c1)CCC3)CCC2 ; Cc1c2c(cc3c1N(c1cccc4c5ccccc5c5ccccc5c14)c1cccc4c1B3c1cc3c(c(C)c1N4c1cccc4c5ccccc5c5ccccc5c14)CCCC3)CCCC2]

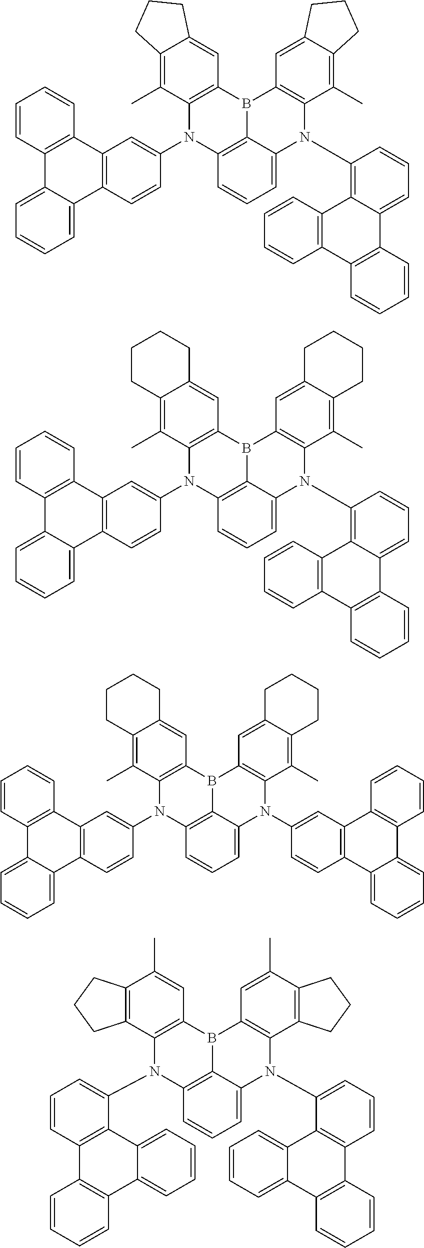

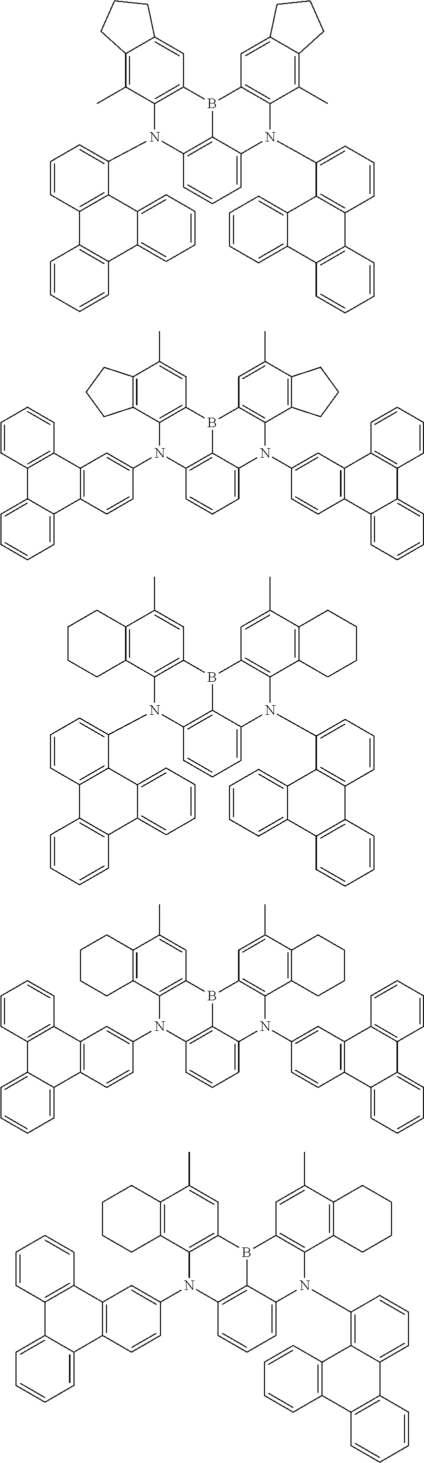

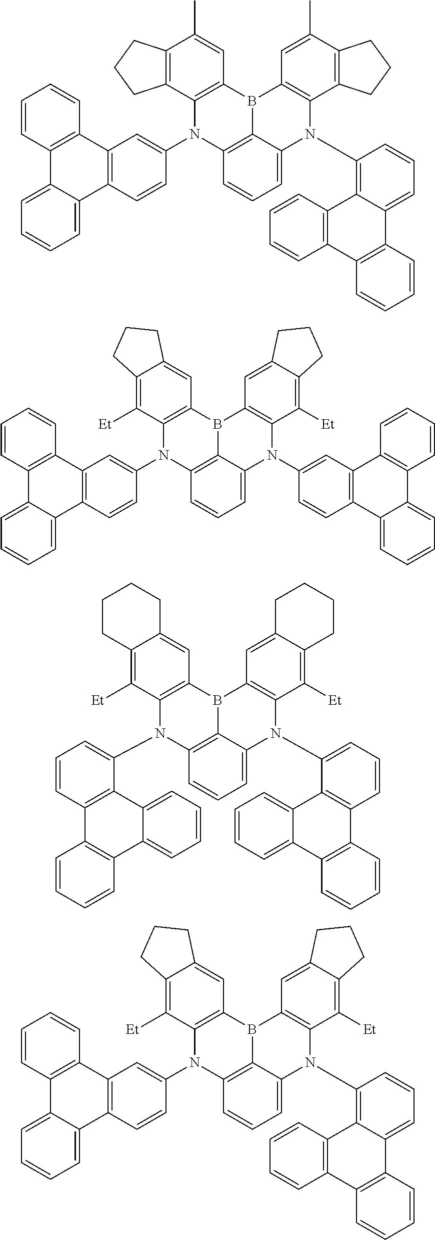

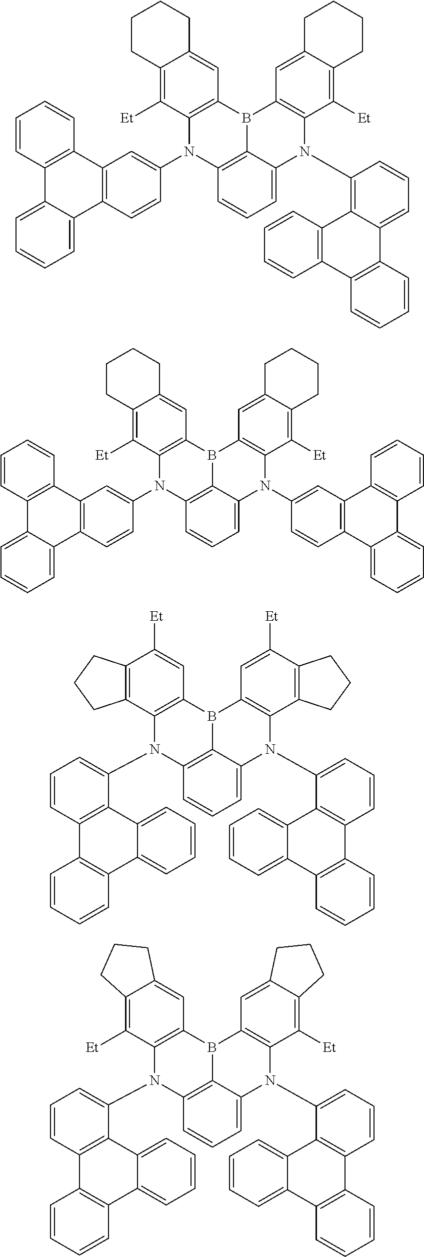

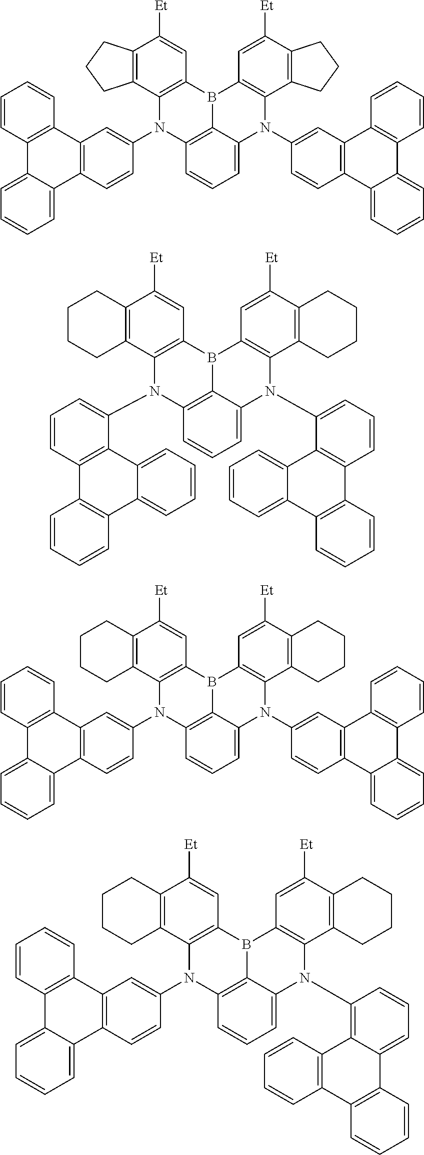 [SMILES: CCc1cc2c(c3c1CCC3)N(c1ccc3c4ccccc4c4ccccc4c3c1)c1cccc3c1B2c1cc(CC)c2c(c1N3c1ccc3c4ccccc4c4ccccc4c3c1)CCC2 ; CCc1cc2c(c3c1CCCC3)N(c1cccc3c4ccccc4c4ccccc4c13)c1cccc3c1B2c1cc(CC)c2c(c1N3c1cccc3c4ccccc4c4ccccc4c13)CCCC2 ; CCc1cc2c(c3c1CCCC3)N(c1ccc3c4ccccc4c4ccccc4c3c1)c1cccc3c1B2c1cc(CC)c2c(c1N3c1ccc3c4ccccc4c4ccccc4c3c1)CCCC2 ; CCc1cc2c(c3c1CCCC3)N(c1ccc3c4ccccc4c4ccccc4c3c1)c1cccc3c1B2c1cc(CC)c2c(c1N3c1cccc3c4ccccc4c4ccccc4c13)CCCC2]

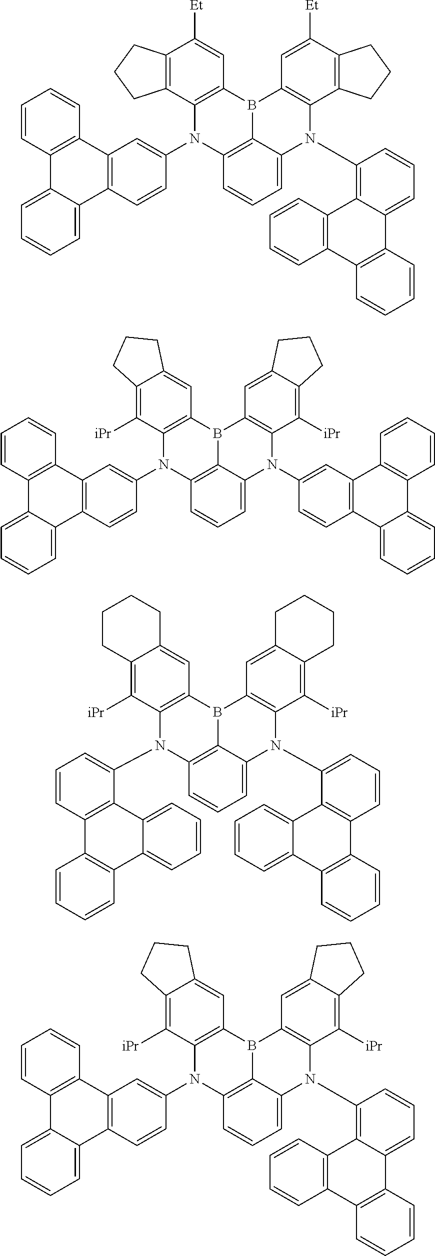

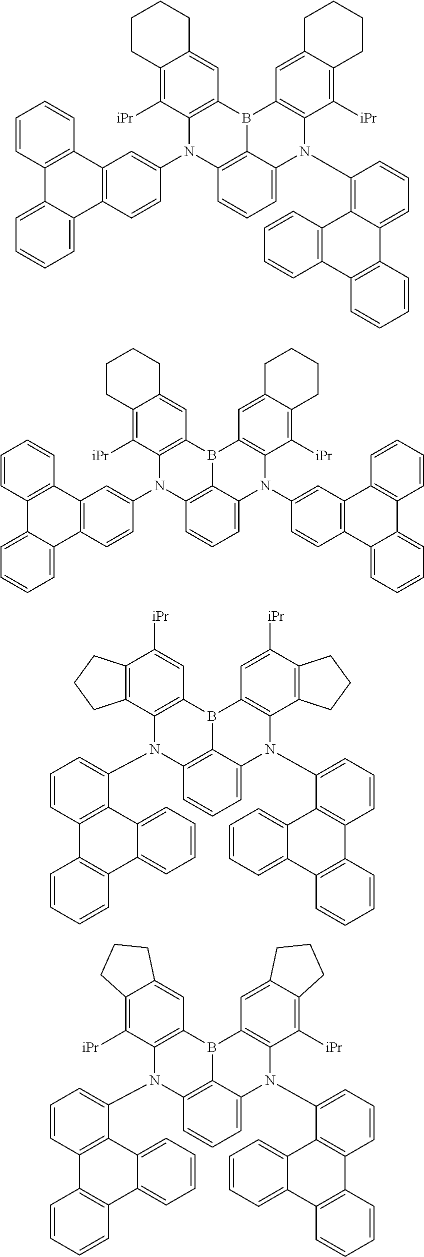

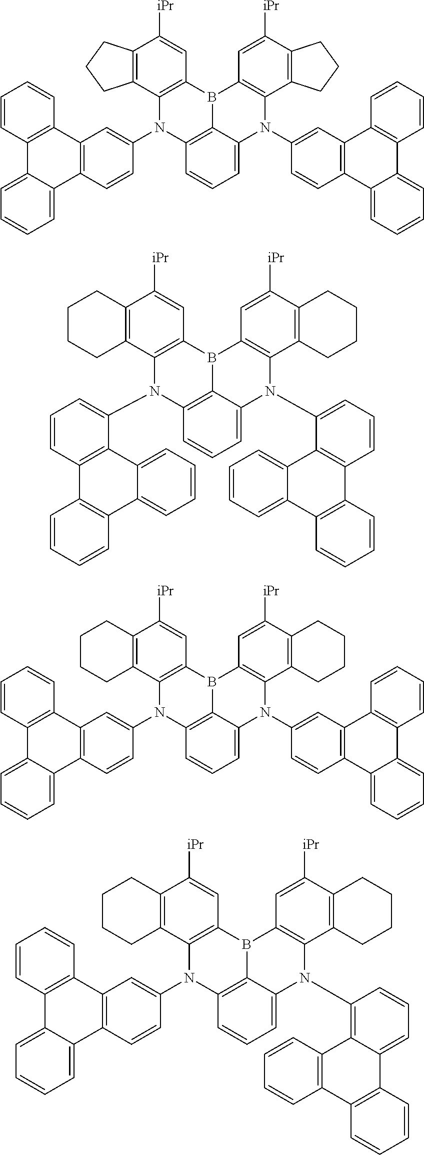 [SMILES: CC(C)c1cc2c(c3c1CCC3)N(c1ccc3c4ccccc4c4ccccc4c3c1)c1cccc3c1B2c1cc(C(C)C)c2c(c1N3c1ccc3c4ccccc4c4ccccc4c3c1)CCC2 ; CC(C)c1cc2c(c3c1CCCC3)N(c1cccc3c4ccccc4c4ccccc4c13)c1cccc3c1B2c1cc(C(C)C)c2c(c1N3c1cccc3c4ccccc4c4ccccc4c13)CCCC2 ; CC(C)c1cc2c(c3c1CCCC3)N(c1ccc3c4ccccc4c4ccccc4c3c1)c1cccc3c1B2c1cc(C(C)C)c2c(c1N3c1ccc3c4ccccc4c4ccccc4c3c1)CCCC2 ; CC(C)c1cc2c(c3c1CCCC3)N(c1ccc3c4ccccc4c4ccccc4c3c1)c1cccc3c1B2c1cc(C(C)C)c2c(c1N3c1cccc3c4ccccc4c4ccccc4c13)CCCC2]

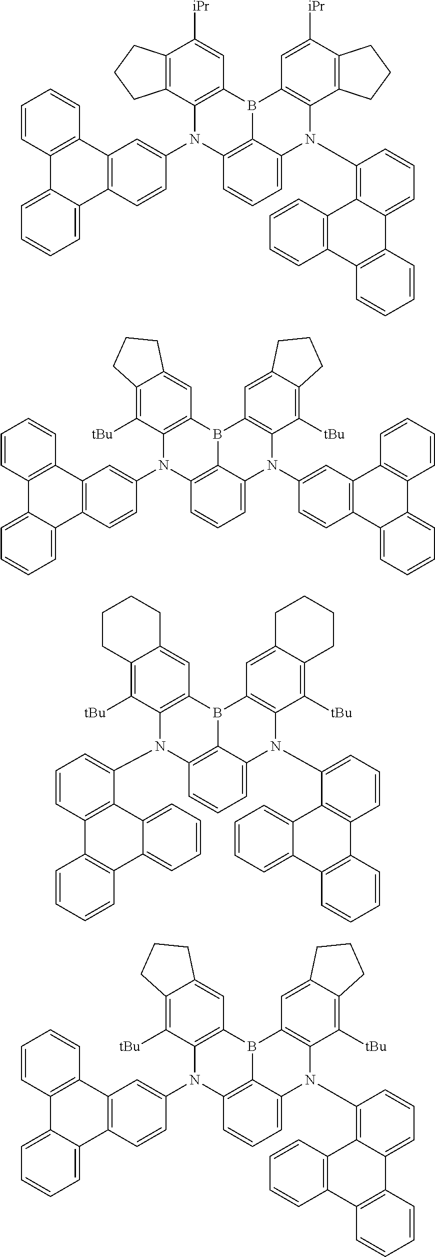

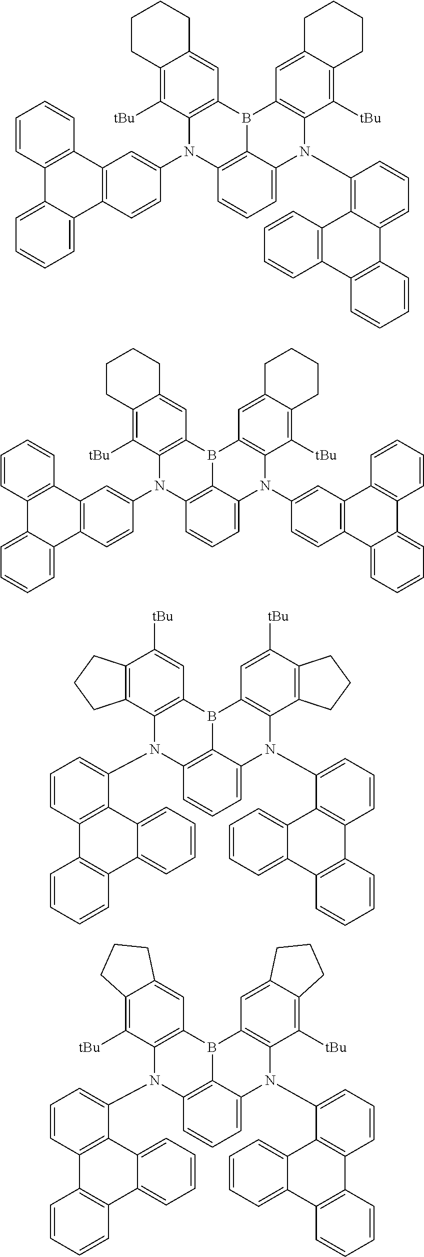

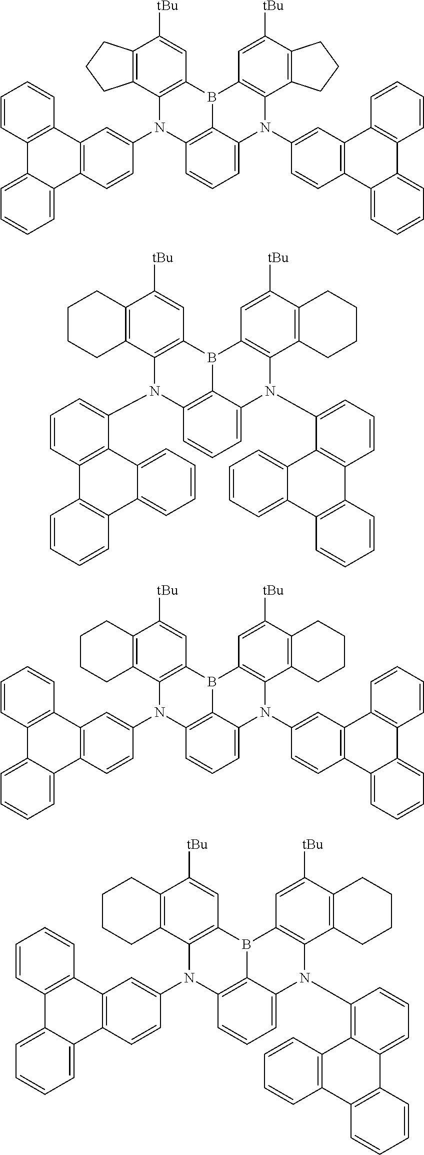 [SMILES: CC(C)(C)c1cc2c(c3c1CCC3)N(c1ccc3c4ccccc4c4ccccc4c3c1)c1cccc3c1B2c1cc(C(C)(C)C)c2c(c1N3c1ccc3c4ccccc4c4ccccc4c3c1)CCC2 ; CC(C)(C)c1cc2c(c3c1CCCC3)N(c1cccc3c4ccccc4c4ccccc4c13)c1cccc3c1B2c1cc(C(C)(C)C)c2c(c1N3c1cccc3c4ccccc4c4ccccc4c13)CCCC2 ; CC(C)(C)c1cc2c(c3c1CCCC3)N(c1ccc3c4ccccc4c4ccccc4c3c1)c1cccc3c1B2c1cc(C(C)(C)C)c2c(c1N3c1ccc3c4ccccc4c4ccccc4c3c1)CCCC2 ; CC(C)(C)c1cc2c(c3c1CCCC3)N(c1ccc3c4ccccc4c4ccccc4c3c1)c1cccc3c1B2c1cc(C(C)(C)C)c2c(c1N3c1cccc3c4ccccc4c4ccccc4c13)CCCC2]

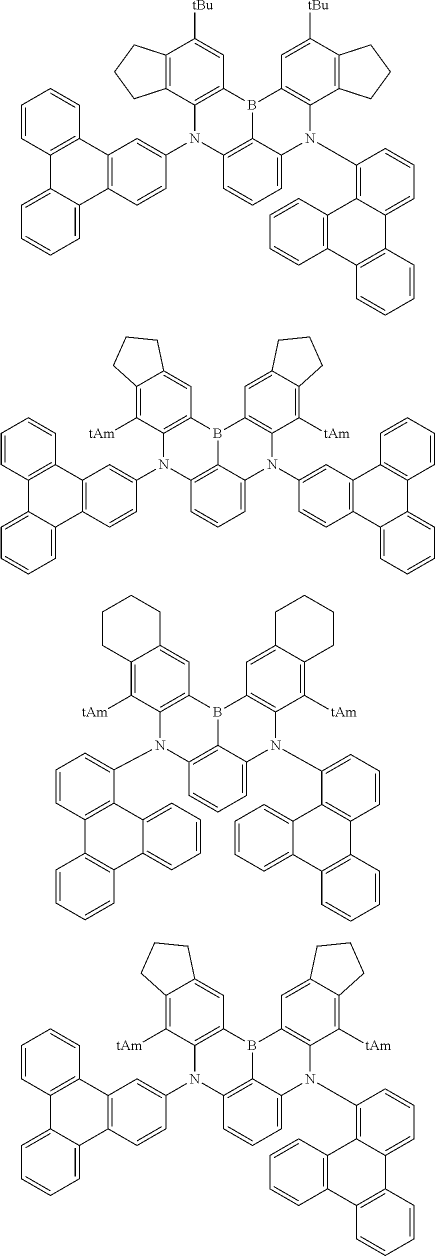

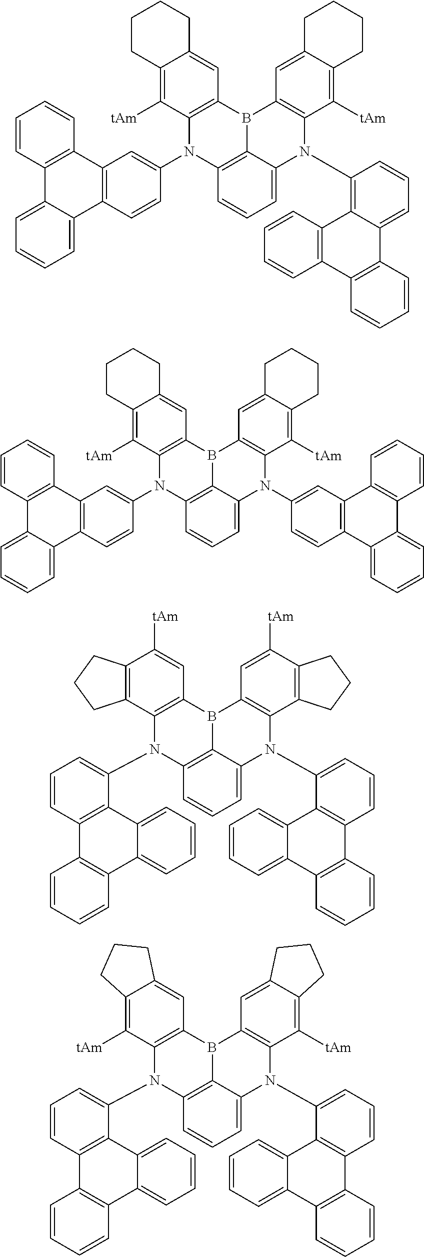

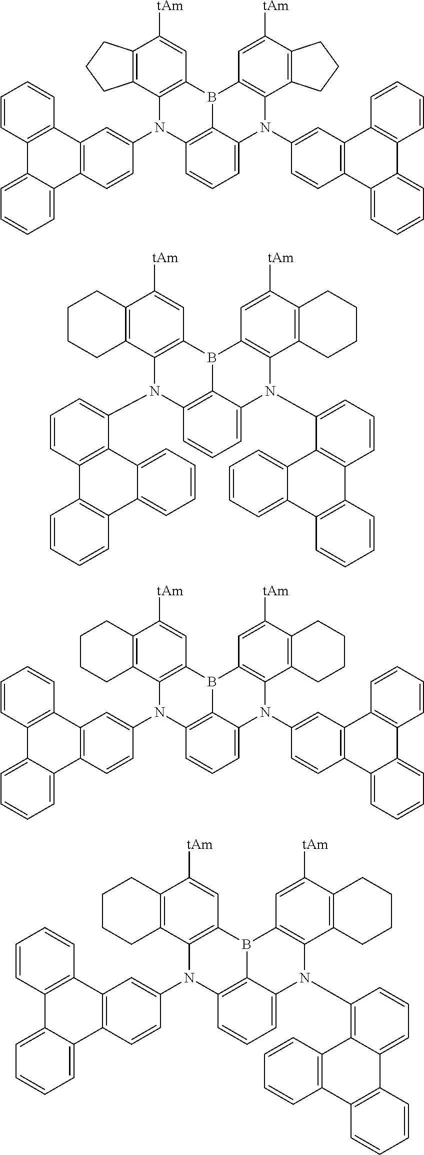

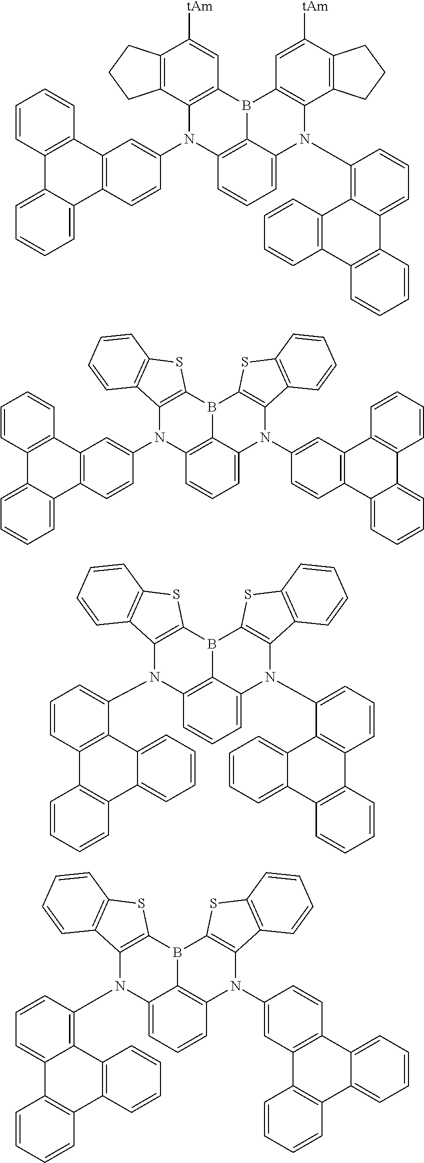

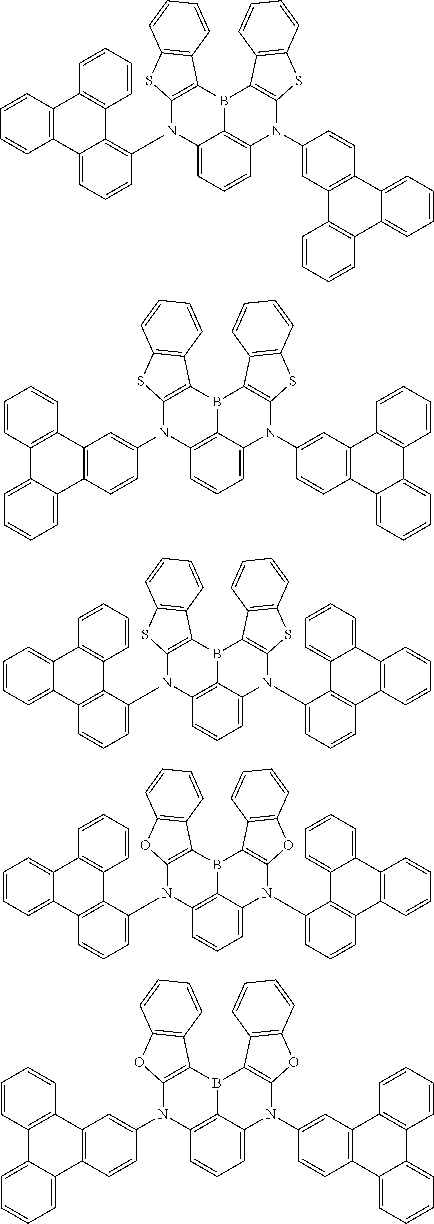

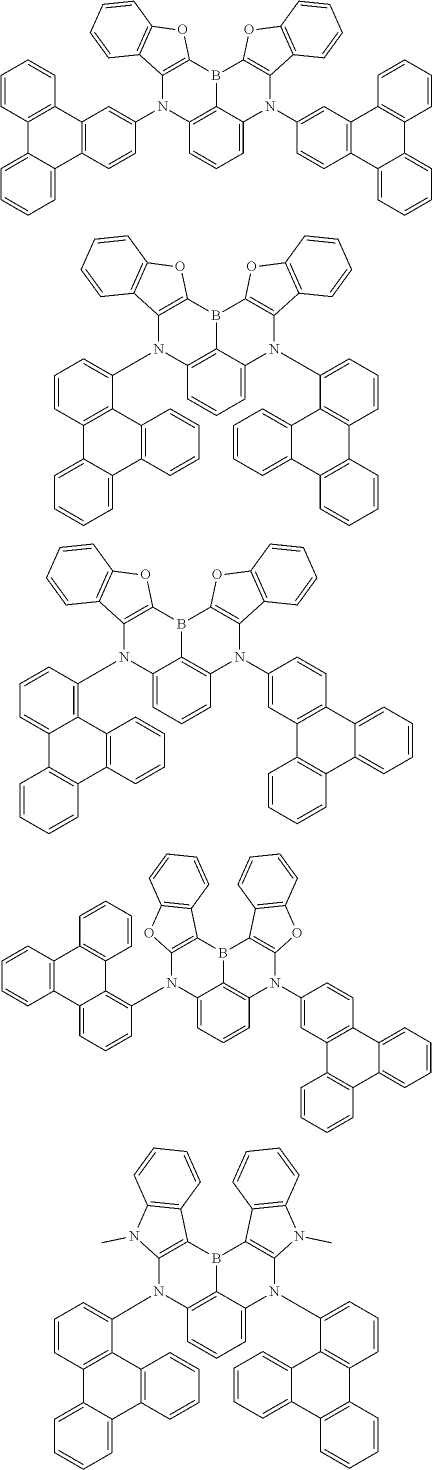

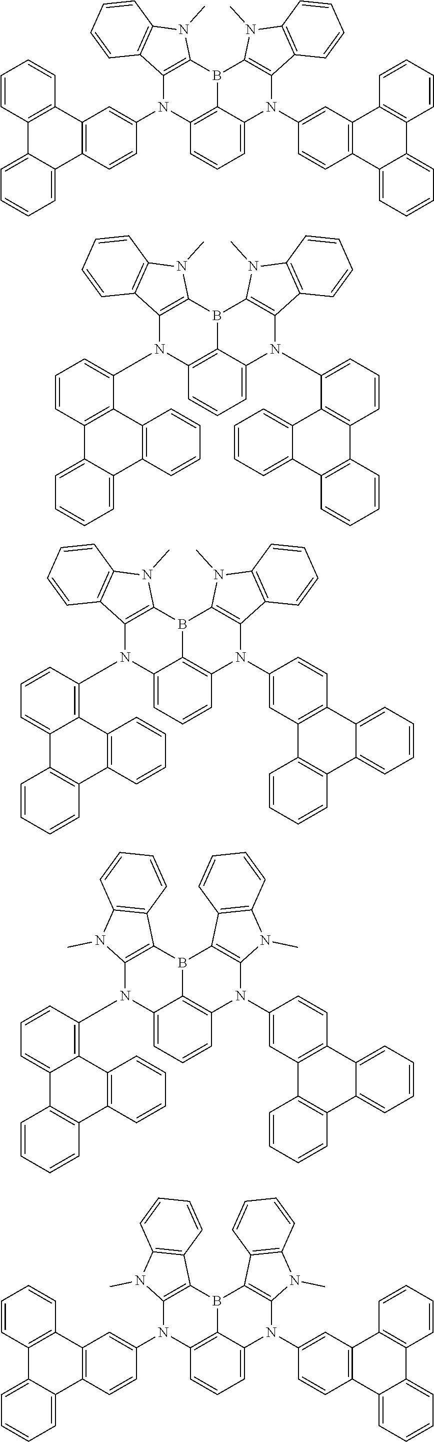

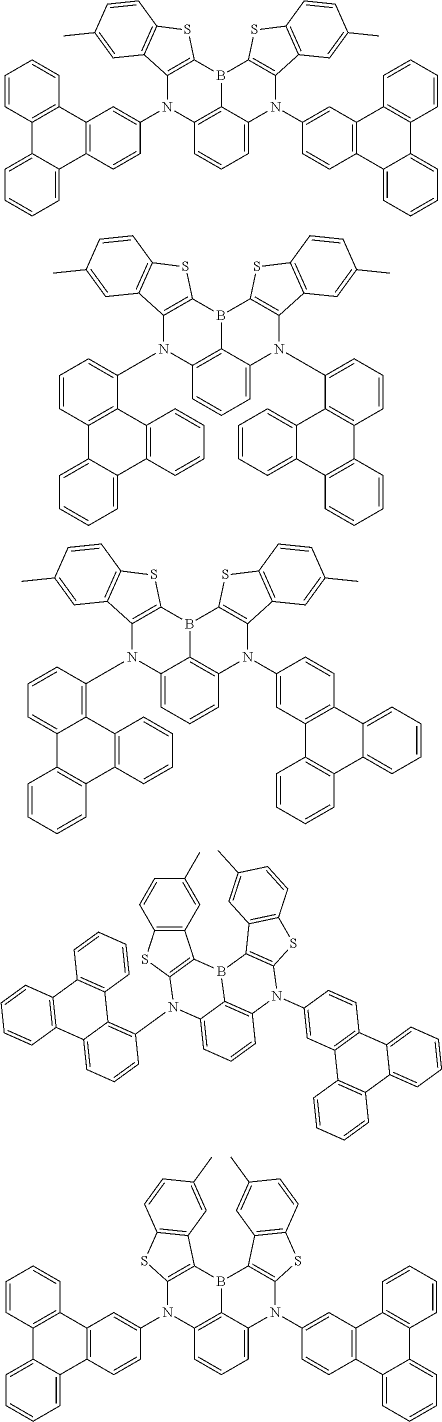

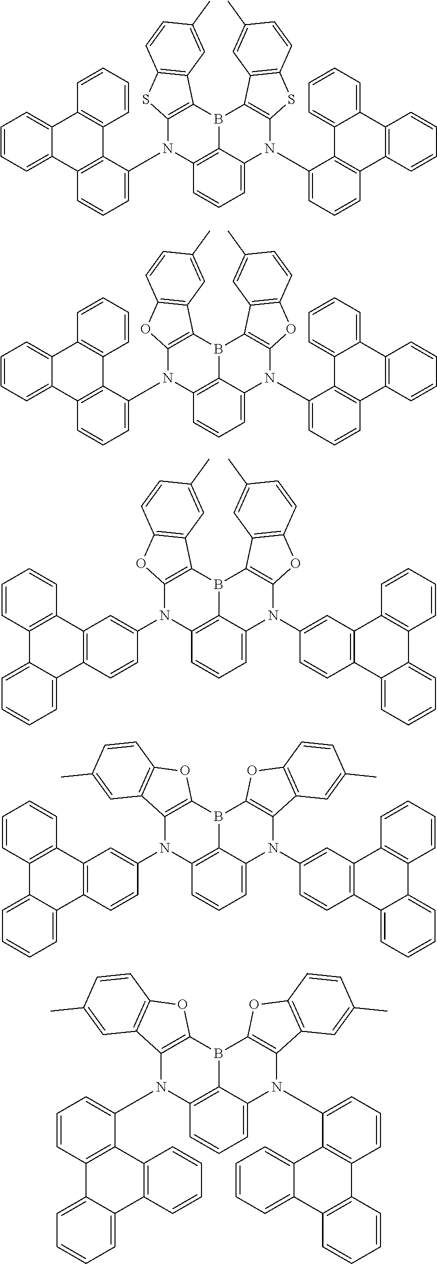

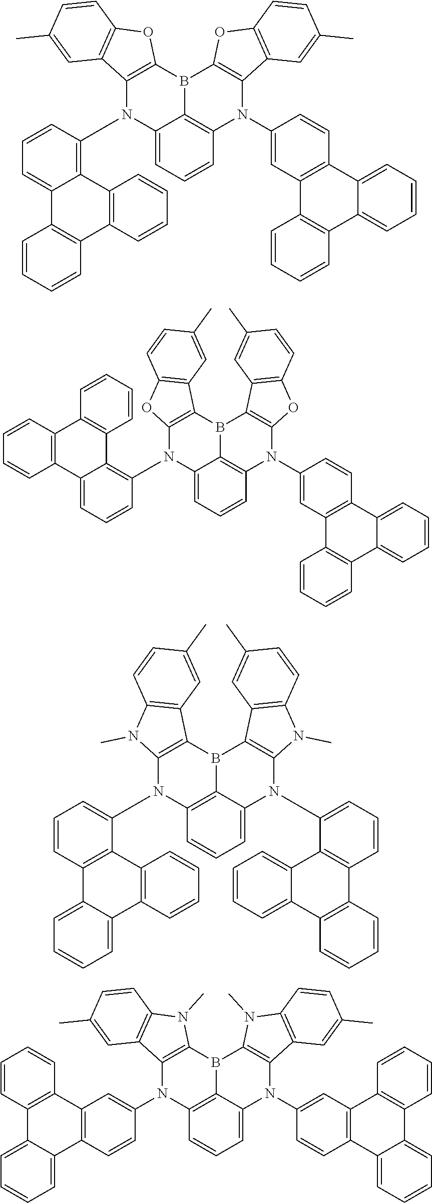

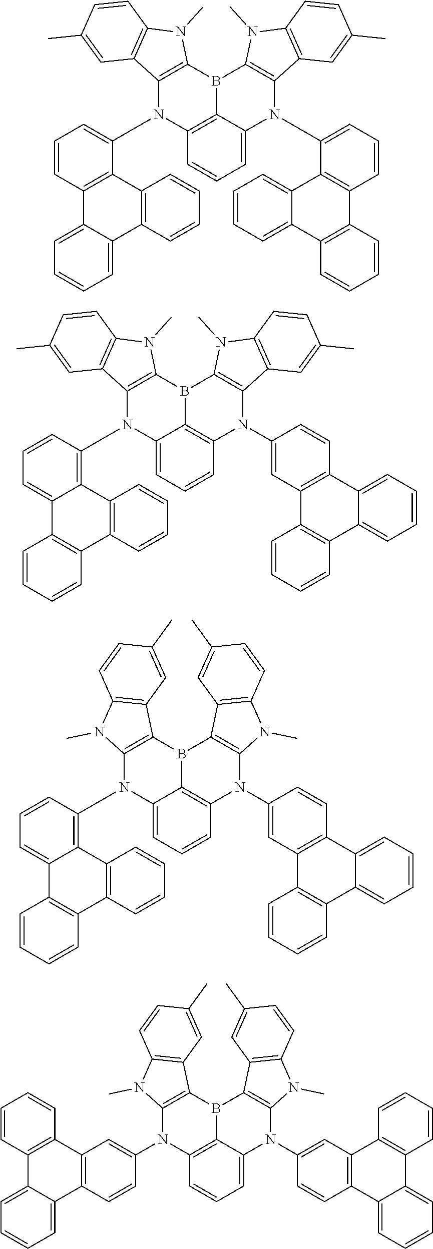

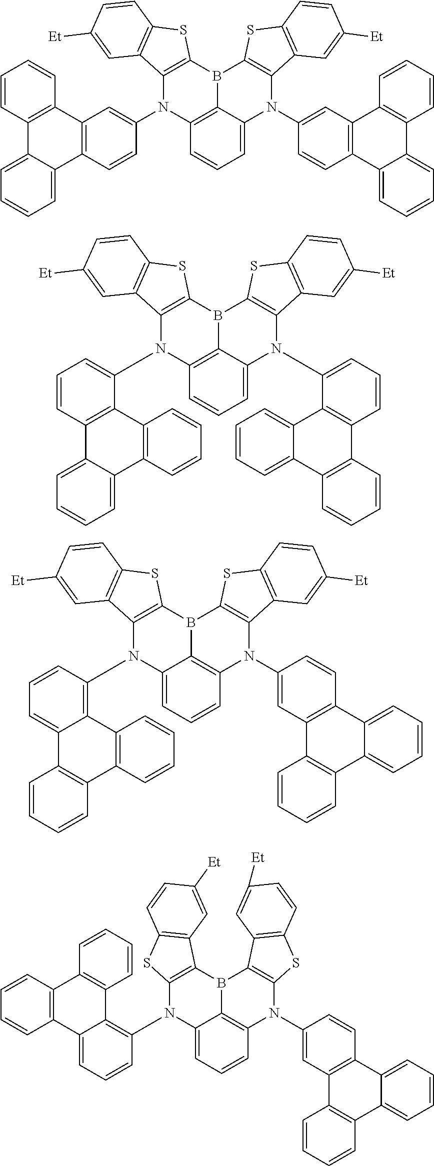

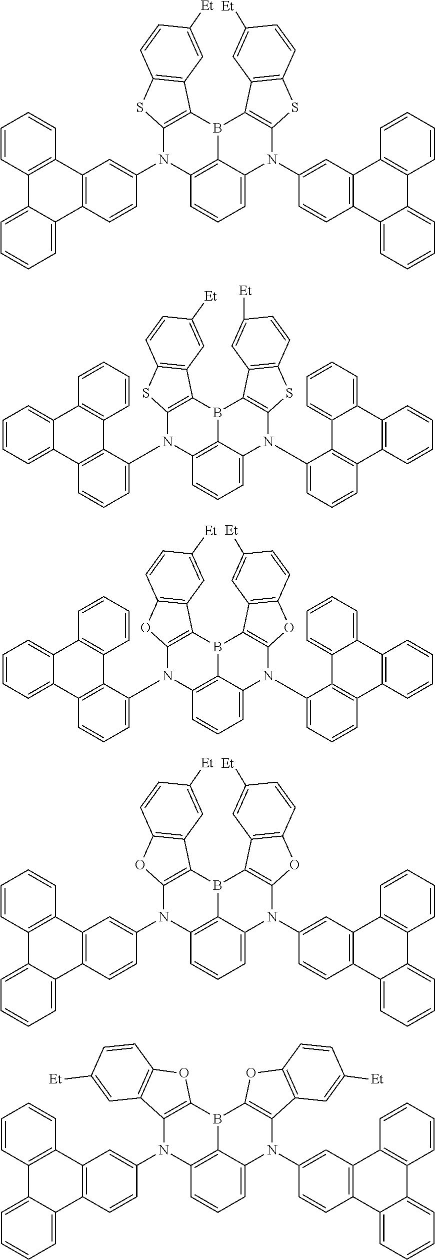

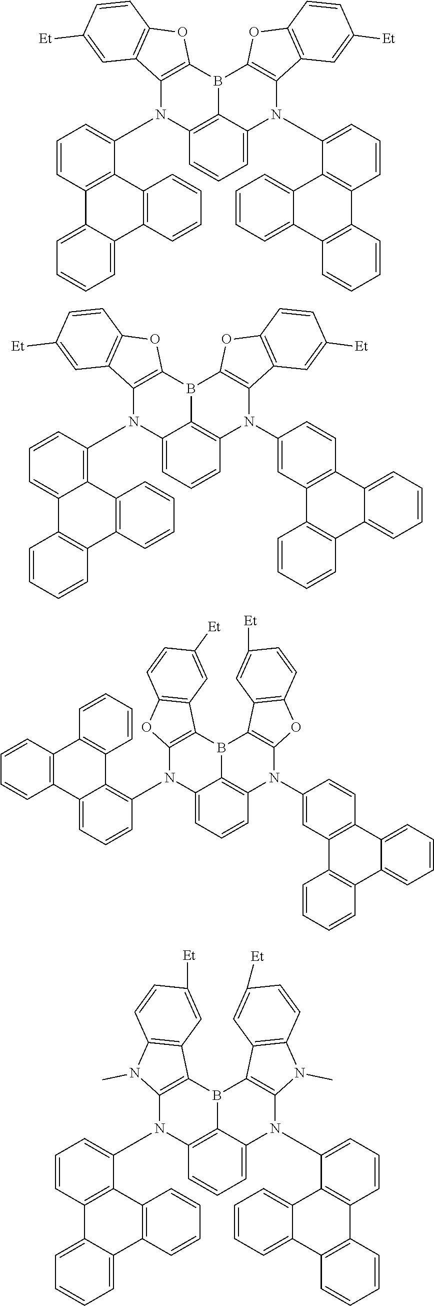

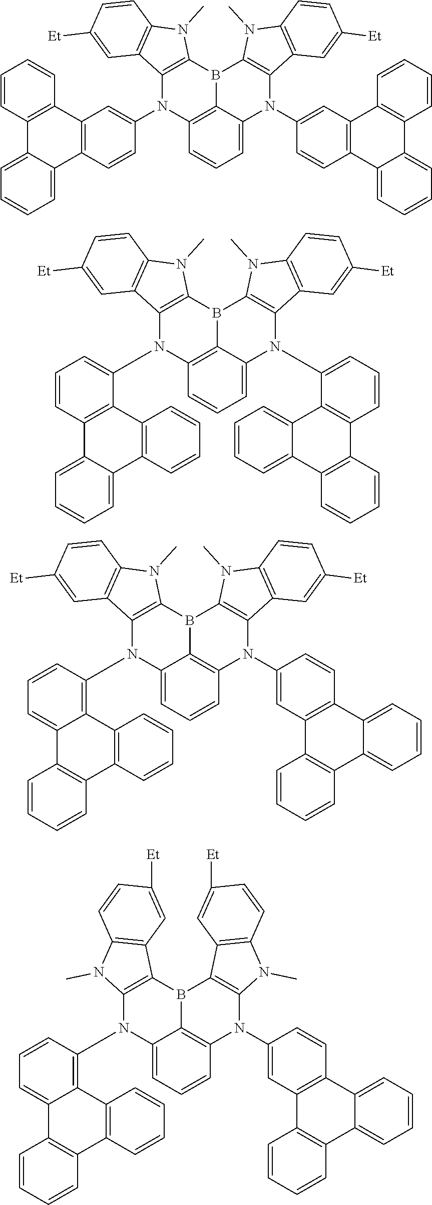

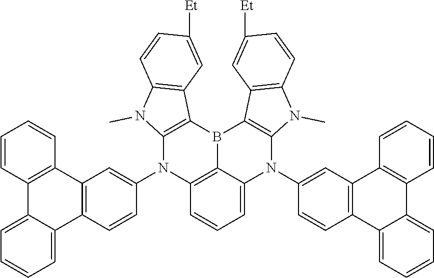 [SMILES: CCc1ccc2c(c1)c1c(n2C)N(c2ccc3c4ccccc4c4ccccc4c3c2)c2cccc3c2B1c1c(n(C)c2ccc(CC)cc12)N3c1ccc2c3ccccc3c3ccccc3c2c1]

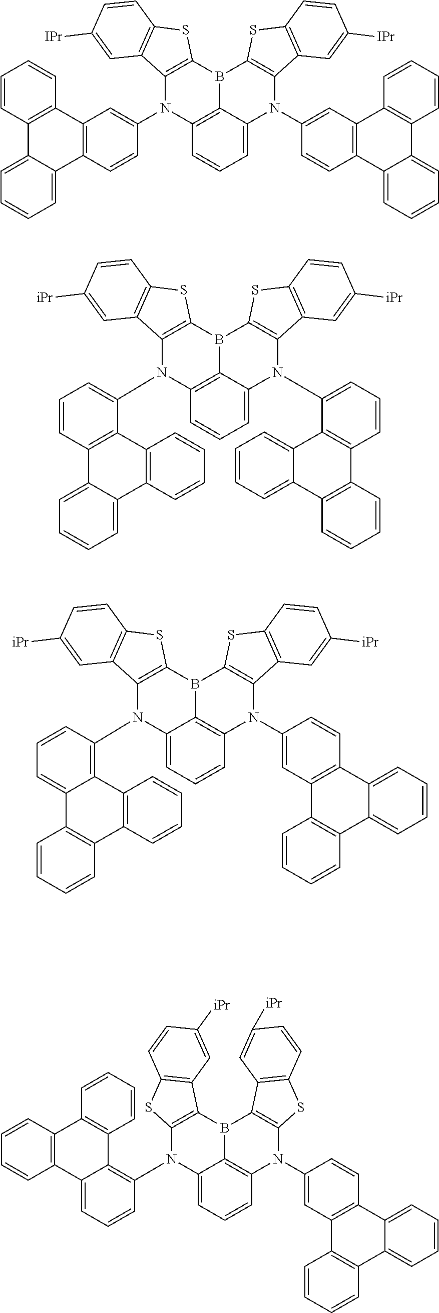

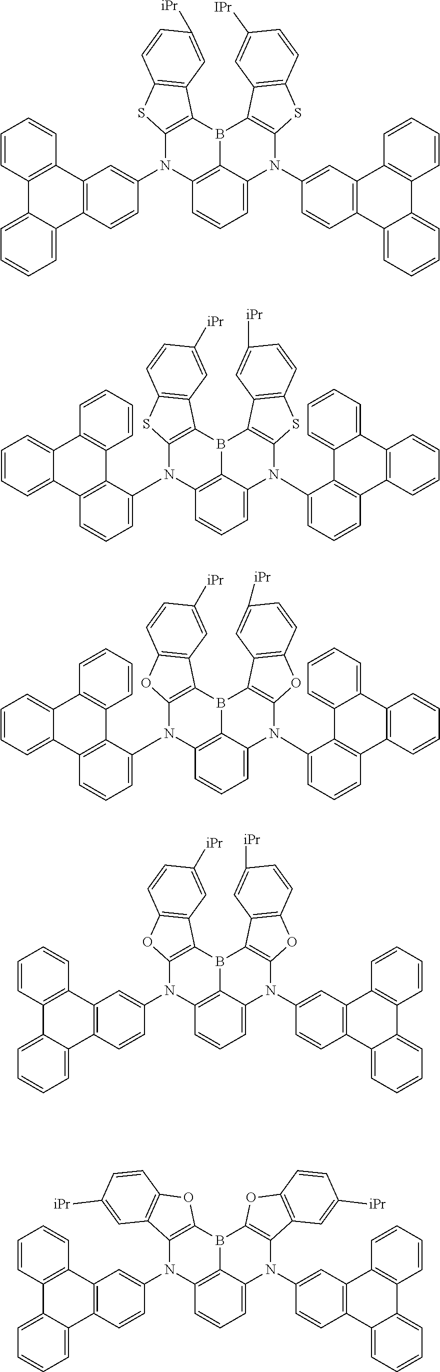

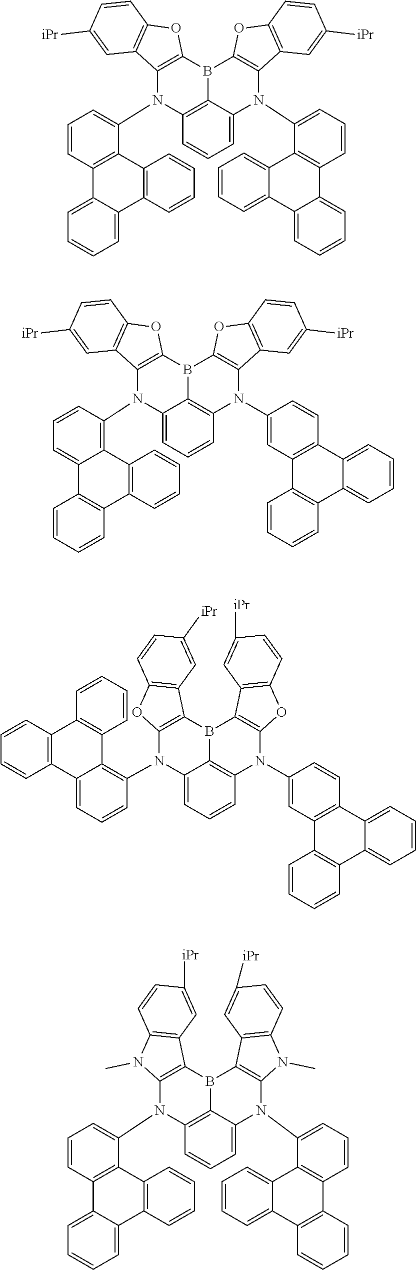 [SMILES: CC(C)c1ccc2oc3c(c2c1)N(c1cccc2c4ccccc4c4ccccc4c12)c1cccc2c1B3c1oc3ccc(C(C)C)cc3c1N2c1cccc2c3ccccc3c3ccccc3c12 ; CC(C)c1ccc2oc3c(c2c1)N(c1ccc2c4ccccc4c4ccccc4c2c1)c1cccc2c1B3c1oc3ccc(C(C)C)cc3c1N2c1cccc2c3ccccc3c3ccccc3c12 ; CC(C)c1ccc2oc3c(c2c1)B1c2c(cccc2N(c2cccc4c5ccccc5c5ccccc5c24)c2oc4ccc(C(C)C)cc4c21)N3c1ccc2c3ccccc3c3ccccc3c2c1 ; CC(C)c1ccc2c(c1)c1c(n2C)N(c2cccc3c4ccccc4c4ccccc4c23)c2cccc3c2B1c1c(n(C)c2ccc(C(C)C)cc12)N3c1cccc2c3ccccc3c3ccccc3c12]

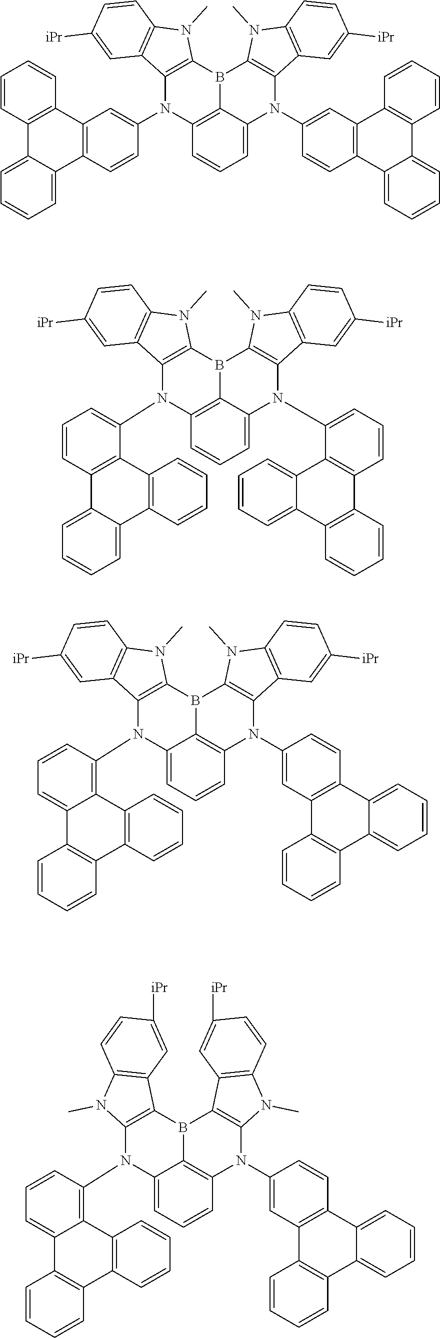 [SMILES: CC(C)c1ccc2c(c1)c1c(n2C)B2c3c(cccc3N(c3ccc4c5ccccc5c5ccccc5c4c3)c3c2n(C)c2ccc(C(C)C)cc32)N1c1ccc2c3ccccc3c3ccccc3c2c1 ; CC(C)c1ccc2c(c1)c1c(n2C)B2c3c(cccc3N(c3cccc4c5ccccc5c5ccccc5c34)c3c2n(C)c2ccc(C(C)C)cc32)N1c1cccc2c3ccccc3c3ccccc3c12 ; CC(C)c1ccc2c(c1)c1c(n2C)B2c3c(cccc3N(c3cccc4c5ccccc5c5ccccc5c34)c3c2n(C)c2ccc(C(C)C)cc32)N1c1ccc2c3ccccc3c3ccccc3c2c1 ; CC(C)c1ccc2c(c1)c1c(n2C)N(c2ccc3c4ccccc4c4ccccc4c3c2)c2cccc3c2B1c1c(n(C)c2ccc(C(C)C)cc12)N3c1cccc2c3ccccc3c3ccccc3c12]

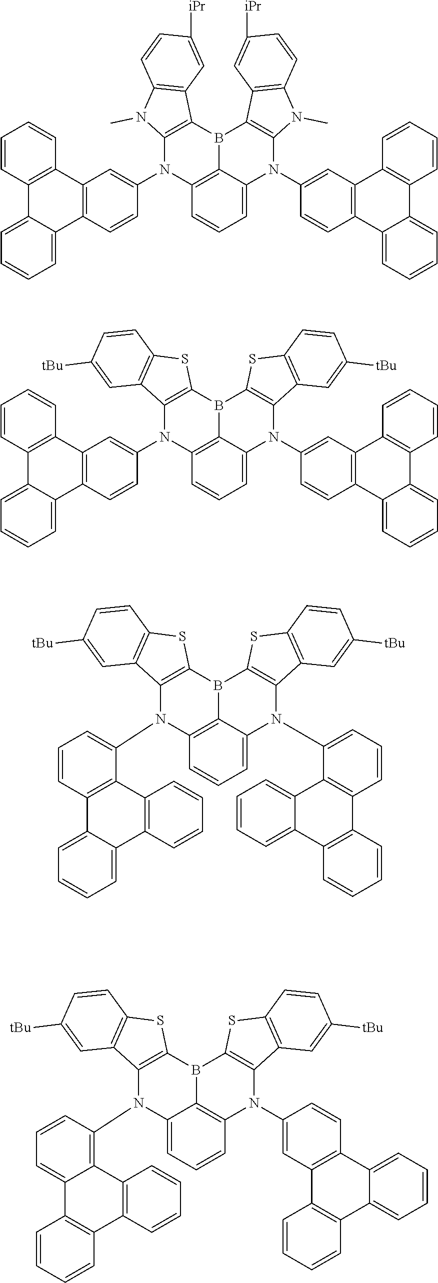 [SMILES: CC(C)c1ccc2c(c1)c1c(n2C)N(c2ccc3c4ccccc4c4ccccc4c3c2)c2cccc3c2B1c1c(n(C)c2ccc(C(C)C)cc12)N3c1ccc2c3ccccc3c3ccccc3c2c1 ; CC(C)(C)c1ccc2sc3c(c2c1)N(c1ccc2c4ccccc4c4ccccc4c2c1)c1cccc2c1B3c1sc3ccc(C(C)(C)C)cc3c1N2c1ccc2c3ccccc3c3ccccc3c2c1 ; CC(C)(C)c1ccc2sc3c(c2c1)N(c1cccc2c4ccccc4c4ccccc4c12)c1cccc2c1B3c1sc3ccc(C(C)(C)C)cc3c1N2c1cccc2c3ccccc3c3ccccc3c12 ; CC(C)(C)c1ccc2sc3c(c2c1)N(c1ccc2c4ccccc4c4ccccc4c2c1)c1cccc2c1B3c1sc3ccc(C(C)(C)C)cc3c1N2c1cccc2c3ccccc3c3ccccc3c12]

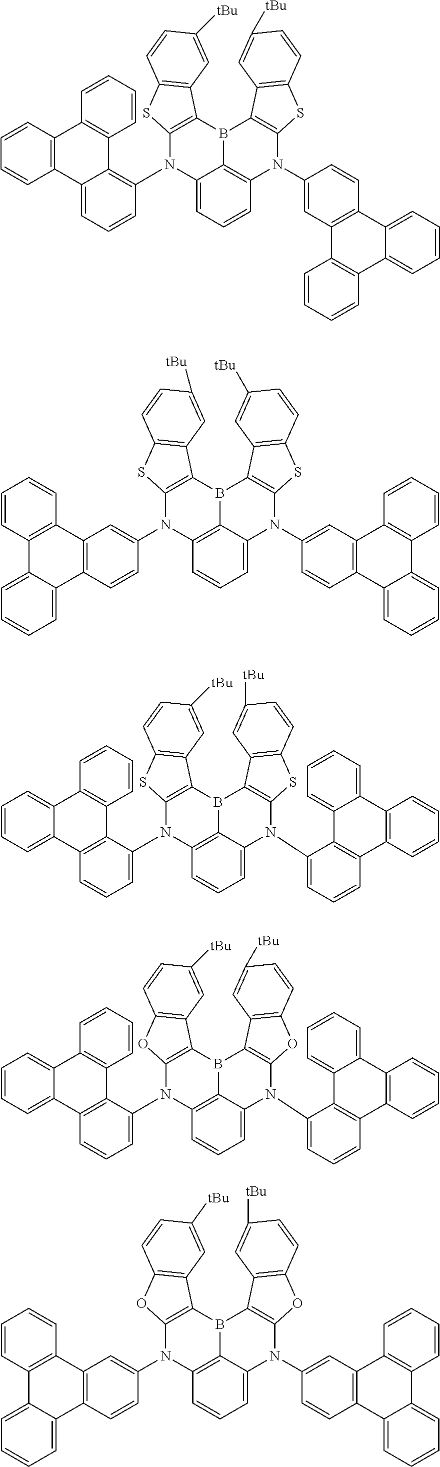

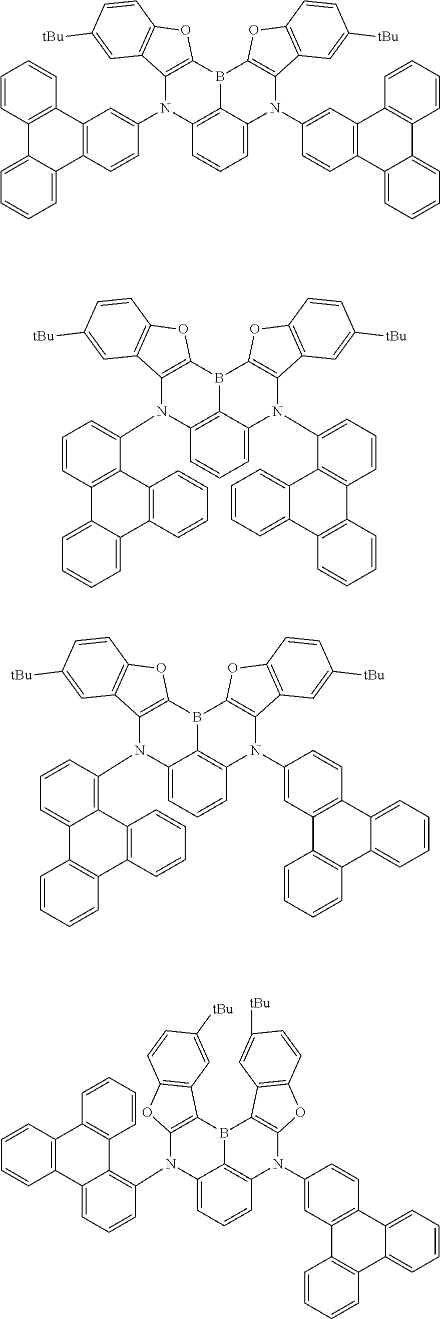 [SMILES: CC(C)(C)c1ccc2oc3c(c2c1)N(c1ccc2c4ccccc4c4ccccc4c2c1)c1cccc2c1B3c1oc3ccc(C(C)(C)C)cc3c1N2c1ccc2c3ccccc3c3ccccc3c2c1 ; CC(C)(C)c1ccc2oc3c(c2c1)N(c1cccc2c4ccccc4c4ccccc4c12)c1cccc2c1B3c1oc3ccc(C(C)(C)C)cc3c1N2c1cccc2c3ccccc3c3ccccc3c12 ; CC(C)(C)c1ccc2oc3c(c2c1)N(c1ccc2c4ccccc4c4ccccc4c2c1)c1cccc2c1B3c1oc3ccc(C(C)(C)C)cc3c1N2c1cccc2c3ccccc3c3ccccc3c12 ; CC(C)(C)c1ccc2oc3c(c2c1)B1c2c(cccc2N(c2cccc4c5ccccc5c5ccccc5c24)c2oc4ccc(C(C)(C)C)cc4c21)N3c1ccc2c3ccccc3c3ccccc3c2c1]

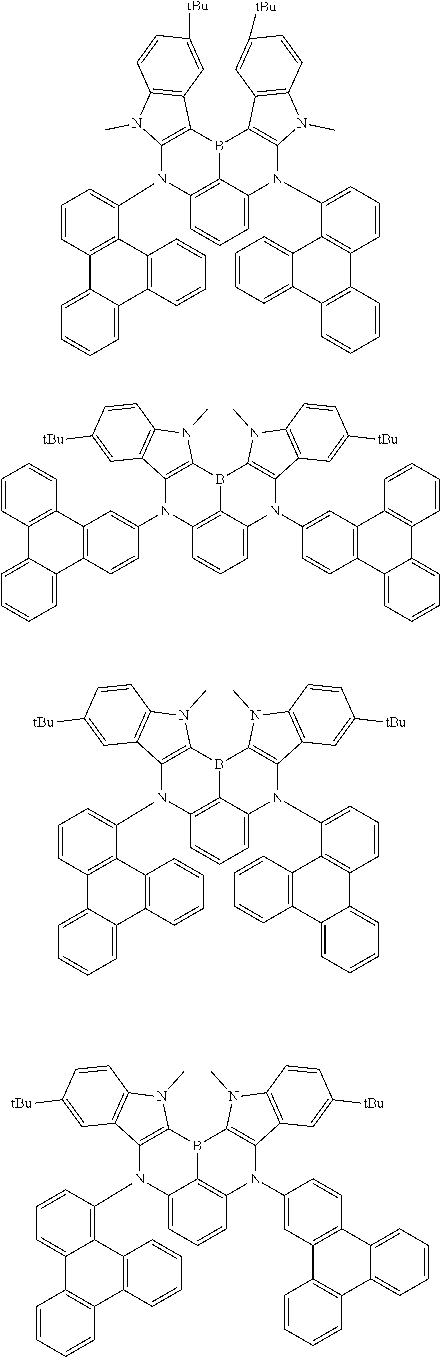 [SMILES: Cn1c2c(c3cc(C(C)(C)C)ccc31)B1c3c(cccc3N(c3cccc4c5ccccc5c5ccccc5c34)c3c1c1cc(C(C)(C)C)ccc1n3C)N2c1cccc2c3ccccc3c3ccccc3c12 ; Cn1c2c(c3cc(C(C)(C)C)ccc31)N(c1ccc3c4ccccc4c4ccccc4c3c1)c1cccc3c1B2c1c(c2cc(C(C)(C)C)ccc2n1C)N3c1ccc2c3ccccc3c3ccccc3c2c1 ; Cn1c2c(c3cc(C(C)(C)C)ccc31)N(c1cccc3c4ccccc4c4ccccc4c13)c1cccc3c1B2c1c(c2cc(C(C)(C)C)ccc2n1C)N3c1cccc2c3ccccc3c3ccccc3c12 ; Cn1c2c(c3cc(C(C)(C)C)ccc31)N(c1ccc3c4ccccc4c4ccccc4c3c1)c1cccc3c1B2c1c(c2cc(C(C)(C)C)ccc2n1C)N3c1cccc2c3ccccc3c3ccccc3c12]

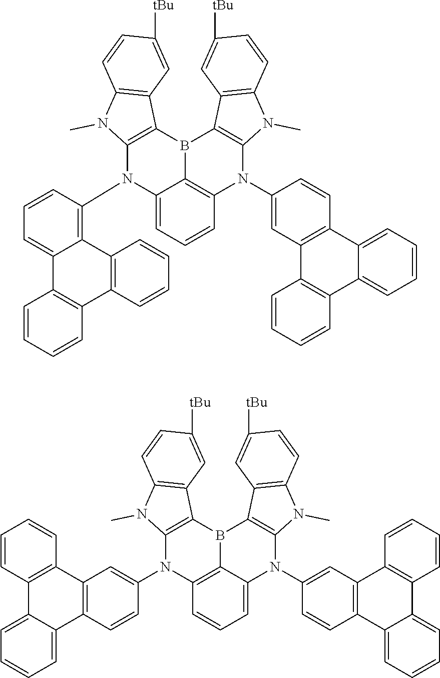 [SMILES: Cn1c2c(c3cc(C(C)(C)C)ccc31)B1c3c(cccc3N(c3cccc4c5ccccc5c5ccccc5c34)c3c1c1cc(C(C)(C)C)ccc1n3C)N2c1ccc2c3ccccc3c3ccccc3c2c1 ; Cn1c2c(c3cc(C(C)(C)C)ccc31)B1c3c(cccc3N(c3ccc4c5ccccc5c5ccccc5c4c3)c3c1c1cc(C(C)(C)C)ccc1n3C)N2c1ccc2c3ccccc3c3ccccc3c2c1]

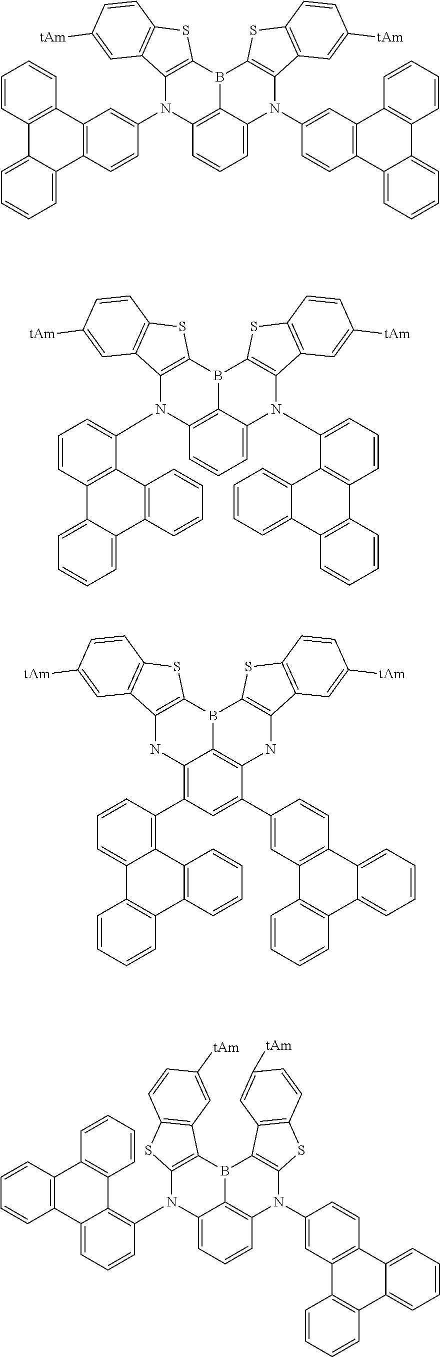

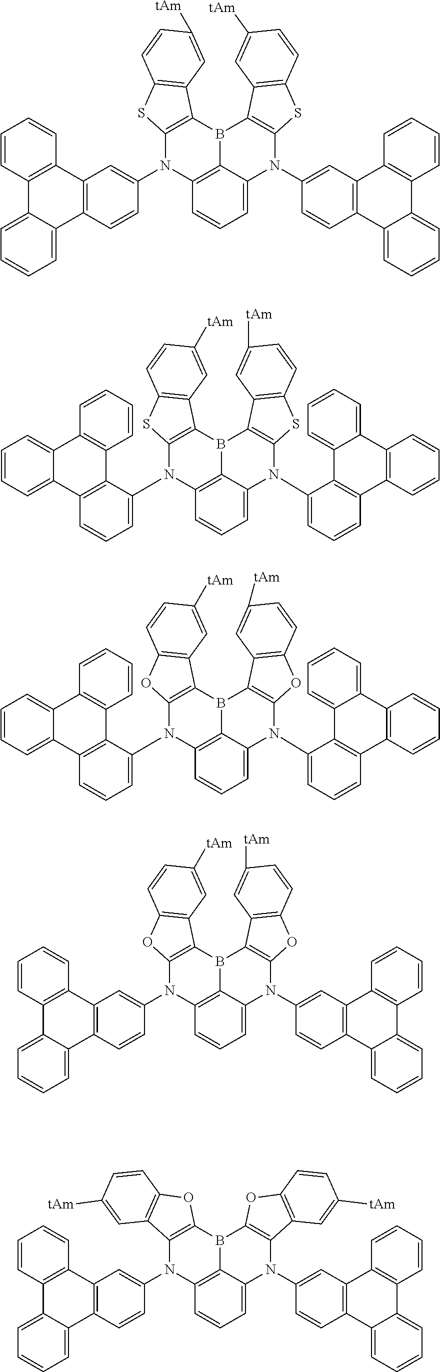

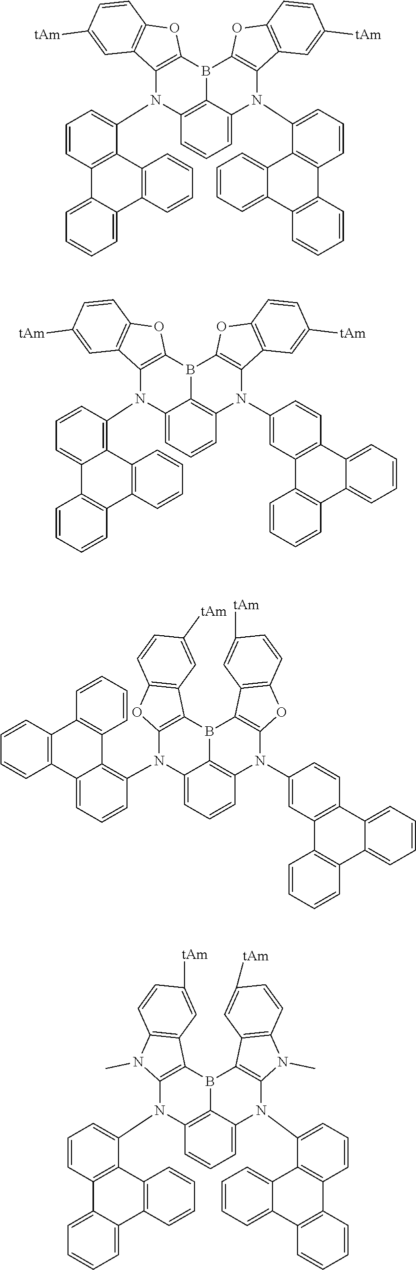

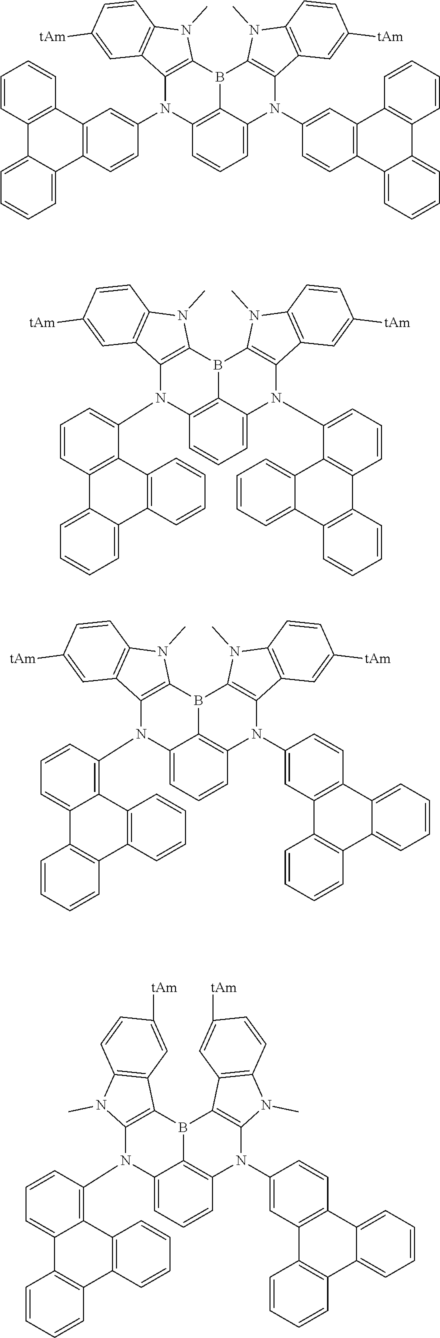

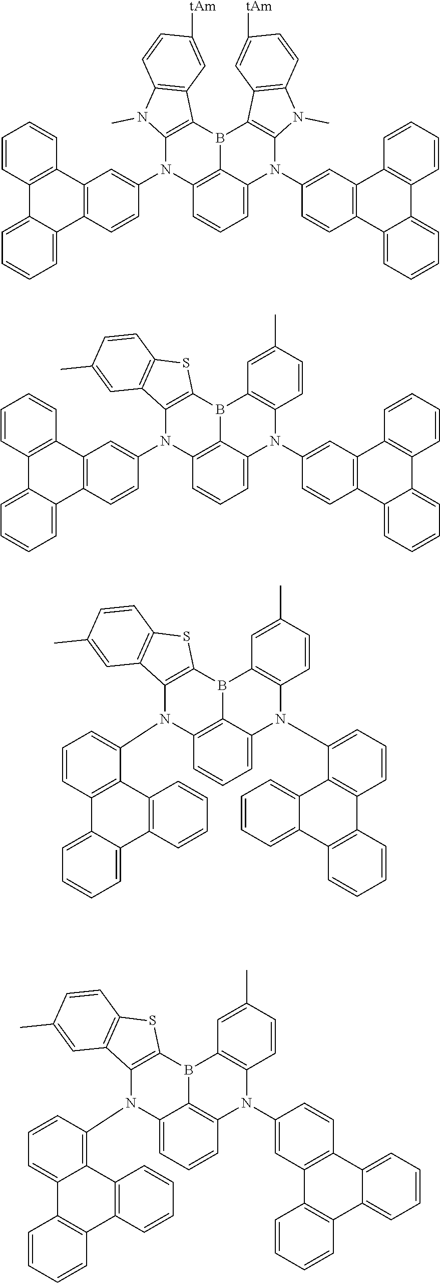

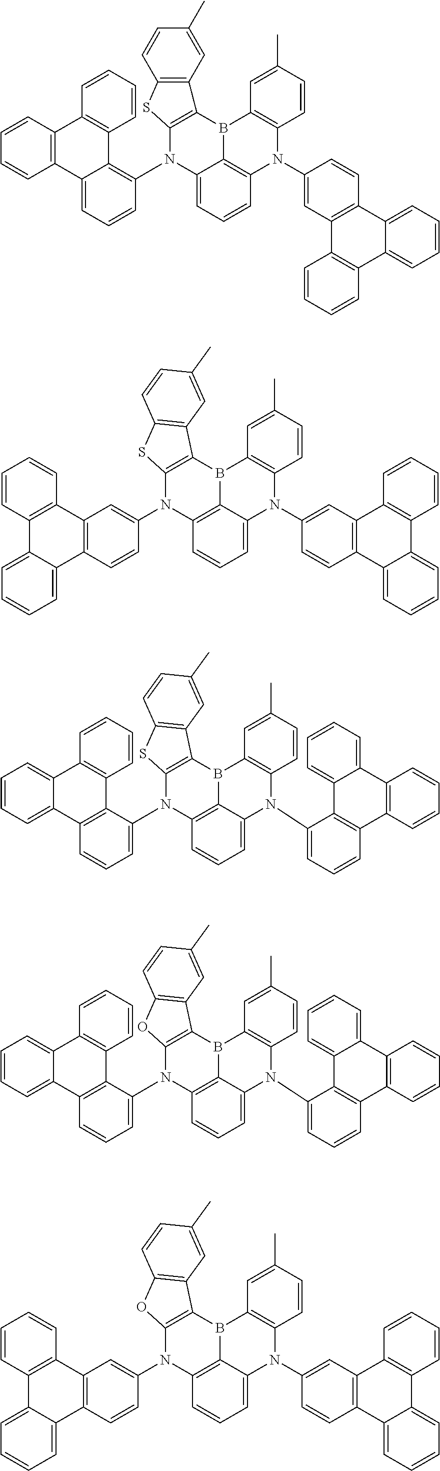

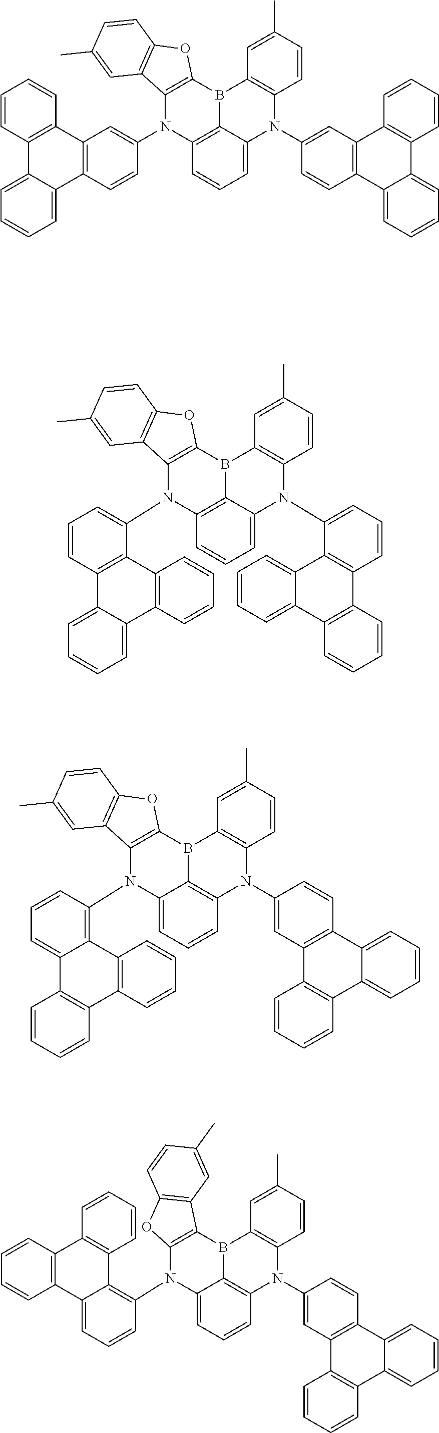 [SMILES: Cc1ccc2c(c1)B1c3oc4ccc(C)cc4c3N(c3ccc4c5ccccc5c5ccccc5c4c3)c3cccc(c31)N2c1ccc2c3ccccc3c3ccccc3c2c1 ; Cc1ccc2c(c1)B1c3oc4ccc(C)cc4c3N(c3cccc4c5ccccc5c5ccccc5c34)c3cccc(c31)N2c1cccc2c3ccccc3c3ccccc3c12 ; Cc1ccc2c(c1)B1c3oc4ccc(C)cc4c3N(c3cccc4c5ccccc5c5ccccc5c34)c3cccc(c31)N2c1ccc2c3ccccc3c3ccccc3c2c1 ; Cc1ccc2c(c1)B1c3c(cccc3N(c3cccc4c5ccccc5c5ccccc5c34)c3oc4ccc(C)cc4c31)N2c1ccc2c3ccccc3c3ccccc3c2c1]

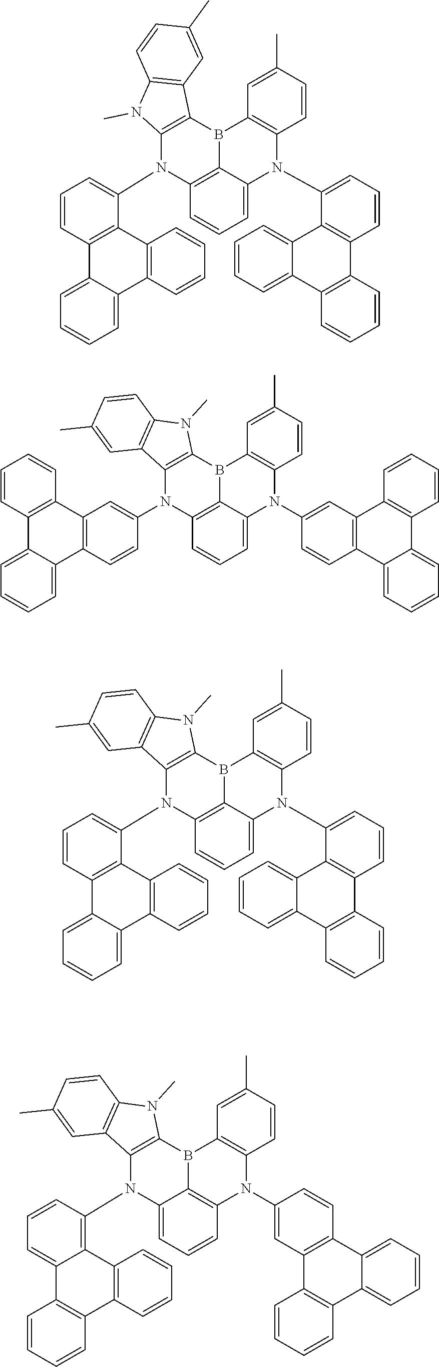 [SMILES: Cc1ccc2c(c1)B1c3c(cccc3N(c3cccc4c5ccccc5c5ccccc5c34)c3c1c1cc(C)ccc1n3C)N2c1cccc2c3ccccc3c3ccccc3c12 ; Cc1ccc2c(c1)B1c3c(cccc3N(c3ccc4c5ccccc5c5ccccc5c4c3)c3c1n(C)c1ccc(C)cc31)N2c1ccc2c3ccccc3c3ccccc3c2c1 ; Cc1ccc2c(c1)B1c3c(cccc3N(c3cccc4c5ccccc5c5ccccc5c34)c3c1n(C)c1ccc(C)cc31)N2c1cccc2c3ccccc3c3ccccc3c12 ; Cc1ccc2c(c1)B1c3c(cccc3N(c3cccc4c5ccccc5c5ccccc5c34)c3c1n(C)c1ccc(C)cc31)N2c1ccc2c3ccccc3c3ccccc3c2c1]

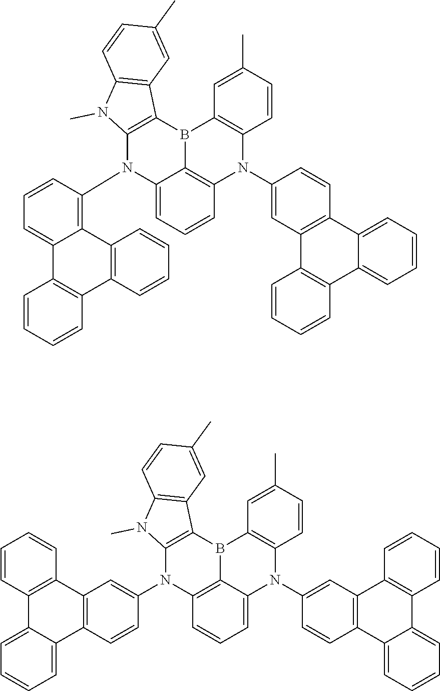 [SMILES: Cc1ccc2c(c1)B1c3c(cccc3N(c3cccc4c5ccccc5c5ccccc5c34)c3c1c1cc(C)ccc1n3C)N2c1ccc2c3ccccc3c3ccccc3c2c1 ; Cc1ccc2c(c1)B1c3c(cccc3N(c3ccc4c5ccccc5c5ccccc5c4c3)c3c1c1cc(C)ccc1n3C)N2c1ccc2c3ccccc3c3ccccc3c2c1]

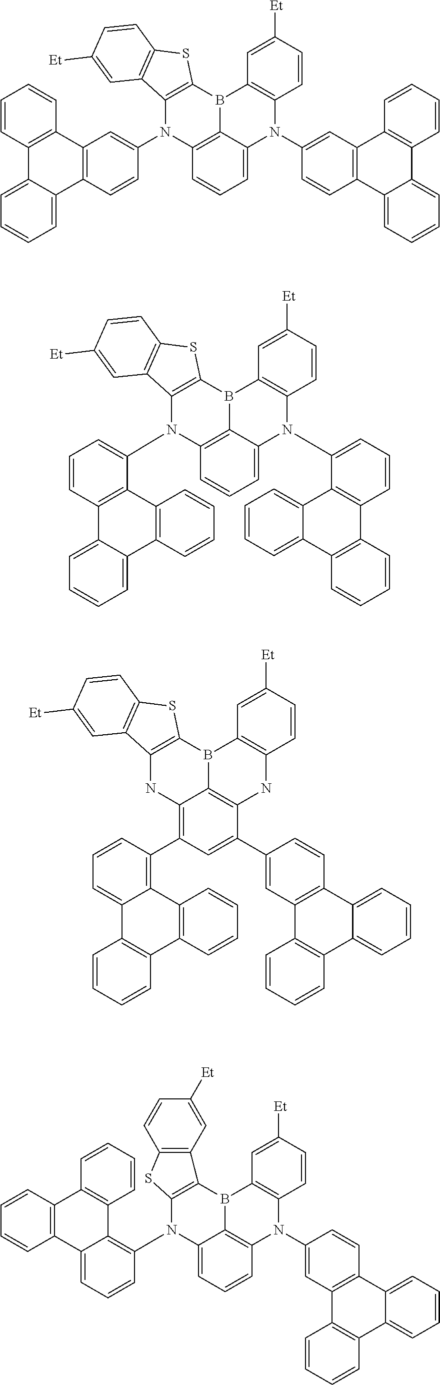 [SMILES: CCc1ccc2c(c1)B1c3sc4ccc(CC)cc4c3N(c3ccc4c5ccccc5c5ccccc5c4c3)c3cccc(c31)N2c1ccc2c3ccccc3c3ccccc3c2c1 ; CCc1ccc2c(c1)B1c3sc4ccc(CC)cc4c3N(c3cccc4c5ccccc5c5ccccc5c34)c3cccc(c31)N2c1cccc2c3ccccc3c3ccccc3c12 ; CCc1ccc2c(c1)B1c3sc4ccc(CC)cc4c3Nc3c(-c4cccc5c6ccccc6c6ccccc6c45)cc(-c4ccc5c6ccccc6c6ccccc6c5c4)c(c31)N2 ; CCc1ccc2c(c1)B1c3c(cccc3N(c3cccc4c5ccccc5c5ccccc5c34)c3sc4ccc(CC)cc4c31)N2c1ccc2c3ccccc3c3ccccc3c2c1]

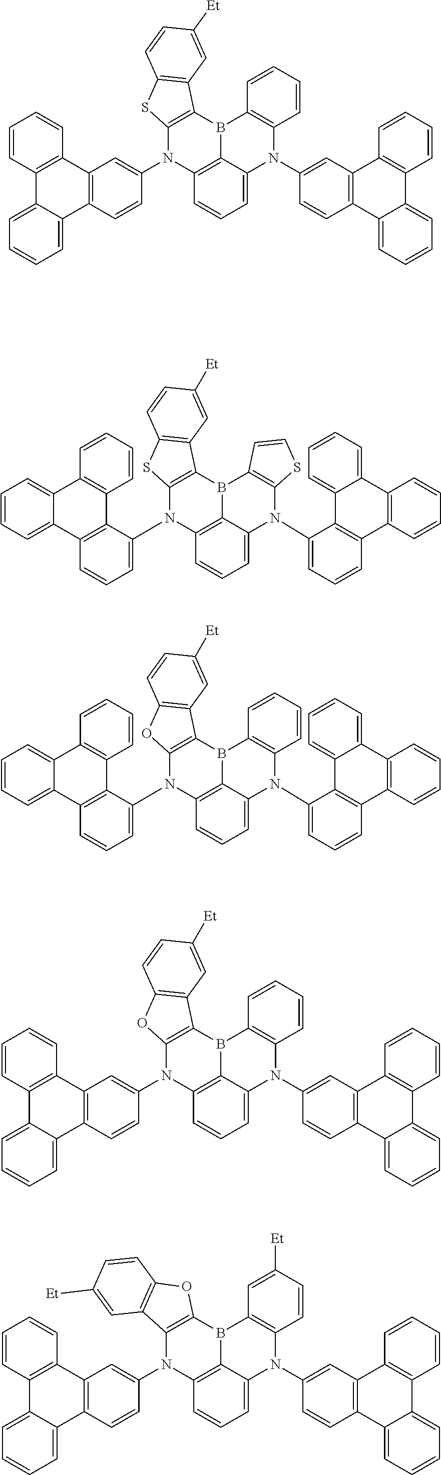 [SMILES: CCc1ccc2sc3c(c2c1)B1c2ccccc2N(c2ccc4c5ccccc5c5ccccc5c4c2)c2cccc(c21)N3c1ccc2c3ccccc3c3ccccc3c2c1 ; CCc1ccc2sc3c(c2c1)B1c2ccsc2N(c2cccc4c5ccccc5c5ccccc5c24)c2cccc(c21)N3c1cccc2c3ccccc3c3ccccc3c12 ; CCc1ccc2oc3c(c2c1)B1c2ccccc2N(c2cccc4c5ccccc5c5ccccc5c24)c2cccc(c21)N3c1cccc2c3ccccc3c3ccccc3c12 ; CCc1ccc2oc3c(c2c1)B1c2ccccc2N(c2ccc4c5ccccc5c5ccccc5c4c2)c2cccc(c21)N3c1ccc2c3ccccc3c3ccccc3c2c1 ; CCc1ccc2c(c1)B1c3oc4ccc(CC)cc4c3N(c3ccc4c5ccccc5c5ccccc5c4c3)c3cccc(c31)N2c1ccc2c3ccccc3c3ccccc3c2c1]

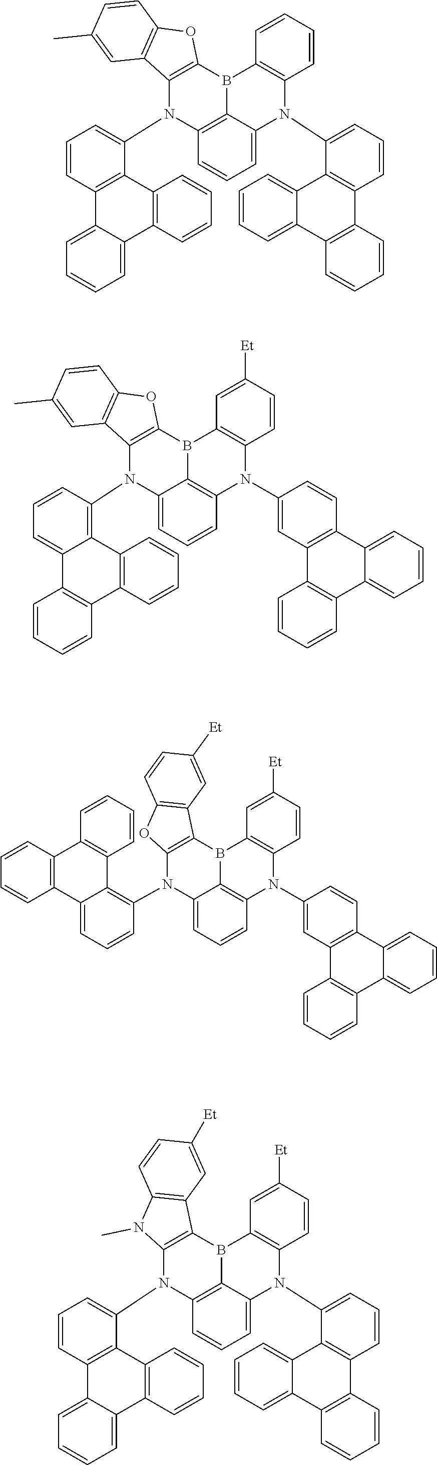 [SMILES: Cc1ccc2oc3c(c2c1)N(c1cccc2c4ccccc4c4ccccc4c12)c1cccc2c1B3c1ccccc1N2c1cccc2c3ccccc3c3ccccc3c12 ; CCc1ccc2c(c1)B1c3oc4ccc(C)cc4c3N(c3cccc4c5ccccc5c5ccccc5c34)c3cccc(c31)N2c1ccc2c3ccccc3c3ccccc3c2c1 ; CCc1ccc2c(c1)B1c3c(cccc3N(c3cccc4c5ccccc5c5ccccc5c34)c3oc4ccc(CC)cc4c31)N2c1ccc2c3ccccc3c3ccccc3c2c1 ; CCc1ccc2c(c1)B1c3c(cccc3N(c3cccc4c5ccccc5c5ccccc5c34)c3c1c1cc(CC)ccc1n3C)N2c1cccc2c3ccccc3c3ccccc3c12]

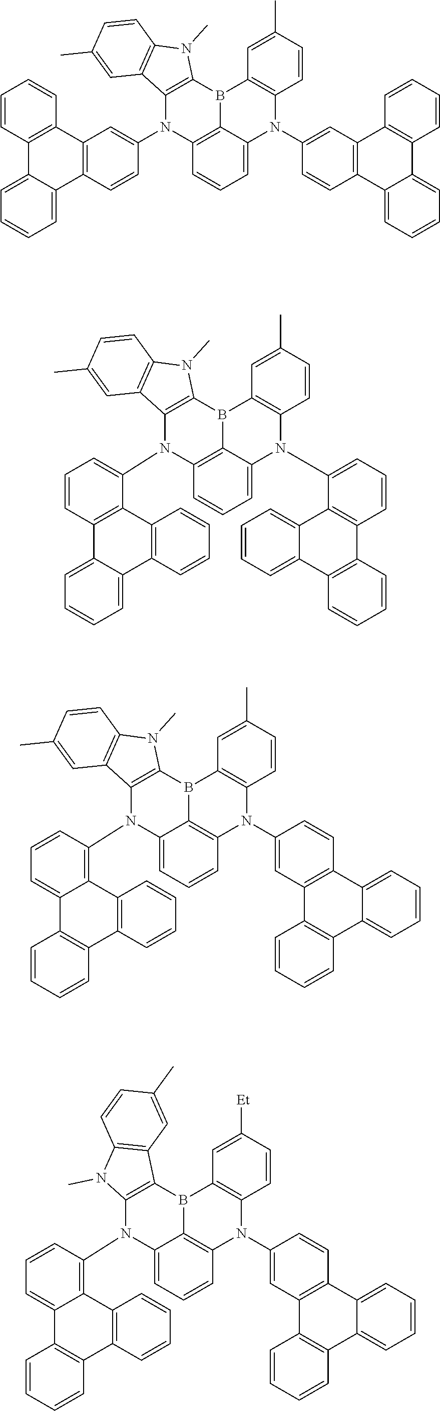 [SMILES: Cc1ccc2c(c1)B1c3c(cccc3N(c3ccc4c5ccccc5c5ccccc5c4c3)c3c1n(C)c1ccc(C)cc31)N2c1ccc2c3ccccc3c3ccccc3c2c1 ; Cc1ccc2c(c1)B1c3c(cccc3N(c3cccc4c5ccccc5c5ccccc5c34)c3c1n(C)c1ccc(C)cc31)N2c1cccc2c3ccccc3c3ccccc3c12 ; Cc1ccc2c(c1)B1c3c(cccc3N(c3cccc4c5ccccc5c5ccccc5c34)c3c1n(C)c1ccc(C)cc31)N2c1ccc2c3ccccc3c3ccccc3c2c1 ; CCc1ccc2c(c1)B1c3c(cccc3N(c3cccc4c5ccccc5c5ccccc5c34)c3c1c1cc(C)ccc1n3C)N2c1ccc2c3ccccc3c3ccccc3c2c1]

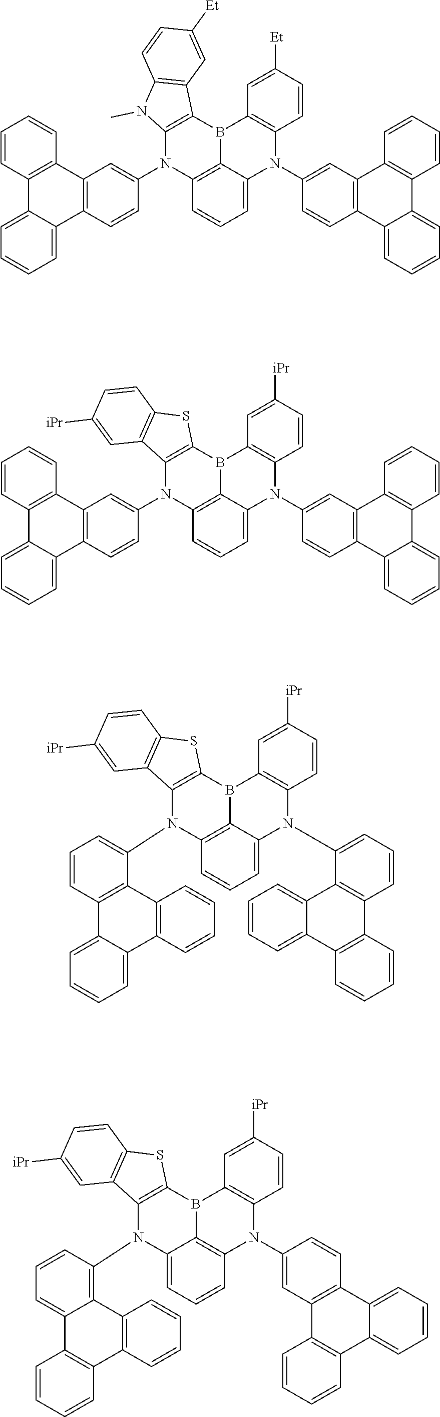 [SMILES: CCc1ccc2c(c1)B1c3c(cccc3N(c3ccc4c5ccccc5c5ccccc5c4c3)c3c1c1cc(CC)ccc1n3C)N2c1ccc2c3ccccc3c3ccccc3c2c1 ; CC(C)c1ccc2c(c1)B1c3sc4ccc(C(C)C)cc4c3N(c3ccc4c5ccccc5c5ccccc5c4c3)c3cccc(c31)N2c1ccc2c3ccccc3c3ccccc3c2c1 ; CC(C)c1ccc2c(c1)B1c3sc4ccc(C(C)C)cc4c3N(c3cccc4c5ccccc5c5ccccc5c34)c3cccc(c31)N2c1cccc2c3ccccc3c3ccccc3c12 ; CC(C)c1ccc2c(c1)B1c3sc4ccc(C(C)C)cc4c3N(c3cccc4c5ccccc5c5ccccc5c34)c3cccc(c31)N2c1ccc2c3ccccc3c3ccccc3c2c1]

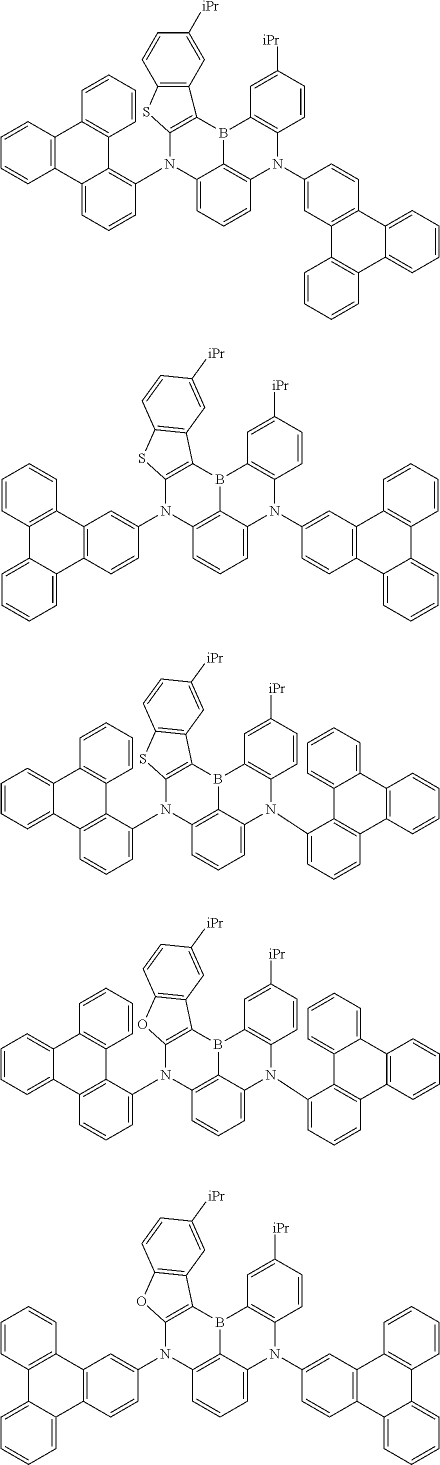

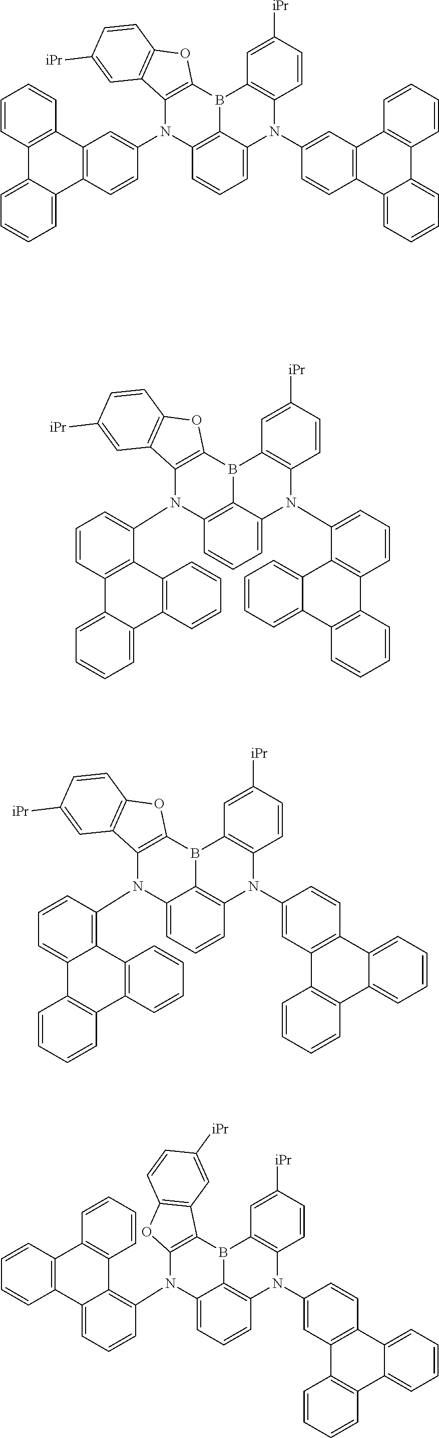 [SMILES: CC(C)c1ccc2c(c1)B1c3oc4ccc(C(C)C)cc4c3N(c3ccc4c5ccccc5c5ccccc5c4c3)c3cccc(c31)N2c1ccc2c3ccccc3c3ccccc3c2c1 ; CC(C)c1ccc2c(c1)B1c3oc4ccc(C(C)C)cc4c3N(c3cccc4c5ccccc5c5ccccc5c34)c3cccc(c31)N2c1cccc2c3ccccc3c3ccccc3c12 ; CC(C)c1ccc2c(c1)B1c3oc4ccc(C(C)C)cc4c3N(c3cccc4c5ccccc5c5ccccc5c34)c3cccc(c31)N2c1ccc2c3ccccc3c3ccccc3c2c1 ; CC(C)c1ccc2c(c1)B1c3c(cccc3N(c3cccc4c5ccccc5c5ccccc5c34)c3oc4ccc(C(C)C)cc4c31)N2c1ccc2c3ccccc3c3ccccc3c2c1]

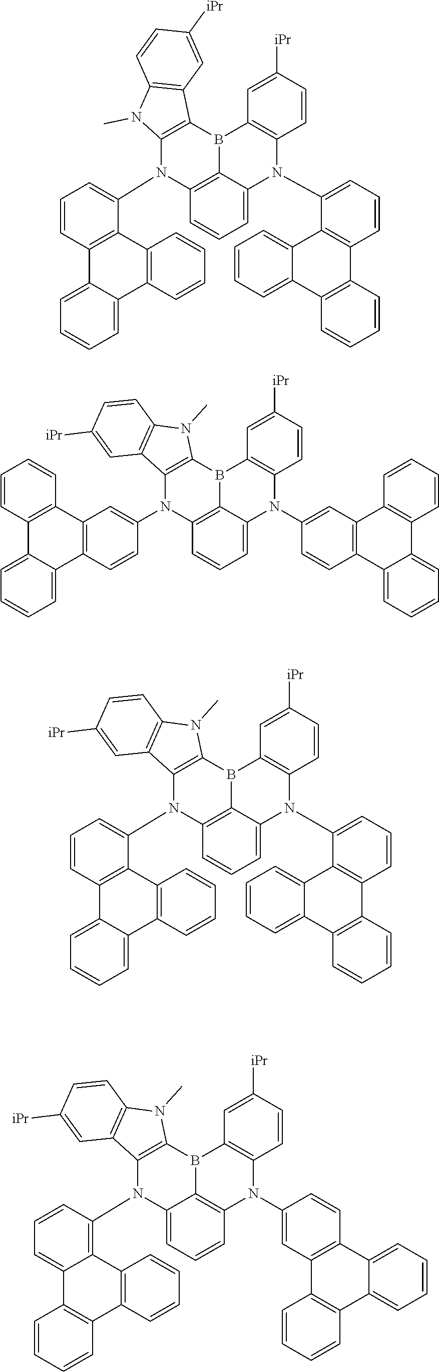 [SMILES: CC(C)c1ccc2c(c1)B1c3c(cccc3N(c3cccc4c5ccccc5c5ccccc5c34)c3c1c1cc(C(C)C)ccc1n3C)N2c1cccc2c3ccccc3c3ccccc3c12 ; CC(C)c1ccc2c(c1)B1c3c(cccc3N(c3ccc4c5ccccc5c5ccccc5c4c3)c3c1n(C)c1ccc(C(C)C)cc31)N2c1ccc2c3ccccc3c3ccccc3c2c1 ; CC(C)c1ccc2c(c1)B1c3c(cccc3N(c3cccc4c5ccccc5c5ccccc5c34)c3c1n(C)c1ccc(C(C)C)cc31)N2c1cccc2c3ccccc3c3ccccc3c12 ; CC(C)c1ccc2c(c1)B1c3c(cccc3N(c3cccc4c5ccccc5c5ccccc5c34)c3c1n(C)c1ccc(C(C)C)cc31)N2c1ccc2c3ccccc3c3ccccc3c2c1]

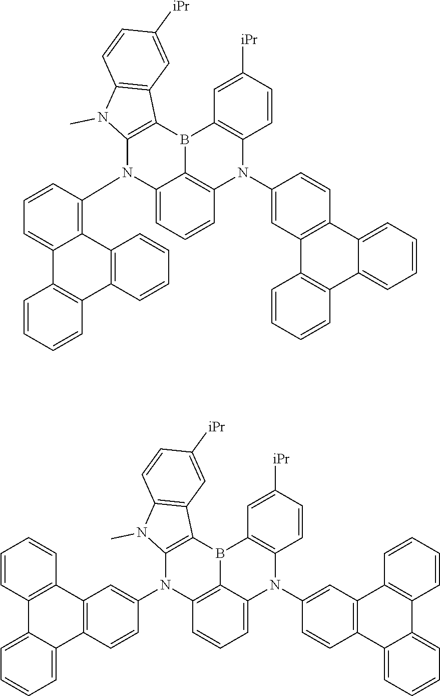 [SMILES: CC(C)c1ccc2c(c1)B1c3c(cccc3N(c3cccc4c5ccccc5c5ccccc5c34)c3c1c1cc(C(C)C)ccc1n3C)N2c1ccc2c3ccccc3c3ccccc3c2c1 ; CC(C)c1ccc2c(c1)B1c3c(cccc3N(c3ccc4c5ccccc5c5ccccc5c4c3)c3c1c1cc(C(C)C)ccc1n3C)N2c1ccc2c3ccccc3c3ccccc3c2c1]

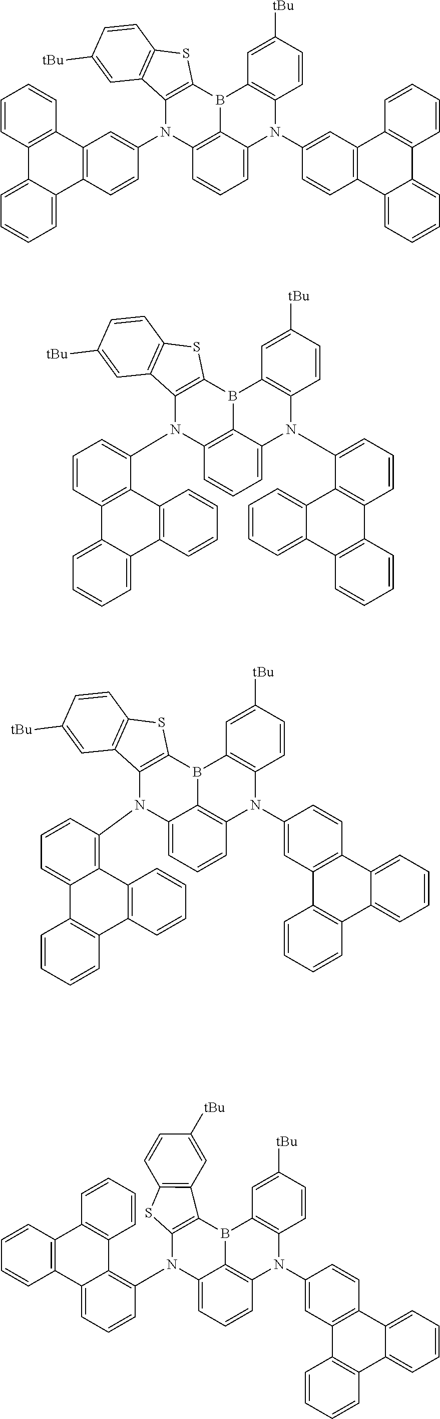 [SMILES: CC(C)(C)c1ccc2c(c1)B1c3sc4ccc(C(C)(C)C)cc4c3N(c3ccc4c5ccccc5c5ccccc5c4c3)c3cccc(c31)N2c1ccc2c3ccccc3c3ccccc3c2c1 ; CC(C)(C)c1ccc2c(c1)B1c3sc4ccc(C(C)(C)C)cc4c3N(c3cccc4c5ccccc5c5ccccc5c34)c3cccc(c31)N2c1cccc2c3ccccc3c3ccccc3c12 ; CC(C)(C)c1ccc2c(c1)B1c3sc4ccc(C(C)(C)C)cc4c3N(c3cccc4c5ccccc5c5ccccc5c34)c3cccc(c31)N2c1ccc2c3ccccc3c3ccccc3c2c1 ; CC(C)(C)c1ccc2c(c1)B1c3c(cccc3N(c3cccc4c5ccccc5c5ccccc5c34)c3sc4ccc(C(C)(C)C)cc4c31)N2c1ccc2c3ccccc3c3ccccc3c2c1]

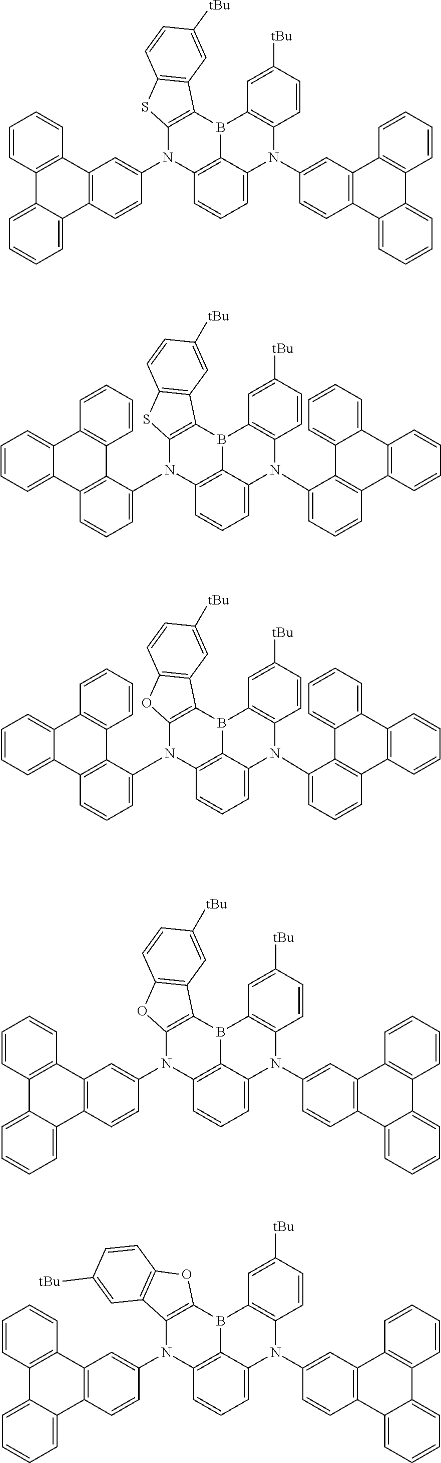

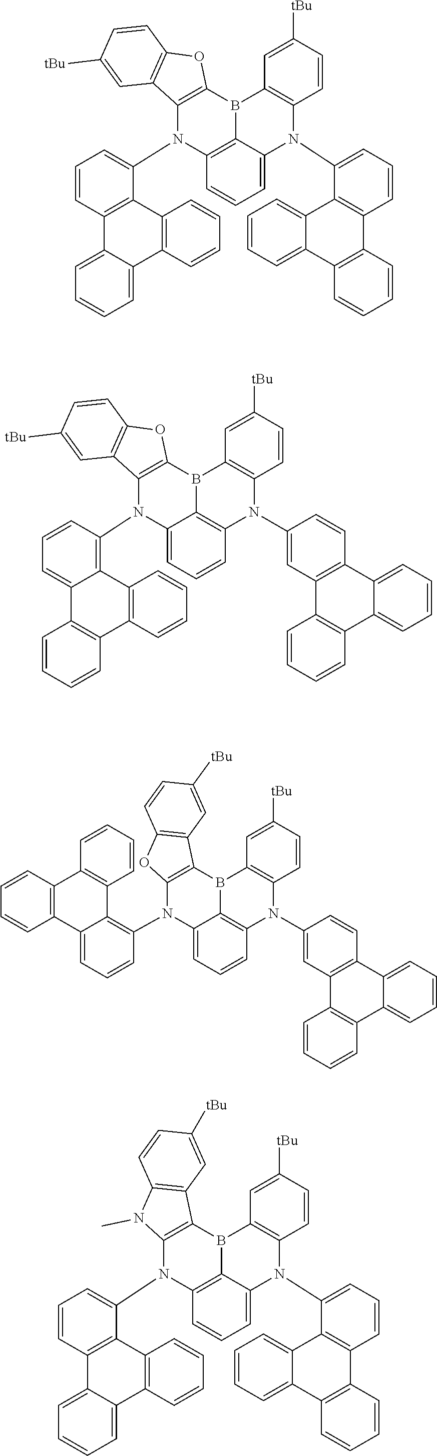 [SMILES: CC(C)(C)c1ccc2c(c1)B1c3oc4ccc(C(C)(C)C)cc4c3N(c3cccc4c5ccccc5c5ccccc5c34)c3cccc(c31)N2c1cccc2c3ccccc3c3ccccc3c12 ; CC(C)(C)c1ccc2c(c1)B1c3oc4ccc(C(C)(C)C)cc4c3N(c3cccc4c5ccccc5c5ccccc5c34)c3cccc(c31)N2c1ccc2c3ccccc3c3ccccc3c2c1 ; CC(C)(C)c1ccc2c(c1)B1c3c(cccc3N(c3cccc4c5ccccc5c5ccccc5c34)c3oc4ccc(C(C)(C)C)cc4c31)N2c1ccc2c3ccccc3c3ccccc3c2c1 ; Cn1c2c(c3cc(C(C)(C)C)ccc31)B1c3cc(C(C)(C)C)ccc3N(c3cccc4c5ccccc5c5ccccc5c34)c3cccc(c31)N2c1cccc2c3ccccc3c3ccccc3c12]

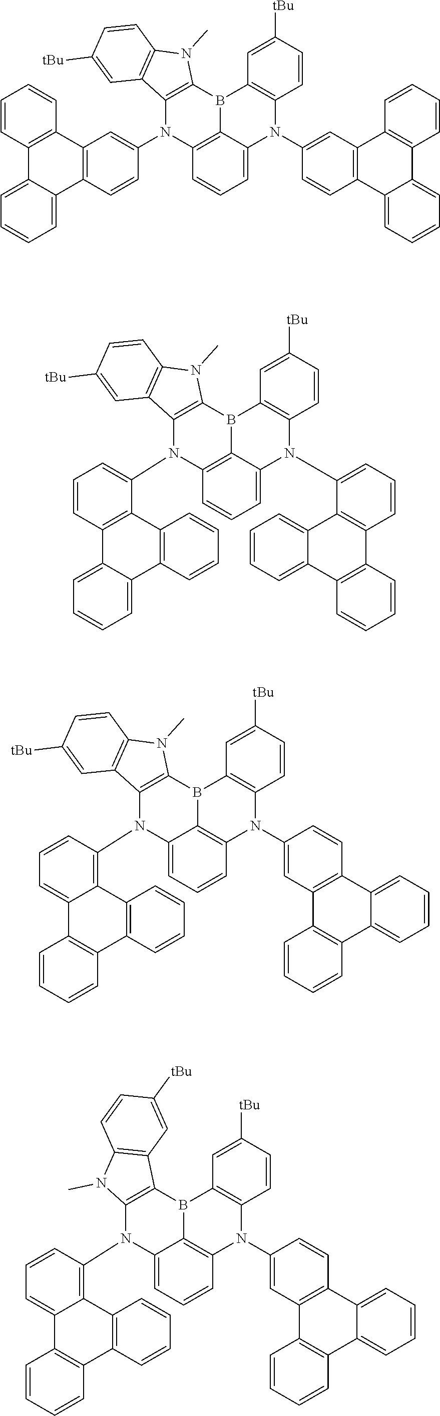 [SMILES: Cn1c2c(c3cc(C(C)(C)C)ccc31)N(c1ccc3c4ccccc4c4ccccc4c3c1)c1cccc3c1B2c1cc(C(C)(C)C)ccc1N3c1ccc2c3ccccc3c3ccccc3c2c1 ; Cn1c2c(c3cc(C(C)(C)C)ccc31)N(c1cccc3c4ccccc4c4ccccc4c13)c1cccc3c1B2c1cc(C(C)(C)C)ccc1N3c1cccc2c3ccccc3c3ccccc3c12 ; Cn1c2c(c3cc(C(C)(C)C)ccc31)N(c1cccc3c4ccccc4c4ccccc4c13)c1cccc3c1B2c1cc(C(C)(C)C)ccc1N3c1ccc2c3ccccc3c3ccccc3c2c1 ; Cn1c2c(c3cc(C(C)(C)C)ccc31)B1c3cc(C(C)(C)C)ccc3N(c3ccc4c5ccccc5c5ccccc5c4c3)c3cccc(c31)N2c1cccc2c3ccccc3c3ccccc3c12]

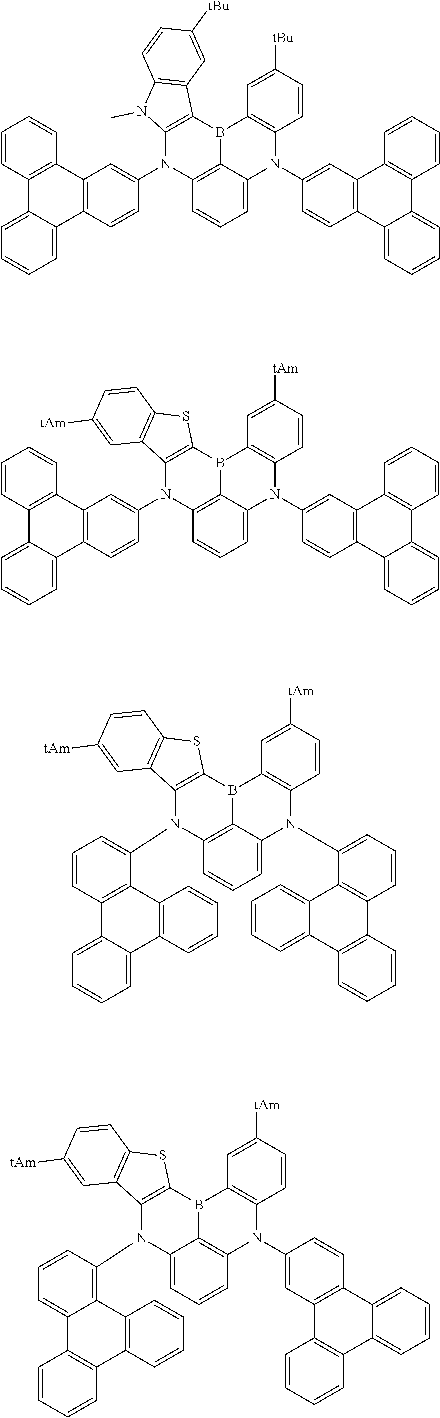

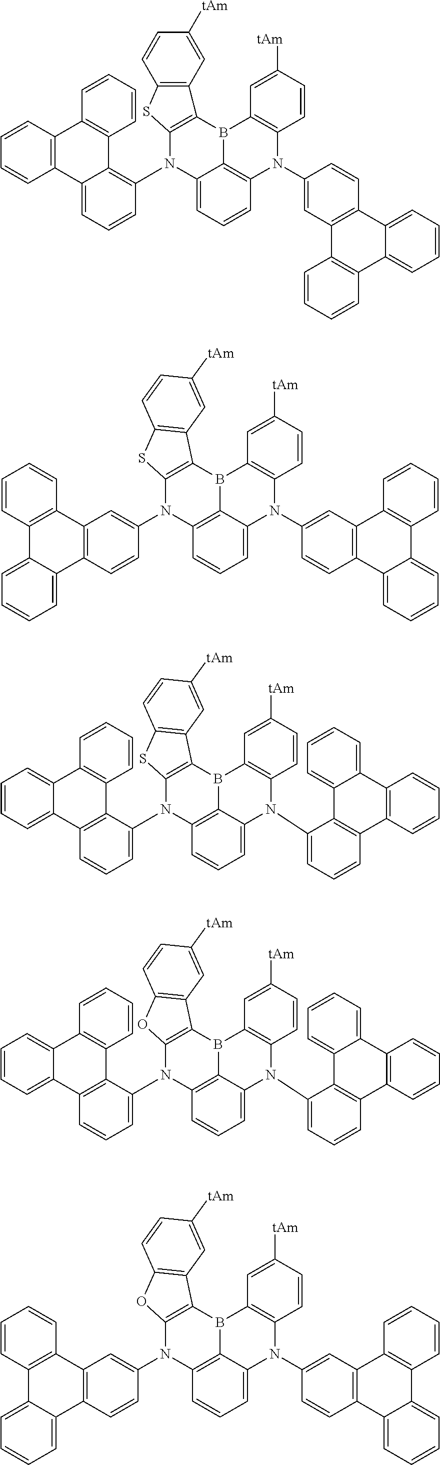

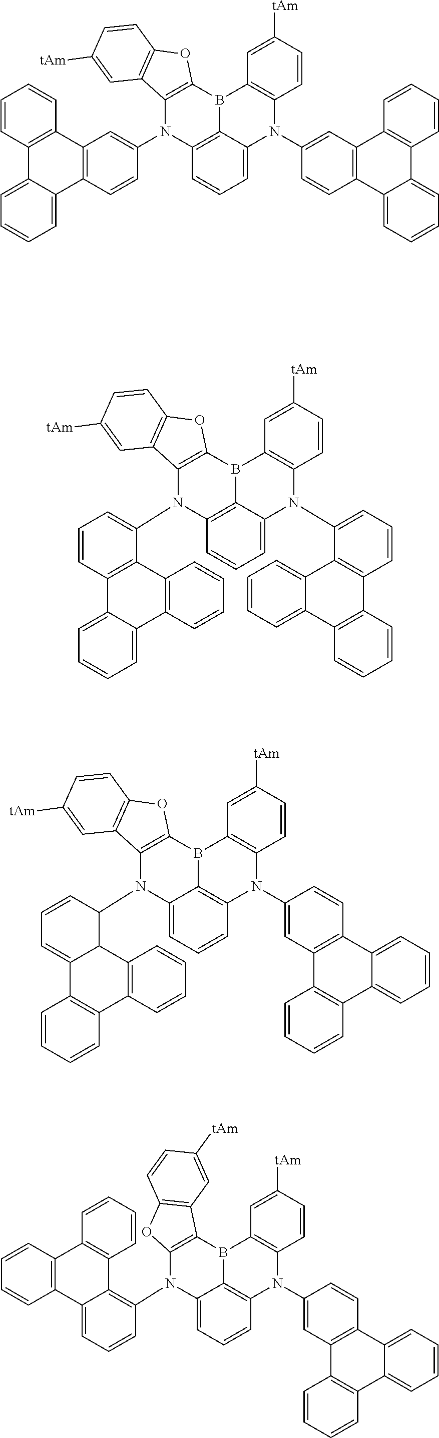

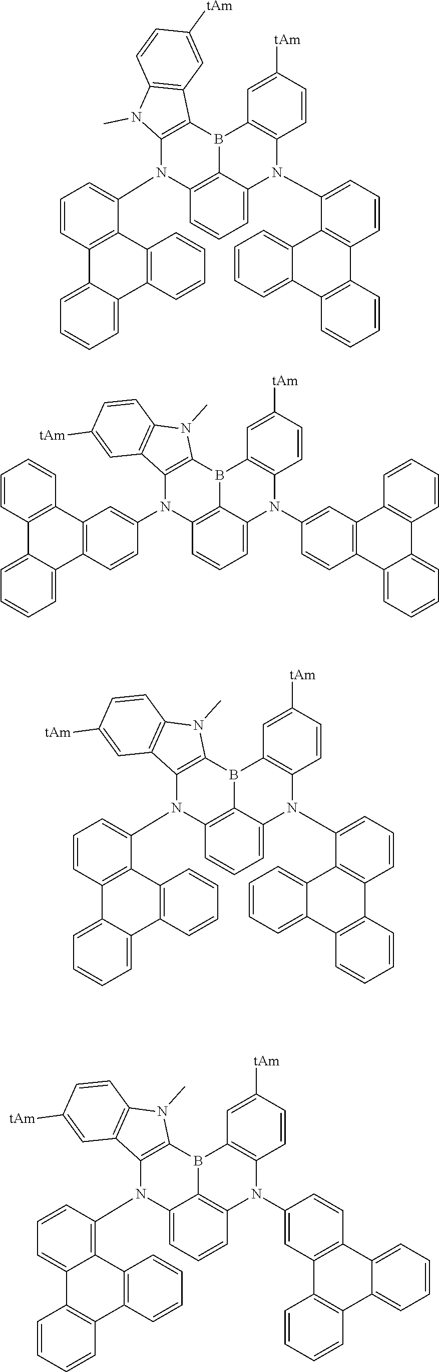

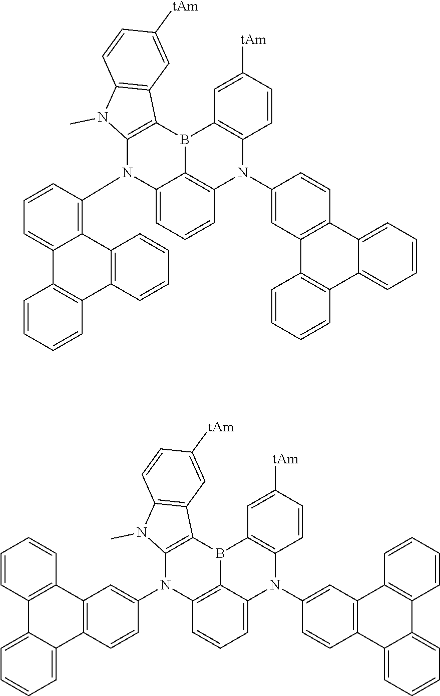

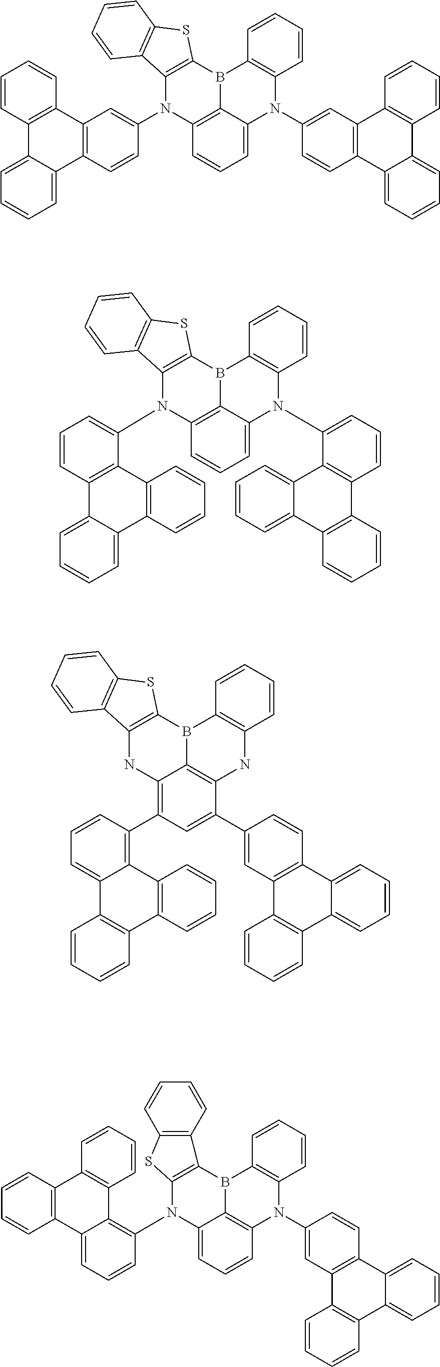 [SMILES: c1ccc2c(c1)B1c3sc4ccccc4c3N(c3ccc4c5ccccc5c5ccccc5c4c3)c3cccc(c31)N2c1ccc2c3ccccc3c3ccccc3c2c1 ; c1ccc2c(c1)B1c3sc4ccccc4c3N(c3cccc4c5ccccc5c5ccccc5c34)c3cccc(c31)N2c1cccc2c3ccccc3c3ccccc3c12 ; c1ccc2c(c1)Nc1c(-c3ccc4c5ccccc5c5ccccc5c4c3)cc(-c3cccc4c5ccccc5c5ccccc5c34)c3c1B2c1sc2ccccc2c1N3 ; c1ccc2c(c1)B1c3c(cccc3N(c3cccc4c5ccccc5c5ccccc5c34)c3sc4ccccc4c31)N2c1ccc2c3ccccc3c3ccccc3c2c1]

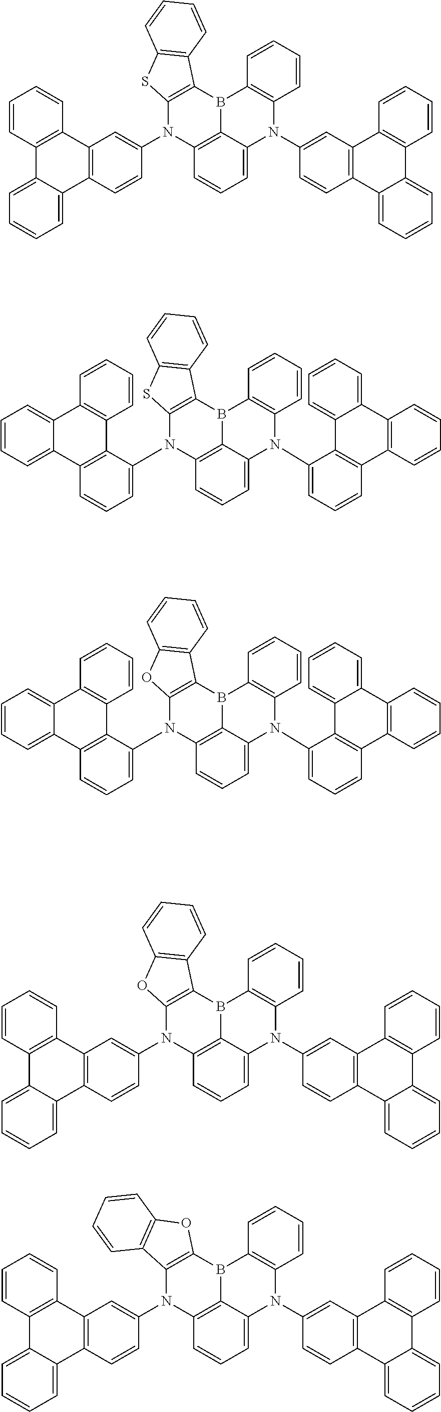 [SMILES: c1ccc2c(c1)B1c3c(cccc3N(c3ccc4c5ccccc5c5ccccc5c4c3)c3sc4ccccc4c31)N2c1ccc2c3ccccc3c3ccccc3c2c1 ; c1ccc2c(c1)B1c3c(cccc3N(c3cccc4c5ccccc5c5ccccc5c34)c3sc4ccccc4c31)N2c1cccc2c3ccccc3c3ccccc3c12 ; c1ccc2c(c1)B1c3c(cccc3N(c3cccc4c5ccccc5c5ccccc5c34)c3oc4ccccc4c31)N2c1cccc2c3ccccc3c3ccccc3c12 ; c1ccc2c(c1)B1c3c(cccc3N(c3ccc4c5ccccc5c5ccccc5c4c3)c3oc4ccccc4c31)N2c1ccc2c3ccccc3c3ccccc3c2c1 ; c1ccc2c(c1)B1c3oc4ccccc4c3N(c3ccc4c5ccccc5c5ccccc5c4c3)c3cccc(c31)N2c1ccc2c3ccccc3c3ccccc3c2c1]

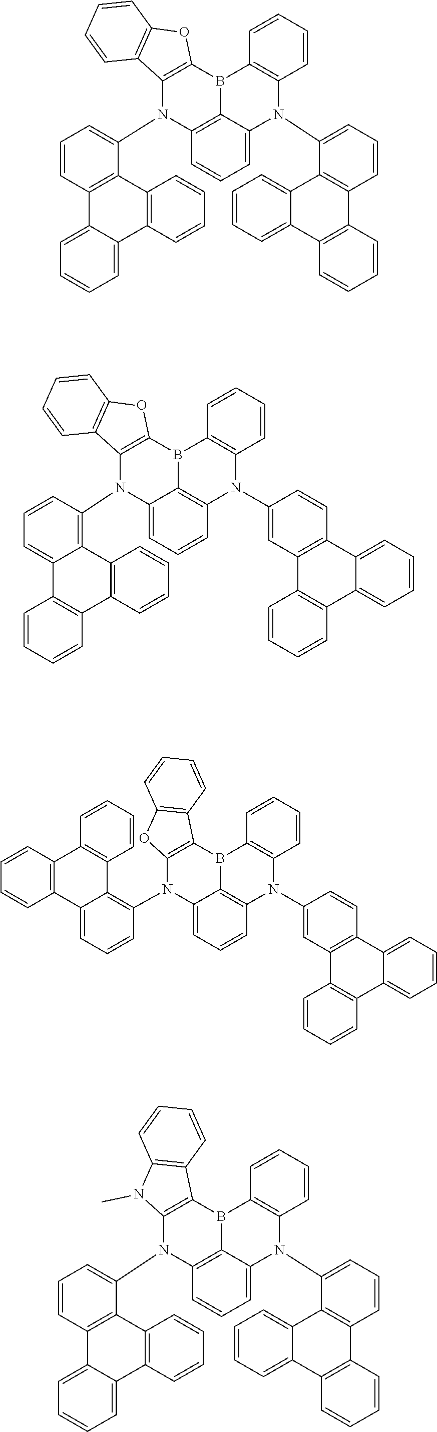 [SMILES: c1ccc2c(c1)B1c3oc4ccccc4c3N(c3cccc4c5ccccc5c5ccccc5c34)c3cccc(c31)N2c1cccc2c3ccccc3c3ccccc3c12 ; c1ccc2c(c1)B1c3oc4ccccc4c3N(c3cccc4c5ccccc5c5ccccc5c34)c3cccc(c31)N2c1ccc2c3ccccc3c3ccccc3c2c1 ; c1ccc2c(c1)B1c3c(cccc3N(c3cccc4c5ccccc5c5ccccc5c34)c3oc4ccccc4c31)N2c1ccc2c3ccccc3c3ccccc3c2c1 ; Cn1c2c(c3ccccc31)B1c3ccccc3N(c3cccc4c5ccccc5c5ccccc5c34)c3cccc(c31)N2c1cccc2c3ccccc3c3ccccc3c12]

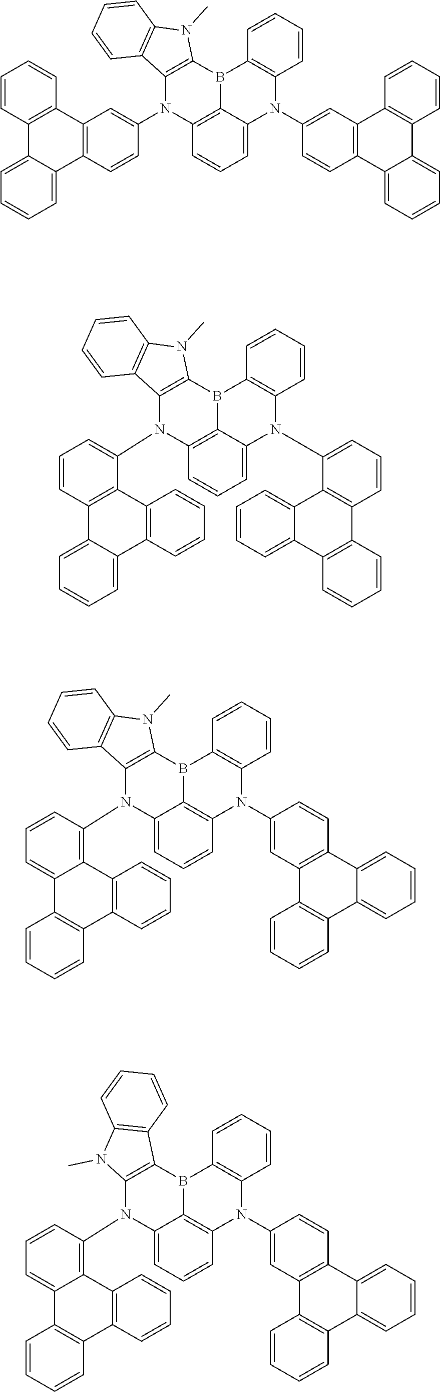 [SMILES: Cn1c2c(c3ccccc31)N(c1ccc3c4ccccc4c4ccccc4c3c1)c1cccc3c1B2c1ccccc1N3c1ccc2c3ccccc3c3ccccc3c2c1 ; Cn1c2c(c3ccccc31)N(c1cccc3c4ccccc4c4ccccc4c13)c1cccc3c1B2c1ccccc1N3c1cccc2c3ccccc3c3ccccc3c12 ; Cn1c2c(c3ccccc31)N(c1cccc3c4ccccc4c4ccccc4c13)c1cccc3c1B2c1ccccc1N3c1ccc2c3ccccc3c3ccccc3c2c1 ; Cn1c2c(c3ccccc31)B1c3ccccc3N(c3ccc4c5ccccc5c5ccccc5c4c3)c3cccc(c31)N2c1cccc2c3ccccc3c3ccccc3c12]

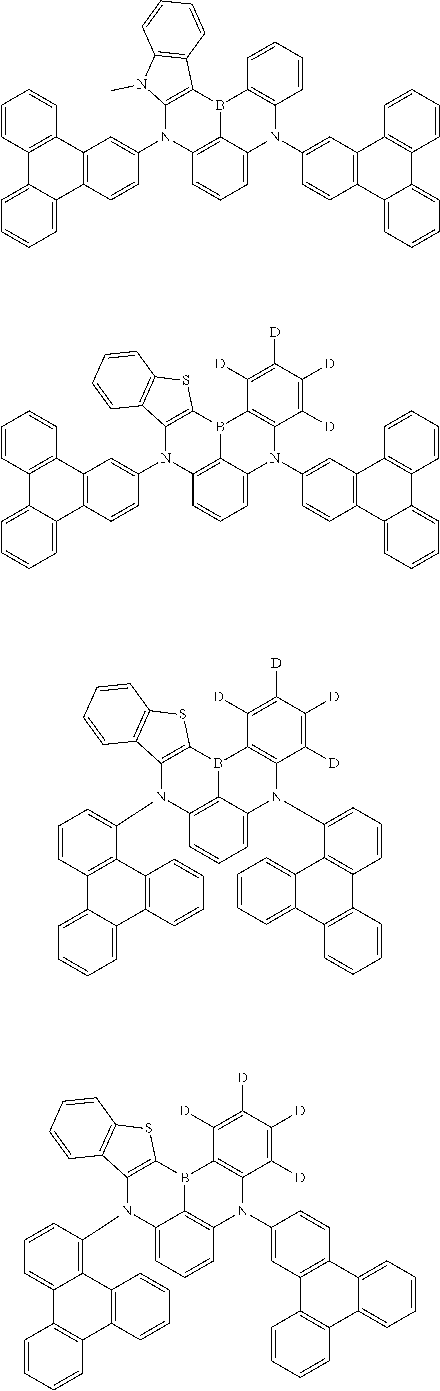 [SMILES: Cn1c2c(c3ccccc31)B1c3ccccc3N(c3ccc4c5ccccc5c5ccccc5c4c3)c3cccc(c31)N2c1ccc2c3ccccc3c3ccccc3c2c1 ; [2H]c1c([2H])c([2H])c2c(c1[2H])B1c3sc4ccccc4c3N(c3ccc4c5ccccc5c5ccccc5c4c3)c3cccc(c31)N2c1ccc2c3ccccc3c3ccccc3c2c1 ; [2H]c1c([2H])c([2H])c2c(c1[2H])B1c3sc4ccccc4c3N(c3cccc4c5ccccc5c5ccccc5c34)c3cccc(c31)N2c1cccc2c3ccccc3c3ccccc3c12 ; [2H]c1c([2H])c([2H])c2c(c1[2H])B1c3sc4ccccc4c3N(c3cccc4c5ccccc5c5ccccc5c34)c3cccc(c31)N2c1ccc2c3ccccc3c3ccccc3c2c1]

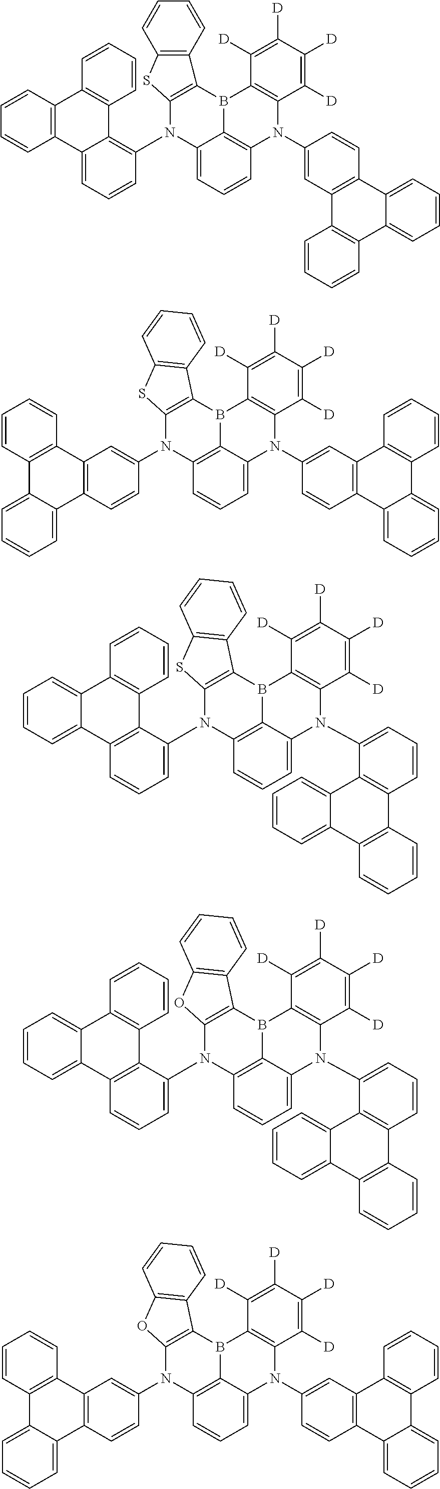

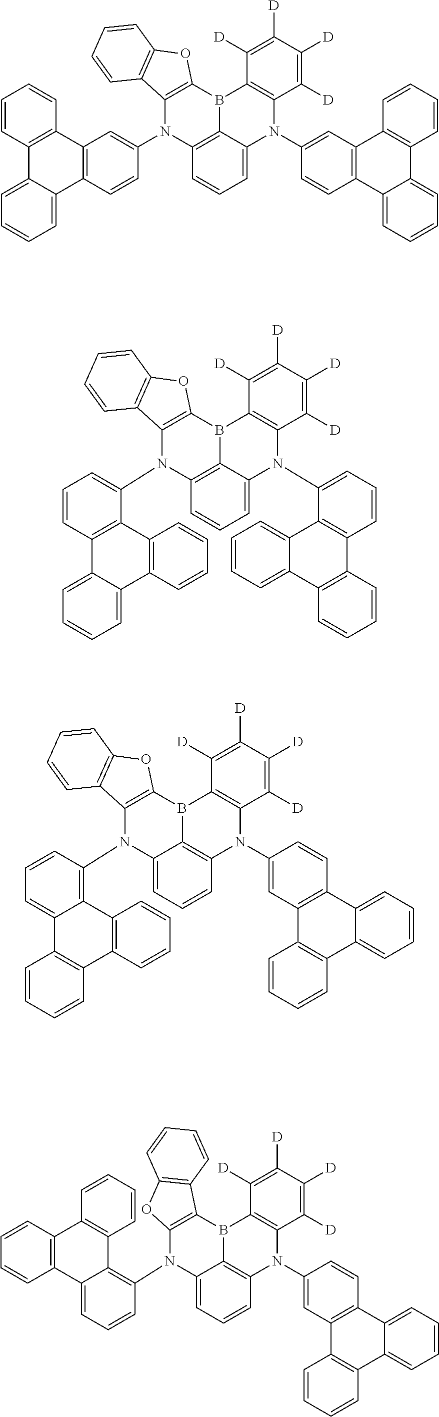 [SMILES: [2H]c1c([2H])c([2H])c2c(c1[2H])B1c3oc4ccccc4c3N(c3ccc4c5ccccc5c5ccccc5c4c3)c3cccc(c31)N2c1ccc2c3ccccc3c3ccccc3c2c1 ; [2H]c1c([2H])c([2H])c2c(c1[2H])B1c3oc4ccccc4c3N(c3cccc4c5ccccc5c5ccccc5c34)c3cccc(c31)N2c1cccc2c3ccccc3c3ccccc3c12 ; [2H]c1c([2H])c([2H])c2c(c1[2H])B1c3oc4ccccc4c3N(c3cccc4c5ccccc5c5ccccc5c34)c3cccc(c31)N2c1ccc2c3ccccc3c3ccccc3c2c1 ; [2H]c1c([2H])c([2H])c2c(c1[2H])B1c3c(cccc3N(c3cccc4c5ccccc5c5ccccc5c34)c3oc4ccccc4c31)N2c1ccc2c3ccccc3c3ccccc3c2c1]

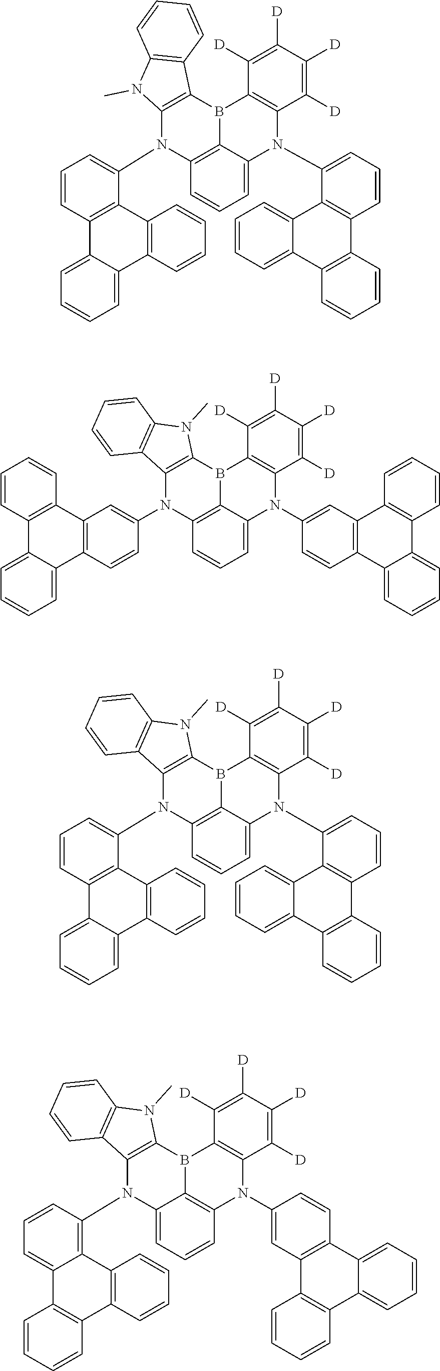 [SMILES: [2H]c1c([2H])c([2H])c2c(c1[2H])B1c3c(cccc3N(c3cccc4c5ccccc5c5ccccc5c34)c3c1c1ccccc1n3C)N2c1cccc2c3ccccc3c3ccccc3c12 ; [2H]c1c([2H])c([2H])c2c(c1[2H])B1c3c(cccc3N(c3ccc4c5ccccc5c5ccccc5c4c3)c3c1n(C)c1ccccc31)N2c1ccc2c3ccccc3c3ccccc3c2c1 ; [2H]c1c([2H])c([2H])c2c(c1[2H])B1c3c(cccc3N(c3cccc4c5ccccc5c5ccccc5c34)c3c1n(C)c1ccccc31)N2c1cccc2c3ccccc3c3ccccc3c12 ; [2H]c1c([2H])c([2H])c2c(c1[2H])B1c3c(cccc3N(c3cccc4c5ccccc5c5ccccc5c34)c3c1n(C)c1ccccc31)N2c1ccc2c3ccccc3c3ccccc3c2c1]

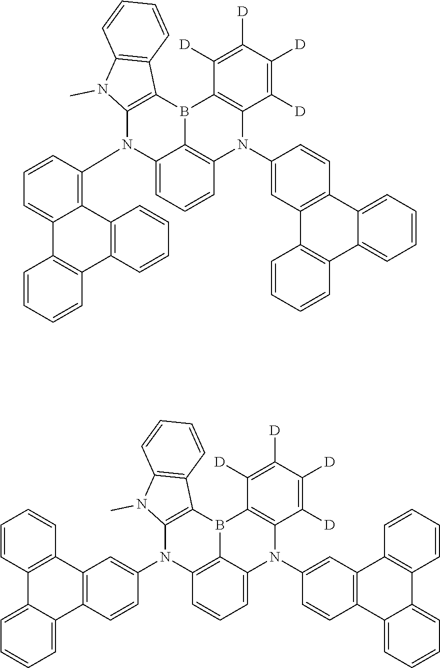 [SMILES: [2H]c1c([2H])c([2H])c2c(c1[2H])B1c3c(cccc3N(c3cccc4c5ccccc5c5ccccc5c34)c3c1c1ccccc1n3C)N2c1ccc2c3ccccc3c3ccccc3c2c1 ; [2H]c1c([2H])c([2H])c2c(c1[2H])B1c3c(cccc3N(c3ccc4c5ccccc5c5ccccc5c4c3)c3c1c1ccccc1n3C)N2c1ccc2c3ccccc3c3ccccc3c2c1]

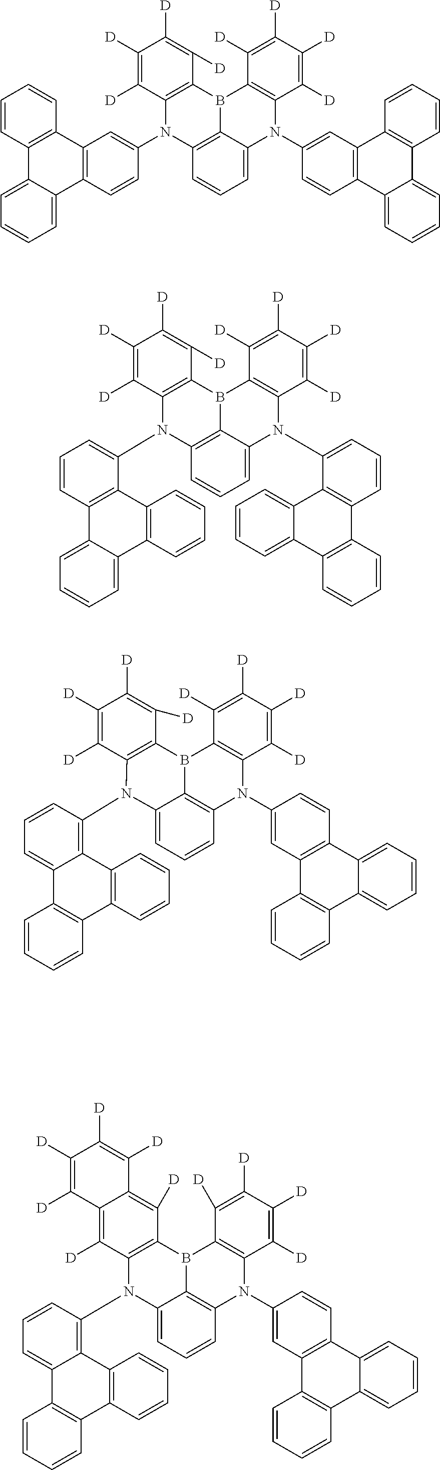

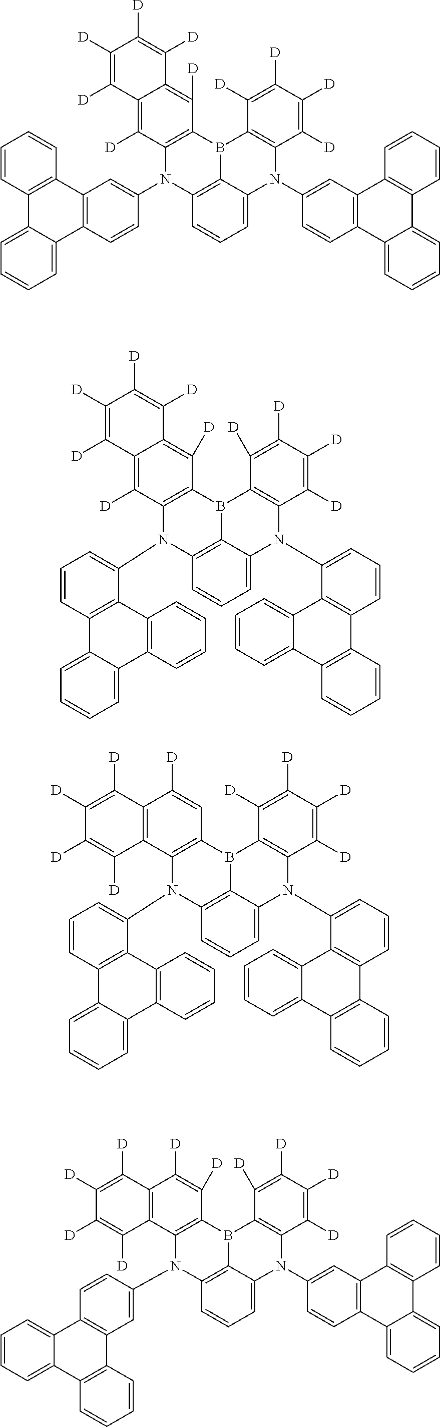

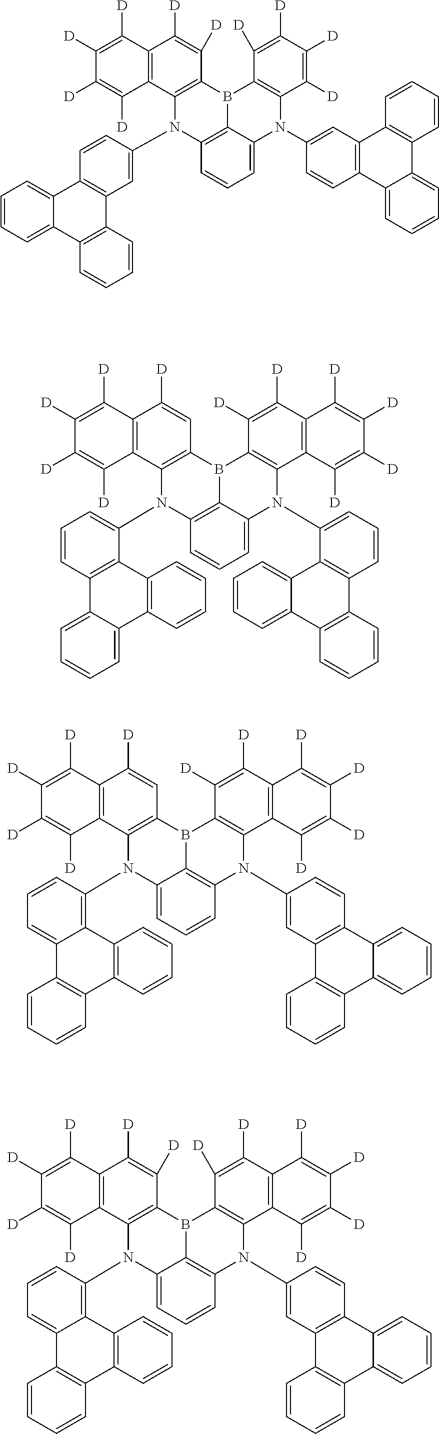

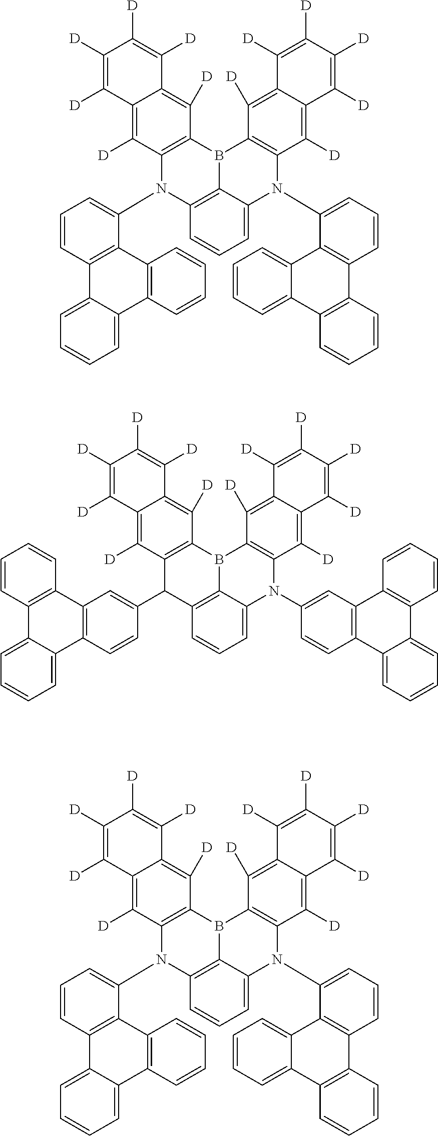

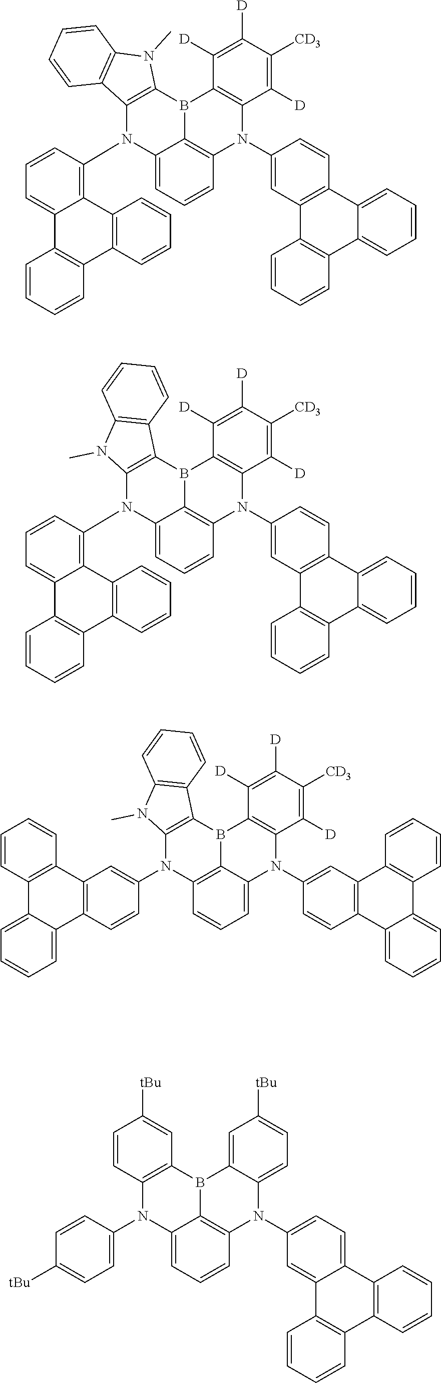 [SMILES: [2H]c1c([2H])c(C([2H])([2H])[2H])c([2H])c2c1B1c3c(cccc3N(c3cccc4c5ccccc5c5ccccc5c34)c3c1n(C)c1ccccc31)N2c1ccc2c3ccccc3c3ccccc3c2c1 ; [2H]c1c([2H])c(C([2H])([2H])[2H])c([2H])c2c1B1c3c(cccc3N(c3cccc4c5ccccc5c5ccccc5c34)c3c1c1ccccc1n3C)N2c1ccc2c3ccccc3c3ccccc3c2c1 ; [2H]c1c([2H])c(C([2H])([2H])[2H])c([2H])c2c1B1c3c(cccc3N(c3ccc4c5ccccc5c5ccccc5c4c3)c3c1c1ccccc1n3C)N2c1ccc2c3ccccc3c3ccccc3c2c1 ; CC(C)(C)c1ccc(N2c3ccc(C(C)(C)C)cc3B3c4cc(C(C)(C)C)ccc4N(c4ccc5c6ccccc6c6ccccc6c5c4)c4cccc2c43)cc1]

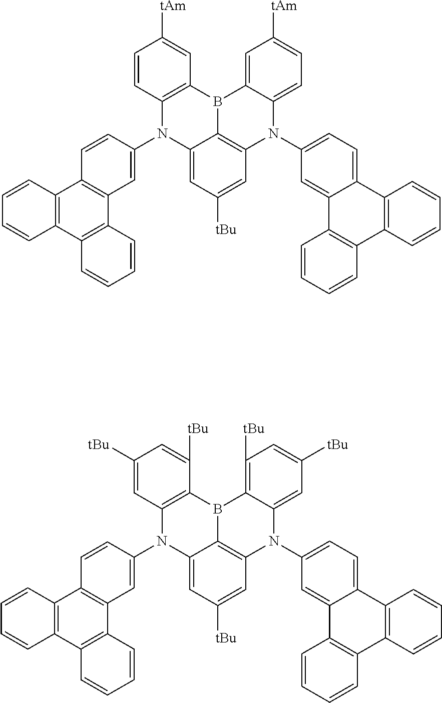

It can be understood that hydrogen atoms in the above-mentioned structures of the boron-containing triphenylene compound may be further substituted.

The boron-containing triphenylene compound provided by the present disclosure can be used as an organic functional material in a functional layer of an organic electronic device, such as the functional layer of an organic light-emitting diode (OLED) device. The organic functional material may include, but is not limited thereto: a hole injection material (HIM), a hole transport material (HTM), an electron transport material (ETM), an electron injection material (EIM), an electron blocking material (EBM), a hole blocking material (HBM), an emitter, a host material, and an organic dye.

In some embodiments, the boron-containing triphenylene compound can be used in the light-emitting layer. Specifically, the boron-containing triphenylene compound can be used as a guest material in the light-emitting layer.

Further, in some embodiments, the boron-containing triphenylene compound provided by the present disclosure can be applied in the light-emitting layer as a blue luminescence material.

The present disclosure further provides a mixture including the boron-containing triphenylene compound as described above and another organic functional material, which is selected from a hole injection material, a hole transport material, an electron transport material, an electron injection material, an electron blocking material, a hole blocking material, an emitter, a host material, or an organic dye. The emitter may be selected from an emitter in a singlet state (such as a fluorescence emitter), an emitter in a triplet state (such as a phosphorescence emitter), or an organic thermally excited delayed fluorescence material.

In some embodiments, the above-mentioned another organic functional material may be a host material, such as a blue light host material. Preferably, the blue light host material may be an anthracene-based organic compound.

The present disclosure further provides a composition, which includes at least the boron-containing triphenylene compound or the mixture as described above, and at least one organic solvent.

It can be understood that the composition may be ink. When the composition is used in a printing process, the viscosity and surface tension of the ink are important parameters. The appropriate surface tension of the ink is suitable for a specific substrate and a specific printing method. In some embodiments, the surface tension of the ink according to the present disclosure ranges from 19 dyne/cm to 50 dyne/cm at an operation temperature or a temperature of 25° C., preferably ranging from 22 dyne/cm to 35 dyne/cm, or 25 dyne/cm to 33 dyne/cm. In some embodiments, the viscosity of the ink according to the present disclosure ranges from 1 cps to 100 cps at an operation temperature or a temperature of 25° C., preferably ranging from 1 cps to 50 cps, 1.5 cps to 20 cps, or 4.0 cps to 20 cps. The ink prepared in the above-mentioned methods is beneficial for inkjet printing.

It can be understood that the viscosity of ink can be adjusted through different methods, such as selecting appropriate solvents or adjusting the concentration of a functional material in the ink. The ink containing the boron-containing triphenylene compound according to the present disclosure is beneficial for adjusting the ink in an appropriate range based on the printing method. In some embodiments, a weight percentage of the boron-containing triphenylene compound or the mixture in the composition ranges from 0.3 wt % to 30 wt %, such as 0.5 wt % to 20 wt %, 0.5 wt % to 15 wt %, 0.5 wt % to 10 wt %, or 1 wt % to 5 wt %.

In some embodiments, the above-mentioned organic solvent may be selected from at least one of an aromatic-based solvent, an heteroaromatic-based solvent, an ester-based solvent, an aromatic ketone-based solvent, an aromatic ether-based solvent, an aliphatic ketone-based solvent, an aliphatic ether-based solvent, an alicyclic compound, an olefin compound, a borate ester compound, or a phosphate ester compound.

In some embodiments, the aromatic-based solvent or the heteroaromatic-based solvent suitable for the present disclosure may be selected from, but not limited thereto: p-diisopropylbenzene, pentyl benzene, tetrahydronaphthalene, cyclohexylbenzene, chloronaphthalene, 1,4-dimethylnaphthalene, 3-isopropylbiphenyl, p-methylisopropyl benzene, dipentyl benzene, tripentyl benzene, pentyl toluene, o-diethylbenzene, m-diethylbenzene, p-diethylbenzene, 1,2,3,4-tetratoluene, 1,2,3,5-tetratoluene, 1,2,4,5-tetratoluene, butadiene benzene, dodecylbenzene, dihexylbenzene, dibutylbenzene, p-diisopropylbenzene, cyclohexylbenzene, benzylbutylbenzene, dimethylnaphthalene, 3-isopropylbiphenyl, p-methylcumene, 1-methylnaphthalene, 1,2,4-trichlorobenzene, 4,4-difluorodiphenylmethane, 1,2-dimethoxy-4-(1-propenyl) benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl) pyridine, benzyl benzoate, 1,1-bis(3,4-dimethylphenyl) ethane, 2-isopropylnaphthalene, quinoline, isoquinoline, methyl 2-furanoate, and/or ethyl 2-furanoate.

In some embodiments, the ester-based solvent suitable for the present disclosure may be selected from, but not limited thereto: octanoate, sebacate, stearate, benzoate, phenylacetate, cinnamate, oxalate, maleate, alkyl lactone, oleate, and the like. Preferably, the ester-based solvent may be selected from at least one of octyl octanoate, diethyl sebacate, diallyl phthalate, and/or isononyl isononanoate.

In some embodiments, the aromatic ketone-based solvent suitable for the present disclosure may be selected from, but not limited thereto: 1-tetrahydronaphthalenone, 2-tetrahydronaphthalenone, 2-(phenyl epoxy) tetrahydronaphthalenone, 6-(methoxyl) tetrahydronaphthalenone, acetophenone, phenylacetone, benzophenone, and derivatives of these compounds. For example, the above-mentioned derivatives may be selected from at least one of 4-methylacetophenone, 3-methylacetophenone, 2-methylacetophenone, 4-methylphenylacetone, 3-methylphenylacetone, and/or 2-methylphenylacetone.

In some embodiments, the aromatic ether-based solvent suitable for the present disclosure may be selected from, but not limited thereto: 3-phenoxytoluene, butoxybenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylbasic ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenylanisole, 1,2-dimethoxybenzene, 1-methoxynaphthalene, diphenyl ether, 2-phenoxymethyl ether, 2-phenoxytetrahydrofuran, and/or ethyl-2-naphthyl ether.

In some embodiments, the aliphatic ketone-based solvent suitable for the present disclosure may be selected from, but not limited thereto: 2-nonone, 3-nonone, 5-nonone, 2-decanone, 2,5-hexanedione, 2,6,8-trimethyl-4-nonone, fenchone, phorone, isophorone, and/or di-n-pentyl ketone.

In some embodiments, the aliphatic ether-based solvent suitable for the present disclosure may be selected from, but not limited thereto: amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, and/or tetraethylene glycol dimethyl ether.

It can be understood that the organic solvent may be used individually or used as a mixture of two or more organic solvents.

In some embodiments, the composition according to the present disclosure includes another organic solvent, other than the boron-containing triphenylene compound or the mixture, and the organic solvent as described above. Examples of another organic solvent may be selected from, but not limited thereto: methanol, ethanol, 2-methoxyethanol, dichloromethane, chloroform, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethyl sulfoxide, tetralin, naphthane, and/or indene.

In some embodiments, according to the composition of the present application, a boiling point needs to be considered when selecting the organic solvent. In some embodiments, the boiling point of the organic solvent is greater than or equal to 150° C., preferably greater than or equal to 180° C., 200° C., 250° C., or 300° C. The boiling point within these ranges are beneficial to prevent nozzles of inkjet printing heads from clogging.

It can be understood that the organic solvent can be evaporated from a solvent system to form a film including the boron-containing triphenylene compound.

In some embodiments, the composition may be a solution. In some embodiments, the composition may be a suspension. The solution or the suspension may also include an additive for adjusting viscosity, forming performance of a film, improving adhesion, or the like. The additive may be selected from but not limited to at least one of a surfactant, a lubricant, a wetting agent, a dispersant, a hydrophobic agent, and an adhesive.

The present disclosure further provides a use of the composition as a coating material or printing ink in the preparation of an organic electronic device. In some embodiments, the composition may be used to prepare the organic electronic device by a printing process or coating process. The printing process or the coating process includes but is not limited thereto: inkjet printing, intaglio printing, jet printing, letterpress printing, screen printing, dip coating, rotating coating, scraper coating, roller printing, rotary roller printing, lithographic printing, flexographic printing brush, rotary printing, spray coating, brush coating or pad printing, slit extrusion coating, or the like. In some embodiments, the printing process or the coating process may be intaglio printing, jet printing, or inkjet printing.

The present disclosure further provides a use of the boron-containing triphenylene compound, the mixture, or the composition as described above in the organic electronic device. The organic electronic device includes at least one organic functional layer. The organic functional layer includes at least the boron-containing triphenylene compound or the mixture as described above, or the organic functional layer is prepared from the above-mentioned composition.

Further, the organic electronic device may include a cathode, an anode, and at least one organic functional layer. The organic functional layer includes at least the boron-containing triphenylene compound or the mixture as described above, or the organic functional layer is prepared from the above-mentioned composition. The organic functional layer may include, but is not limited to, a hole injection layer (HIL), a hole transport layer (HTL), a light-emitting layer (EML), an electron blocking layer (EBL), an electron injection layer (EIL), an electron transport layer (ETL), and a hole blocking layer (HBL). In some embodiments, the organic functional layer is the light-emitting layer.

The organic electronic device may be, but not limited to, an organic light-emitting diode (OLED), an organic photovoltaic battery (OPV), an organic light-emitting battery (OLEEC), an organic field-effect tube (OFET), an organic light-emitting field-effect tube, an organic laser, an organic spin electron device, an organic sensor, an organic plasmon emission diode (OPED), or the like. In some embodiments, the organic electronic device may be an organic electroluminescent device, such as the OLED, or the organic light-emitting field-effect tube. In some embodiments, the organic electronic device may be the OLED. In at least one embodiment, the boron-containing triphenylene compound of the present application is applied to the light-emitting layer of the OLED device.

In an embodiment, the organic electronic device includes a substrate, and an anode, a hole injection layer, a hole transport layer, an electron blocking layer, a light-emitting layer, an electron transport layer, an electron injection layer, and a cathode sequentially stacked on the substrate. The light-emitting layer includes at least the boron-containing triphenylene compound or the mixture as described above, or the light-emitting layer is prepared from the composition as described above. It can be understood that the structure of the organic electronic device is not limited thereto.

The substrate may be a transparent substrate or an opaque substrate. In addition, the substrate may be rigid or elastic. Specifically, the substrate may be plastic, metal, a semiconductor wafer, or a glass. The substrate may have a smooth surface. For example, the substrate may be a substrate without surface defects. In some embodiments, the substrate may be flexible, and a material of the substrate may be selected from but not limited to a polymer film or plastic. A glass transition temperature Tg of a material of the substrate may be greater than 150° C., 200° C., 250° C., or 300° ° C. Examples of a suitable flexible substrate include polyethylene terephthalate (PET) and polyethylene naphthalene-2,6-dicarboxylate (PEN).

The anode is an electrode used for injecting holes, and the holes in the anode may be easily injected into the hole injection layer, the hole transport layer, or the light-emitting layer. A material of the anode may include at least one of conductive metal, conductive metal oxide, and conductive polymer. In some embodiments, absolute value of a difference between work function of the anode and HOMO energy level or valence band energy level of a light-emitting material of the light-emitting layer, or a p-type semiconductor material of the HIL, the HTL, or the EBL is less than 0.5 eV, 0.3 eV, or 0.2 eV. Examples of the material of the anode includes but is not limited thereto: aluminum (Al), copper (Cu), aurum (Au), argentum (Ag), magnesium (Mg), ferrum (Fe), cobalt (Co), nickel (Ni), manganese (Mn), palladium (Pd), platinum (Pt), indium tin oxide (ITO), aluminum doped zinc oxide (AZO), or the like. The material of the anode may be applied to by any suitable technology, such as a suitable physical vapor deposition method including RF magnetron sputtering, vacuum thermal evaporation, electron beam (e-beam), or the like. In some embodiments, the anode is a patterned structure.

The cathode is an electrode used for injecting electrons, and the electrons in the cathode can be easily injected into the electron injection layer, the electron transport layer, or the light-emitting layer. A material of the cathode may include at least one of conductive metal and conductive metal oxide. In some embodiments, absolute value of a difference between work function of the cathode and LUMO energy level or valence band energy level of the light-emitting material of the light-emitting layer, or a n-type semiconductor material of the EIL, the ETL, or the HBL is less than 0.5 eV, 0.3 eV, or 0.2 eV. All materials that can be used in the cathode of an organic electronic device may be used as the material of the cathode of the organic electronic device according to the present disclosure. The material of the cathode includes, but is not limited thereto: Al, Au, Ag, calcium (Ca), barium (Ba), Mg, LiF/Al, MgAg alloy, BaF₂/Al, Cu, Fe, Co, Ni, Mn, Pd, Pt, ITO, or the like. The material of the cathode may be applied to by any suitable technology, such as a suitable physical vapor deposition method including RF magnetron sputtering, vacuum thermal evaporation, electron beam (e-beam), or the like.

The hole injection layer can be used for promoting an injection of holes from the anode to the light-emitting layer. A hole injection material in the hole injection layer may be used to receive holes injected from a positive electrode at low voltages. Preferably, HOMO energy level of the hole injection material is between work function of a positive electrode material and HOMO energy level of a peripheral organic material layer. The hole injection material includes, but is not limited thereto: metalloporphyrin, oligothiophene, an organic material based on arylamine, an organic material based on hexacyano hexaazabenzophenanthrene, an organic material based on quinacridone, an organic material based on perylene, anthraquinone, conductive polymer based on polyaniline, polythiophene, or the like.

The hole transport layer can be used for transmitting holes. A hole transport material in the hole transport layer has high hole mobility, and can be used to receive holes transmitted from the anode or the hole injection layer and transmit the holes to the light-emitting layer. The hole transport material includes, but is not limited thereto: an organic material based on aromatic amine, an organic material based on carbazole, conductive polymer, block copolymer with both conjugated and non-conjugated portions.

The electron blocking layer can be disposed between the hole transport layer and the light-emitting layer. A material of the electron blocking layer can be a compound based on spiro indole acridine or other materials known in the art.

The light-emitting layer can emit red light, green light, or blue light, and may be made of a phosphorescence material or a fluorescence material. The light-emitting material in the light-emitting layer may be a material that can receive holes and electrons from the hole transport layer and the electron transport layer, respectively, and combine them to emit light in a visible light region. Preferably, the light-emitting material may be a material with good fluorescence quantum efficiency or phosphorescence quantum efficiency.

Examples of a host material used for the light-emitting layer include a fused aromatic derivative or a heteroaromatic compound. Specifically, examples of the fused aromatic derivatives include but are not limited thereto: an anthracene derivative, a pyrene derivative, a naphthalene derivative, a pentacene derivative, a phenanthrene compound, a fluoranthene compound, or the like. Examples of the heteroaromatic compound include but are not limited thereto: a carbazole derivative, a dibenzofuran derivative, a ladder type furan compound, a pyrimidine derivative, or the like.

The electron transport layer can be used for transmitting electrons. Preferably, an electron transport material in the electron transport layer has high electron mobility, and can be used to receive electrons injected from a negative electrode and transmit the electrons to the light-emitting layer. Examples of the electron transport material may include, but are not limited thereto: an Al-based complex of 8-hydroxyquinoline, a complex containing Alq₃, an organic radical compound, a hydroxyflavone metal complex, 8-hydroxyquinoline lithium (LiQ), and a compound based on benzimidazole.

The electron injection layer can be used for injecting electrons. Preferably, an electron injection material in the electron injection layer has ability to transmit electrons, and can achieve an effect of injecting electrons from a negative electrode and an excellent effect of injecting electrons into the light-emitting layer or the light-emitting material, preventing excitons generated by the light-emitting layer from transmitting to the hole injection layer. Further, the electron injection material has excellent ability to form a thin film. Examples of the electron injection material include, but are not limited thereto: 8-hydroxyquinoline lithium (LiQ), fluorenone, anthraquinone dimethyl, biphenylquinone, thian dioxide, azole, diazole, triazole, imidazole, perylene tetracarboxylic acid, fluorene methane, anthrone, derivatives thereof, a metal complex, a 5-membered ring derivative containing nitrogen, or the like.

It can be understood that, the organic electronic device may further include the hole blocking layer disposed between the light-emitting layer and the electron transport layer. The hole blocking layer is a layer that blocks holes from reaching a negative electrode and usually formed under the same conditions as the hole injection layer. Examples of a hole blocking material in the hole blocking layer may include, but are not limited thereto: a diazole derivative, a triazole derivative, a phenanthroline derivative, bromocresol purple sodium salt (BCP), an aluminum complex, or the like.

An emission wavelength of the organic electronic device may range from 300 nm to 1000 nm, 350 nm to 900 nm, or 400 nm to 800 nm.

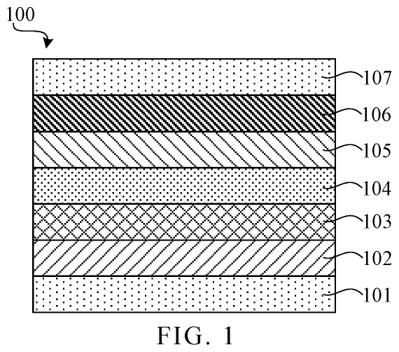

Referring to FIG. 1, some specific embodiments of the present disclosure provide an organic electronic device 100, which includes a substrate 101, an anode 102, a hole injection layer 103, a hole transport layer 104, a light-emitting layer 105, an electron transport layer 106, and a cathode 107.

In some embodiments, the organic electronic device according to the present disclosure is a solution type organic electronic device, and one or more functional layers in the organic electronic device is prepared by a printing process. Further, the solution type organic electronic device may be a solution type OLED.

The present disclosure further provides an application of the organic electronic device in preparation of various electronic devices. The electronic devices include, but are not limited thereto: a display device, an illumination device, a light source, a sensor, or the like.

The present disclosure further provides an electronic device including the organic electronic device. The electronic device may be, but not limited to, a display device, an illumination source, a sensor, or the like.

The following are specific embodiments to illustrate the present disclosure. The following embodiments are only partial embodiments of the present disclosure and are not a limitation to the present disclosure.

### SPECIFIC EXAMPLES

The following is specific illustration of synthesis routes and synthesis methods of the compounds containing boron and triphenylene (hereinafter referred to compounds 1-14) of the present disclosure through specific examples. The following examples are only preferred examples of the present disclosure, but cannot be understood as limitations to the present disclosure.

### Example 1

Synthetic Route of the Compound 1 is as follows:

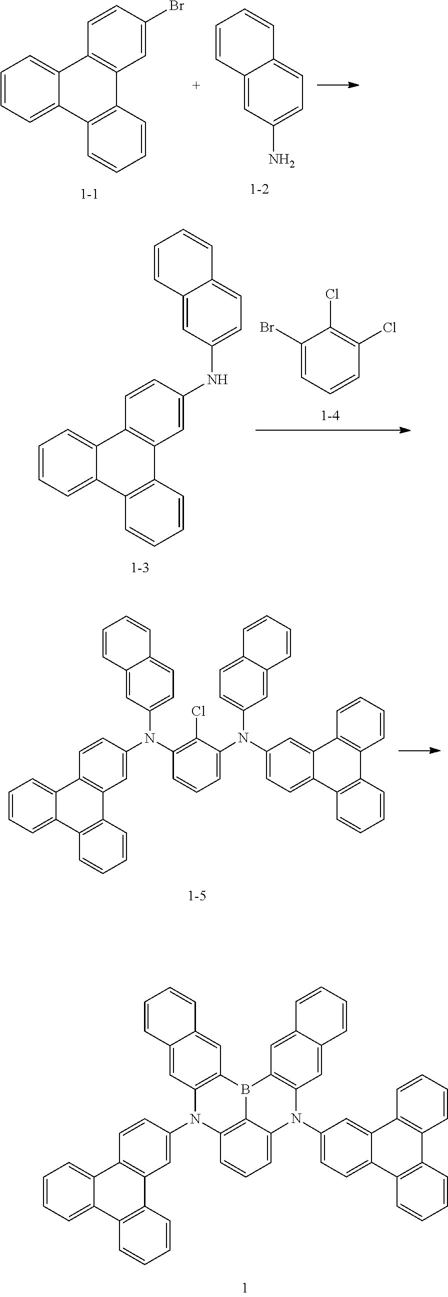

### 1) Synthesis of Intermediate 1-3

Compound 1-1 (10 mmol), compound 1-2 (10 mmol), palladium bis dibenzylideneacetone (Pd(dba)₂, 0.1 mmol), tri-tert-butylphosphine (TTBP, 0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 1-3 (7.87 mmol) with yield of 78.7%. A result of atmospheric solids analysis probe-mass spectrometry (ASAP-MS) of the intermediate 1-3 was as follows: MS (ASAP)=369.

### 2) Synthesis of Intermediate 1-5

The intermediate 1-3 (20 mmol), compound 1-4 (10 mmol), bis(di tert-butyl-4-dimethylamino phenylphosphine)palladium chloride (Pd-132, 0.1 mmol), 2-dicyclohexylphosphine-2′,6′-dimethoxyl-1,1′-biphenyl (S-Phos, 0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 1-5 (6.08 mmol) with yield of 60.8%. MS=846.

### 3) Synthesis of Compound 1

The intermediate 1-5 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 1 with yield of 42.1%. MS=820.

### Example 2

Synthetic Route of the Compound 2 is as follows:

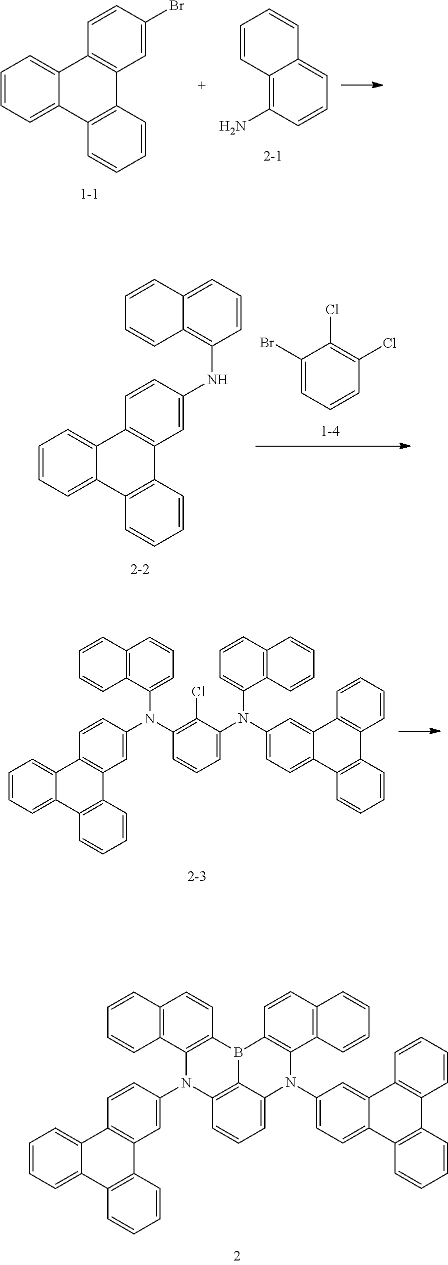

### 1) Synthesis of Intermediate 2-2

Compound 1-1 (10 mmol), compound 2-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 2-2 (7.94 mmol) with yield of 79.4%. MS=369.

### 2) Synthesis of Intermediate 2-3

The intermediate 2-2 (20 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 2-3 (6.81 mmol) with yield of 68.1%. MS=846.

### 3) Synthesis of Compound 2

The intermediate 2-3 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 2 with yield of 35.9%. MS=820.

### Example 3

Synthetic Route of the Compound 3 is as follows:

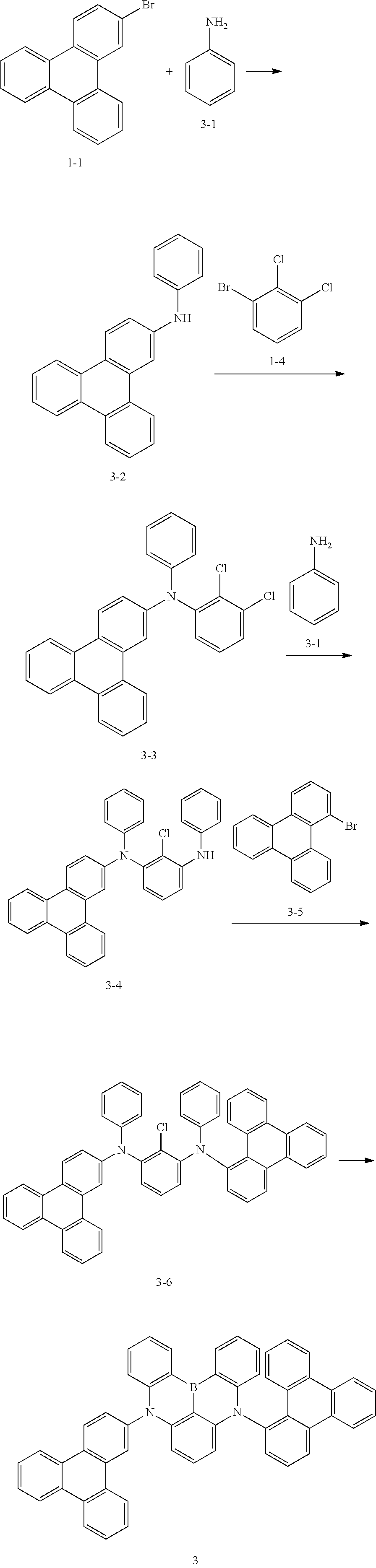

### 1) Synthesis of Intermediate 3-2

Compound 1-1 (10 mmol), compound 3-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 3-2 (8.59 mmol) with yield of 85.9%. MS=319.

### 2) Synthesis of Intermediate 3-3

The intermediate 3-2 (10 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 3-3 (8.49 mmol) with yield of 84.9%. MS=463.

### 3) Synthesis of Intermediate 3-4

The intermediate 3-3 (10 mmol), compound 3-1 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 3-4 (8.15 mmol) with yield of 81.5%. MS=520.

### 4) Synthesis of Intermediate 3-6

The intermediate 3-4 (10 mmol), compound 3-5 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 3-6 (5.94 mmol) with yield of 59.4%. MS=746.

### 5) Synthesis of Compound 3

The intermediate 3-6 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hours. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 3 with yield of 25.6%. MS=720.

### Example 4

Synthetic Route of the Compound 4 is as follows:

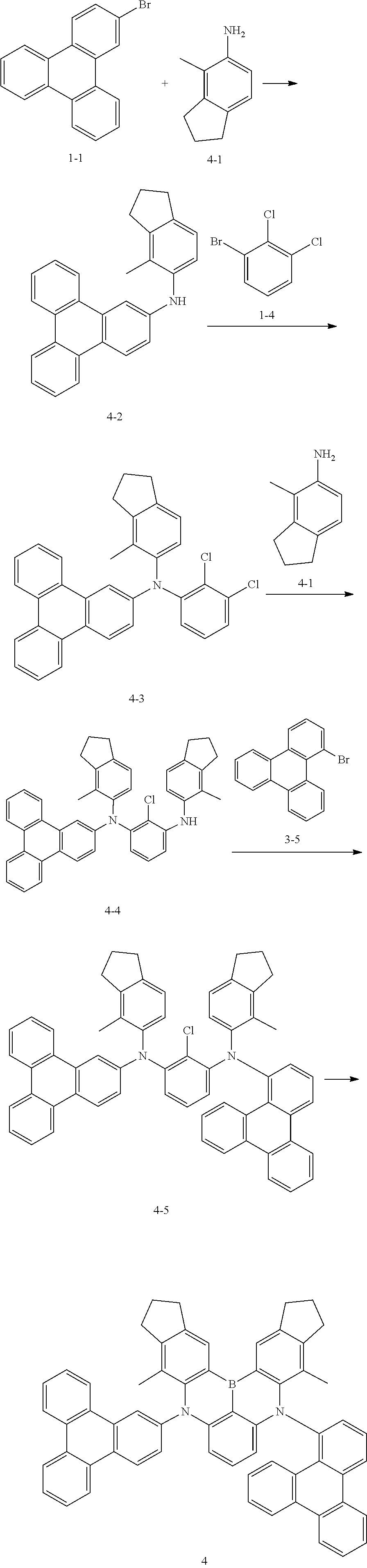

### 1) Synthesis of Intermediate 4-2

Compound 1-1 (10 mmol), compound 4-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 4-2 (7.29 mmol) with yield of 72.9%. MS=373.

### 2) Synthesis of Intermediate 4-3

The intermediate 4-2 (10 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 4-3 (6.97 mmol) with yield of 69.7%. MS=517.

### 3) Synthesis of Intermediate 4-4

The intermediate 4-3 (10 mmol), compound 4-1 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 4-4 (5.56 mmol) with yield of 55.6%. MS=628.

### 4) Synthesis of Intermediate 4-5

The intermediate 4-4 (10 mmol), compound 3-5 (10 mmol), Pd-132 (0.1 mmol), S-Phos (0.2 mmol), and sodium tert-butoxide (30 mmol) were dissolved in toluene, and stirred for 6 hours at a temperature of 100° ° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 4-5 (5.78 mmol) with yield of 57.8%. MS=854.

### 5) Synthesis of Compound 4

The intermediate 4-5 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 4 with yield of 47.2%. MS=828.

### Example 5

Synthetic Route of the Compound 5 is as follows:

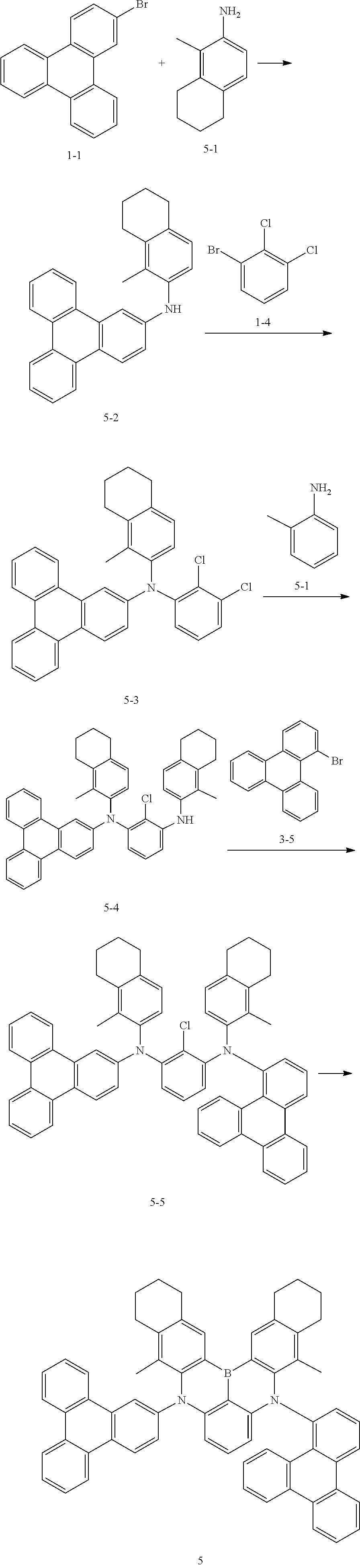

### 1) Synthesis of Intermediate 5-2

Compound 1-1 (10 mmol), compound 5-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 5-2 (6.58 mmol) with yield of 65.8%. MS=387.

### 2) Synthesis of Intermediate 5-3

The intermediate 5-2 (10 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 5-3 (7.21 mmol) with yield of 72.1%. MS=531.

### 3) Synthesis of Intermediate 5-4

The intermediate 5-3 (10 mmol), compound 5-1 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 5-4 (5.28 mmol) with yield of 52.8%. MS=656.

### 4) Synthesis of Intermediate 5-5

The intermediate 5-4 (10 mmol), compound 3-5 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 5-5 (5.37 mmol) with yield of 53.7%. MS=882.

### 5) Synthesis of Compound 5

The intermediate 5-5 (10 mmol) and dried tert-butyl benzene (100 mL) were added into a three necked-flask (250 mL), and cooled to a temperature of 30° ° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 5 with yield of 22.9%. MS=856.

### Example 6

Synthetic Route of the Compound 6 is as follows:

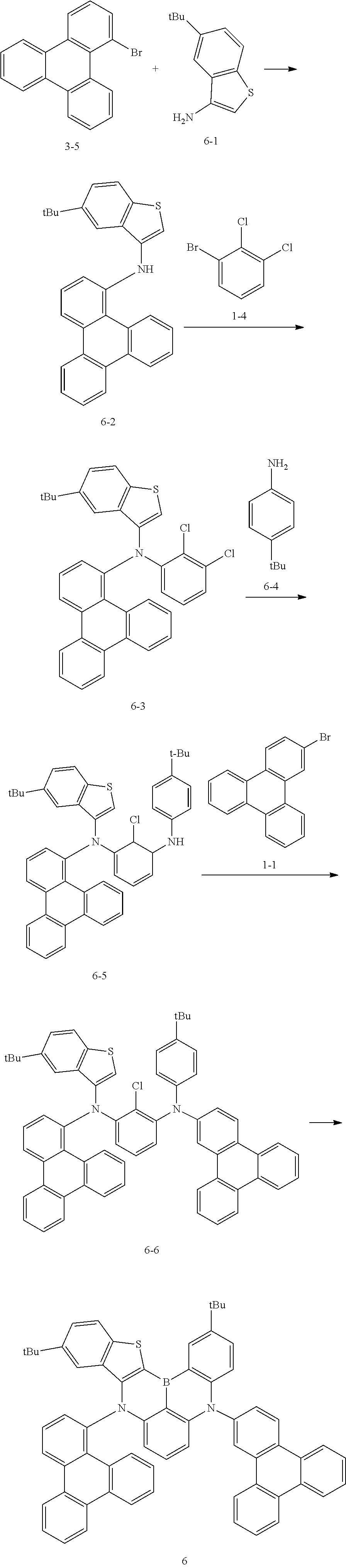

### 1) Synthesis of Intermediate 6-2

Compound 6-1 (10 mmol), compound 3-5 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 6-2 (6.08 mmol) with yield of 60.8%. MS=431.

### 2) Synthesis of Intermediate 6-3

The intermediate 6-2 (10 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 6-3 (7.74 mmol) with yield of 77.4%. MS=575.

### 3) Synthesis of Intermediate 6-5

The intermediate 6-3 (10 mmol), compound 6-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 6-5 (6.09 mmol) with yield of 60.9%. MS=668.

### 4) Synthesis of Intermediate 6-6

The intermediate 6-5 (10 mmol), compound 1-1 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 6-6 (4.97 mmol) with yield of 49.7%. MS=914.

### 5) Synthesis of Compound 6

The intermediate 6-6 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 6 with yield of 32.7%. MS=888.

### Example 7

Synthetic Route of the Compound 7 is as follows:

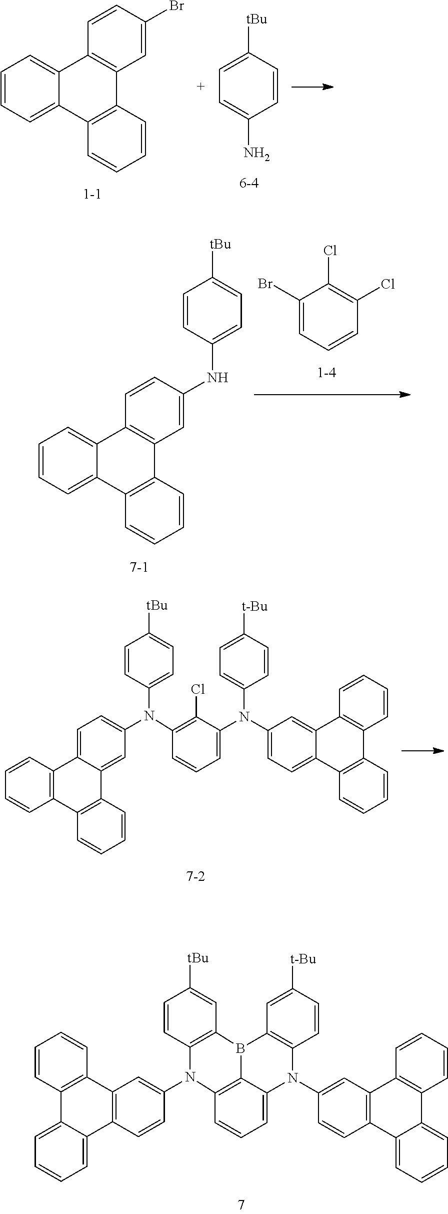

### 1) Synthesis of Intermediate 7-1

Compound 1-1 (10 mmol), compound 6-4 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 7-1 (8.29 mmol) with yield of 82.9%. MS=375.

### 2) Synthesis of Intermediate 7-2

The intermediate 7-1 (20 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 7-2 (8.57 mmol) with yield of 85.7%. MS=858.

### 3) Synthesis of Compound 7

The intermediate 7-2 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 7 with yield of 44.7%. MS=832.

### Example 8

Synthetic Route of the Compound 8 is as follows:

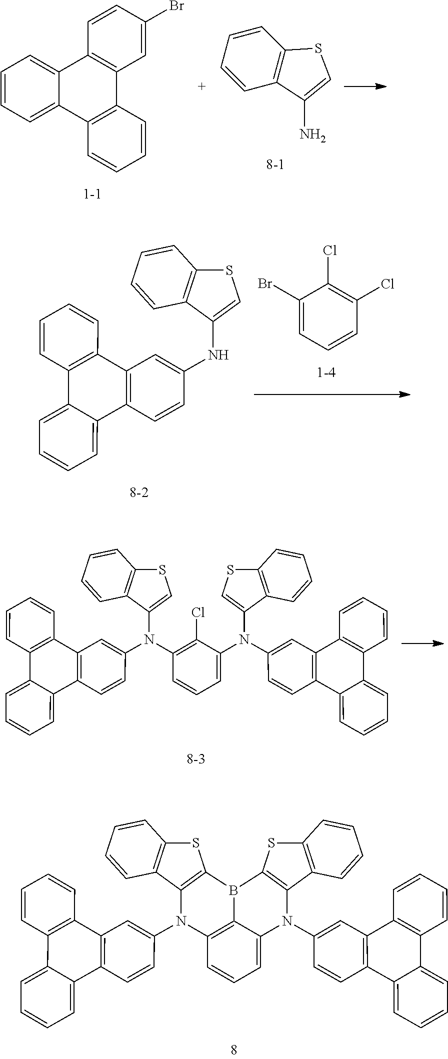

### 1) Synthesis of Intermediate 8-2

Compound 1-1 (10 mmol), compound 8-1 (10 mmol), Pd(dba)₂ (0.1 mmol), TTBP (0.2 mmol), and sodium tert-butoxide (30 mmol) were dissolved in toluene, and stirred for 6 hours at a temperature of 100° ° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 8-2 (8.46 mmol) with yield of 84.6%. MS=375.

### 2) Synthesis of Intermediate 8-3

The intermediate 8-2 (20 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 8-3 (7.86 mmol) with yield of 78.6%. MS=858.

### 3) Synthesis of Compound 8

The intermediate 8-3 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 8 with yield of 38.4%. MS=832.

### Example 9

Synthetic Route of the Compound 9 is as follows:

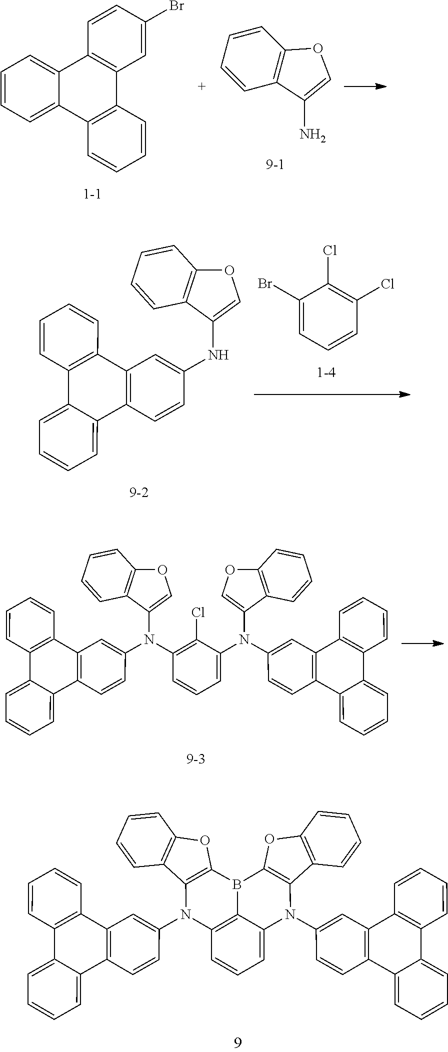

### 1) Synthesis of Intermediate 9-2

Compound 1-1 (10 mmol), compound 9-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 9-2 (8.31 mmol) with yield of 83.1%. MS=359.

### 2) Synthesis of Intermediate 9-3

The intermediate 9-2 (20 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 9-3 (7.67 mmol) with yield of 76.7%. MS=826.

### 3) Synthesis of Compound 9

The intermediate 9-3 (10 mmol) and dried tert-butyl benzene (100 mL) were added into a three necked-flask (250 mL), and cooled to a temperature of 30° ° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 9 with yield of 33.4%. MS=800.

### Example 10

Synthetic Route of the Compound 10 is as follows:

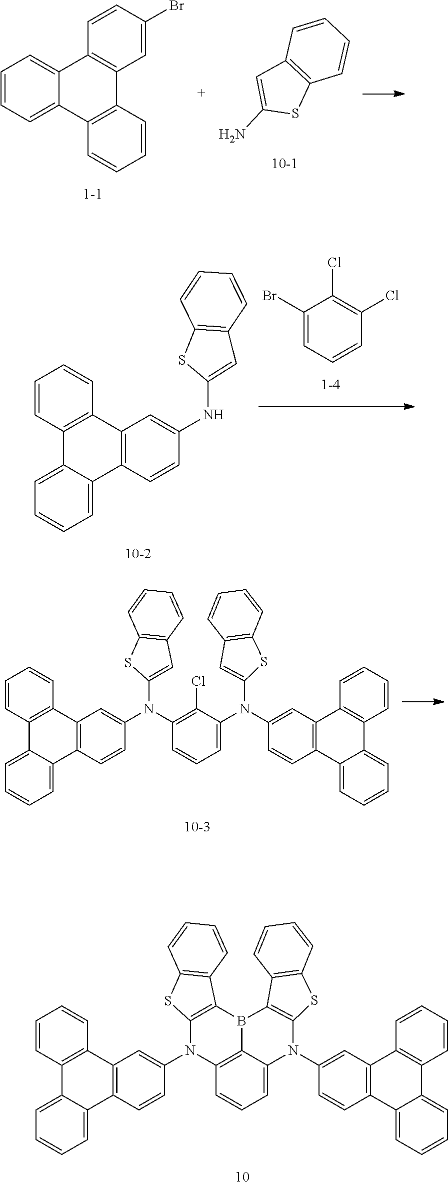

### 1) Synthesis of Intermediate 10-2

Compound 1-1 (10 mmol), compound 10-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 10-2 (8.06 mmol) with yield of 80.6%. MS=376.

### 2) Synthesis of Intermediate 10-3

The intermediate 10-2 (20 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 10-3 (6.91 mmol) with yield of 69.1%. MS=858.

### 3) Synthesis of Compound 10

The intermediate 10-3 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 10 with yield of 42.8%. MS=832.

### Example 11

Synthetic Route of the Compound 11 is as follows:

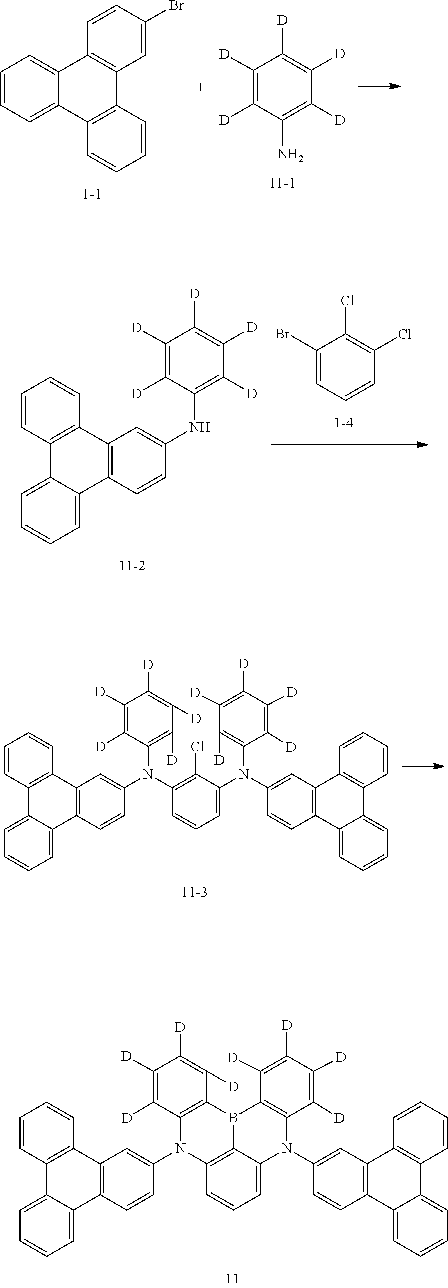

### 1) Synthesis of Intermediate 11-2

Compound 1-1 (10 mmol), compound 11-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 11-2 (8.36 mmol) with yield of 83.6%. MS=324.

### 2) Synthesis of Intermediate 11-3

The intermediate 11-2 (20 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 11-3 (6.21 mmol) with yield of 62.1%. MS=756.

### 3) Synthesis of Compound 11

The intermediate 11-3 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 11 with yield of 36.7%. MS=728.

### Example 12

Synthetic Route of the Compound 12 is as follows:

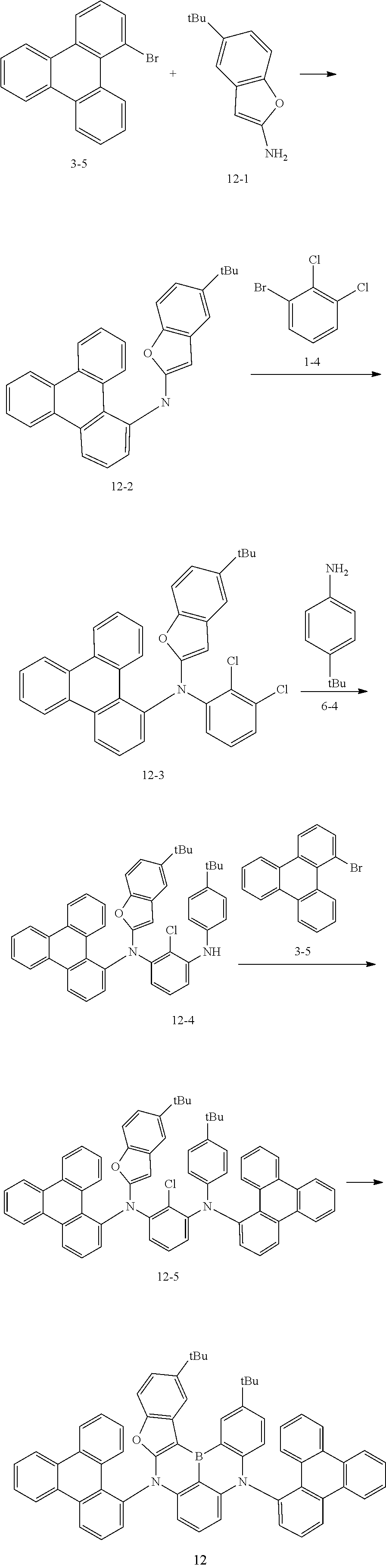

### 1) Synthesis of Intermediate 12-2

Compound 12-1 (10 mmol), compound 3-5 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 12-2 (5.38 mmol) with yield of 53.8%. MS=415

### 2) Synthesis of Intermediate 12-3

The intermediate 12-2 (10 mmol), compound 1-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 12-3 (4.94 mmol) with yield of 49.4%. MS=559.

### 3) Synthesis of Intermediate 12-4

The intermediate 12-3 (10 mmol), compound 6-4 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 12-4 (6.67 mmol) with yield of 66.7%. MS=672.

### 4) Synthesis of Intermediate 12-5

The intermediate 12-4 (10 mmol), compound 3-5 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 12-5 (4.11 mmol) with yield of 41.1%. MS=898.

### 5) Synthesis of Compound 12

The intermediate 12-5 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 12 with yield of 15.9%. MS=872.

### Example 13

Synthetic Route of the Compound 13 is as follows

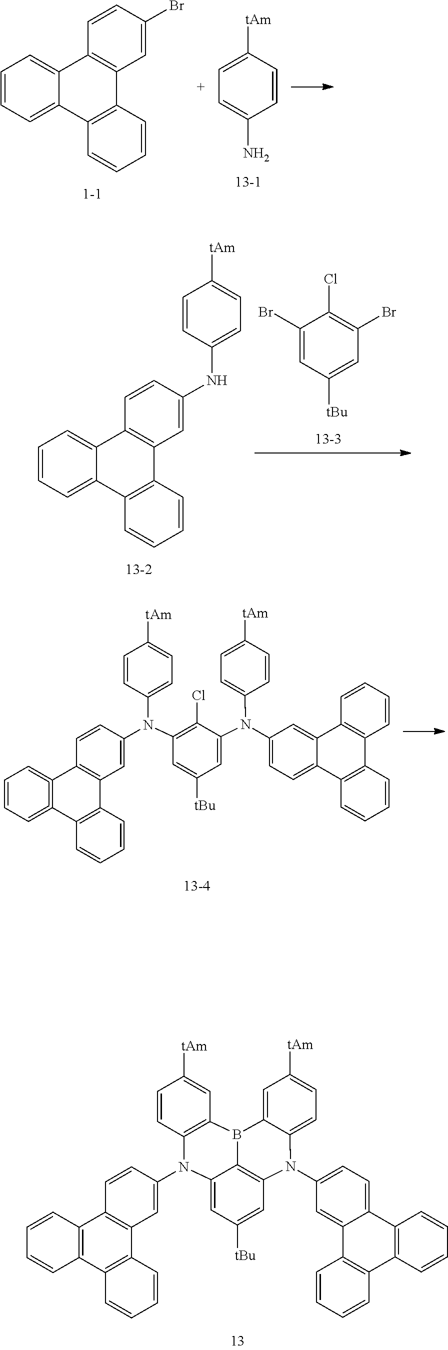

### 1) Synthesis of Intermediate 13-2

Compound 1-1 (10 mmol), compound 13-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 13-2 (8.11 mmol) with yield of 81.1%. MS=389.

### 2) Synthesis of Intermediate 13-4

The intermediate 13-2 (20 mmol), compound 13-3 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 13-4 (7.48 mmol) with yield of 74.8%. MS=942.

### 3) Synthesis of Compound 13

The intermediate 13-4 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 13 with yield of 32.8%. MS=916.

### Example 14

Synthetic Route of the Compound 14 is as follows

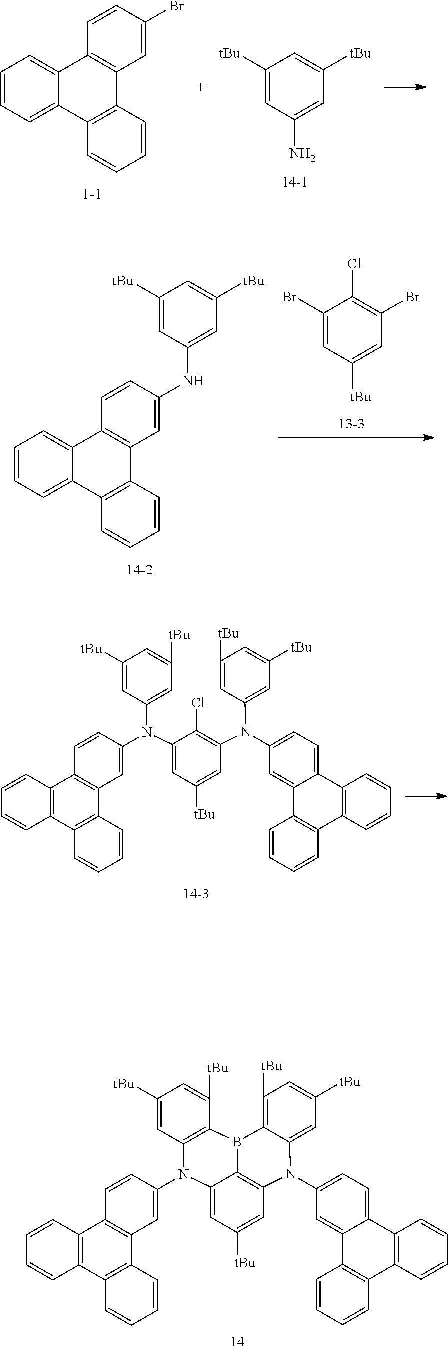 [SMILES: Brc1ccc2c3ccccc3c3ccccc3c2c1 ; CC(C)(C)c1cc(N)cc(C(C)(C)C)c1 ; CC(C)(C)c1cc(Nc2ccc3c4ccccc4c4ccccc4c3c2)cc(C(C)(C)C)c1 ; CC(C)(C)c1cc(Br)c(Cl)c(Br)c1 ; CC(C)(C)c1cc(N(c2ccc3c4ccccc4c4ccccc4c3c2)c2cc(C(C)(C)C)cc(N(c3cc(C(C)(C)C)cc(C(C)(C)C)c3)c3ccc4c5ccccc5c5ccccc5c4c3)c2Cl)cc(C(C)(C)C)c1 ; CC(C)(C)c1cc2c3c(c1)N(c1ccc4c5ccccc5c5ccccc5c4c1)c1cc(C(C)(C)C)cc(C(C)(C)C)c1B3c1c(cc(C(C)(C)C)cc1C(C)(C)C)N2c1ccc2c3ccccc3c3ccccc3c2c1]

### 1) Synthesis of Intermediate 14-2

Compound 1-1 (10 mmol), compound 14-1 (10 mmol), Pd(dba)₂ (0.1 mmol), TTBP (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 14-2 (8.51 mmol) with yield of 85.1%. MS=431.

### 2) Synthesis of Intermediate 14-3

The intermediate 14-2 (20 mmol), compound 13-3 (10 mmol), Pd-132 (0.1 mmol), S-Phos (0.2 mmol), and sodium tert-butoxide (30 mmol) were dissolved in toluene, and stirred for 6 hours at a temperature of 100° C. in a nitrogen atmosphere. After the reaction was completed, the reaction solution was cooled, then toluene was removed by rotary evaporation. Subsequently, the solution was extracted and washed with water to obtain an organic phase. The organic phase was purified by column chromatography to obtain the intermediate 14-3 (7.11 mmol) with yield of 71.1%. MS=1026.

### 3) Synthesis of Compound 14

The intermediate 14-3 (10 mmol) and dried tert-butyl benzene (100 mL) were added into a three necked-flask (250 mL), and cooled to a temperature of 30° C. in a nitrogen atmosphere. Tert-butyllithium (t-BuLi, 21 mmol) and n-hexane were added into the solution dropwise. The temperature of the solution was raised to 60° C., then the solution was carried out for 2 hours. After the reaction was completed, n-hexane was removed from the reaction solution by rotary evaporation. Then the reaction solution was cooled again to the temperature of 30° C., and boron tribromide solution (21 mmol) was added. The temperature was raised to room temperature, and the reaction solution was stirred for 0.5 hour. Subsequently, the reaction solution was cooled to a temperature of 0° C., and N, N-diisopropylethylamine (42 mmol) was added dropwise. After the dropping was completed, the temperature was raised to room temperature under a stirring state. The temperature was continuously raised to 120° C., the reaction solution was stirred for 3 hours, and cooled to room temperature. Then sodium carbonate aqueous solution and ethyl acetate were added into the reaction solution to quench the reaction. The aqueous phase was extracted with ethyl acetate and the organic phases were merged, and the solvent was removed by rotary evaporation to obtain a crude product. Then the crude product was purified by column chromatography to obtain a pure product. Finally, the pure product was further purified by recrystallization using toluene and ethyl acetate as solvents, to obtain a light yellow solid powder that was the compound 14 with yield of 31.5%. MS=1000.

In addition, the present disclosure provides a comparative example, in which the structure of the comparative compound 1 is as follows:

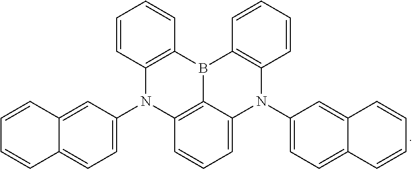 [SMILES: c1ccc2c(c1)B1c3ccccc3N(c3ccc4ccccc4c3)c3cccc(c31)N2c1ccc2ccccc2c1]

In the present disclosure, HOMO energy levels, LUMO energy levels, T1 energy levels, and sS1 energy levels of the compounds 1-14 prepared from the above-mentioned examples 1-14 and the comparative compound 1 are tested, as shown in table 1 below.

TABLE 1

| | | HOMO | LUMO | T1 | S1 |
|---|---|---|---|---|---|
| Example | Compound | (eV) | (eV) | (eV) | (eV) |
| Example 1 | Compound 1 | −5.13 | −2.25 | 2.51 | 3.01 |
| Example 2 | Compound 2 | −5.12 | −2.23 | 2.55 | 3.07 |
| Example 3 | Compound 3 | −5.16 | −2.21 | 2.52 | 3.11 |
| Example 4 | Compound 4 | −5.07 | −2.26 | 2.52 | 3.08 |
| Example 5 | Compound 5 | −5.04 | −2.27 | 2.57 | 3.04 |
| Example 6 | Compound 6 | −5.01 | −2.28 | 2.54 | 3.01 |
| Example 7 | Compound 7 | −5.13 | −2.26 | 2.55 | 3.07 |
| Example 8 | Compound 8 | −5.15 | −2.27 | 2.56 | 3.03 |
| Example 9 | Compound 9 | −5.07 | −2.35 | 2.51 | 2.95 |
| Example 10 | Compound 10 | −5.03 | −2.32 | 2.51 | 2.91 |
| Example 11 | Compound 11 | −5.05 | −2.34 | 2.56 | 2.91 |
| Example 12 | Compound 12 | −4.99 | −2.31 | 2.52 | 2.93 |
| Example 13 | Compound 13 | −5.07 | −2.31 | 2.58 | 3.05 |
| Example 14 | Compound 14 | −5.10 | −2.26 | 2.56 | 3.01 |
| Comparative | Comparative | −5.14 | −2.25 | 2.47 | 2.85 |
| example 1 | compound 1 | | | | |

It can be seen from table 1 that, compared to the comparative compound 1, the T1 energy levels and S1 energy levels of the compounds 1-14 significantly increase, indicating that emission wavelengths of the compounds 1-14 shift towards the emission wavelength of blue light compared to the comparative compound 1. Therefore, under the same experimental conditions, when any one of compounds 1-14 is applied to the OLED device as the guest material of the light-emitting material, it makes the light emitted by the OLED device bluer, which can improve the luminescence efficiency of the OLED device.

### Preparation and Characterization of OLED Devices

The following is a detailed explanation of preparation methods of OLED devices including the compounds prepared in specific examples according to the present disclosure. In the following preparation methods of the OLED devices, indium tin oxide (ITO) is used as the material of the anode, poly(3,4-ethylenedioxythiophene) (PEDOT) is used as the hole injection material, polyvinyl carbazole (PVK) is used as the hole transport material, BH is used as the host material of the light-emitting material, ET and Liq (8-Hydroxyquinoline lithium) are used as the electron transport material, Al is used as the material of the cathode, and the compounds 1-14 and the comparative compound 1 are respectively used as guest materials of the light-emitting material, to prepare corresponding OLED devices. Structures of the BH, ET, and Liq are listed as follows:

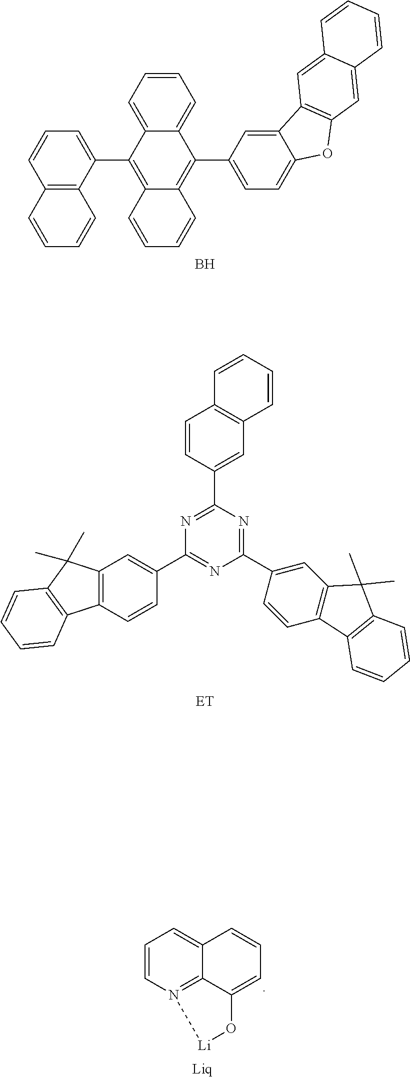

Specifically, the preparation method of the OLED device includes the following steps.

Step a, an ITO conductive glass substrate was provided and cleaned with cleaning agent, followed by UV ozone treatment. The cleaning agent included, but was not limited to, one or more of chloroform, acetone, and isopropanol.

Step b, PEDOT was coated on the ITO conductive glass substrate in a spin way, then treated on a hot plate at a temperature of 180° C. for 10 minutes to obtain a hole injection layer with a thickness of 40 nm.

Step c, toluene was used as a solvent to obtain a PVK solution, in which the PVK has a concentration of 5 mg/ml. Then the PVK solution was coated on the hole injection layer in a spin way, and treated on a hot plate at a temperature of 180 ºC for 60 minutes to obtain a hole transport layer with a thickness of 20 nm.

Step d, an organic light-emitting mixture was coated on the hole transport layer in a spin way, and treated on a hot plate at a temperature of 140° C. for 10 minutes to obtain a light-emitting layer with a thickness of 40 nm. In the organic light-emitting mixture, the solvent was methyl benzoate, the host material was BH, and the guest material was respectively the compounds 1-14 and the comparative compound 1. The weight percentage of the host material to the guest material was 95:5, and the concentration of the light-emitting material including the host material and the guest material in the organic light-emitting mixture was 15 mg/ml.

Step e, the substrate was transferred to a vacuum chamber, ET and Liq were placed in different evaporation units, and co-deposited on the light-emitting layer at a ratio of 50 wt % in high vacuum, to obtain an electron transport layer with a thickness of 20 nm.

Step f, Al was deposited on the electron transport layer to obtain a cathode with a thickness of 100 nm.

Step g, the above-mentioned device was encapsulated by UV cured resin to obtain corresponding OLED devices.

Specifically, in the above-mentioned preparation method, the compounds 1-14 and comparative compound 1 were used as guest materials in the light-emitting layer to prepare corresponding OLED-1 to OLED-14 and OLED-Ref1 devices. It can be understood that in the preparation methods of the above-mentioned OLED devices, except for the guest materials, all other experimental conditions are the same.

Further, the current voltage (J-V) characteristics of the above-mentioned OLED devices were characterized, and color coordinates (CIE, (x, y)), voltages (V), luminescence efficiency (CE@1knits), and lifespan (LT90@1knits) corresponding to the OLED-1 to OLED-14 and OLED-Ref1 devices were tested, and the results are shown in table 2. The luminescence efficiency (CE@1knits) is the relative value obtained at the current density of 10 mA/cm², and the lifespan (LT90@1knits) refers to a time when the brightness of the device delays from initial brightness of 1000 nits to 90% of the initial brightness under a constant current.

TABLE 2

| | | | | CE@ | LT90@ |
|---|---|---|---|---|---|
| | | CIE | Voltage | 1knits | 1knits |
| Device | Guest material | (x, y) | (V) | (cd/A) | (h) |
| OLED-1 | Compound 1 | 0.141, 0.082 | 5.5 | 5.9 | 156 |
| OLED-2 | Compound 2 | 0.141, 0.082 | 5.5 | 5.8 | 151 |
| OLED-3 | Compound 3 | 0.142, 0.085 | 5.5 | 5.9 | 147 |
| OLED-4 | Compound 4 | 0.143, 0.085 | 5.5 | 6.2 | 168 |
| OLED-5 | Compound 5 | 0.141, 0.083 | 5.5 | 6.3 | 163 |
| OLED-6 | Compound 6 | 0.141, 0.083 | 5.5 | 6.4 | 165 |
| OLED-7 | Compound 7 | 0.141, 0.081 | 5.5 | 6.5 | 167 |
| OLED-8 | Compound 8 | 0.141, 0.085 | 5.6 | 5.7 | 149 |
| OLED-9 | Compound 9 | 0.141, 0.082 | 5.6 | 5.9 | 155 |
| OLED-10 | Compound 10 | 0.143, 0.082 | 5.5 | 5.7 | 150 |
| OLED-11 | Compound 11 | 0.143, 0.081 | 5.5 | 6.5 | 180 |
| OLED-12 | Compound 12 | 0.141, 0.084 | 5.5 | 6.3 | 166 |
| OLED-13 | Compound 13 | 0.143, 0.083 | 5.5 | 6.4 | 171 |
| OLED-14 | Compound 14 | 0.141, 0.083 | 5.5 | 6.2 | 169 |
| OLED-Ref1 | Comparative | 0.151, 0.137 | 6.2 | 2.9 | 101 |
| | compound 1 | | | | |

It can be seen from table 2 that the color coordinates of OLED-1 to OLED-14 devices are better than the color coordinate of the OLED-Ref1 device, that is, compared to the comparative compound 1 that is used as the guest material in the light-emitting layer, when the boron-containing triphenylene compound provided in the present disclosure is used as the guest material in the light-emitting layer, the color coordinates of the OLED devices prepared using the boron-containing triphenylene compound are better than the color coordinate of the OLED device prepared using the comparative compound 1.

In addition, the luminescence efficiency of OLED-1 to OLED-14 devices is within the range of 5.7 cd/A to 6.5 cd/A, and their lifespan is within the range of 149 hours to 180 hours. Therefore, compared to the OLED device that is prepared using the comparative compound 1 as the guest material in the light-emitting layer, the blue light OLED devices that is prepared using the compounds 1-14 of the present disclosure as the guest material in the organic light-emitting layer have better luminescence efficiency and lifespan. Specifically, compared to the blue light OLED device prepared by using the comparative compound 1 as the guest material in the light-emitting layer, the lifespan of the blue light OLED devices prepared by using the boron-containing triphenylene compound of the present disclosure as the guest material in the light-emitting layer is increased by 50% to 80%.

In the above-mentioned examples 1-14, the luminescence efficiency of the blue OLED devices prepared using the compounds 4-7 and 11-14 is within the range of 6.2 cd/A to 6.5 cd/A, and the lifespan is within the range of 160 hours to 180 hours. This is because, compared to compounds in other examples of the present disclosure, in the compounds 4-7 and 11-14 prepared from examples 4-7 and 11-14, solubilized groups including tert-butyl, benzo cyclopentane, and, tetrahydronaphthalene are introduced. The introduction of the above-mentioned solubilized groups increases the molecular conjugation of the compounds, improving the luminescence efficiency and lifespan of the OLED devices.

Compared to naphthalene in the comparative compound 1 of the comparative example 1, the introduction of triphenylene in the boron-containing triphenylene compound provided in the present disclosure can improve the overall molecular solubility of the compound, making the solubility of the compound better than that of comparative compound 1, thus facilitating the purification of the compound, which can improve the purity of the boron-containing triphenylene compound, and is beneficial for further improving the luminescence efficiency of the OLED devices and prolonging their service life.

The boron-containing triphenylene compound, the mixture, the composition, and the organic electronic device provided by the embodiments of the present disclosure are described in detail. In this context, specific embodiments are adopted to illustrate a principle and implementation modes of the present disclosure. The description of the above-mentioned embodiments is only used to help understand methods and a core idea of the present disclosure. At the same time, for those skilled in the art, according to the idea of the present disclosure, there might be changes in specific implementation modes and a scope of the present disclosure, which falls within the scope of the protection of the present disclosure. In conclusion, contents of the specification should not be interpreted as a limitation of the present disclosure.

What is claimed is:

1. A boron-containing triphenylene compound, having a structure represented by formula (1): 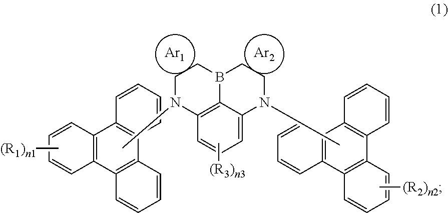
wherein Ar₁ and Ar₂ are each independently selected from any one of formula (A-1) to formula (A-5): 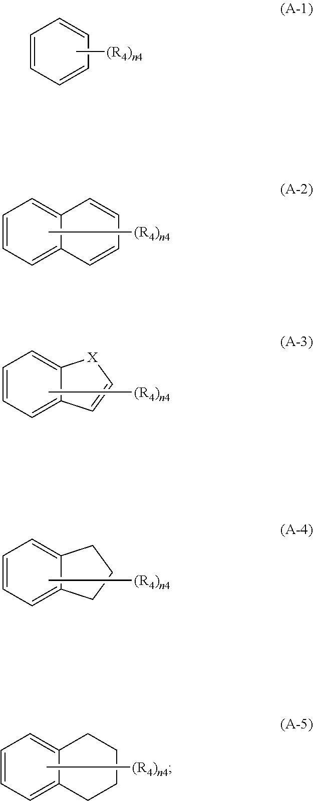
X is selected from O, S, CR₅R₆, or NR₇;
R₁-R₇ are each independently selected from H, D, a C₁₋₂₀ linear alkyl group, a C₁₋₂₀ linear alkoxyl group, a C₁₋₂₀ linear thioalkoxyl group, a C₃₋₂₀ branched alkyl group, a C₃₋₂₀ cyclic alkyl group, a C₃₋₂₀ branched alkoxyl group, a C₃₋₂₀ cyclic alkoxyl group, a C₃₋₂₀ branched thioalkoxyl group, a C₃₋₂₀ cyclic thioalkoxyl group, silyl, a ketone group containing 1-20 carbon atoms, an alkoxycarbonyl group containing 2-20 carbon atoms, an aryloxycarbonyl group containing 7-20 carbon atoms, an alkenyl group containing 1-20 carbon atoms, a cyanoyl group, a carbamoyl group, a haloformyl group, a formyl group, an isocyanoyl group, an isocyanate group, a thiocyanate group, an isothiocyanate group, a hydroxyl group, a nitro group, CF₃, Cl, Br, F, a substituted or unsubstituted aromatic group containing 6-30 ring atoms, a substituted or unsubstituted heteroaromatic group containing 5-30 ring atoms, a substituted or unsubstituted aryloxy group containing 6-30 ring atoms, a substituted or unsubstituted heteroaryloxy group containing 5-30 ring atoms, or combinations thereof at each occurrence; and
n1-n4 are each independently selected from 0, 1, 2, or 3.

2. The boron-containing triphenylene compound of claim 1, wherein the boron-containing triphenylene compound is selected from any one of formula (2-1) to formula (2-8):

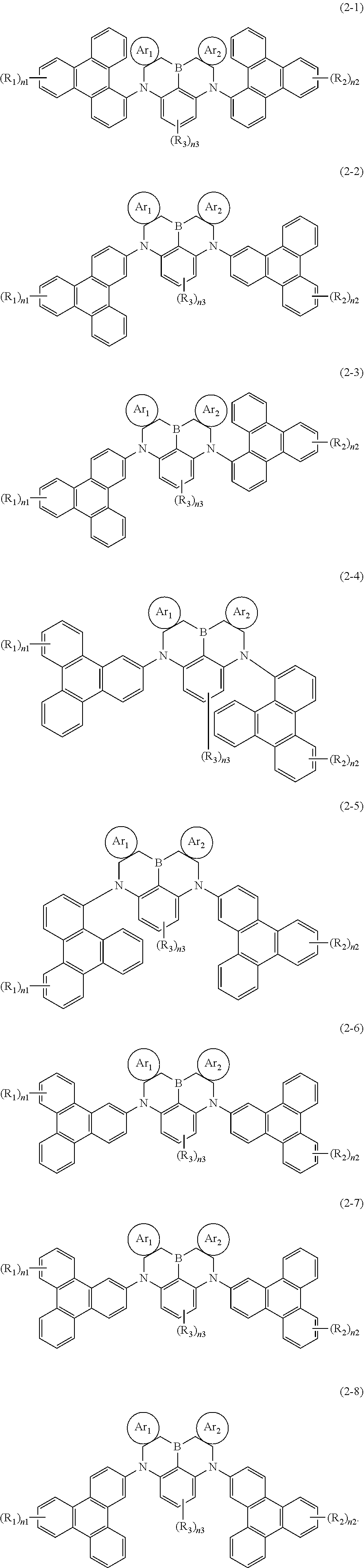

3. The boron-containing triphenylene compound of claim 1, wherein the boron-containing triphenylene compound is selected from any one of formula (3-1) to formula (3-22):

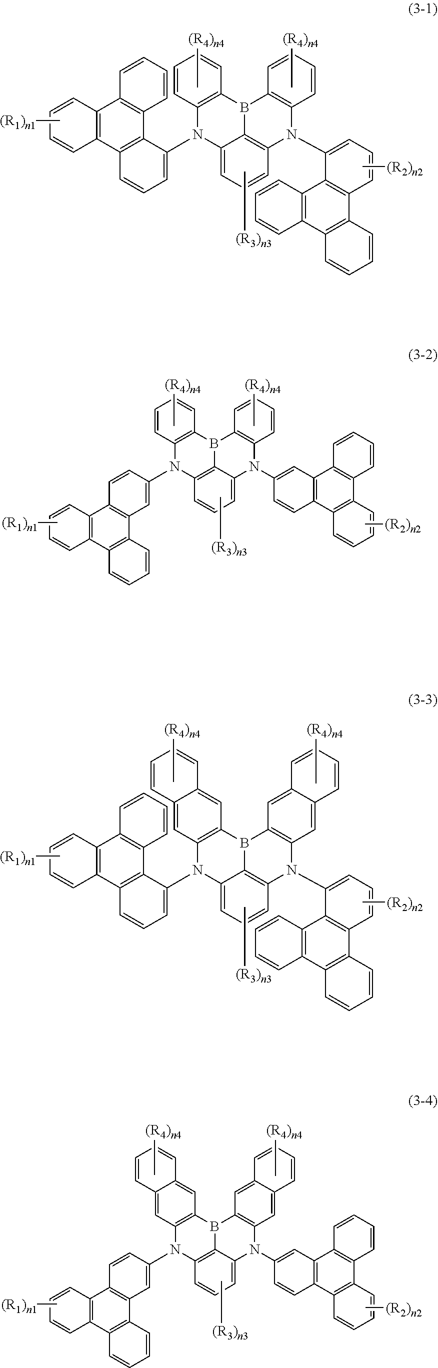

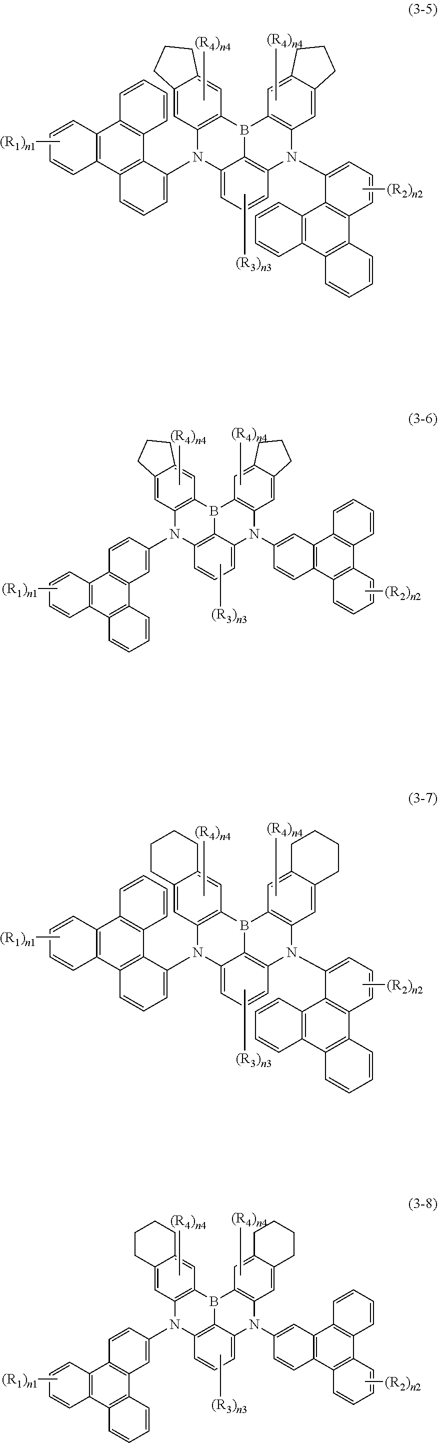

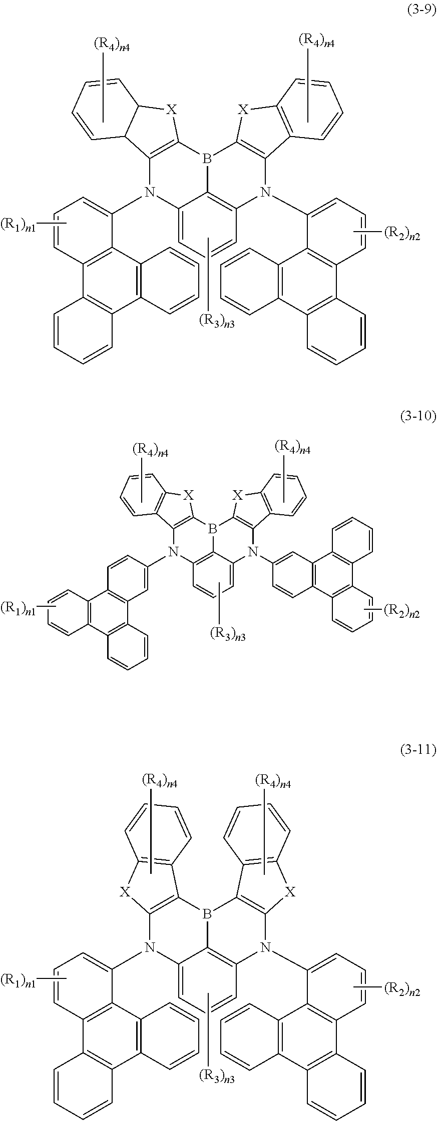

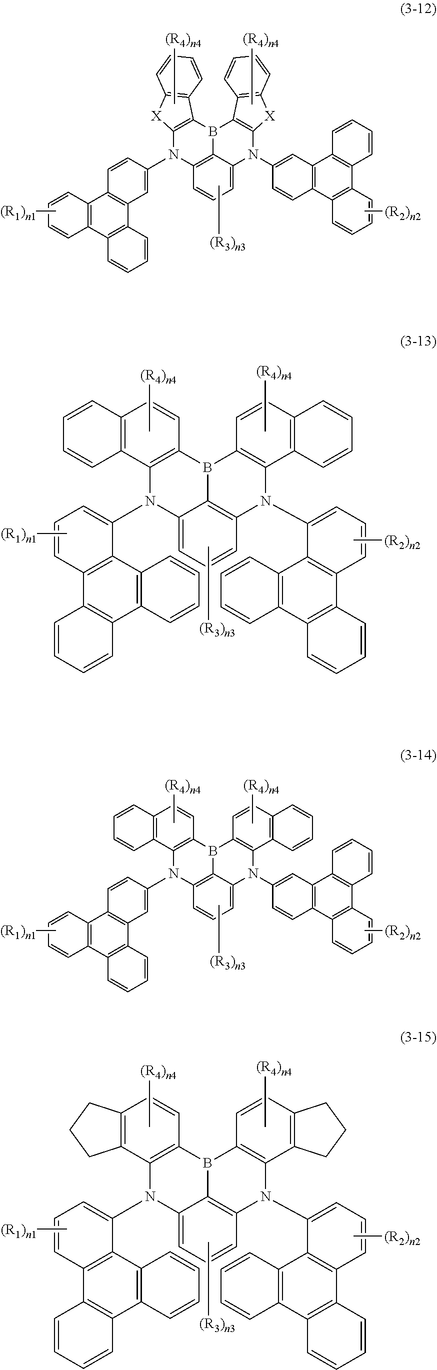

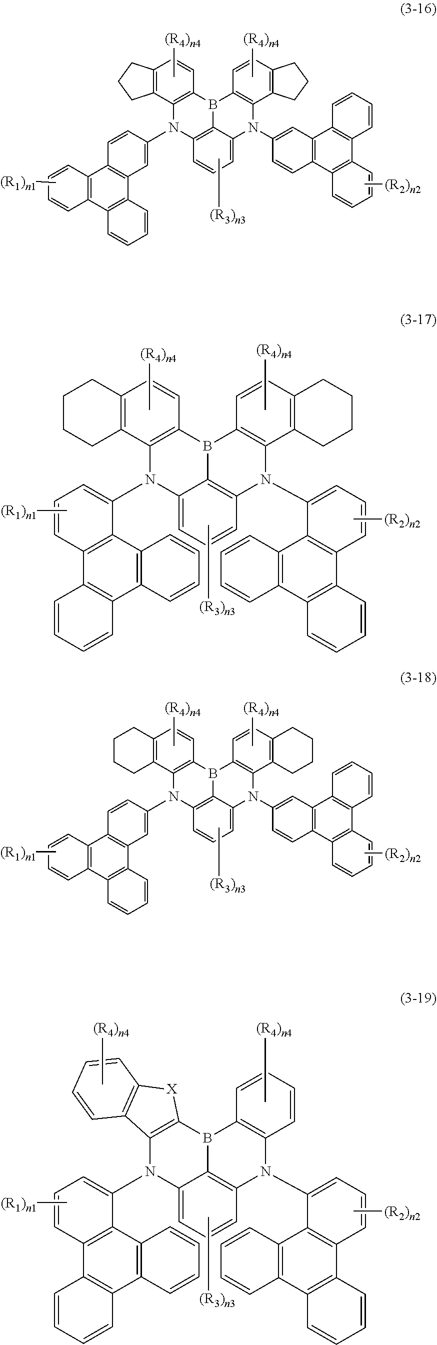

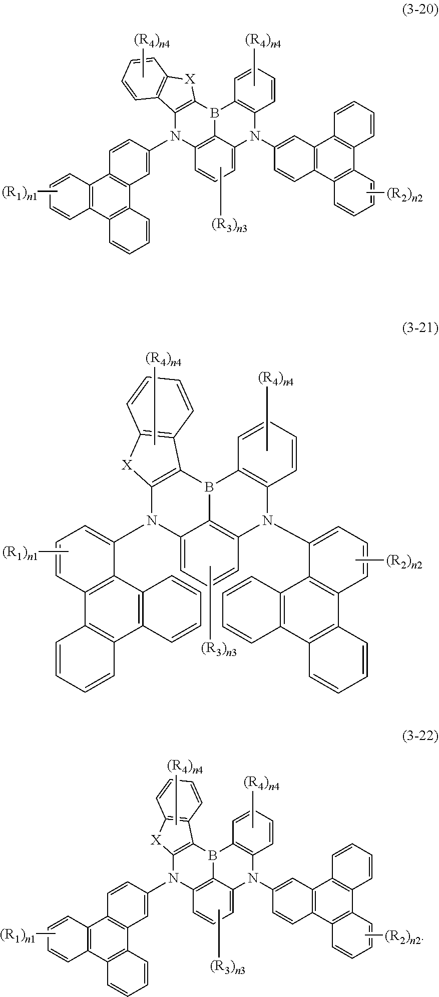

4. The boron-containing triphenylene compound of claim 1, wherein Ar₁ and Ar₂ are each independently selected from any one of formula (B-1) to formula (B-8): 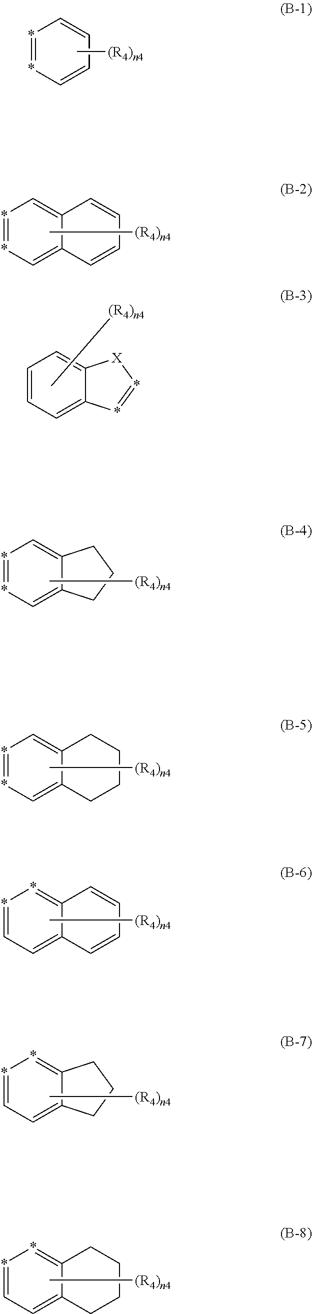
wherein “*” indicates a fused site.

5. The boron-containing triphenylene compound of claim 1, wherein two adjacent R₁ groups do not form a ring with each other, and R₁ is independently selected from H, D, a C₁₋₄ linear alkyl group, or a C₃₋₅ branched alkyl group at each occurrence; or
two adjacent R₁ groups form 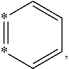 [SMILES: *1:*cccc1]
and “*” indicates a linking site.

6. The boron-containing triphenylene compound of claim 1, wherein two adjacent R₂ groups do not form a ring with each other, and R₂ is independently selected from H, D, a C₁₋₄ linear alkyl group, or a C₃₋₅ branched alkyl group at each occurrence; or 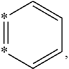 [SMILES: *1:*cccc1]
two adjacent R₂ groups form and “*” indicates a linking site.

7. The boron-containing triphenylene compound of claim 1, wherein two adjacent R₃ groups do not form a ring with each other, and R₃ is independently selected from H, D, a C₁₋₄ linear alkyl group, or a C₃₋₅ branched alkyl group at each occurrence; or
two adjacent R₃ groups form an aromatic ring containing six ring atoms or an aliphatic ring with each other.

8. The boron-containing triphenylene compound of claim 1, wherein R₄ is independently selected from H, D, a C₁₋₄ linear alkyl group, or a C₃₋₅ branched alkyl group at each occurrence.

9. The boron-containing triphenylene compound of claim 1, wherein X is selected from O, S, N—CH₃, N-Ph, or C(CH₃)₂, wherein Ph indicates benzene.

10. The boron-containing triphenylene compound of claim 1, wherein the boron-containing triphenylene compound is selected from any one of the following structures:

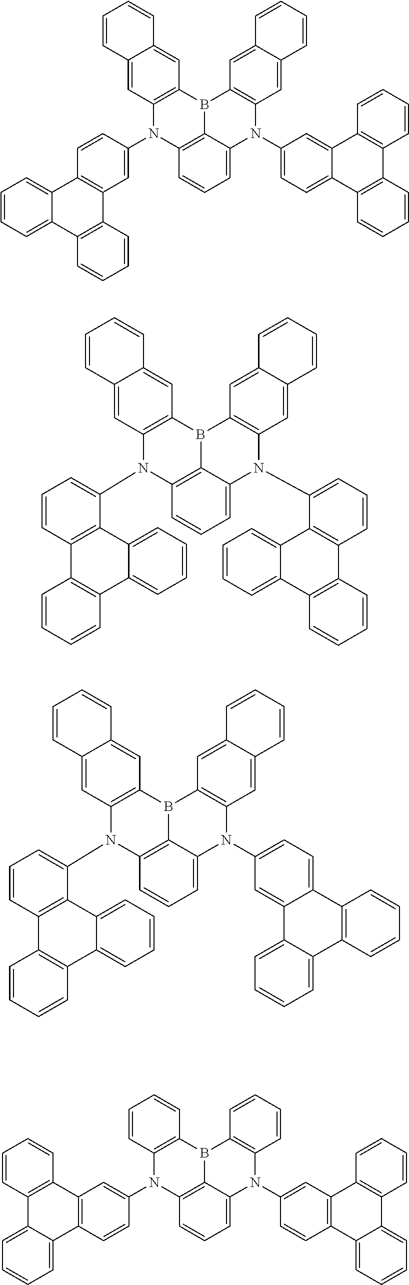

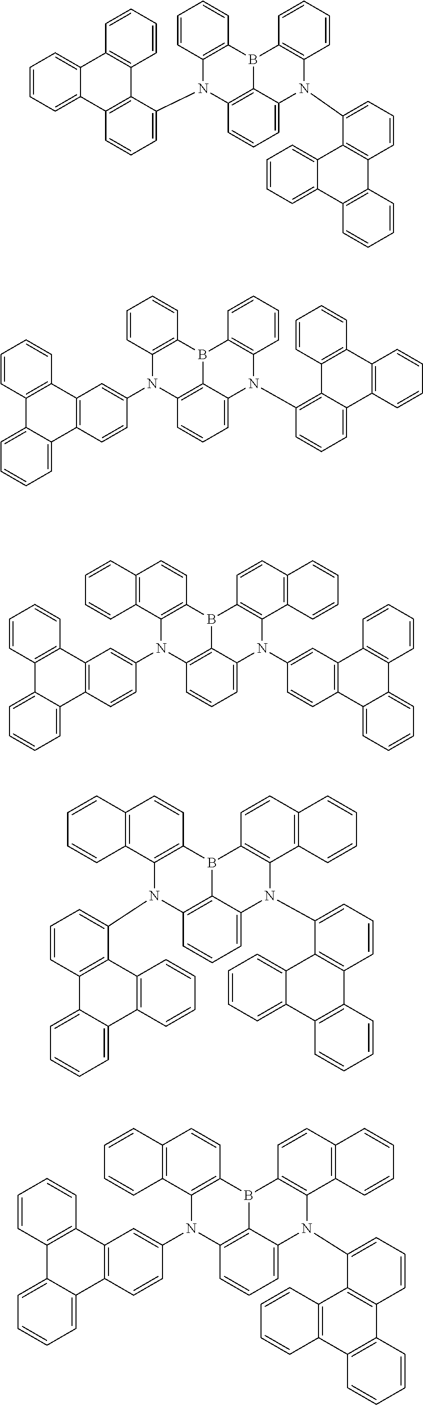 [SMILES: c1ccc2c(c1)B1c3ccccc3N(c3cccc4c5ccccc5c5ccccc5c34)c3cccc(c31)N2c1cccc2c3ccccc3c3ccccc3c12 ; c1ccc2c(c1)B1c3ccccc3N(c3cccc4c5ccccc5c5ccccc5c34)c3cccc(c31)N2c1ccc2c3ccccc3c3ccccc3c2c1 ; c1cc2c3c(c1)N(c1ccc4c5ccccc5c5ccccc5c4c1)c1c(ccc4ccccc14)B3c1ccc3ccccc3c1N2c1ccc2c3ccccc3c3ccccc3c2c1 ; c1cc2c3c(c1)N(c1cccc4c5ccccc5c5ccccc5c14)c1c(ccc4ccccc14)B3c1ccc3ccccc3c1N2c1cccc2c3ccccc3c3ccccc3c12 ; c1cc2c3c(c1)N(c1cccc4c5ccccc5c5ccccc5c14)c1c(ccc4ccccc14)B3c1ccc3ccccc3c1N2c1ccc2c3ccccc3c3ccccc3c2c1]

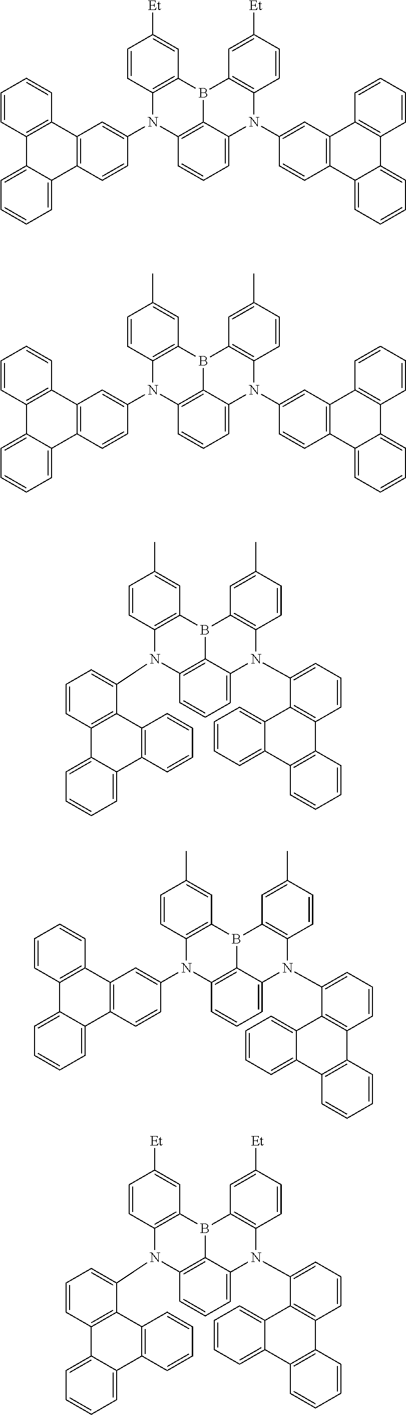 [SMILES: CCc1ccc2c(c1)B1c3cc(CC)ccc3N(c3ccc4c5ccccc5c5ccccc5c4c3)c3cccc(c31)N2c1ccc2c3ccccc3c3ccccc3c2c1 ; Cc1ccc2c(c1)B1c3cc(C)ccc3N(c3ccc4c5ccccc5c5ccccc5c4c3)c3cccc(c31)N2c1ccc2c3ccccc3c3ccccc3c2c1 ; Cc1ccc2c(c1)B1c3cc(C)ccc3N(c3cccc4c5ccccc5c5ccccc5c34)c3cccc(c31)N2c1cccc2c3ccccc3c3ccccc3c12 ; Cc1ccc2c(c1)B1c3cc(C)ccc3N(c3cccc4c5ccccc5c5ccccc5c34)c3cccc(c31)N2c1ccc2c3ccccc3c3ccccc3c2c1 ; CCc1ccc2c(c1)B1c3cc(CC)ccc3N(c3cccc4c5ccccc5c5ccccc5c34)c3cccc(c31)N2c1cccc2c3ccccc3c3ccccc3c12]

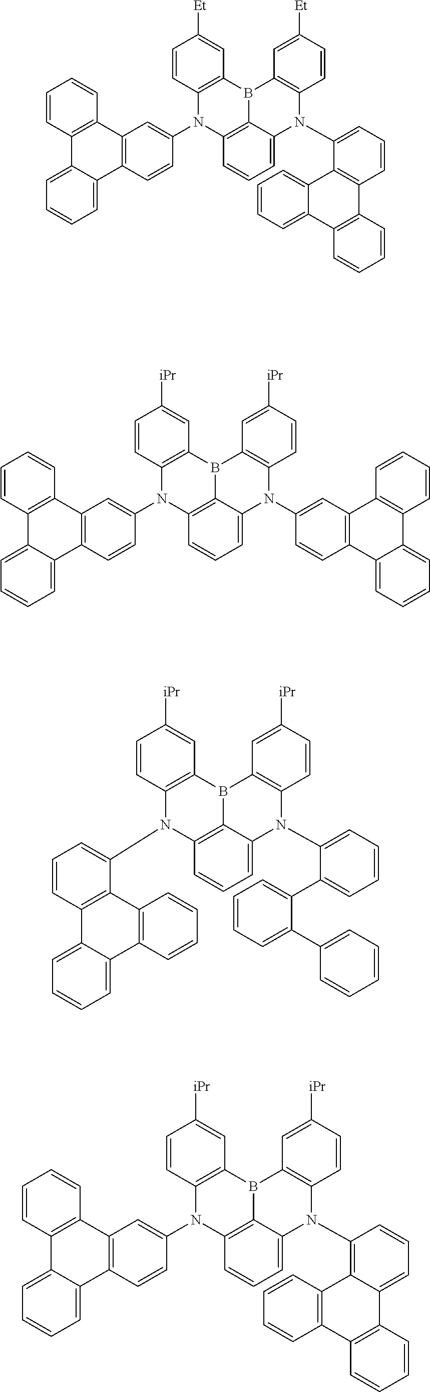 [SMILES: CCc1ccc2c(c1)B1c3cc(CC)ccc3N(c3cccc4c5ccccc5c5ccccc5c34)c3cccc(c31)N2c1ccc2c3ccccc3c3ccccc3c2c1 ; CC(C)c1ccc2c(c1)B1c3cc(C(C)C)ccc3N(c3ccc4c5ccccc5c5ccccc5c4c3)c3cccc(c31)N2c1ccc2c3ccccc3c3ccccc3c2c1 ; CC(C)c1ccc2c(c1)B1c3cc(C(C)C)ccc3N(c3cccc4c5ccccc5c5ccccc5c34)c3cccc(c31)N2c1ccccc1-c1ccccc1-c1ccccc1 ; CC(C)c1ccc2c(c1)B1c3cc(C(C)C)ccc3N(c3cccc4c5ccccc5c5ccccc5c34)c3cccc(c31)N2c1ccc2c3ccccc3c3ccccc3c2c1]

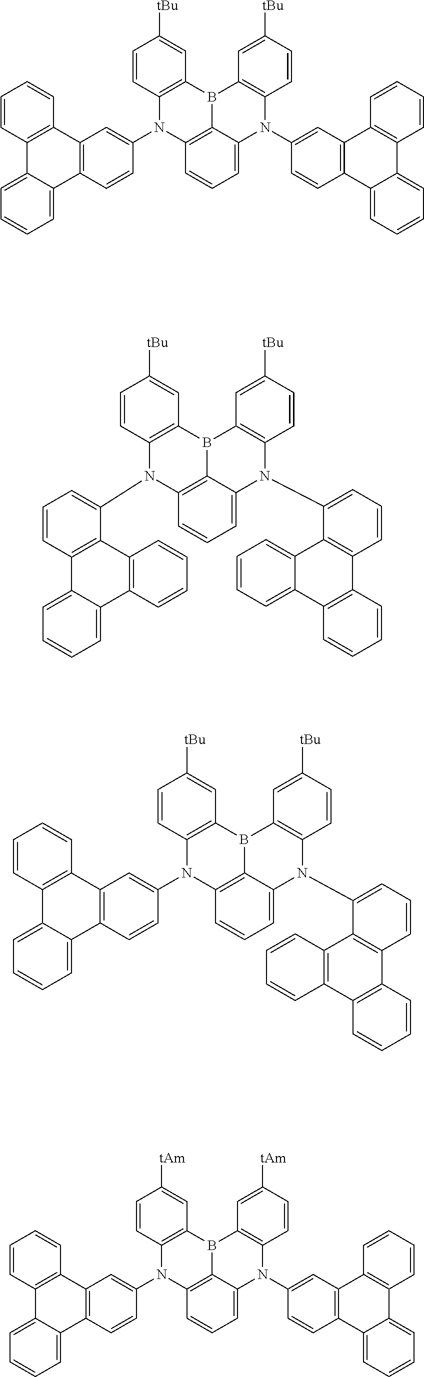

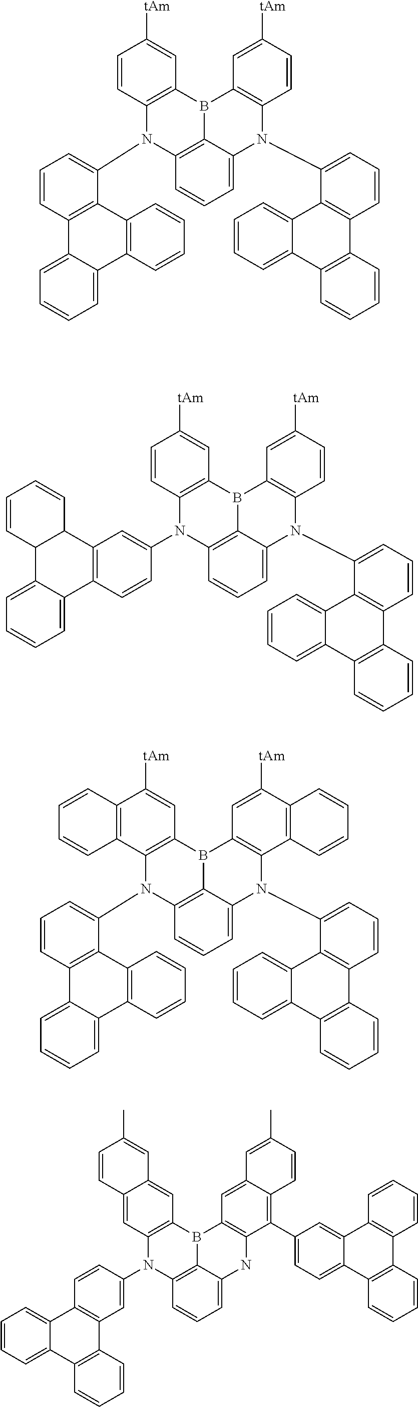

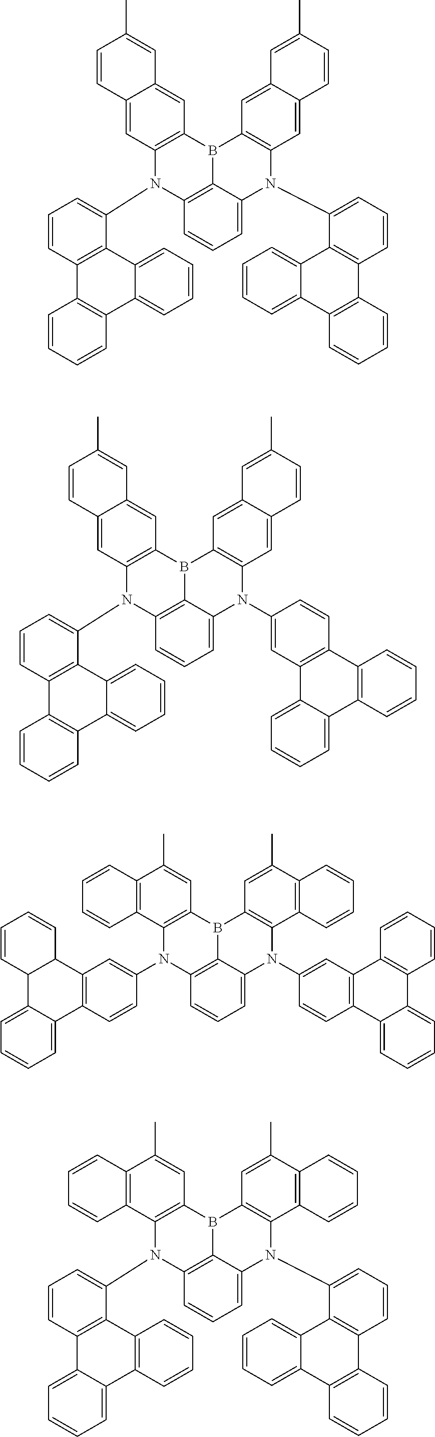 [SMILES: Cc1ccc2cc3c(cc2c1)B1c2cc4cc(C)ccc4cc2N(c2cccc4c5ccccc5c5ccccc5c24)c2cccc(c21)N3c1cccc2c3ccccc3c3ccccc3c12 ; Cc1ccc2cc3c(cc2c1)B1c2cc4cc(C)ccc4cc2N(c2cccc4c5ccccc5c5ccccc5c24)c2cccc(c21)N3c1ccc2c3ccccc3c3ccccc3c2c1 ; Cc1cc2c(c3ccccc13)N(c1ccc3c(c1)C1C=CC=CC1c1ccccc1-3)c1cccc3c1B2c1cc(C)c2ccccc2c1N3c1ccc2c3ccccc3c3ccccc3c2c1 ; Cc1cc2c(c3ccccc13)N(c1cccc3c4ccccc4c4ccccc4c13)c1cccc3c1B2c1cc(C)c2ccccc2c1N3c1cccc2c3ccccc3c3ccccc3c12]

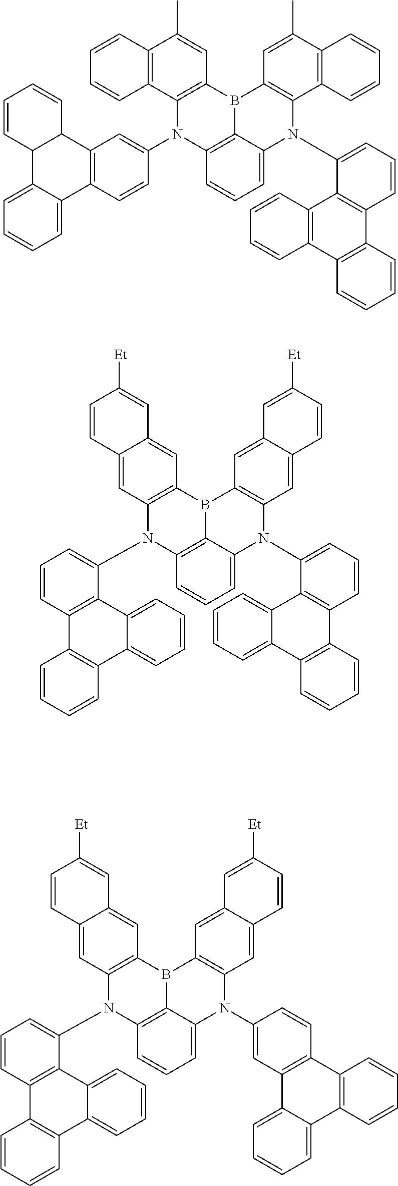 [SMILES: Cc1cc2c(c3ccccc13)N(c1ccc3c(c1)C1C=CC=CC1c1ccccc1-3)c1cccc3c1B2c1cc(C)c2ccccc2c1N3c1cccc2c3ccccc3c3ccccc3c12 ; CCc1ccc2cc3c(cc2c1)B1c2cc4cc(CC)ccc4cc2N(c2cccc4c5ccccc5c5ccccc5c24)c2cccc(c21)N3c1cccc2c3ccccc3c3ccccc3c12 ; CCc1ccc2cc3c(cc2c1)B1c2cc4cc(CC)ccc4cc2N(c2cccc4c5ccccc5c5ccccc5c24)c2cccc(c21)N3c1ccc2c3ccccc3c3ccccc3c2c1]

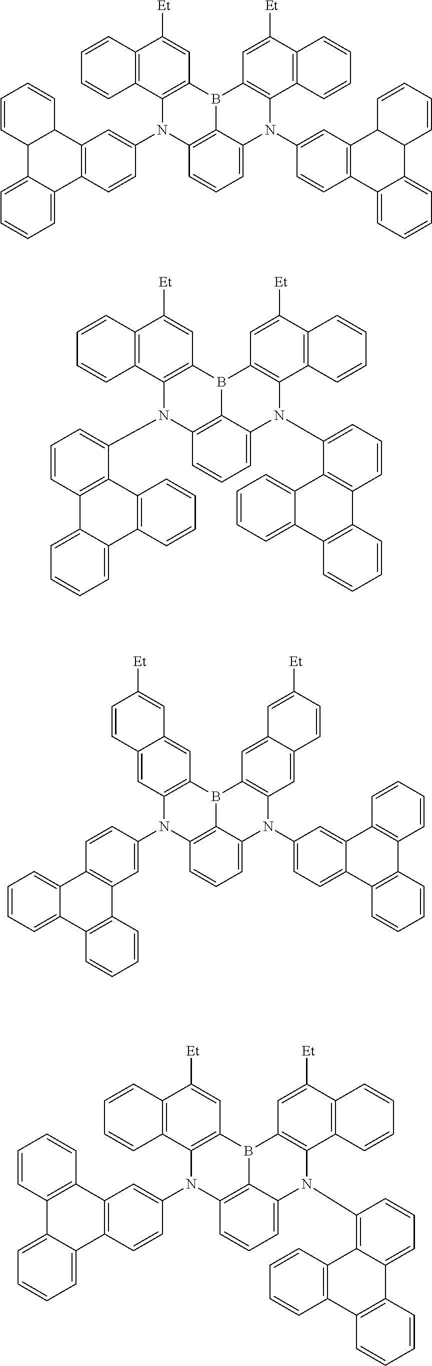 [SMILES: CCc1cc2c(c3ccccc13)N(c1ccc3c(c1)C1C=CC=CC1c1ccccc1-3)c1cccc3c1B2c1cc(CC)c2ccccc2c1N3c1ccc2c(c1)C1C=CC=CC1c1ccccc1-2 ; CCc1cc2c(c3ccccc13)N(c1cccc3c4ccccc4c4ccccc4c13)c1cccc3c1B2c1cc(CC)c2ccccc2c1N3c1cccc2c3ccccc3c3ccccc3c12 ; CCc1ccc2cc3c(cc2c1)B1c2cc4cc(CC)ccc4cc2N(c2ccc4c5ccccc5c5ccccc5c4c2)c2cccc(c21)N3c1ccc2c3ccccc3c3ccccc3c2c1 ; CCc1cc2c(c3ccccc13)N(c1ccc3c4ccccc4c4ccccc4c3c1)c1cccc3c1B2c1cc(CC)c2ccccc2c1N3c1cccc2c3ccccc3c3ccccc3c12]

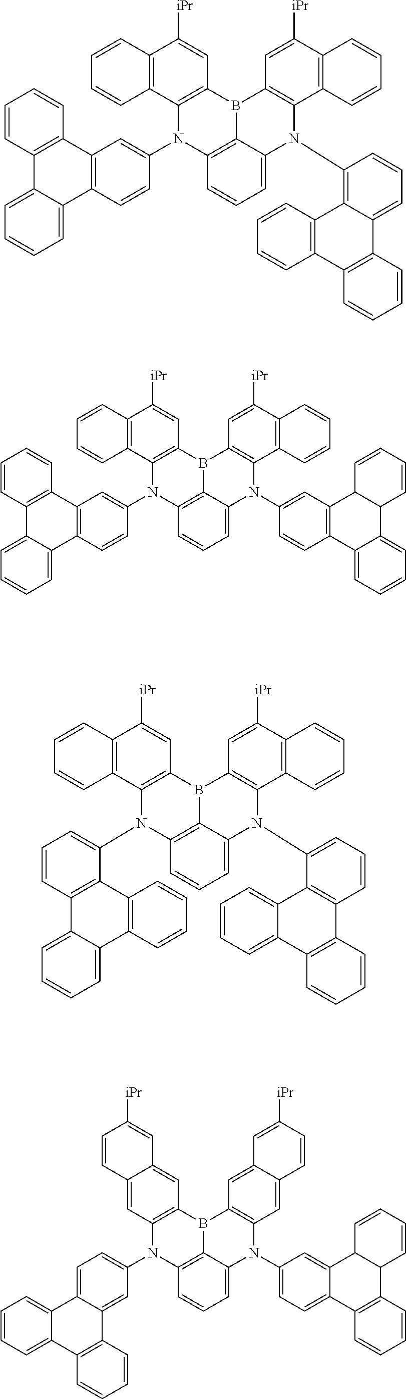 [SMILES: CC(C)c1cc2c(c3ccccc13)N(c1ccc3c4ccccc4c4ccccc4c3c1)c1cccc3c1B2c1cc(C(C)C)c2ccccc2c1N3c1cccc2c3ccccc3c3ccccc3c12 ; CC(C)c1cc2c(c3ccccc13)N(c1ccc3c(c1)C1C=CC=CC1c1ccccc1-3)c1cccc3c1B2c1cc(C(C)C)c2ccccc2c1N3c1ccc2c3ccccc3c3ccccc3c2c1 ; CC(C)c1cc2c(c3ccccc13)N(c1cccc3c4ccccc4c4ccccc4c13)c1cccc3c1B2c1cc(C(C)C)c2ccccc2c1N3c1cccc2c3ccccc3c3ccccc3c12 ; CC(C)c1ccc2cc3c(cc2c1)B1c2cc4cc(C(C)C)ccc4cc2N(c2ccc4c5ccccc5c5ccccc5c4c2)c2cccc(c21)N3c1ccc2c(c1)C1C=CC=CC1c1ccccc1-2]

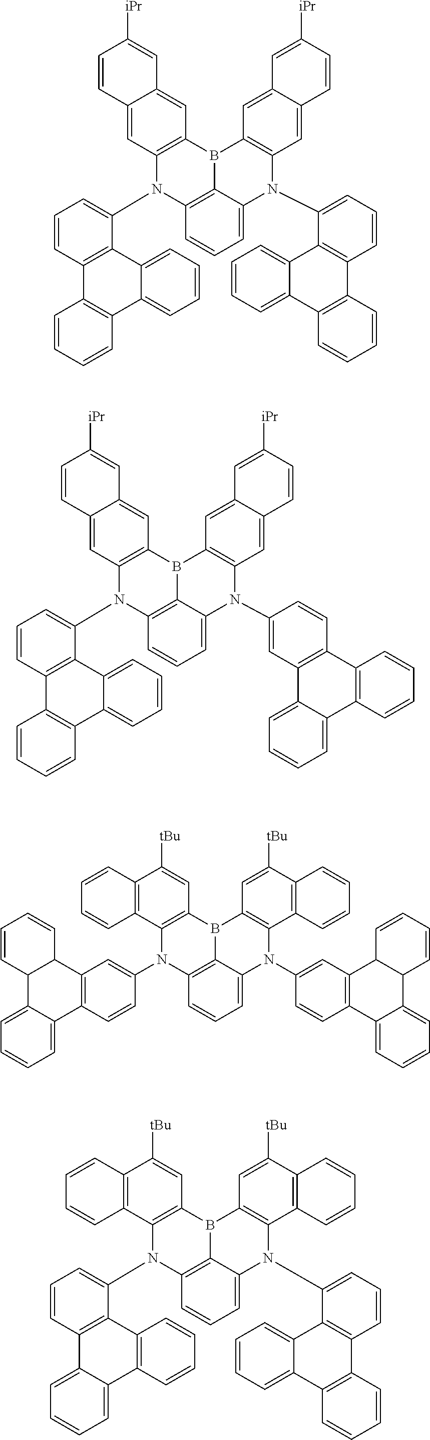 [SMILES: CC(C)c1ccc2cc3c(cc2c1)B1c2cc4cc(C(C)C)ccc4cc2N(c2cccc4c5ccccc5c5ccccc5c24)c2cccc(c21)N3c1cccc2c3ccccc3c3ccccc3c12 ; CC(C)c1ccc2cc3c(cc2c1)B1c2cc4cc(C(C)C)ccc4cc2N(c2cccc4c5ccccc5c5ccccc5c24)c2cccc(c21)N3c1ccc2c3ccccc3c3ccccc3c2c1 ; CC(C)(C)c1cc2c(c3ccccc13)N(c1ccc3c(c1)C1C=CC=CC1c1ccccc1-3)c1cccc3c1B2c1cc(C(C)(C)C)c2ccccc2c1N3c1ccc2c(c1)C1C=CC=CC1c1ccccc1-2 ; CC(C)(C)c1cc2c(c3ccccc13)N(c1cccc3c4ccccc4c4ccccc4c13)c1cccc3c1B2c1cc(C(C)(C)C)c2ccccc2c1N3c1cccc2c3ccccc3c3ccccc3c12]

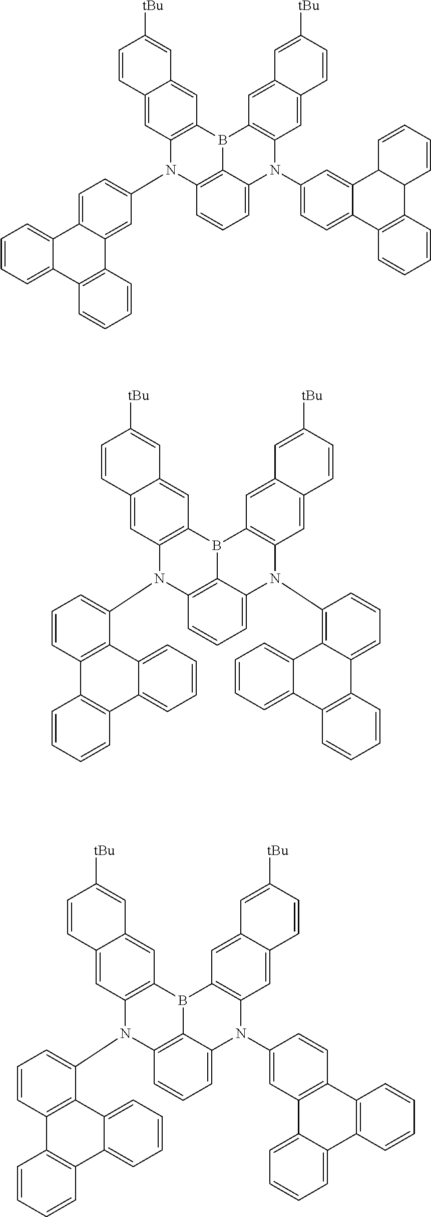 [SMILES: CC(C)(C)c1ccc2cc3c(cc2c1)B1c2cc4cc(C(C)(C)C)ccc4cc2N(c2ccc4c5ccccc5c5ccccc5c4c2)c2cccc(c21)N3c1ccc2c(c1)C1C=CC=CC1c1ccccc1-2 ; CC(C)(C)c1ccc2cc3c(cc2c1)B1c2cc4cc(C(C)(C)C)ccc4cc2N(c2cccc4c5ccccc5c5ccccc5c24)c2cccc(c21)N3c1cccc2c3ccccc3c3ccccc3c12 ; CC(C)(C)c1ccc2cc3c(cc2c1)B1c2cc4cc(C(C)(C)C)ccc4cc2N(c2cccc4c5ccccc5c5ccccc5c24)c2cccc(c21)N3c1ccc2c3ccccc3c3ccccc3c2c1]

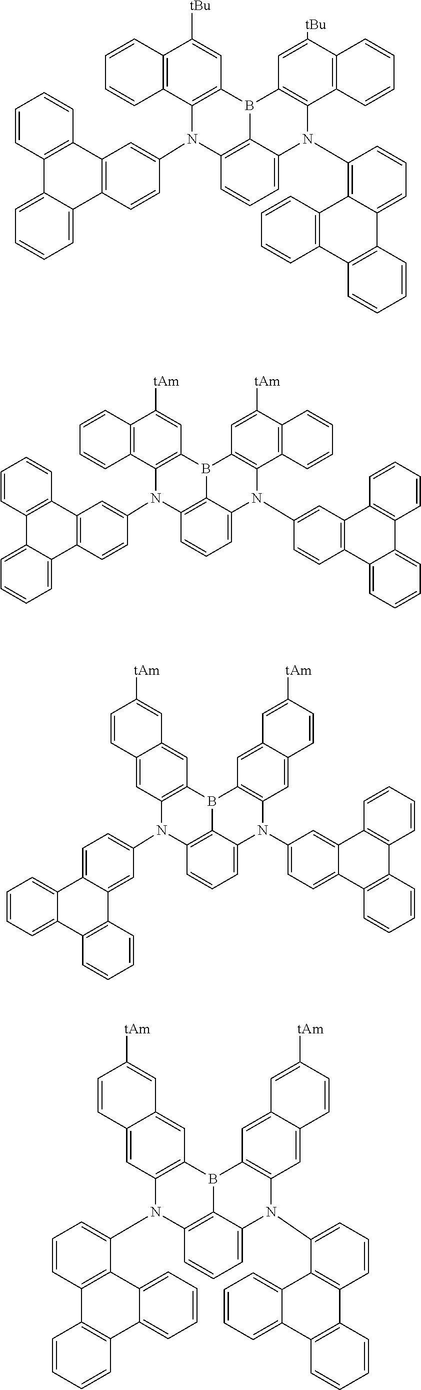

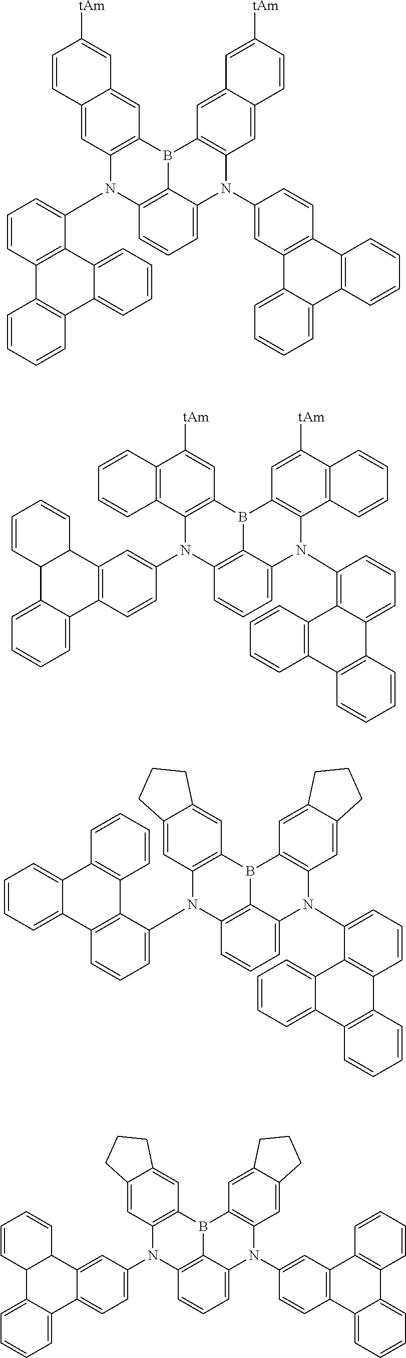

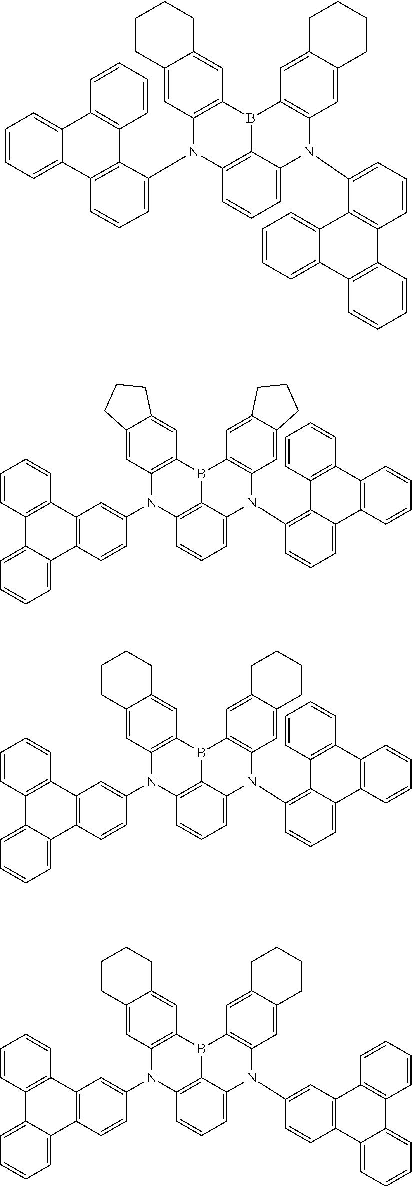 [SMILES: c1cc2c3c(c1)N(c1cccc4c5ccccc5c5ccccc5c14)c1cc4c(cc1B3c1cc3c(cc1N2c1cccc2c5ccccc5c5ccccc5c12)CCCC3)CCCC4 ; c1cc2c3c(c1)N(c1cccc4c5ccccc5c5ccccc5c14)c1cc4c(cc1B3c1cc3c(cc1N2c1ccc2c5ccccc5c5ccccc5c2c1)CCC3)CCC4 ; c1cc2c3c(c1)N(c1cccc4c5ccccc5c5ccccc5c14)c1cc4c(cc1B3c1cc3c(cc1N2c1ccc2c5ccccc5c5ccccc5c2c1)CCCC3)CCCC4 ; c1cc2c3c(c1)N(c1ccc4c5ccccc5c5ccccc5c4c1)c1cc4c(cc1B3c1cc3c(cc1N2c1ccc2c5ccccc5c5ccccc5c2c1)CCCC3)CCCC4]

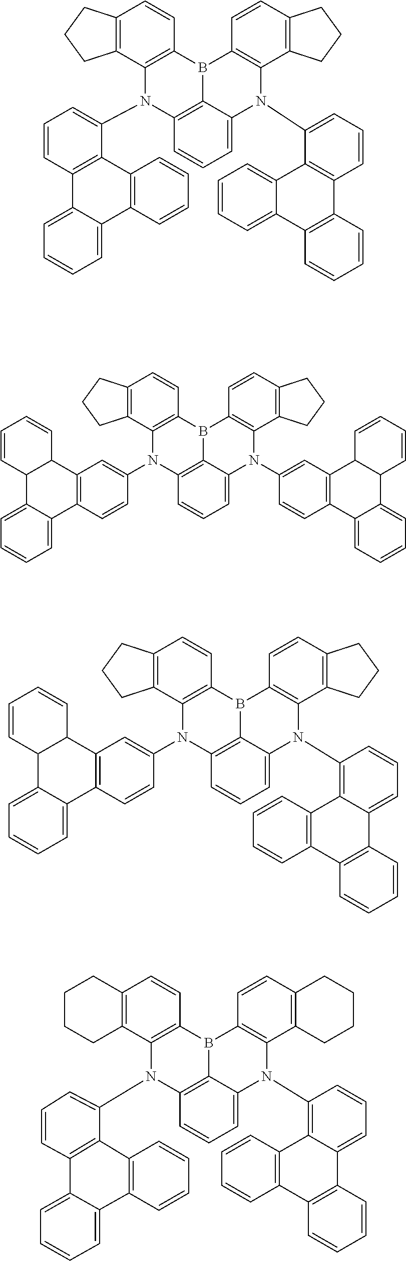 [SMILES: c1cc2c3c(c1)N(c1cccc4c5ccccc5c5ccccc5c14)c1c(ccc4c1CCC4)B3c1ccc3c(c1N2c1cccc2c4ccccc4c4ccccc4c12)CCC3 ; C1=CC2c3ccccc3-c3ccc(N4c5cccc6c5B(c5ccc7c(c54)CCC7)c4ccc5c(c4N6c4ccc6c(c4)C4C=CC=CC4c4ccccc4-6)CCC5)cc3C2C=C1 ; C1=CC2c3ccccc3-c3ccc(N4c5cccc6c5B(c5ccc7c(c54)CCC7)c4ccc5c(c4N6c4cccc6c7ccccc7c7ccccc7c46)CCC5)cc3C2C=C1 ; c1cc2c3c(c1)N(c1cccc4c5ccccc5c5ccccc5c14)c1c(ccc4c1CCCC4)B3c1ccc3c(c1N2c1cccc2c4ccccc4c4ccccc4c12)CCCC3]

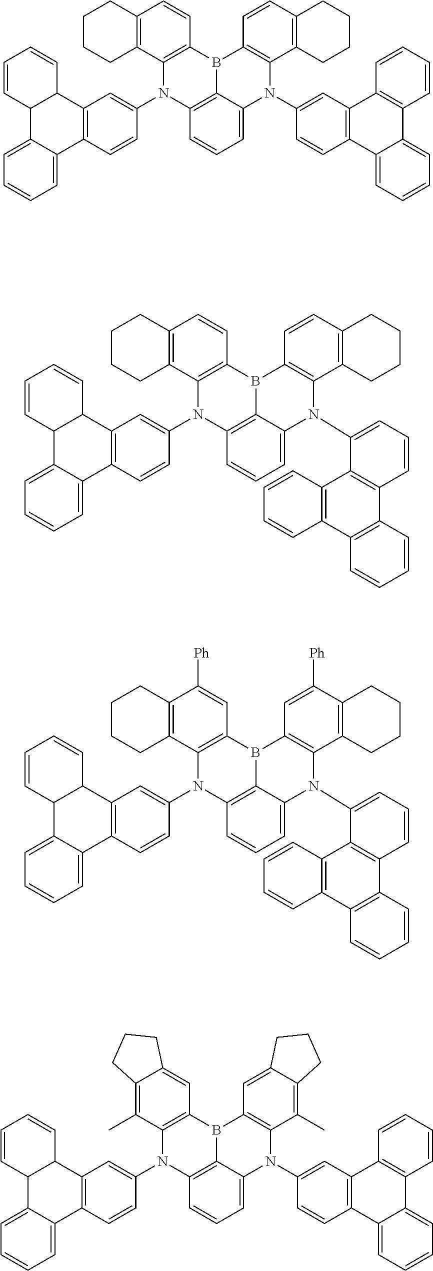 [SMILES: C1=CC2c3ccccc3-c3ccc(N4c5cccc6c5B(c5ccc7c(c54)CCCC7)c4ccc5c(c4N6c4ccc6c7ccccc7c7ccccc7c6c4)CCCC5)cc3C2C=C1 ; C1=CC2c3ccccc3-c3ccc(N4c5cccc6c5B(c5ccc7c(c54)CCCC7)c4ccc5c(c4N6c4cccc6c7ccccc7c7ccccc7c46)CCCC5)cc3C2C=C1 ; C1=CC2c3ccccc3-c3ccc(N4c5cccc6c5B(c5cc(-c7ccccc7)c7c(c54)CCCC7)c4cc(-c5ccccc5)c5c(c4N6c4cccc6c7ccccc7c7ccccc7c46)CCCC5)cc3C2C=C1 ; Cc1c2c(cc3c1N(c1ccc4c(c1)C1C=CC=CC1c1ccccc1-4)c1cccc4c1B3c1cc3c(c(C)c1N4c1ccc4c5ccccc5c5ccccc5c4c1)CCC3)CCC2]

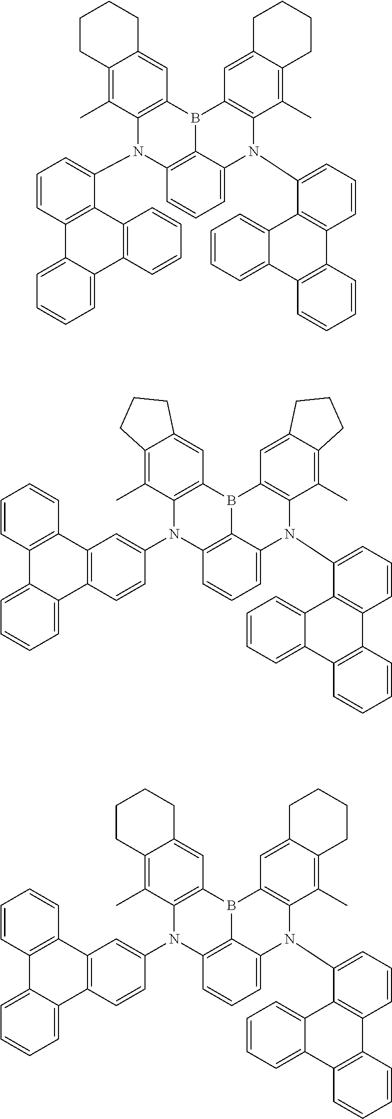 [SMILES: Cc1c2c(cc3c1N(c1cccc4c5ccccc5c5ccccc5c14)c1cccc4c1B3c1cc3c(c(C)c1N4c1cccc4c5ccccc5c5ccccc5c14)CCCC3)CCCC2 ; Cc1c2c(cc3c1N(c1ccc4c5ccccc5c5ccccc5c4c1)c1cccc4c1B3c1cc3c(c(C)c1N4c1cccc4c5ccccc5c5ccccc5c14)CCC3)CCC2 ; Cc1c2c(cc3c1N(c1ccc4c5ccccc5c5ccccc5c4c1)c1cccc4c1B3c1cc3c(c(C)c1N4c1cccc4c5ccccc5c5ccccc5c14)CCCC3)CCCC2]

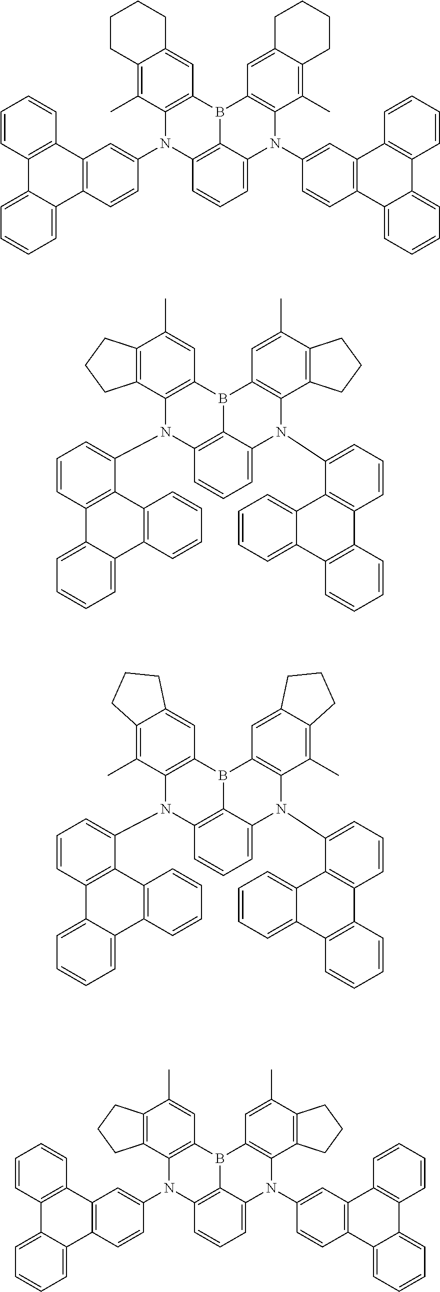 [SMILES: Cc1c2c(cc3c1N(c1ccc4c5ccccc5c5ccccc5c4c1)c1cccc4c1B3c1cc3c(c(C)c1N4c1ccc4c5ccccc5c5ccccc5c4c1)CCCC3)CCCC2 ; Cc1cc2c(c3c1CCC3)N(c1cccc3c4ccccc4c4ccccc4c13)c1cccc3c1B2c1cc(C)c2c(c1N3c1cccc3c4ccccc4c4ccccc4c13)CCC2 ; Cc1c2c(cc3c1N(c1cccc4c5ccccc5c5ccccc5c14)c1cccc4c1B3c1cc3c(c(C)c1N4c1cccc4c5ccccc5c5ccccc5c14)CCC3)CCC2 ; Cc1cc2c(c3c1CCC3)N(c1ccc3c4ccccc4c4ccccc4c3c1)c1cccc3c1B2c1cc(C)c2c(c1N3c1ccc3c4ccccc4c4ccccc4c3c1)CCC2]

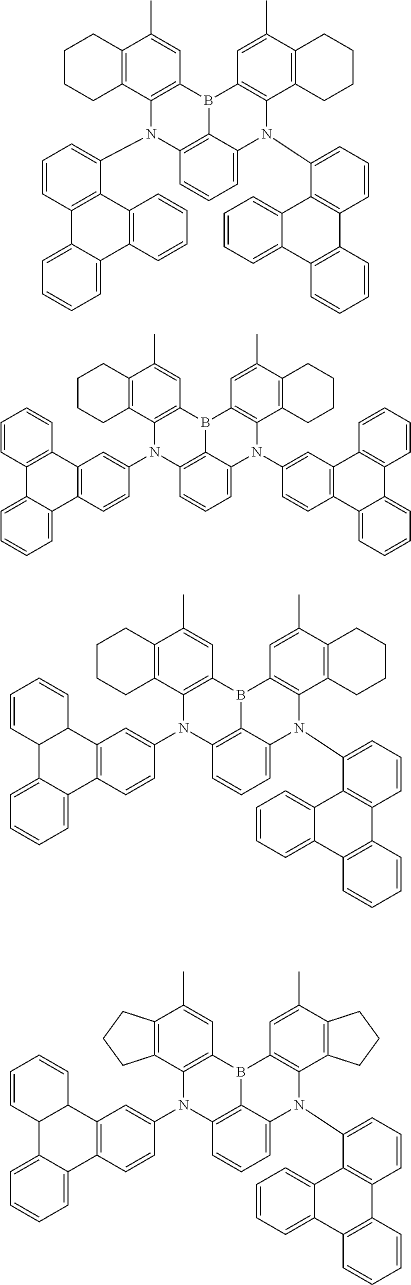 [SMILES: Cc1cc2c(c3c1CCCC3)N(c1cccc3c4ccccc4c4ccccc4c13)c1cccc3c1B2c1cc(C)c2c(c1N3c1cccc3c4ccccc4c4ccccc4c13)CCCC2 ; Cc1cc2c(c3c1CCCC3)N(c1ccc3c4ccccc4c4ccccc4c3c1)c1cccc3c1B2c1cc(C)c2c(c1N3c1ccc3c4ccccc4c4ccccc4c3c1)CCCC2 ; Cc1cc2c(c3c1CCCC3)N(c1ccc3c(c1)C1C=CC=CC1c1ccccc1-3)c1cccc3c1B2c1cc(C)c2c(c1N3c1cccc3c4ccccc4c4ccccc4c13)CCCC2 ; Cc1cc2c(c3c1CCC3)N(c1ccc3c(c1)C1C=CC=CC1c1ccccc1-3)c1cccc3c1B2c1cc(C)c2c(c1N3c1cccc3c4ccccc4c4ccccc4c13)CCC2]

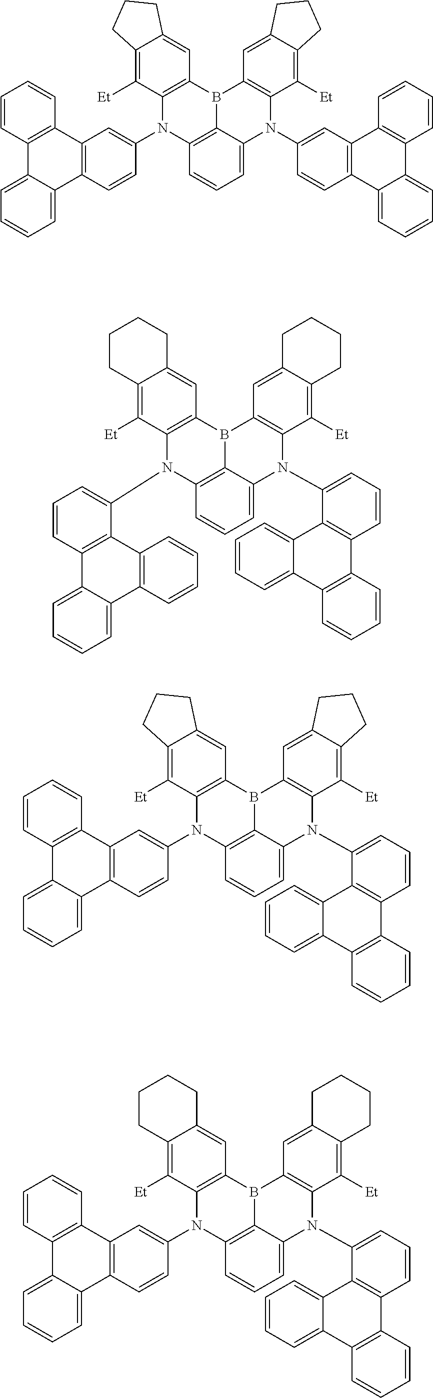 [SMILES: CCc1c2c(cc3c1N(c1ccc4c5ccccc5c5ccccc5c4c1)c1cccc4c1B3c1cc3c(c(CC)c1N4c1ccc4c5ccccc5c5ccccc5c4c1)CCC3)CCC2 ; CCc1c2c(cc3c1N(c1cccc4c5ccccc5c5ccccc5c14)c1cccc4c1B3c1cc3c(c(CC)c1N4c1cccc4c5ccccc5c5ccccc5c14)CCCC3)CCCC2 ; CCc1c2c(cc3c1N(c1ccc4c5ccccc5c5ccccc5c4c1)c1cccc4c1B3c1cc3c(c(CC)c1N4c1cccc4c5ccccc5c5ccccc5c14)CCC3)CCC2 ; CCc1c2c(cc3c1N(c1ccc4c5ccccc5c5ccccc5c4c1)c1cccc4c1B3c1cc3c(c(CC)c1N4c1cccc4c5ccccc5c5ccccc5c14)CCCC3)CCCC2]

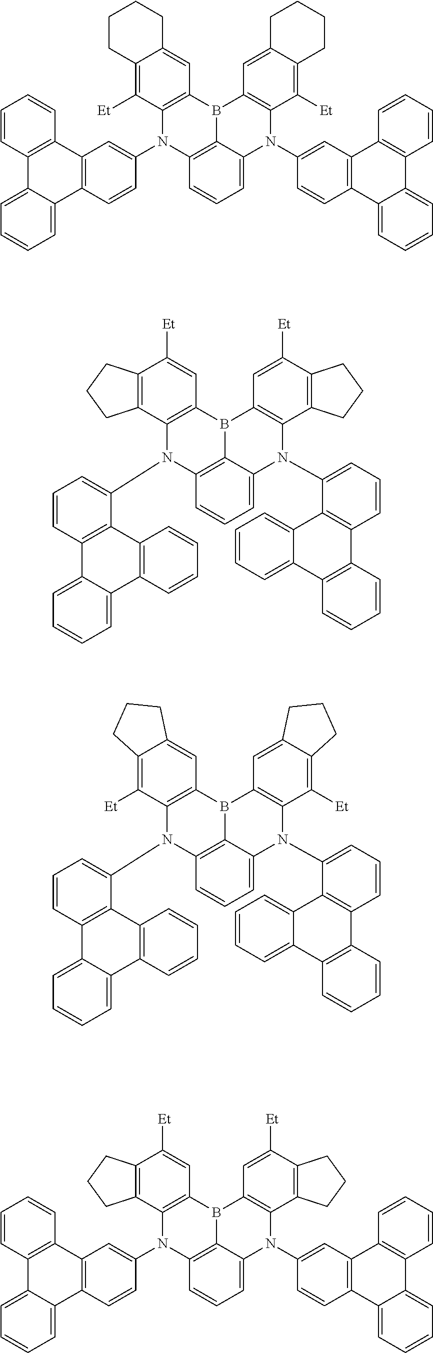 [SMILES: CCc1c2c(cc3c1N(c1ccc4c5ccccc5c5ccccc5c4c1)c1cccc4c1B3c1cc3c(c(CC)c1N4c1ccc4c5ccccc5c5ccccc5c4c1)CCCC3)CCCC2 ; CCc1cc2c(c3c1CCC3)N(c1cccc3c4ccccc4c4ccccc4c13)c1cccc3c1B2c1cc(CC)c2c(c1N3c1cccc3c4ccccc4c4ccccc4c13)CCC2 ; CCc1c2c(cc3c1N(c1cccc4c5ccccc5c5ccccc5c14)c1cccc4c1B3c1cc3c(c(CC)c1N4c1cccc4c5ccccc5c5ccccc5c14)CCC3)CCC2 ; CCc1cc2c(c3c1CCC3)N(c1ccc3c4ccccc4c4ccccc4c3c1)c1cccc3c1B2c1cc(CC)c2c(c1N3c1ccc3c4ccccc4c4ccccc4c3c1)CCC2]

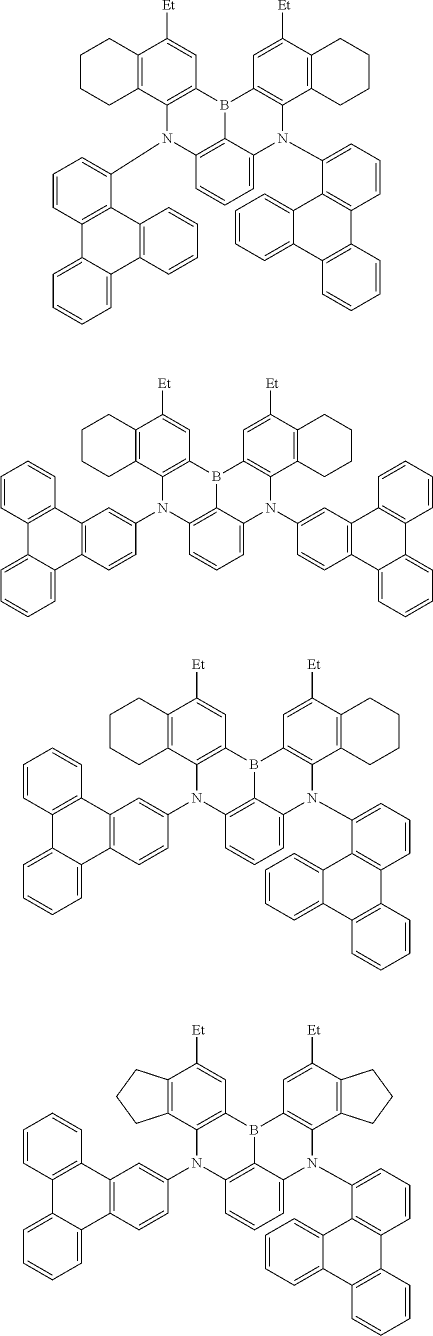 [SMILES: CCc1cc2c(c3c1CCCC3)N(c1cccc3c4ccccc4c4ccccc4c13)c1cccc3c1B2c1cc(CC)c2c(c1N3c1cccc3c4ccccc4c4ccccc4c13)CCCC2 ; CCc1cc2c(c3c1CCCC3)N(c1ccc3c4ccccc4c4ccccc4c3c1)c1cccc3c1B2c1cc(CC)c2c(c1N3c1ccc3c4ccccc4c4ccccc4c3c1)CCCC2 ; CCc1cc2c(c3c1CCCC3)N(c1ccc3c4ccccc4c4ccccc4c3c1)c1cccc3c1B2c1cc(CC)c2c(c1N3c1cccc3c4ccccc4c4ccccc4c13)CCCC2 ; CCc1cc2c(c3c1CCC3)N(c1ccc3c4ccccc4c4ccccc4c3c1)c1cccc3c1B2c1cc(CC)c2c(c1N3c1cccc3c4ccccc4c4ccccc4c13)CCC2]

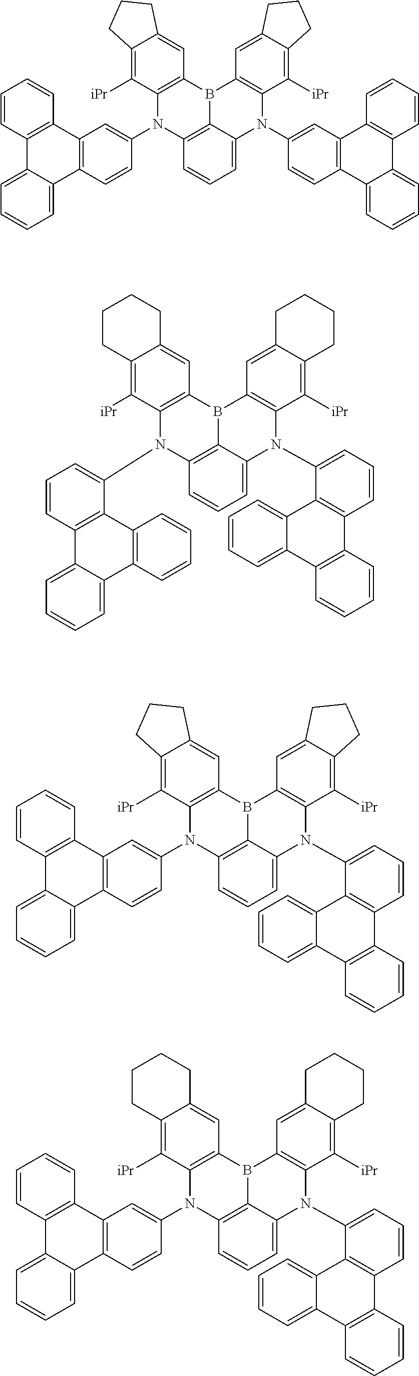 [SMILES: CC(C)c1c2c(cc3c1N(c1ccc4c5ccccc5c5ccccc5c4c1)c1cccc4c1B3c1cc3c(c(C(C)C)c1N4c1ccc4c5ccccc5c5ccccc5c4c1)CCC3)CCC2 ; CC(C)c1c2c(cc3c1N(c1cccc4c5ccccc5c5ccccc5c14)c1cccc4c1B3c1cc3c(c(C(C)C)c1N4c1cccc4c5ccccc5c5ccccc5c14)CCCC3)CCCC2 ; CC(C)c1c2c(cc3c1N(c1ccc4c5ccccc5c5ccccc5c4c1)c1cccc4c1B3c1cc3c(c(C(C)C)c1N4c1cccc4c5ccccc5c5ccccc5c14)CCC3)CCC2 ; CC(C)c1c2c(cc3c1N(c1ccc4c5ccccc5c5ccccc5c4c1)c1cccc4c1B3c1cc3c(c(C(C)C)c1N4c1cccc4c5ccccc5c5ccccc5c14)CCCC3)CCCC2]

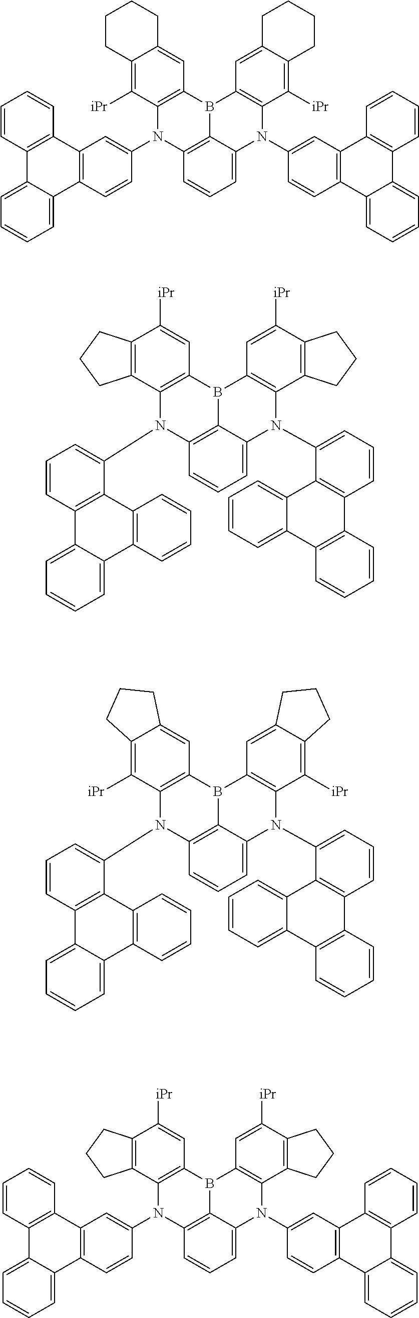 [SMILES: CC(C)c1c2c(cc3c1N(c1ccc4c5ccccc5c5ccccc5c4c1)c1cccc4c1B3c1cc3c(c(C(C)C)c1N4c1ccc4c5ccccc5c5ccccc5c4c1)CCCC3)CCCC2 ; CC(C)c1cc2c(c3c1CCC3)N(c1cccc3c4ccccc4c4ccccc4c13)c1cccc3c1B2c1cc(C(C)C)c2c(c1N3c1cccc3c4ccccc4c4ccccc4c13)CCC2 ; CC(C)c1c2c(cc3c1N(c1cccc4c5ccccc5c5ccccc5c14)c1cccc4c1B3c1cc3c(c(C(C)C)c1N4c1cccc4c5ccccc5c5ccccc5c14)CCC3)CCC2 ; CC(C)c1cc2c(c3c1CCC3)N(c1ccc3c4ccccc4c4ccccc4c3c1)c1cccc3c1B2c1cc(C(C)C)c2c(c1N3c1ccc3c4ccccc4c4ccccc4c3c1)CCC2]

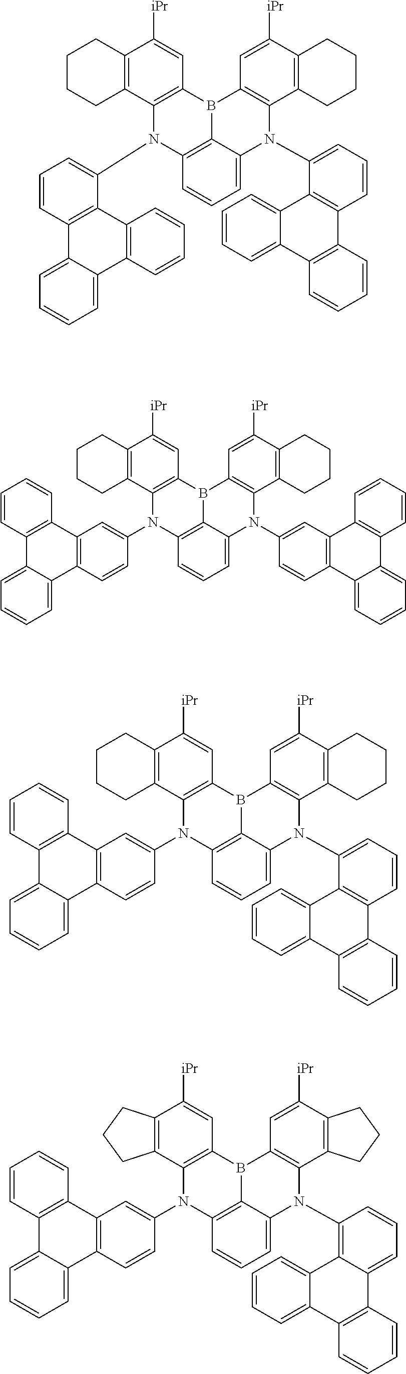 [SMILES: CC(C)c1cc2c(c3c1CCCC3)N(c1cccc3c4ccccc4c4ccccc4c13)c1cccc3c1B2c1cc(C(C)C)c2c(c1N3c1cccc3c4ccccc4c4ccccc4c13)CCCC2 ; CC(C)c1cc2c(c3c1CCCC3)N(c1ccc3c4ccccc4c4ccccc4c3c1)c1cccc3c1B2c1cc(C(C)C)c2c(c1N3c1ccc3c4ccccc4c4ccccc4c3c1)CCCC2 ; CC(C)c1cc2c(c3c1CCCC3)N(c1ccc3c4ccccc4c4ccccc4c3c1)c1cccc3c1B2c1cc(C(C)C)c2c(c1N3c1cccc3c4ccccc4c4ccccc4c13)CCCC2 ; CC(C)c1cc2c(c3c1CCC3)N(c1ccc3c4ccccc4c4ccccc4c3c1)c1cccc3c1B2c1cc(C(C)C)c2c(c1N3c1cccc3c4ccccc4c4ccccc4c13)CCC2]

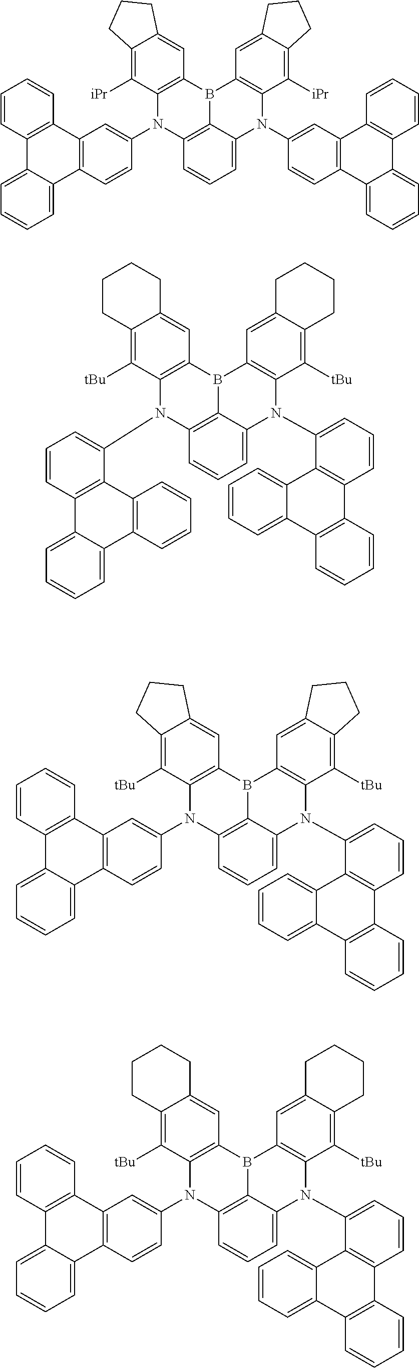 [SMILES: CC(C)c1c2c(cc3c1N(c1ccc4c5ccccc5c5ccccc5c4c1)c1cccc4c1B3c1cc3c(c(C(C)C)c1N4c1ccc4c5ccccc5c5ccccc5c4c1)CCC3)CCC2 ; CC(C)(C)c1c2c(cc3c1N(c1cccc4c5ccccc5c5ccccc5c14)c1cccc4c1B3c1cc3c(c(C(C)(C)C)c1N4c1cccc4c5ccccc5c5ccccc5c14)CCCC3)CCCC2 ; CC(C)(C)c1c2c(cc3c1N(c1ccc4c5ccccc5c5ccccc5c4c1)c1cccc4c1B3c1cc3c(c(C(C)(C)C)c1N4c1cccc4c5ccccc5c5ccccc5c14)CCC3)CCC2 ; CC(C)(C)c1c2c(cc3c1N(c1ccc4c5ccccc5c5ccccc5c4c1)c1cccc4c1B3c1cc3c(c(C(C)(C)C)c1N4c1cccc4c5ccccc5c5ccccc5c14)CCCC3)CCCC2]

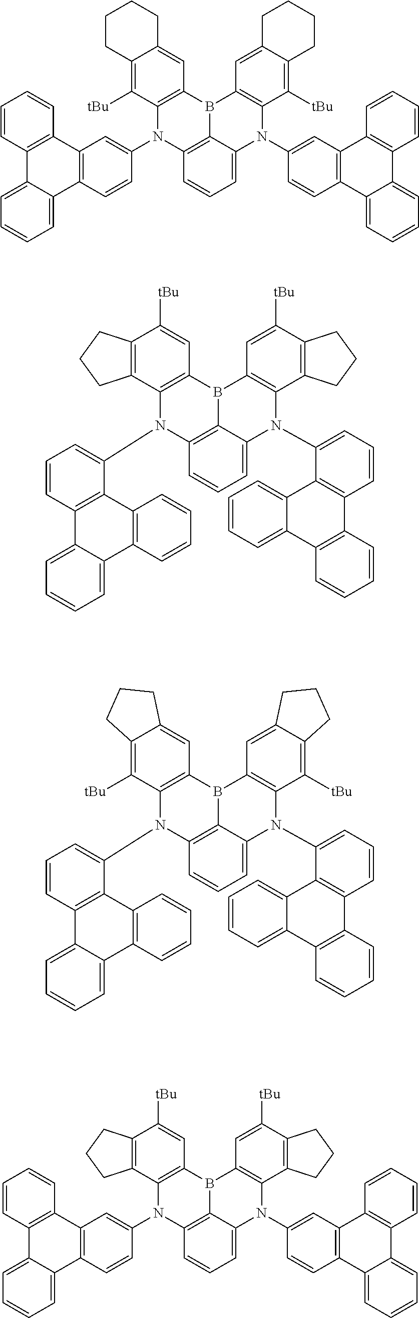 [SMILES: CC(C)(C)c1c2c(cc3c1N(c1ccc4c5ccccc5c5ccccc5c4c1)c1cccc4c1B3c1cc3c(c(C(C)(C)C)c1N4c1ccc4c5ccccc5c5ccccc5c4c1)CCCC3)CCCC2 ; CC(C)(C)c1cc2c(c3c1CCC3)N(c1cccc3c4ccccc4c4ccccc4c13)c1cccc3c1B2c1cc(C(C)(C)C)c2c(c1N3c1cccc3c4ccccc4c4ccccc4c13)CCC2 ; CC(C)(C)c1c2c(cc3c1N(c1cccc4c5ccccc5c5ccccc5c14)c1cccc4c1B3c1cc3c(c(C(C)(C)C)c1N4c1cccc4c5ccccc5c5ccccc5c14)CCC3)CCC2 ; CC(C)(C)c1cc2c(c3c1CCC3)N(c1ccc3c4ccccc4c4ccccc4c3c1)c1cccc3c1B2c1cc(C(C)(C)C)c2c(c1N3c1ccc3c4ccccc4c4ccccc4c3c1)CCC2]

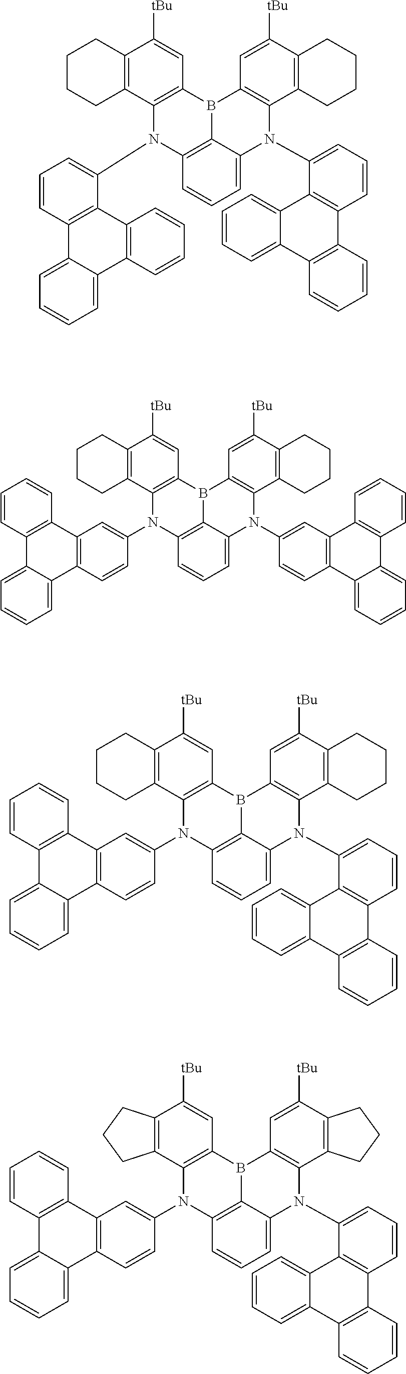 [SMILES: CC(C)(C)c1cc2c(c3c1CCCC3)N(c1cccc3c4ccccc4c4ccccc4c13)c1cccc3c1B2c1cc(C(C)(C)C)c2c(c1N3c1cccc3c4ccccc4c4ccccc4c13)CCCC2 ; CC(C)(C)c1cc2c(c3c1CCCC3)N(c1ccc3c4ccccc4c4ccccc4c3c1)c1cccc3c1B2c1cc(C(C)(C)C)c2c(c1N3c1ccc3c4ccccc4c4ccccc4c3c1)CCCC2 ; CC(C)(C)c1cc2c(c3c1CCCC3)N(c1ccc3c4ccccc4c4ccccc4c3c1)c1cccc3c1B2c1cc(C(C)(C)C)c2c(c1N3c1cccc3c4ccccc4c4ccccc4c13)CCCC2 ; CC(C)(C)c1cc2c(c3c1CCC3)N(c1ccc3c4ccccc4c4ccccc4c3c1)c1cccc3c1B2c1cc(C(C)(C)C)c2c(c1N3c1cccc3c4ccccc4c4ccccc4c13)CCC2]

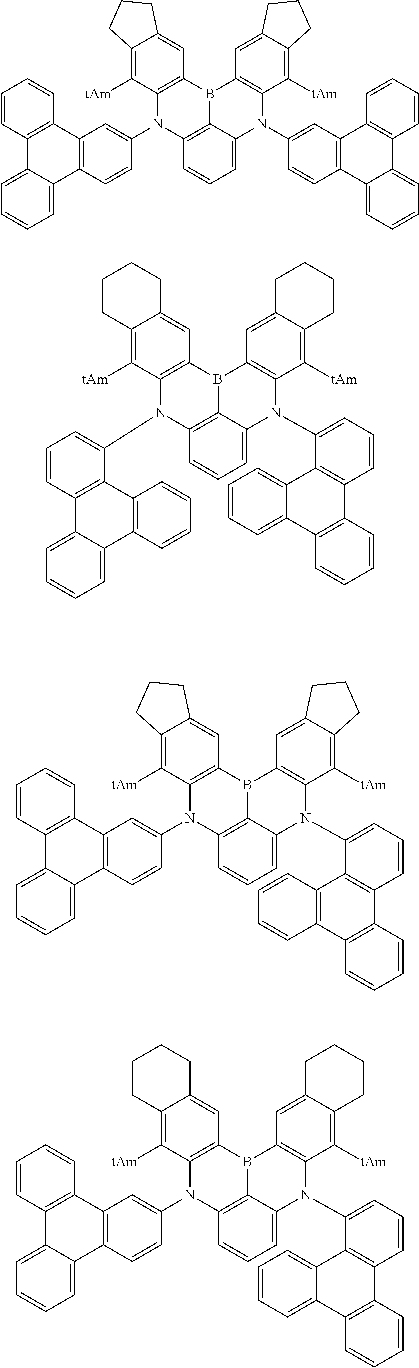

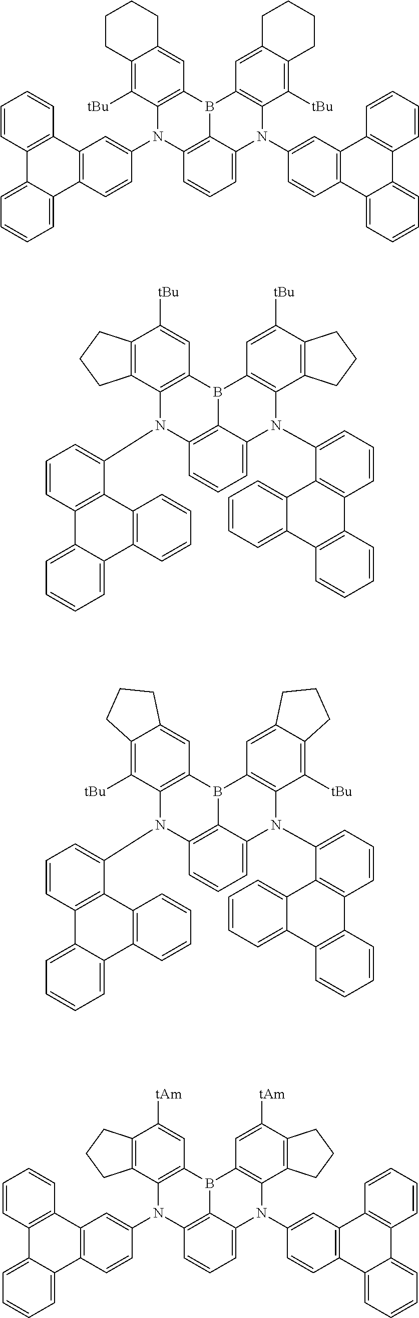

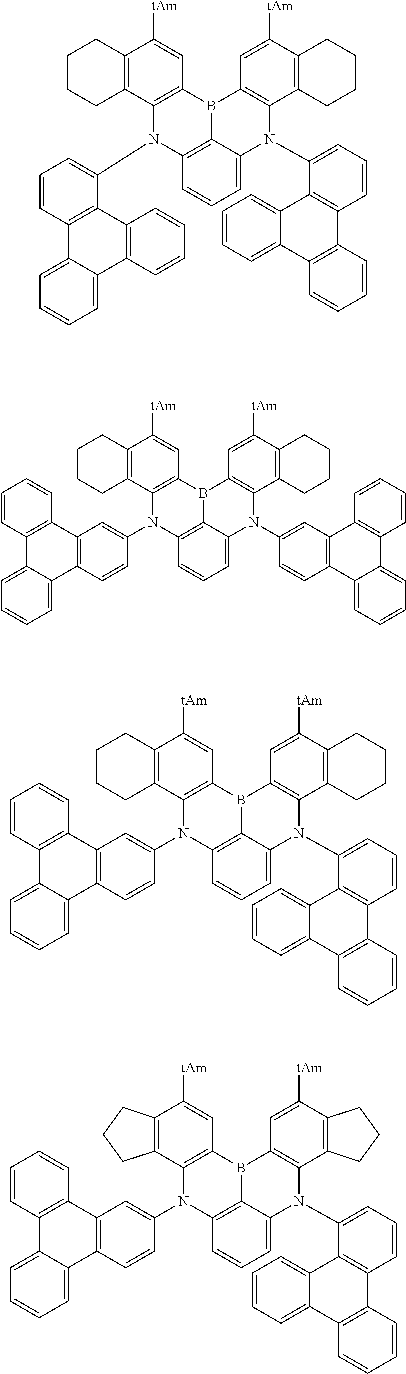

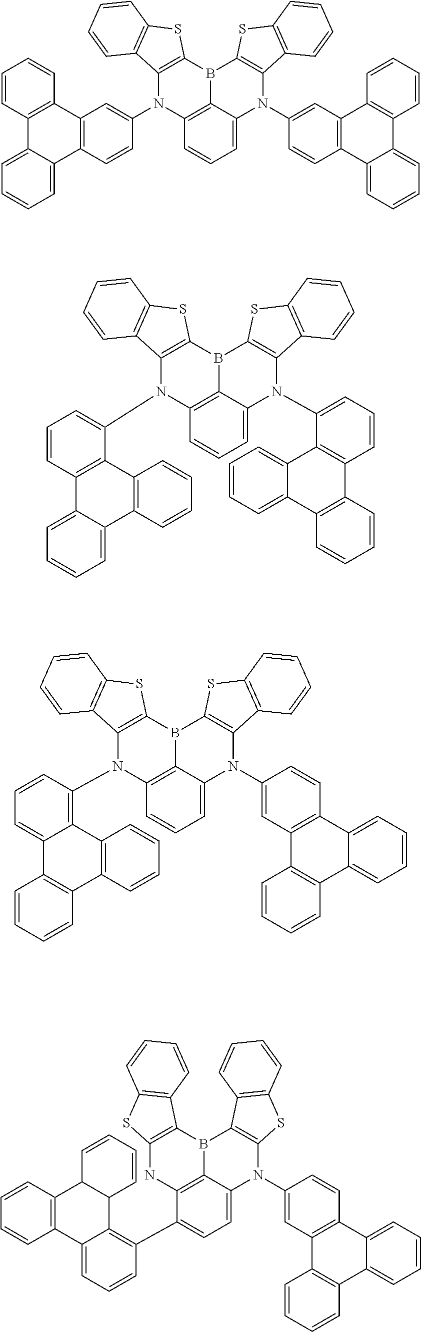 [SMILES: c1cc2c3c(c1)N(c1ccc4c5ccccc5c5ccccc5c4c1)c1c(sc4ccccc14)B3c1sc3ccccc3c1N2c1ccc2c3ccccc3c3ccccc3c2c1 ; c1cc2c3c(c1)N(c1cccc4c5ccccc5c5ccccc5c14)c1c(sc4ccccc14)B3c1sc3ccccc3c1N2c1cccc2c3ccccc3c3ccccc3c12 ; c1cc2c3c(c1)N(c1cccc4c5ccccc5c5ccccc5c14)c1c(sc4ccccc14)B3c1sc3ccccc3c1N2c1ccc2c3ccccc3c3ccccc3c2c1 ; C1=CC2c3ccccc3-c3cccc(-c4ccc5c6c4Nc4sc7ccccc7c4B6c4c(sc6ccccc46)N5c4ccc5c6ccccc6c6ccccc6c5c4)c3C2C=C1]

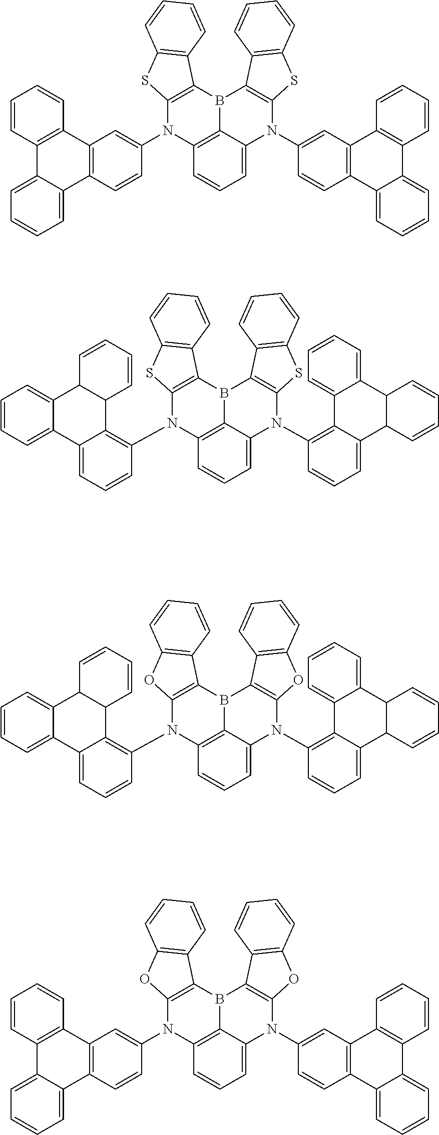 [SMILES: c1cc2c3c(c1)N(c1ccc4c5ccccc5c5ccccc5c4c1)c1sc4ccccc4c1B3c1c(sc3ccccc13)N2c1ccc2c3ccccc3c3ccccc3c2c1 ; C1=CC2c3ccccc3-c3c(cccc3N3c4cccc5c4B(c4c3sc3ccccc43)c3c(sc4ccccc34)N5c3cccc4c3C3C=CC=CC3c3ccccc3-4)C2C=C1 ; C1=CC2c3ccccc3-c3c(cccc3N3c4cccc5c4B(c4c3oc3ccccc43)c3c(oc4ccccc34)N5c3cccc4c3C3C=CC=CC3c3ccccc3-4)C2C=C1 ; c1cc2c3c(c1)N(c1ccc4c5ccccc5c5ccccc5c4c1)c1oc4ccccc4c1B3c1c(oc3ccccc13)N2c1ccc2c3ccccc3c3ccccc3c2c1]

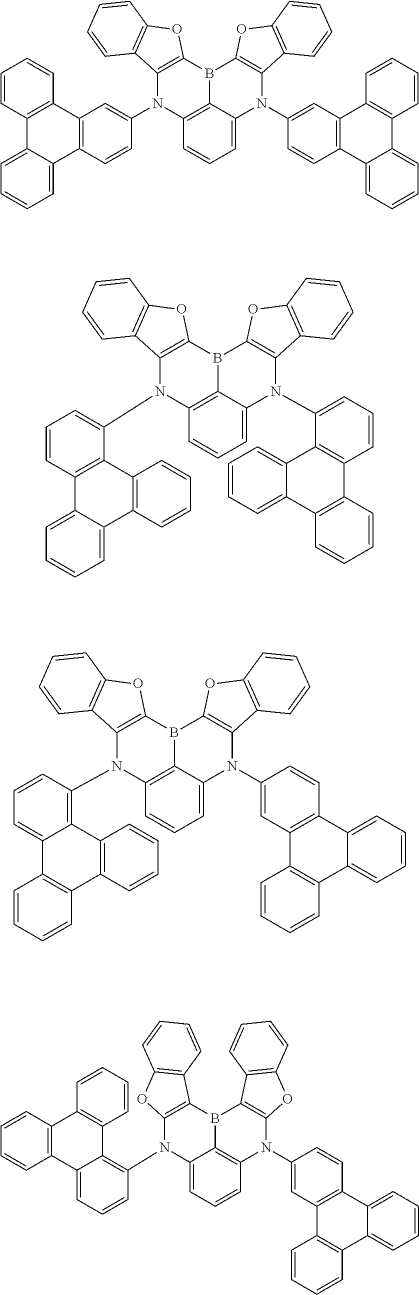 [SMILES: c1cc2c3c(c1)N(c1ccc4c5ccccc5c5ccccc5c4c1)c1c(oc4ccccc14)B3c1oc3ccccc3c1N2c1ccc2c3ccccc3c3ccccc3c2c1 ; c1cc2c3c(c1)N(c1cccc4c5ccccc5c5ccccc5c14)c1c(oc4ccccc14)B3c1oc3ccccc3c1N2c1cccc2c3ccccc3c3ccccc3c12 ; c1cc2c3c(c1)N(c1cccc4c5ccccc5c5ccccc5c14)c1c(oc4ccccc14)B3c1oc3ccccc3c1N2c1ccc2c3ccccc3c3ccccc3c2c1 ; c1cc2c3c(c1)N(c1cccc4c5ccccc5c5ccccc5c14)c1oc4ccccc4c1B3c1c(oc3ccccc13)N2c1ccc2c3ccccc3c3ccccc3c2c1]

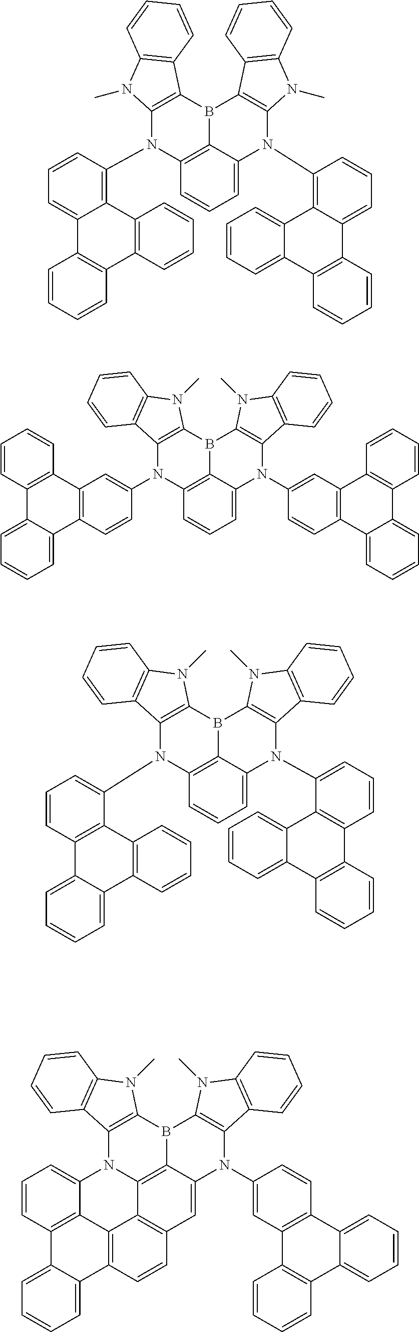 [SMILES: Cn1c2c(c3ccccc31)B1c3c(cccc3N(c3cccc4c5ccccc5c5ccccc5c34)c3c1c1ccccc1n3C)N2c1cccc2c3ccccc3c3ccccc3c12 ; Cn1c2c(c3ccccc31)N(c1ccc3c4ccccc4c4ccccc4c3c1)c1cccc3c1B2c1c(c2ccccc2n1C)N3c1ccc2c3ccccc3c3ccccc3c2c1 ; Cn1c2c(c3ccccc31)N(c1cccc3c4ccccc4c4ccccc4c13)c1cccc3c1B2c1c(c2ccccc2n1C)N3c1cccc2c3ccccc3c3ccccc3c12 ; Cn1c2c(c3ccccc31)N(c1ccc3c4ccccc4c4ccccc4c3c1)c1cc3ccc4c5ccccc5c5cccc6c5c4c3c3c1B2c1c(c2ccccc2n1C)N36]

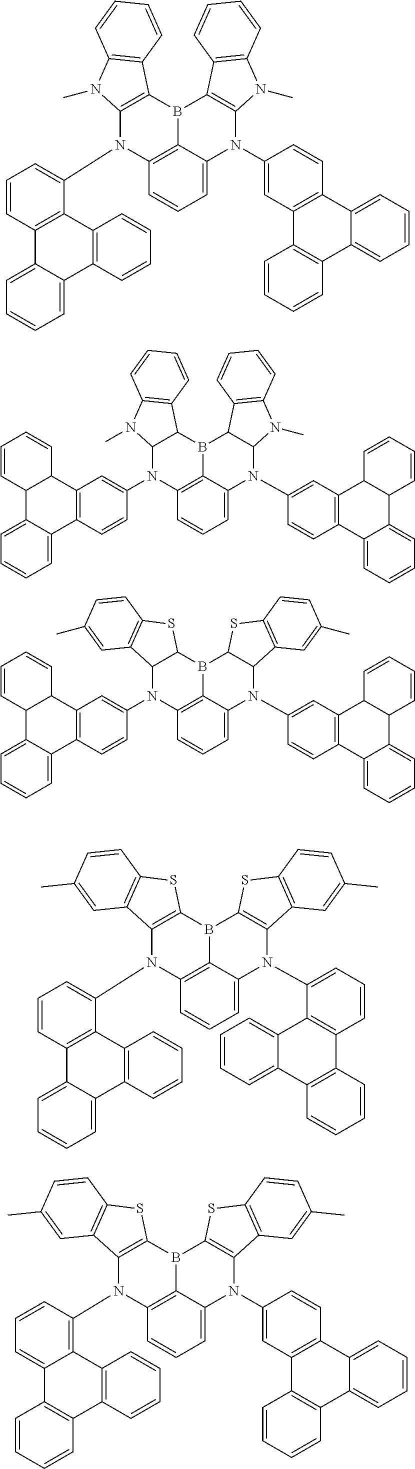

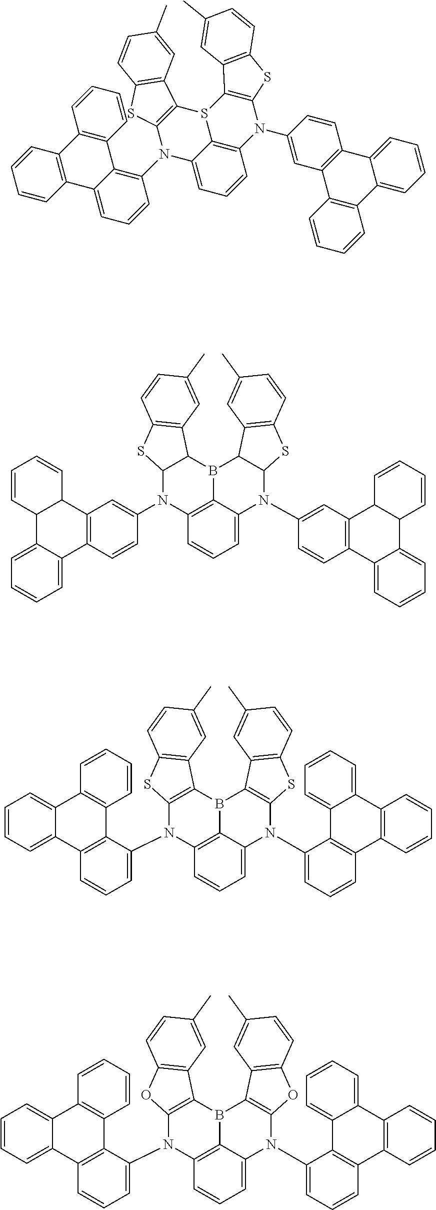

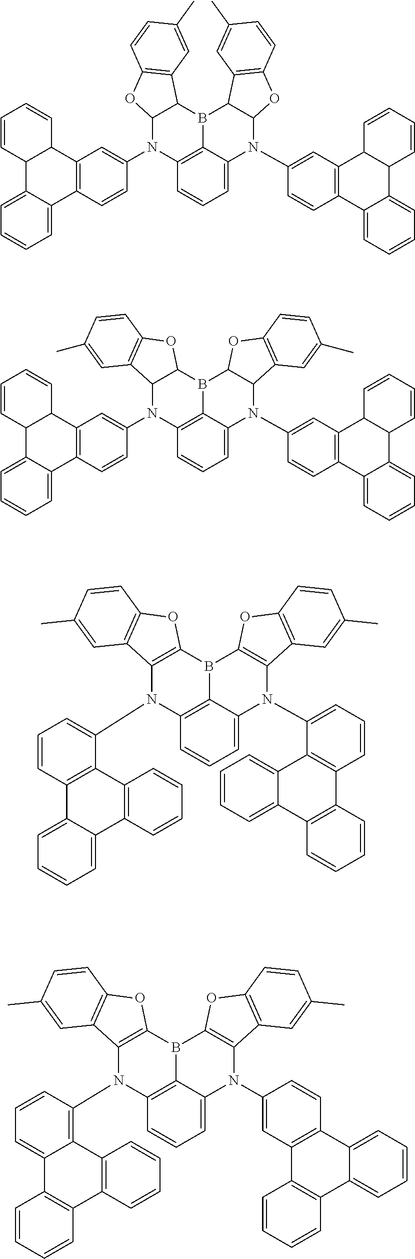

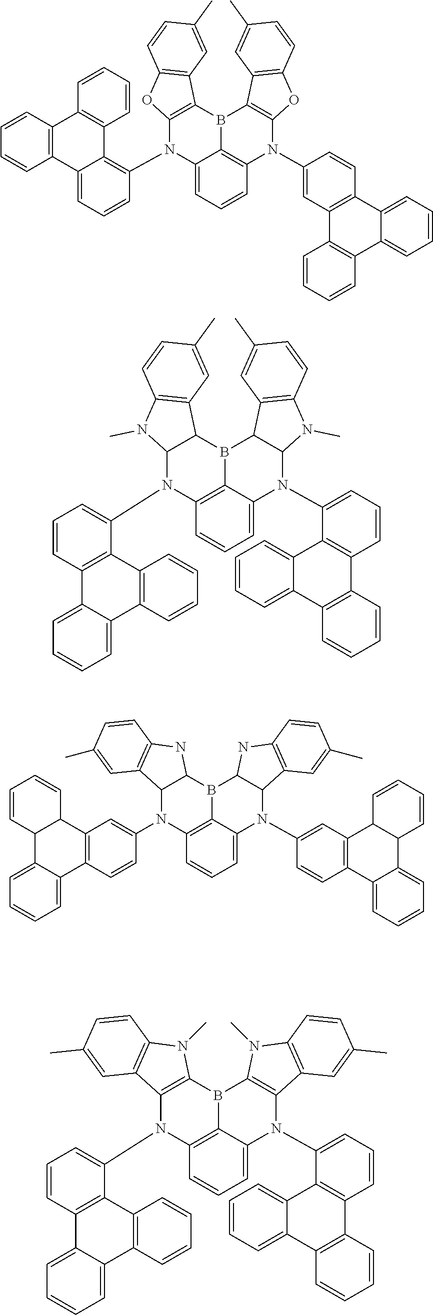 [SMILES: Cc1ccc2oc3c(c2c1)B1c2c(cccc2N(c2cccc4c5ccccc5c5ccccc5c24)c2oc4ccc(C)cc4c21)N3c1ccc2c3ccccc3c3ccccc3c2c1 ; Cc1ccc2c(c1)C1B3c4c(cccc4N(c4cccc5c6ccccc6c6ccccc6c45)C4C3c3cc(C)ccc3N4C)N(c3cccc4c5ccccc5c5ccccc5c34)C1N2C ; Cc1ccc2c(c1)C1C(N2)B2c3c(cccc3N(c3ccc4c(c3)C3C=CC=CC3c3ccccc3-4)C3c4cc(C)ccc4NC23)N1c1ccc2c(c1)C1C=CC=CC1c1ccccc1-2 ; Cc1ccc2c(c1)c1c(n2C)B2c3c(cccc3N(c3cccc4c5ccccc5c5ccccc5c34)c3c2n(C)c2ccc(C)cc32)N1c1cccc2c3ccccc3c3ccccc3c12]

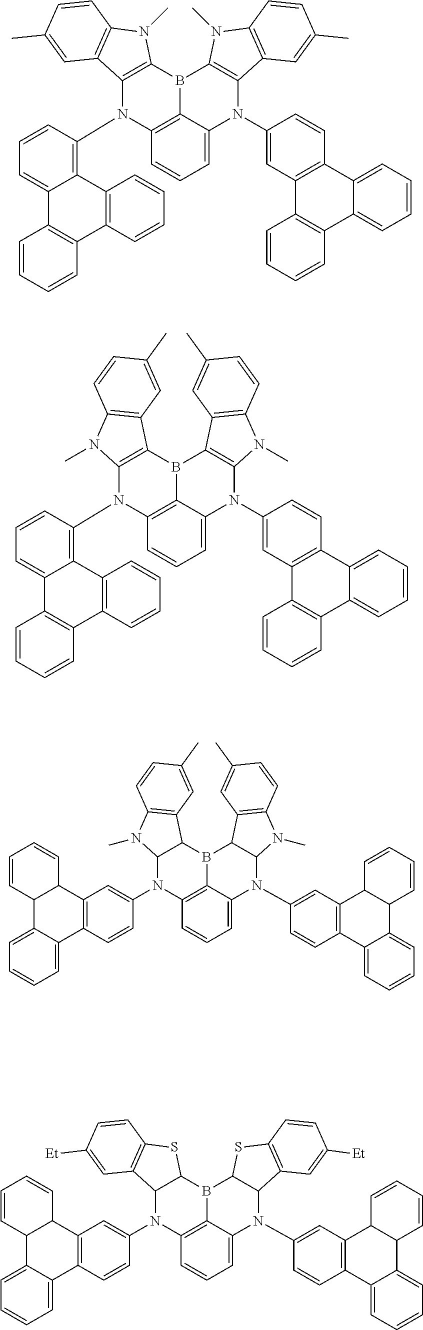 [SMILES: Cc1ccc2c(c1)c1c(n2C)B2c3c(cccc3N(c3cccc4c5ccccc5c5ccccc5c34)c3c2n(C)c2ccc(C)cc32)N1c1ccc2c3ccccc3c3ccccc3c2c1 ; Cc1ccc2c(c1)c1c(n2C)N(c2ccc3c4ccccc4c4ccccc4c3c2)c2cccc3c2B1c1c(n(C)c2ccc(C)cc12)N3c1cccc2c3ccccc3c3ccccc3c12 ; Cc1ccc2c(c1)C1B3c4c(cccc4N(c4ccc5c(c4)C4C=CC=CC4c4ccccc4-5)C4C3c3cc(C)ccc3N4C)N(c3ccc4c(c3)C3C=CC=CC3c3ccccc3-4)C1N2C ; CCc1ccc2c(c1)C1C(S2)B2c3c(cccc3N(c3ccc4c(c3)C3C=CC=CC3c3ccccc3-4)C3c4cc(CC)ccc4SC23)N1c1ccc2c(c1)C1C=CC=CC1c1ccccc1-2]

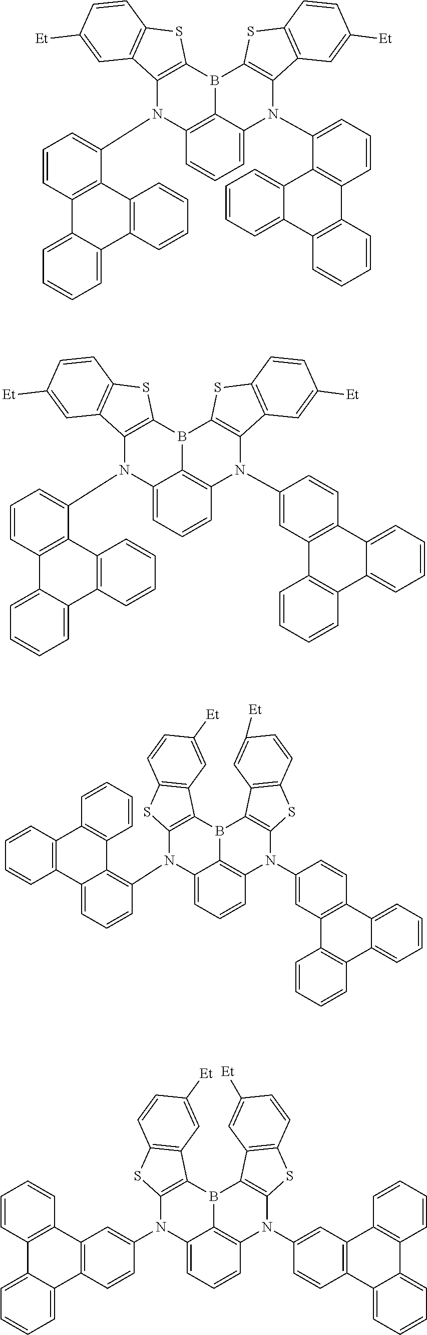 [SMILES: CCc1ccc2sc3c(c2c1)N(c1cccc2c4ccccc4c4ccccc4c12)c1cccc2c1B3c1sc3ccc(CC)cc3c1N2c1cccc2c3ccccc3c3ccccc3c12 ; CCc1ccc2sc3c(c2c1)N(c1ccc2c4ccccc4c4ccccc4c2c1)c1cccc2c1B3c1sc3ccc(CC)cc3c1N2c1cccc2c3ccccc3c3ccccc3c12 ; CCc1ccc2sc3c(c2c1)B1c2c(cccc2N(c2cccc4c5ccccc5c5ccccc5c24)c2sc4ccc(CC)cc4c21)N3c1ccc2c3ccccc3c3ccccc3c2c1 ; CCc1ccc2sc3c(c2c1)B1c2c(cccc2N(c2ccc4c5ccccc5c5ccccc5c4c2)c2sc4ccc(CC)cc4c21)N3c1ccc2c3ccccc3c3ccccc3c2c1]

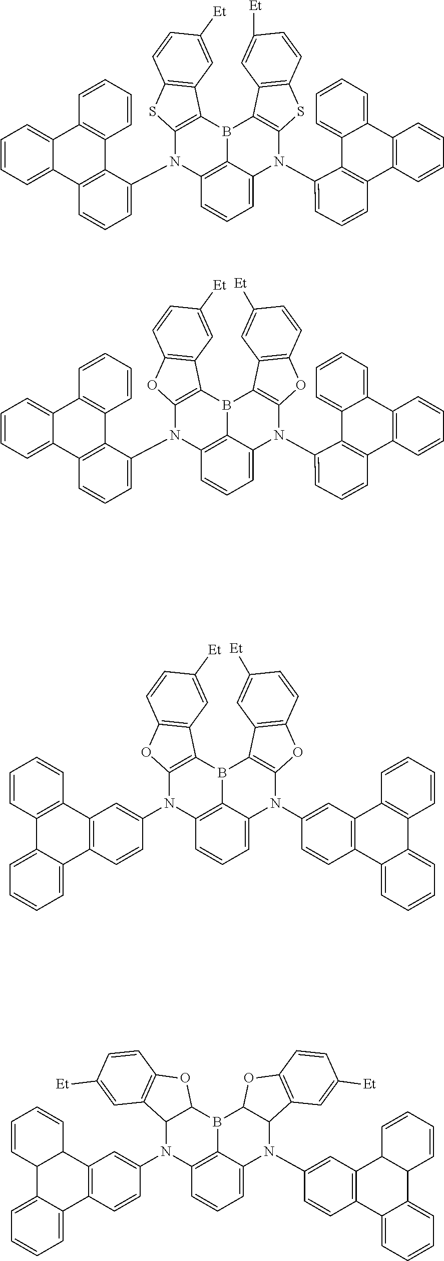 [SMILES: CCc1ccc2sc3c(c2c1)B1c2c(cccc2N(c2cccc4c5ccccc5c5ccccc5c24)c2sc4ccc(CC)cc4c21)N3c1cccc2c3ccccc3c3ccccc3c12 ; CCc1ccc2oc3c(c2c1)B1c2c(cccc2N(c2cccc4c5ccccc5c5ccccc5c24)c2oc4ccc(CC)cc4c21)N3c1cccc2c3ccccc3c3ccccc3c12 ; CCc1ccc2oc3c(c2c1)B1c2c(cccc2N(c2ccc4c5ccccc5c5ccccc5c4c2)c2oc4ccc(CC)cc4c21)N3c1ccc2c3ccccc3c3ccccc3c2c1 ; CCc1ccc2c(c1)C1C(O2)B2c3c(cccc3N(c3ccc4c(c3)C3C=CC=CC3c3ccccc3-4)C3c4cc(CC)ccc4OC23)N1c1ccc2c(c1)C1C=CC=CC1c1ccccc1-2]

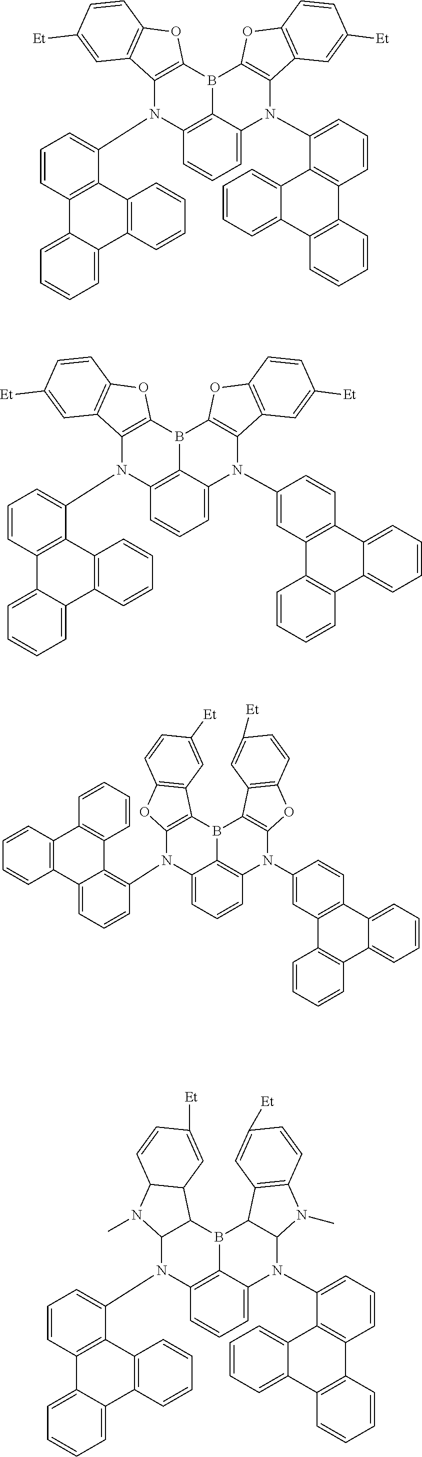 [SMILES: CCc1ccc2oc3c(c2c1)N(c1cccc2c4ccccc4c4ccccc4c12)c1cccc2c1B3c1oc3ccc(CC)cc3c1N2c1cccc2c3ccccc3c3ccccc3c12 ; CCc1ccc2oc3c(c2c1)N(c1ccc2c4ccccc4c4ccccc4c2c1)c1cccc2c1B3c1oc3ccc(CC)cc3c1N2c1cccc2c3ccccc3c3ccccc3c12 ; CCc1ccc2oc3c(c2c1)B1c2c(cccc2N(c2cccc4c5ccccc5c5ccccc5c24)c2oc4ccc(CC)cc4c21)N3c1ccc2c3ccccc3c3ccccc3c2c1 ; CCC1=CC2C3B4c5c(cccc5N(c5cccc6c7ccccc7c7ccccc7c56)C3N(C)C2C=C1)N(c1cccc2c3ccccc3c3ccccc3c12)C1C4c2cc(CC)ccc2N1C]

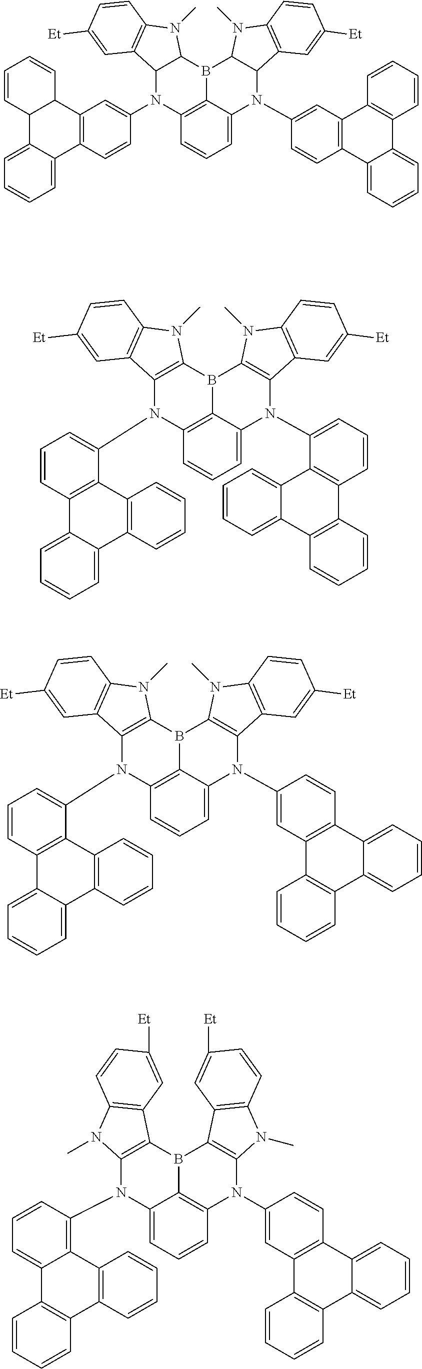 [SMILES: CCc1ccc2c(c1)C1C(B3c4c(cccc4N(c4ccc5c6ccccc6c6ccccc6c5c4)C4c5cc(CC)ccc5N(C)C34)N1c1ccc3c(c1)C1C=CC=CC1c1ccccc1-3)N2C ; CCc1ccc2c(c1)c1c(n2C)B2c3c(cccc3N(c3cccc4c5ccccc5c5ccccc5c34)c3c2n(C)c2ccc(CC)cc32)N1c1cccc2c3ccccc3c3ccccc3c12 ; CCc1ccc2c(c1)c1c(n2C)B2c3c(cccc3N(c3cccc4c5ccccc5c5ccccc5c34)c3c2n(C)c2ccc(CC)cc32)N1c1ccc2c3ccccc3c3ccccc3c2c1 ; CCc1ccc2c(c1)c1c(n2C)N(c2ccc3c4ccccc4c4ccccc4c3c2)c2cccc3c2B1c1c(n(C)c2ccc(CC)cc12)N3c1cccc2c3ccccc3c3ccccc3c12]

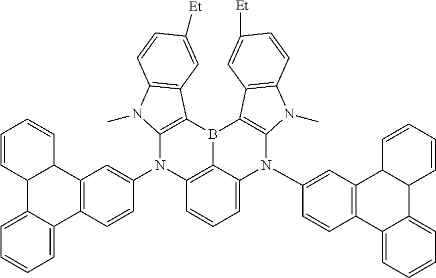 [SMILES: CCc1ccc2c(c1)c1c(n2C)N(c2ccc3c(c2)C2C=CC=CC2c2ccccc2-3)c2cccc3c2B1c1c(n(C)c2ccc(CC)cc12)N3c1ccc2c(c1)C1C=CC=CC1c1ccccc1-2]

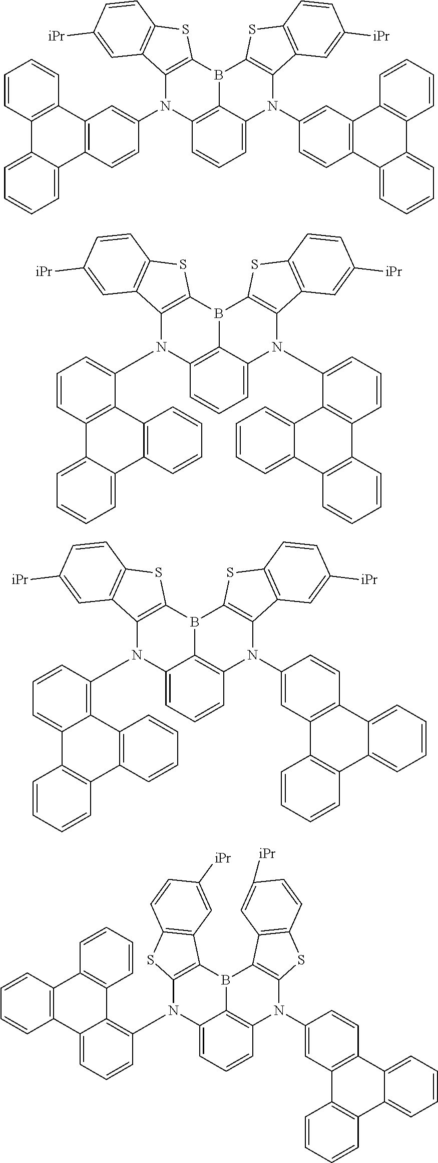

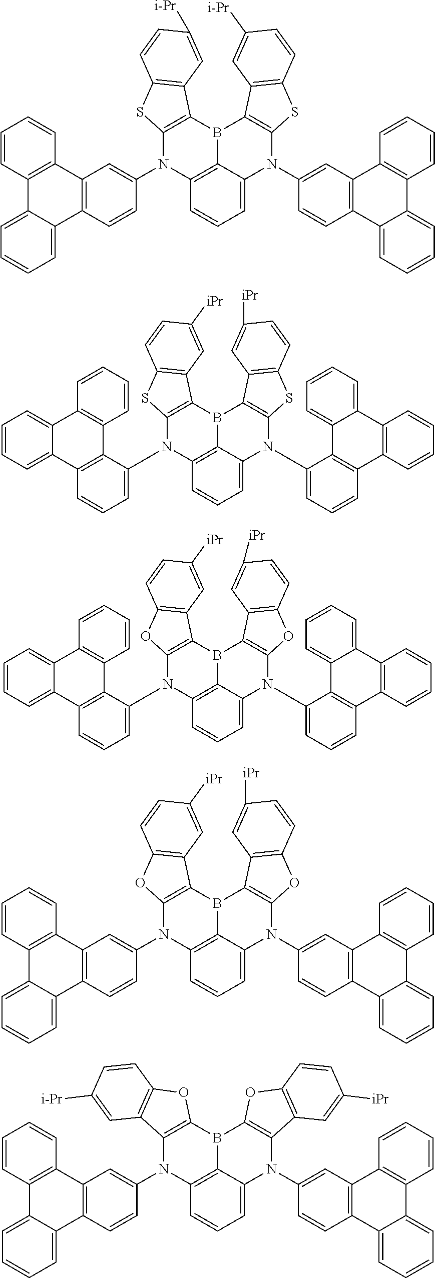

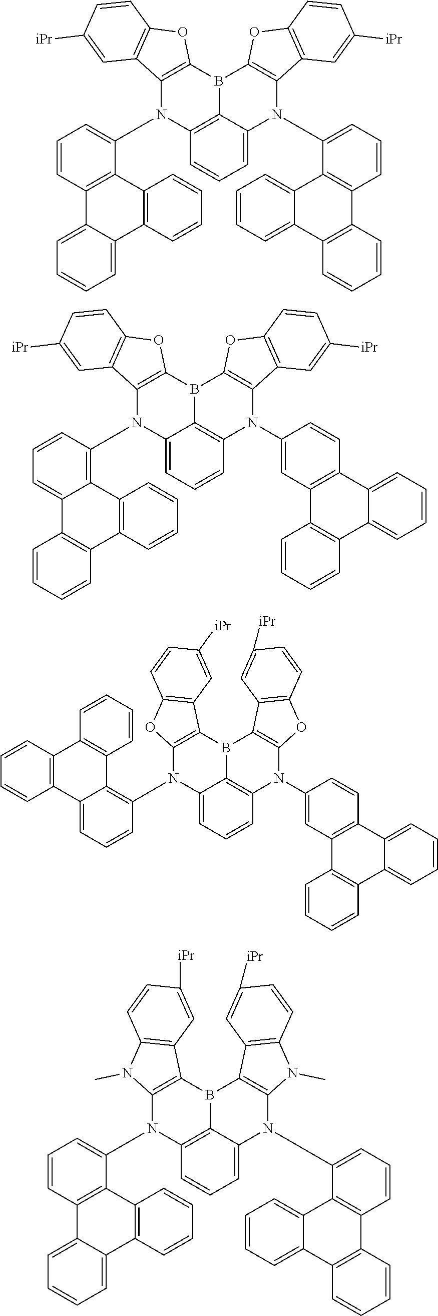

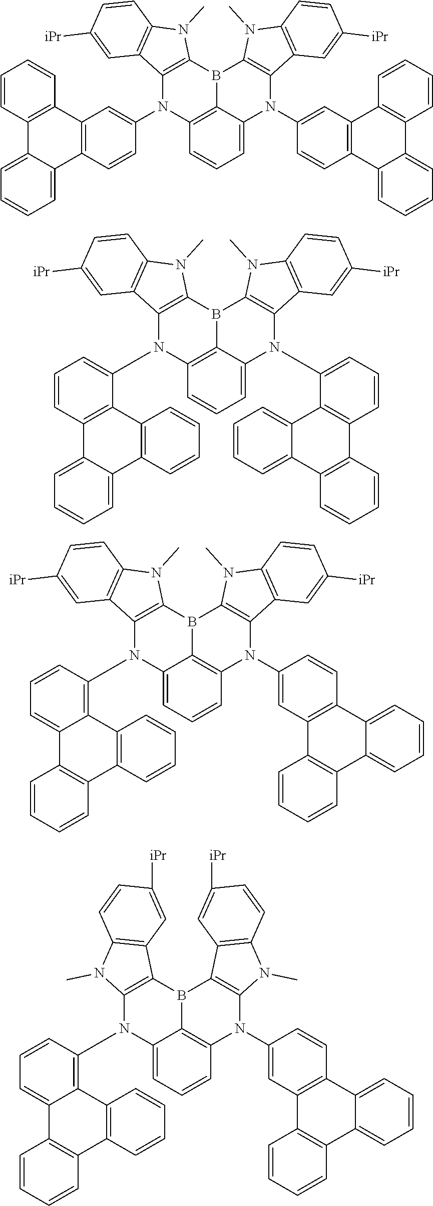

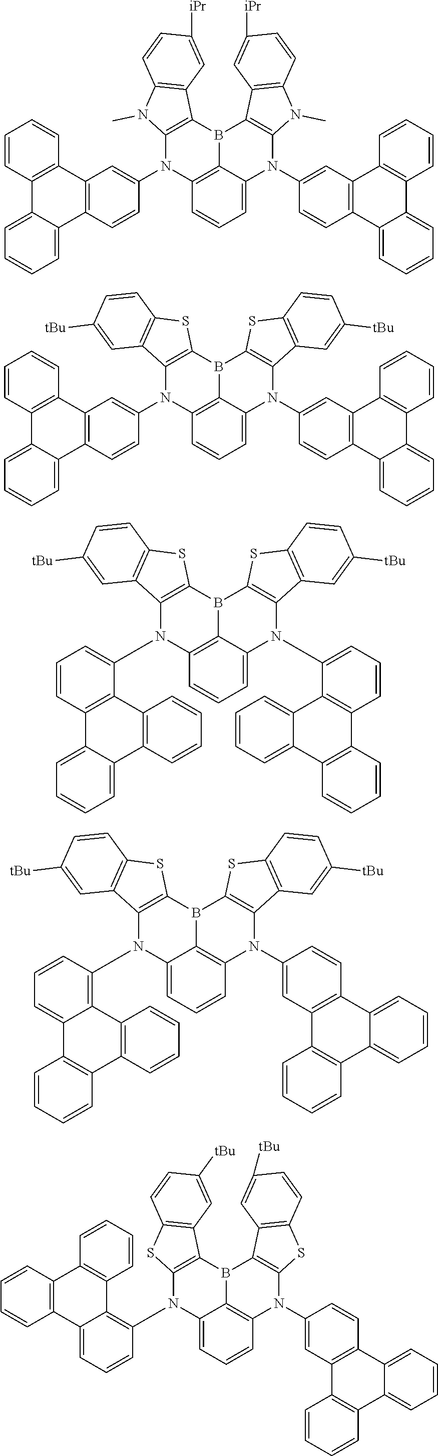

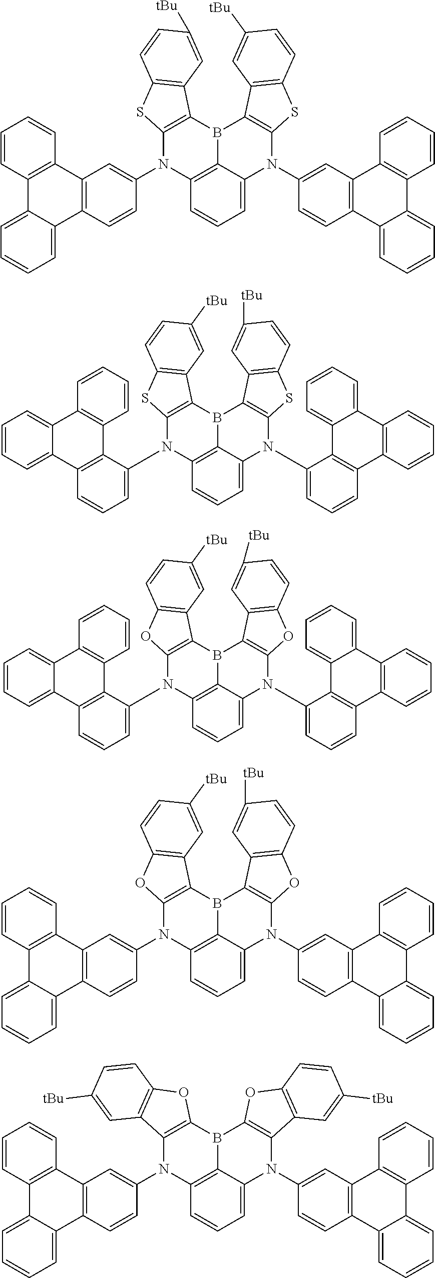

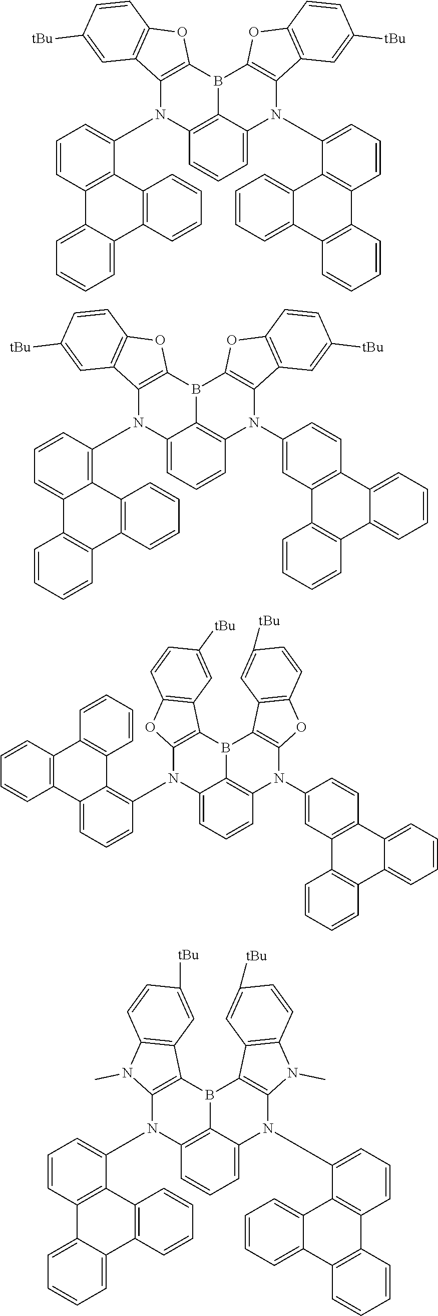

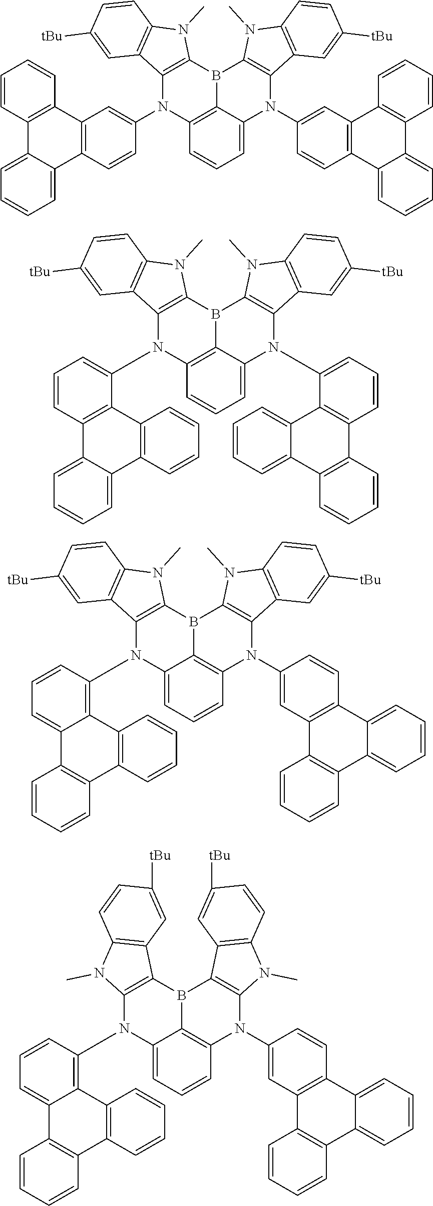

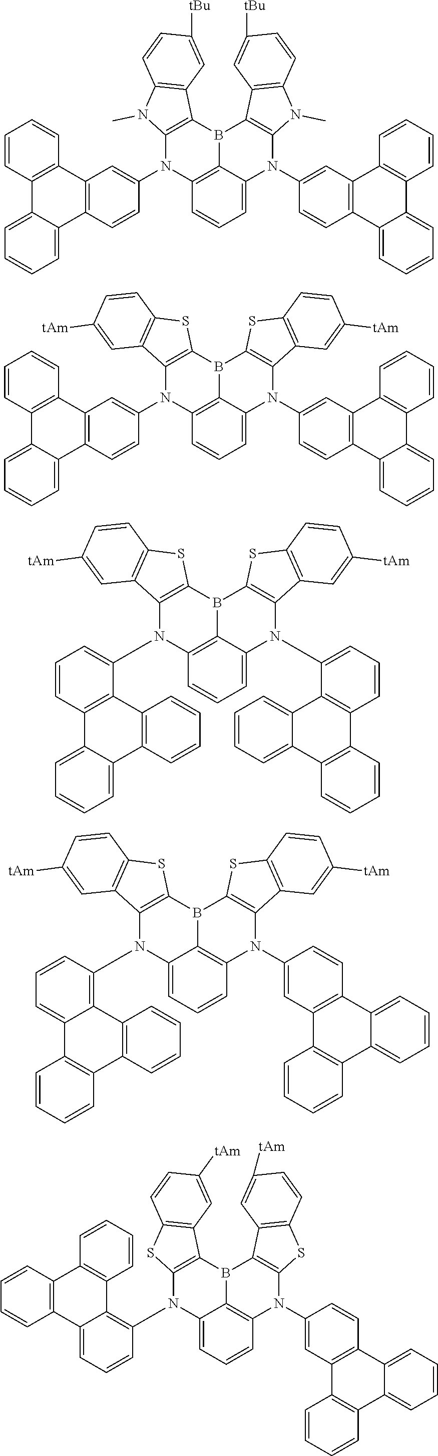

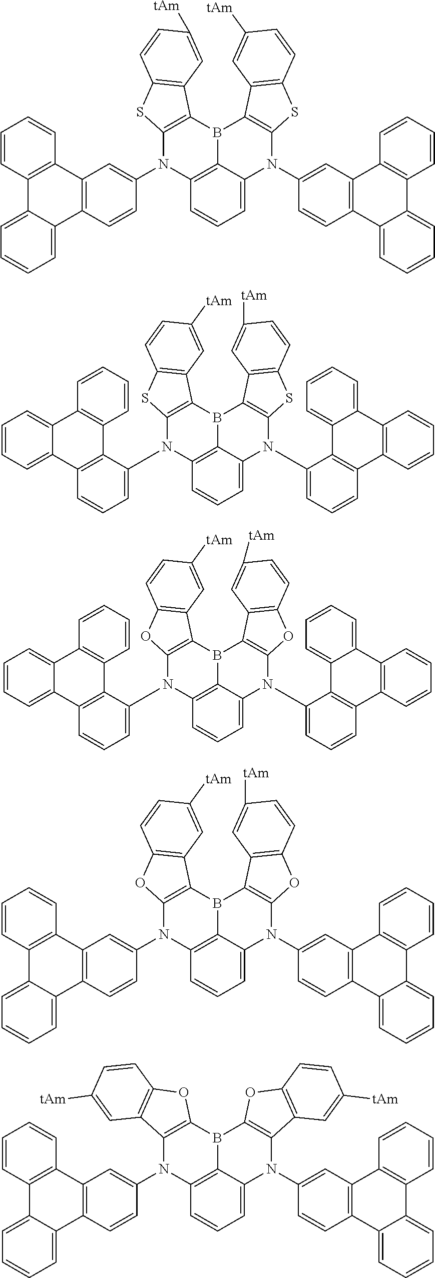

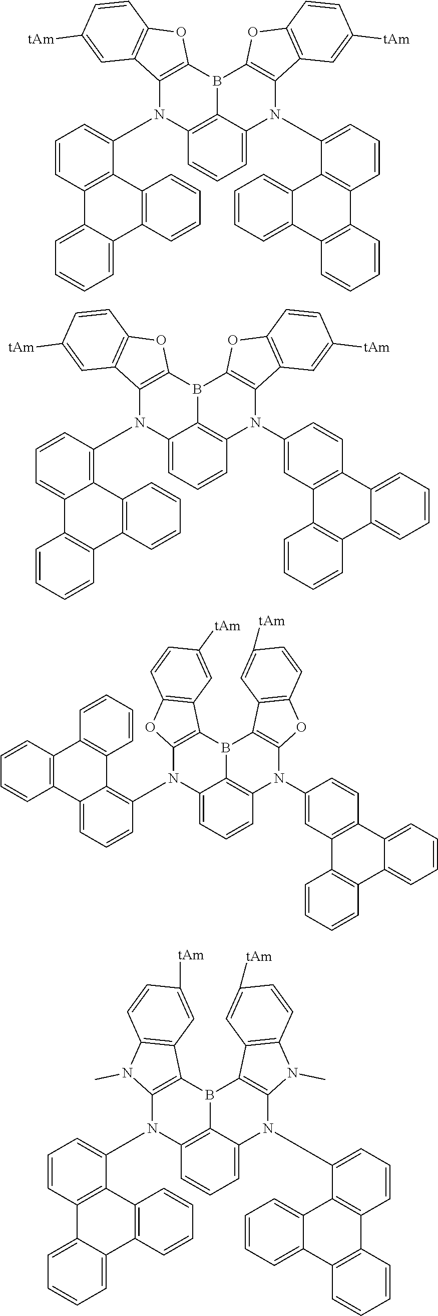

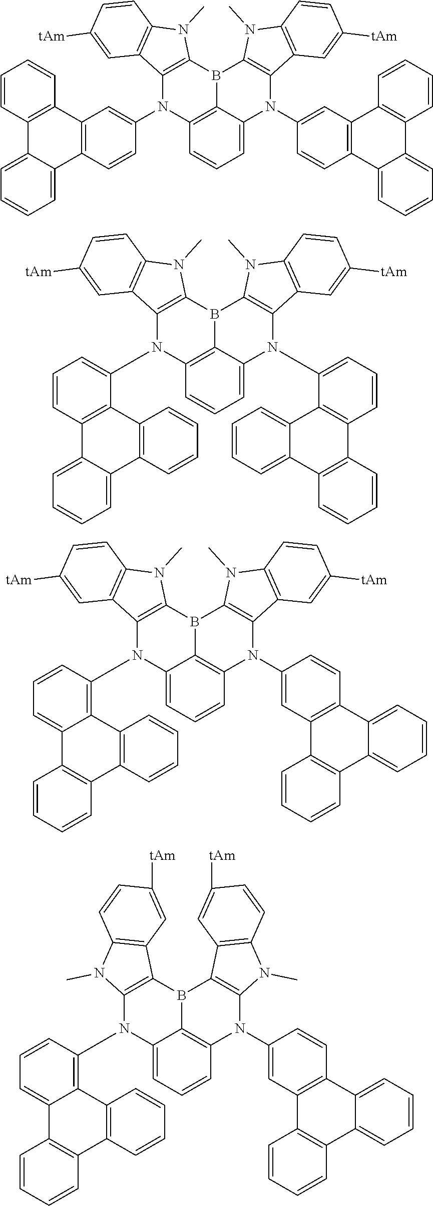

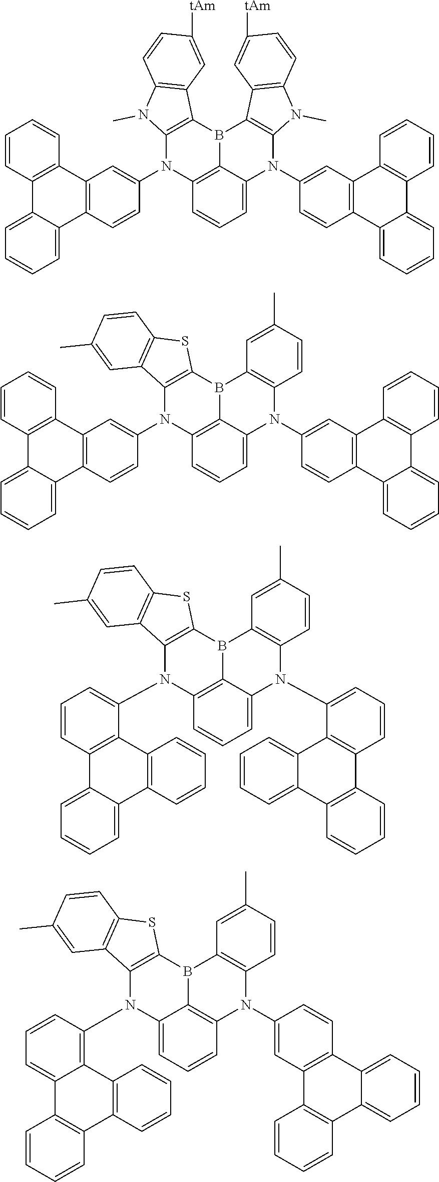

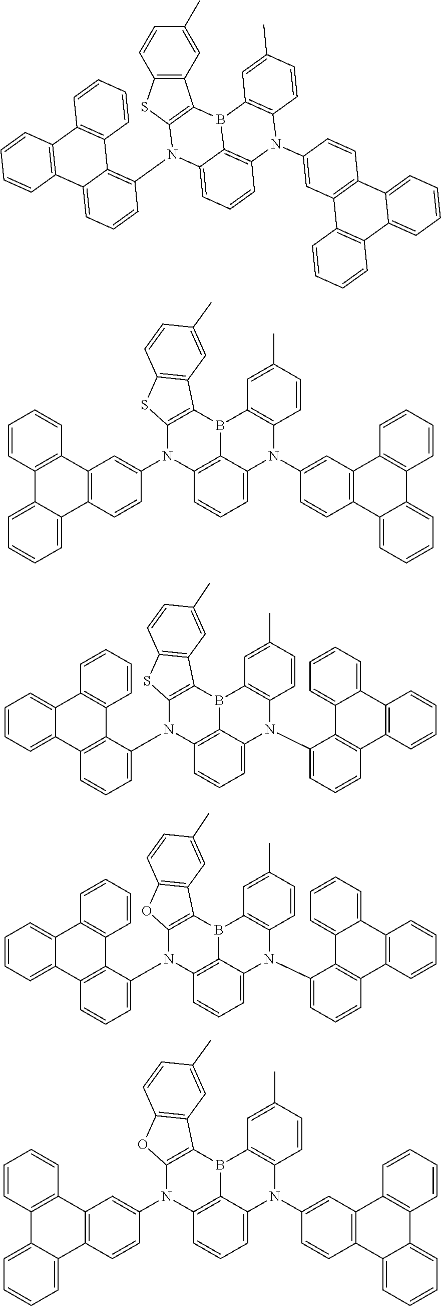

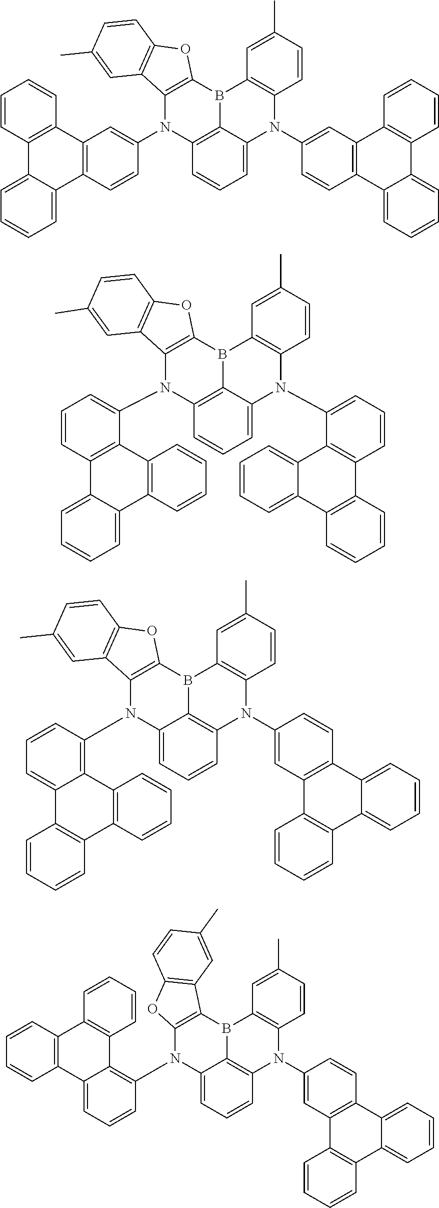

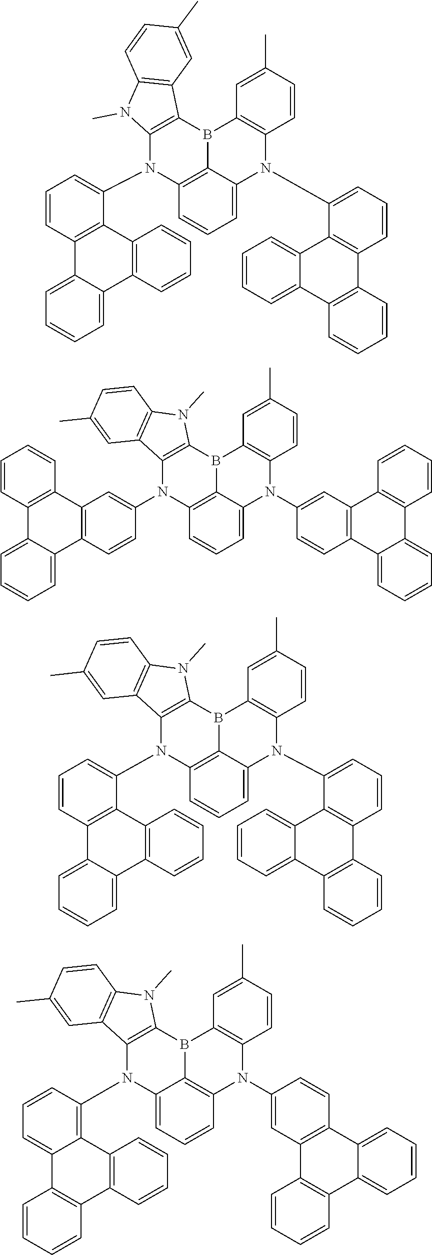

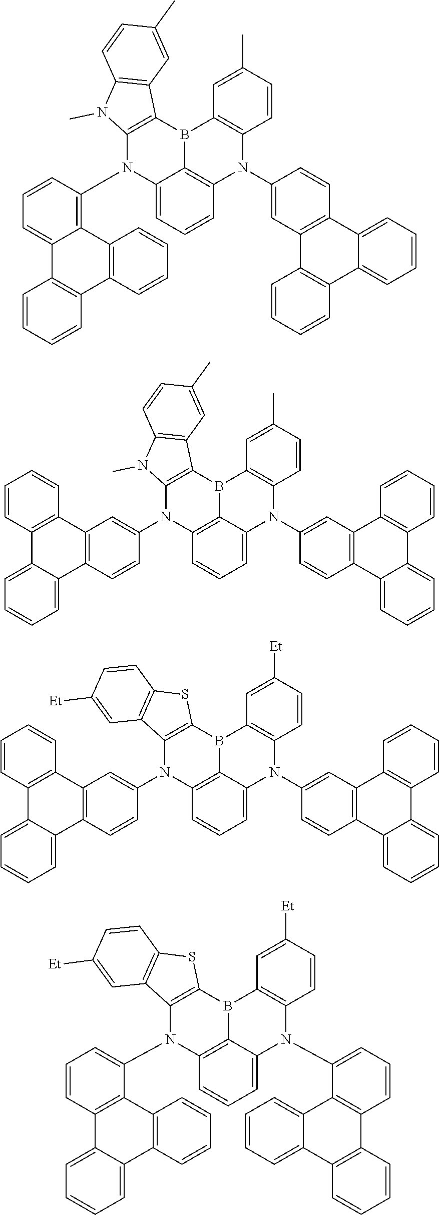 [SMILES: Cc1ccc2c(c1)B1c3c(cccc3N(c3cccc4c5ccccc5c5ccccc5c34)c3c1c1cc(C)ccc1n3C)N2c1ccc2c3ccccc3c3ccccc3c2c1 ; Cc1ccc2c(c1)B1c3c(cccc3N(c3ccc4c5ccccc5c5ccccc5c4c3)c3c1c1cc(C)ccc1n3C)N2c1ccc2c3ccccc3c3ccccc3c2c1 ; CCc1ccc2c(c1)B1c3sc4ccc(CC)cc4c3N(c3ccc4c5ccccc5c5ccccc5c4c3)c3cccc(c31)N2c1ccc2c3ccccc3c3ccccc3c2c1 ; CCc1ccc2c(c1)B1c3sc4ccc(CC)cc4c3N(c3cccc4c5ccccc5c5ccccc5c34)c3cccc(c31)N2c1cccc2c3ccccc3c3ccccc3c12]

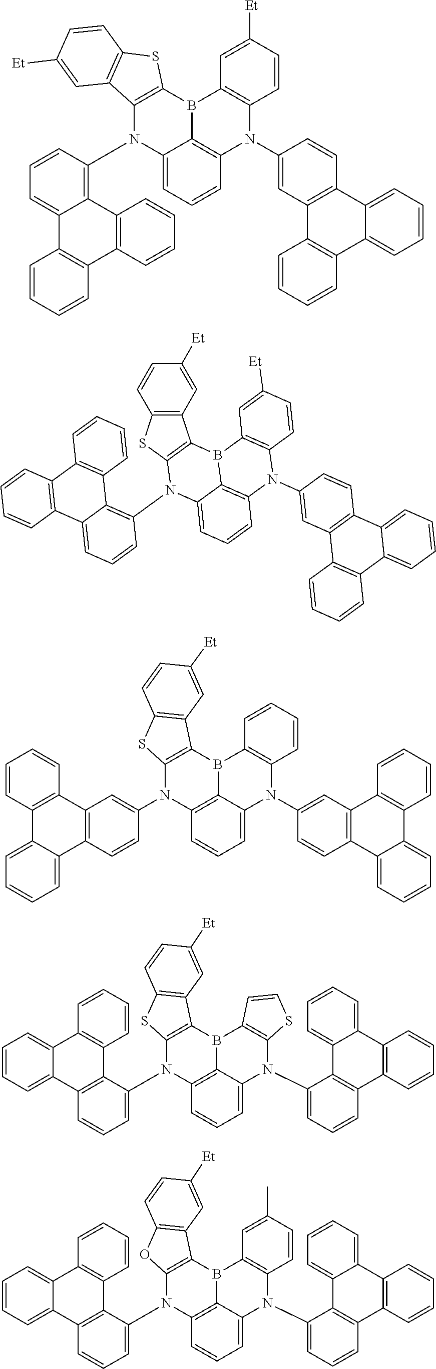

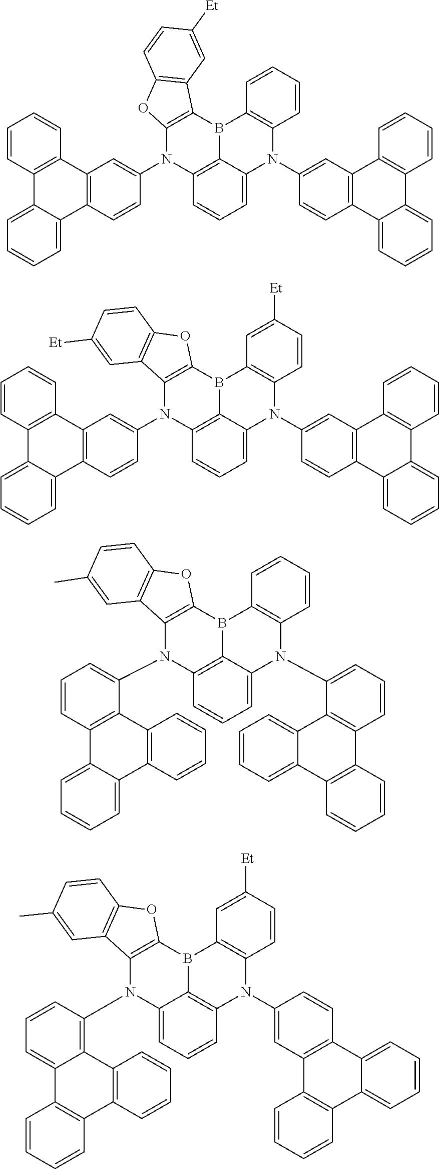 [SMILES: CCc1ccc2oc3c(c2c1)B1c2ccccc2N(c2ccc4c5ccccc5c5ccccc5c4c2)c2cccc(c21)N3c1ccc2c3ccccc3c3ccccc3c2c1 ; CCc1ccc2c(c1)B1c3oc4ccc(CC)cc4c3N(c3ccc4c5ccccc5c5ccccc5c4c3)c3cccc(c31)N2c1ccc2c3ccccc3c3ccccc3c2c1 ; Cc1ccc2oc3c(c2c1)N(c1cccc2c4ccccc4c4ccccc4c12)c1cccc2c1B3c1ccccc1N2c1cccc2c3ccccc3c3ccccc3c12 ; CCc1ccc2c(c1)B1c3oc4ccc(C)cc4c3N(c3cccc4c5ccccc5c5ccccc5c34)c3cccc(c31)N2c1ccc2c3ccccc3c3ccccc3c2c1]

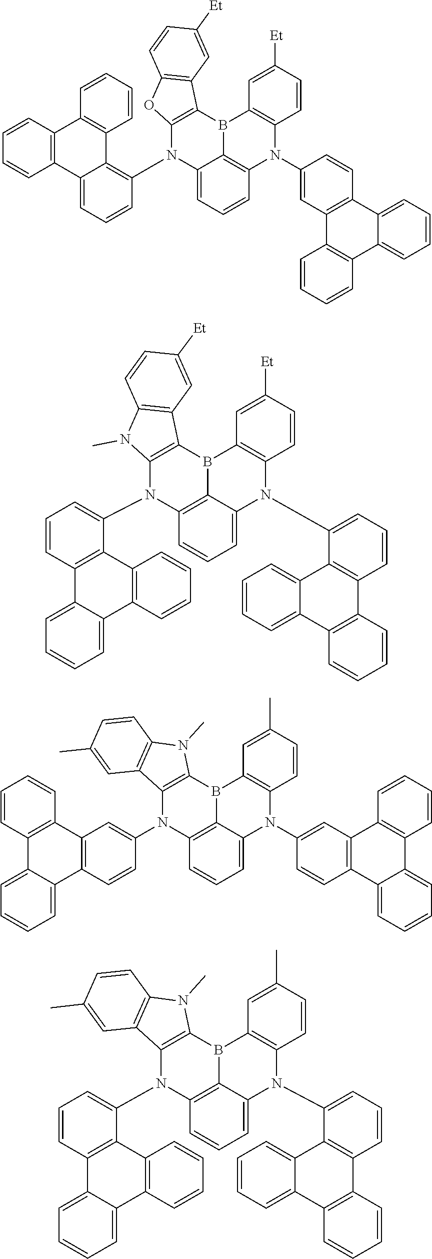 [SMILES: CCc1ccc2c(c1)B1c3c(cccc3N(c3cccc4c5ccccc5c5ccccc5c34)c3oc4ccc(CC)cc4c31)N2c1ccc2c3ccccc3c3ccccc3c2c1 ; CCc1ccc2c(c1)B1c3c(cccc3N(c3cccc4c5ccccc5c5ccccc5c34)c3c1c1cc(CC)ccc1n3C)N2c1cccc2c3ccccc3c3ccccc3c12 ; Cc1ccc2c(c1)B1c3c(cccc3N(c3ccc4c5ccccc5c5ccccc5c4c3)c3c1n(C)c1ccc(C)cc31)N2c1ccc2c3ccccc3c3ccccc3c2c1 ; Cc1ccc2c(c1)B1c3c(cccc3N(c3cccc4c5ccccc5c5ccccc5c34)c3c1n(C)c1ccc(C)cc31)N2c1cccc2c3ccccc3c3ccccc3c12]

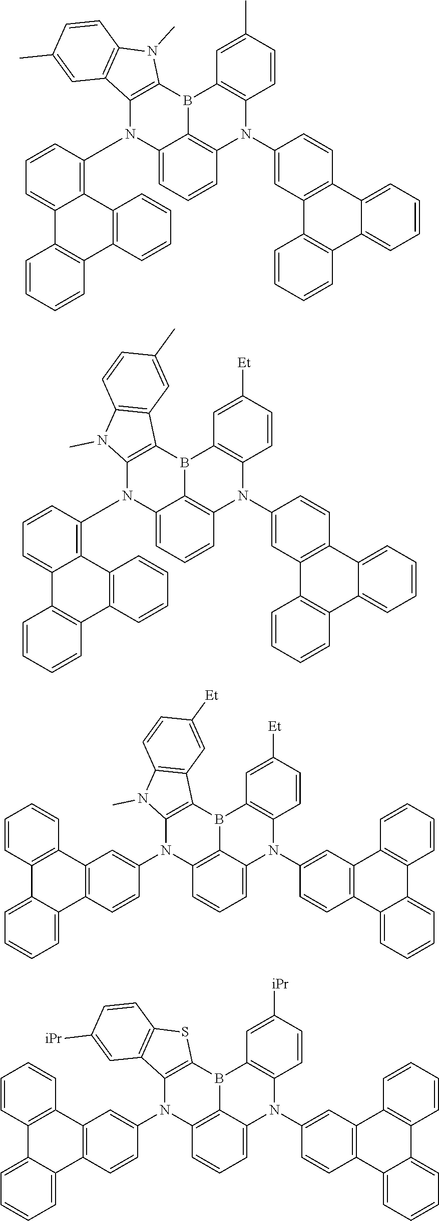 [SMILES: Cc1ccc2c(c1)B1c3c(cccc3N(c3cccc4c5ccccc5c5ccccc5c34)c3c1n(C)c1ccc(C)cc31)N2c1ccc2c3ccccc3c3ccccc3c2c1 ; CCc1ccc2c(c1)B1c3c(cccc3N(c3cccc4c5ccccc5c5ccccc5c34)c3c1c1cc(C)ccc1n3C)N2c1ccc2c3ccccc3c3ccccc3c2c1 ; CCc1ccc2c(c1)B1c3c(cccc3N(c3ccc4c5ccccc5c5ccccc5c4c3)c3c1c1cc(CC)ccc1n3C)N2c1ccc2c3ccccc3c3ccccc3c2c1 ; CC(C)c1ccc2c(c1)B1c3sc4ccc(C(C)C)cc4c3N(c3ccc4c5ccccc5c5ccccc5c4c3)c3cccc(c31)N2c1ccc2c3ccccc3c3ccccc3c2c1]

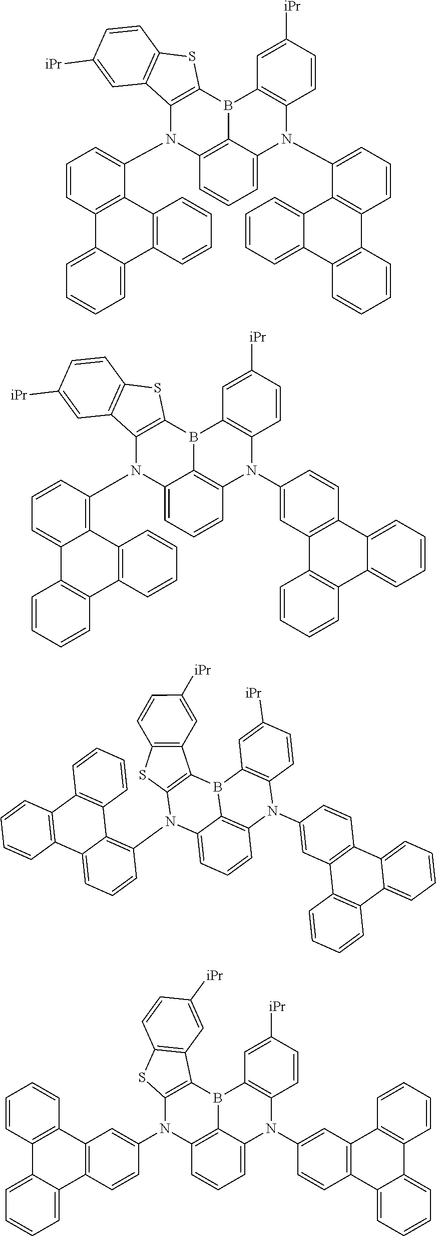

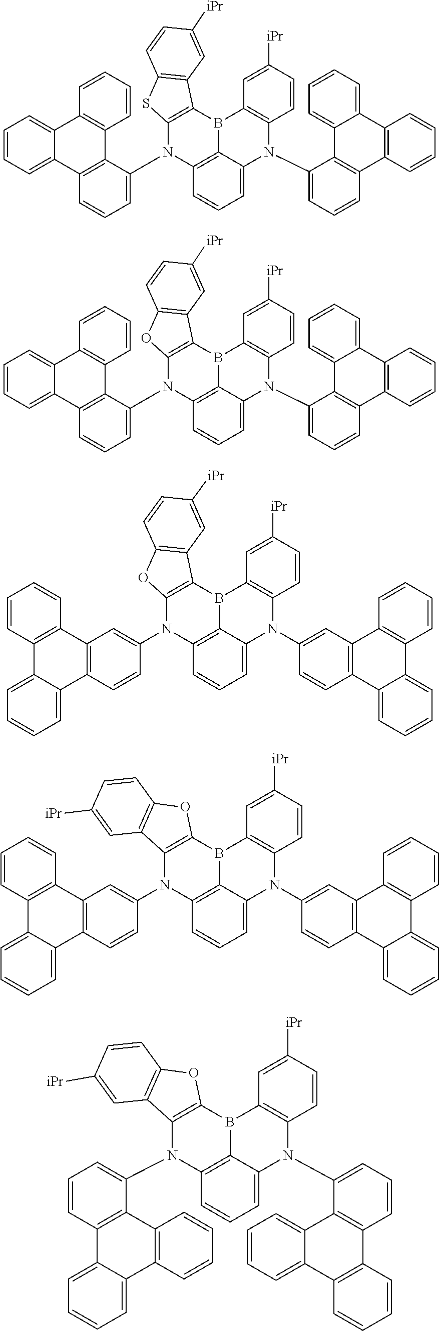

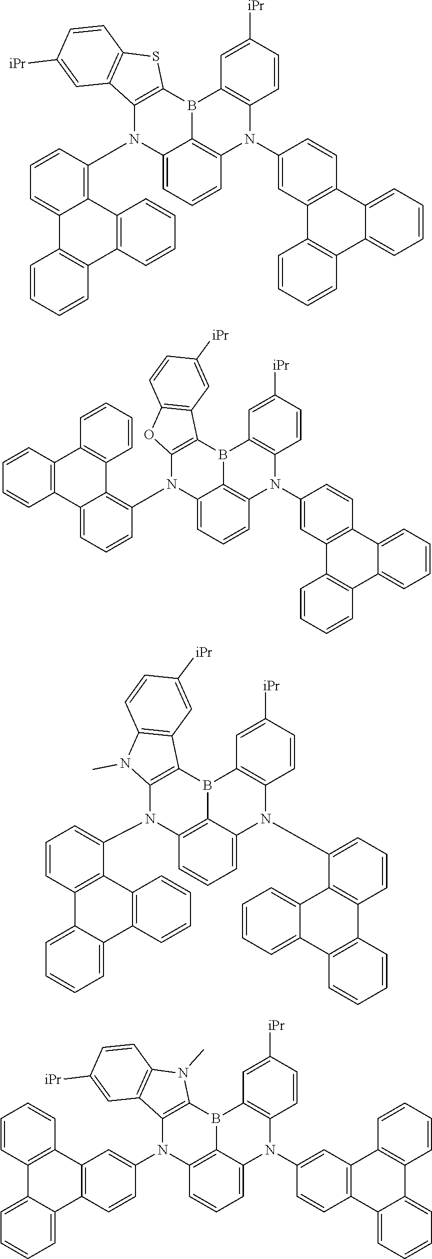 [SMILES: CC(C)c1ccc2c(c1)B1c3sc4ccc(C(C)C)cc4c3N(c3cccc4c5ccccc5c5ccccc5c34)c3cccc(c31)N2c1ccc2c3ccccc3c3ccccc3c2c1 ; CC(C)c1ccc2c(c1)B1c3c(cccc3N(c3cccc4c5ccccc5c5ccccc5c34)c3oc4ccc(C(C)C)cc4c31)N2c1ccc2c3ccccc3c3ccccc3c2c1 ; CC(C)c1ccc2c(c1)B1c3c(cccc3N(c3cccc4c5ccccc5c5ccccc5c34)c3c1c1cc(C(C)C)ccc1n3C)N2c1cccc2c3ccccc3c3ccccc3c12 ; CC(C)c1ccc2c(c1)B1c3c(cccc3N(c3ccc4c5ccccc5c5ccccc5c4c3)c3c1n(C)c1ccc(C(C)C)cc31)N2c1ccc2c3ccccc3c3ccccc3c2c1]

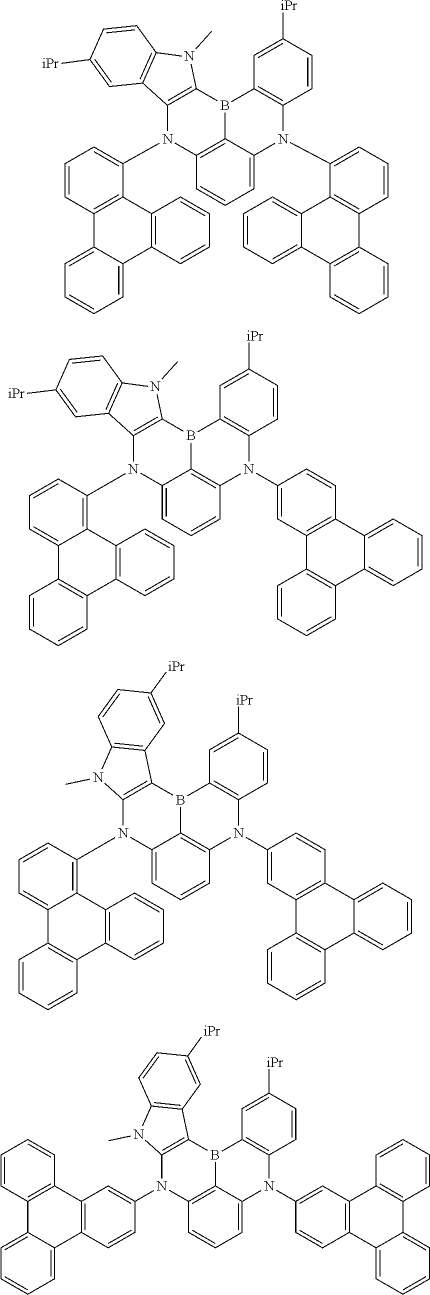

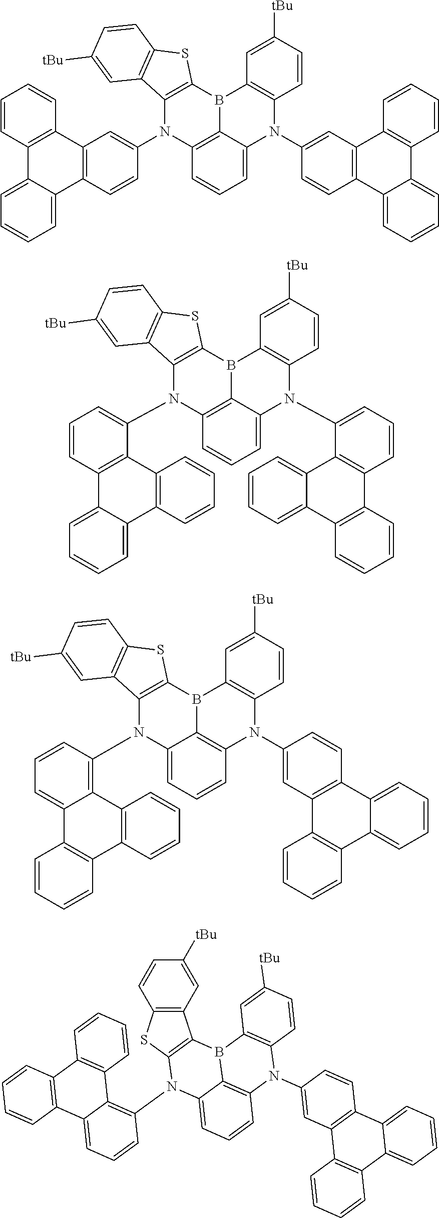 [SMILES: CC(C)(C)c1ccc2c(c1)B1c3sc4ccc(C(C)(C)C)cc4c3N(c3ccc4c5ccccc5c5ccccc5c4c3)c3cccc(c31)N2c1ccc2c3ccccc3c3ccccc3c2c1 ; CC(C)(C)c1ccc2c(c1)B1c3sc4ccc(C(C)(C)C)cc4c3N(c3cccc4c5ccccc5c5ccccc5c34)c3cccc(c31)N2c1cccc2c3ccccc3c3ccccc3c12 ; CC(C)(C)c1ccc2c(c1)B1c3sc4ccc(C(C)(C)C)cc4c3N(c3cccc4c5ccccc5c5ccccc5c34)c3cccc(c31)N2c1ccc2c3ccccc3c3ccccc3c2c1 ; CC(C)(C)c1ccc2c(c1)B1c3c(cccc3N(c3cccc4c5ccccc5c5ccccc5c34)c3sc4ccc(C(C)(C)C)cc4c31)N2c1ccc2c3ccccc3c3ccccc3c2c1]

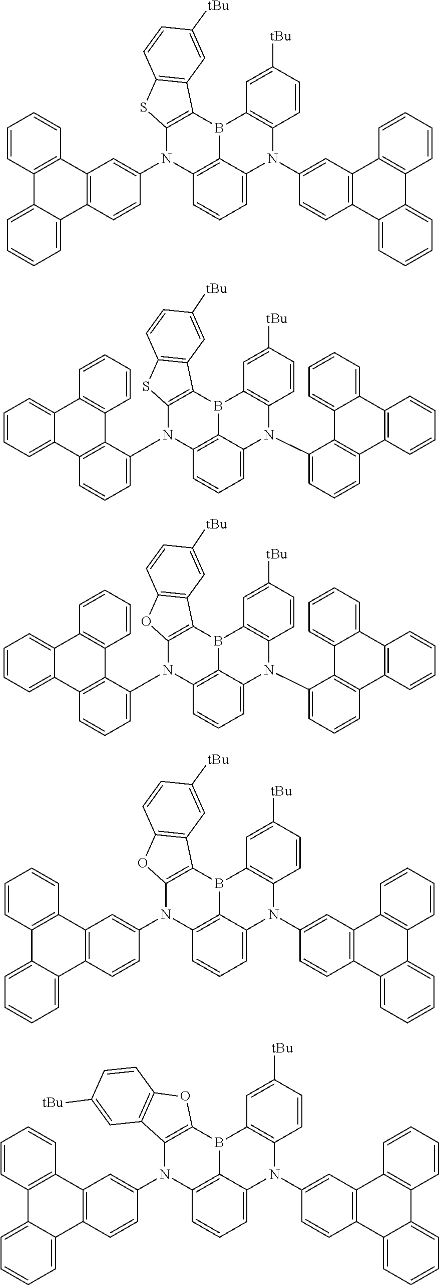

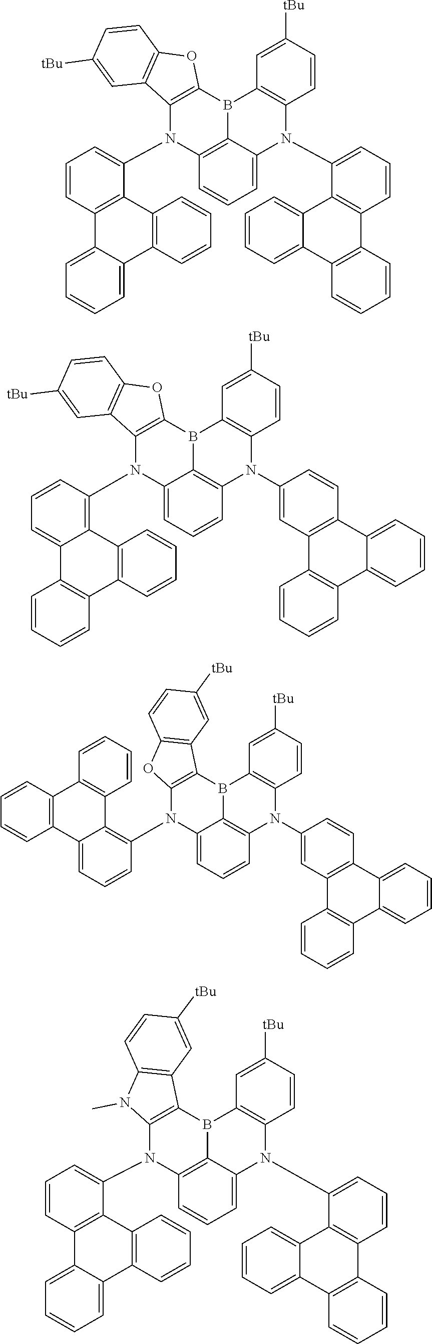

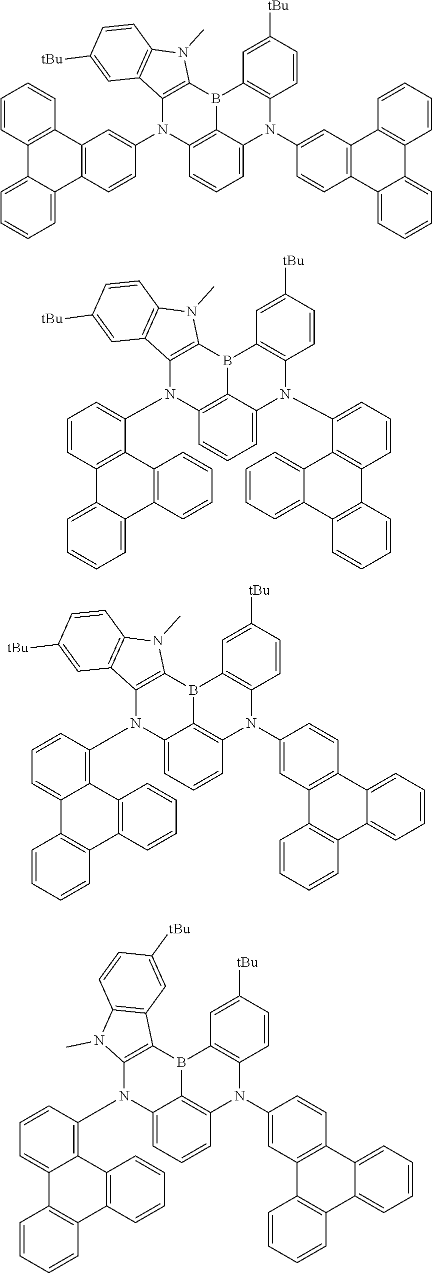

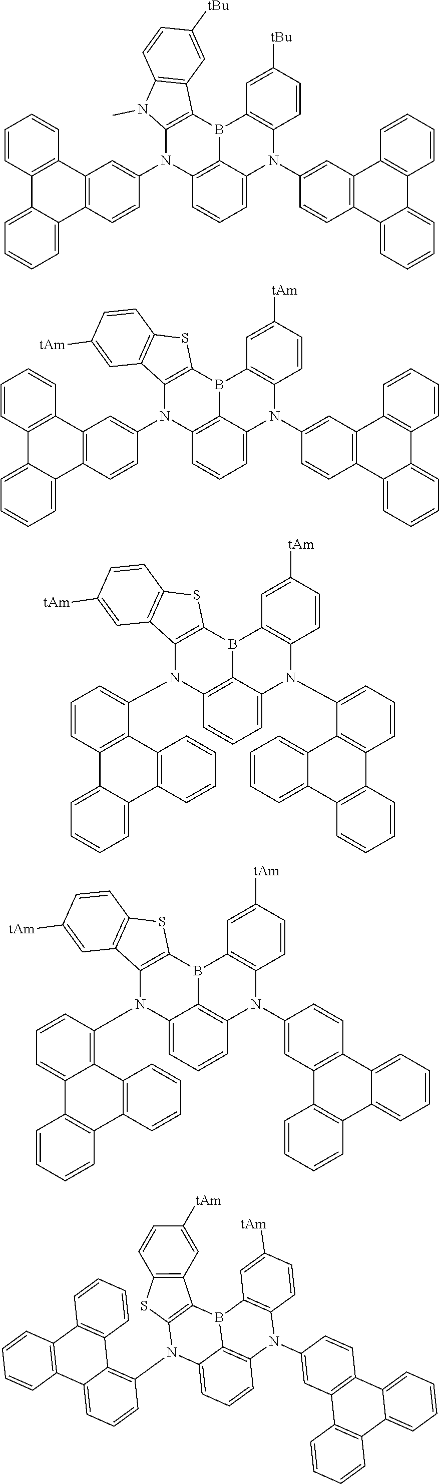

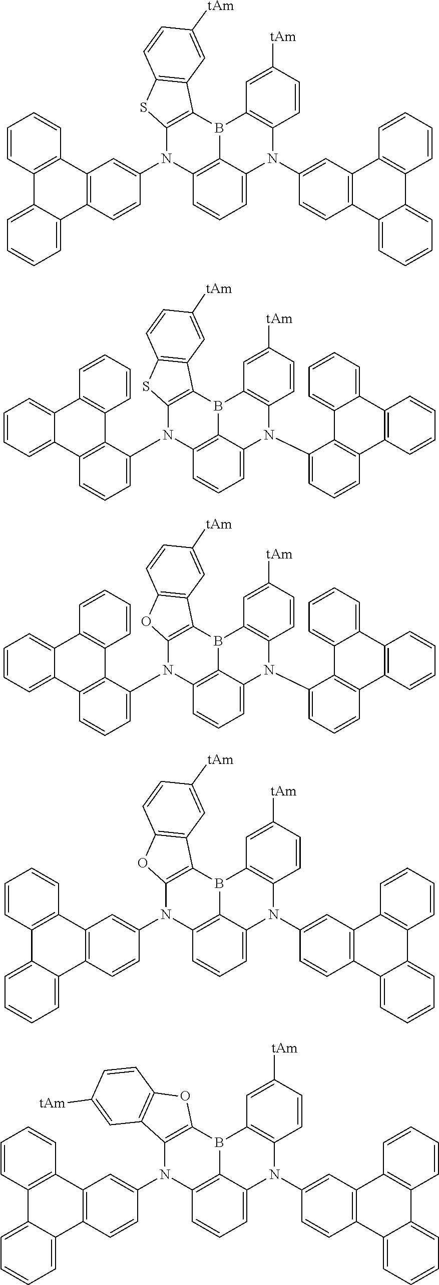

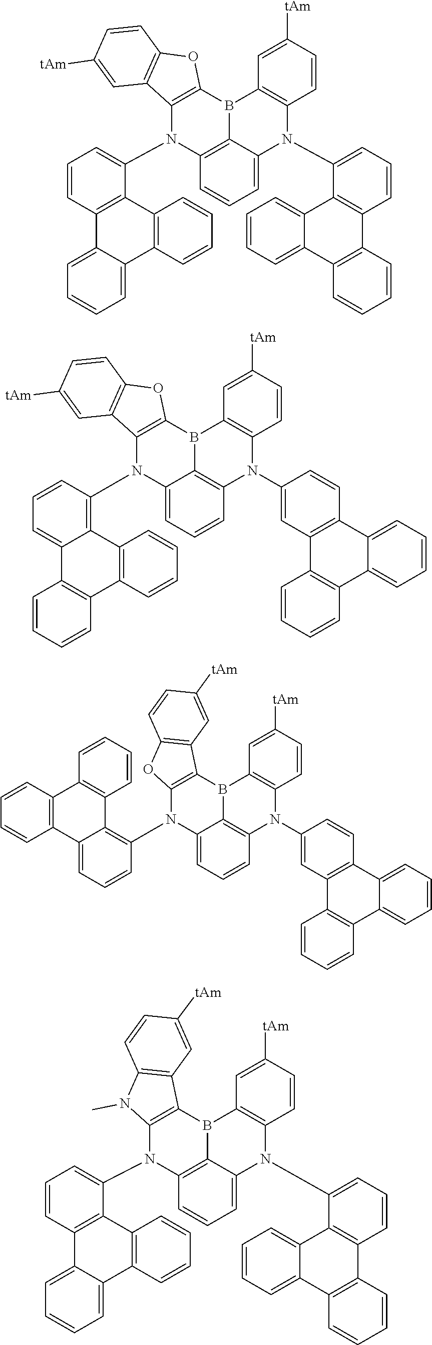

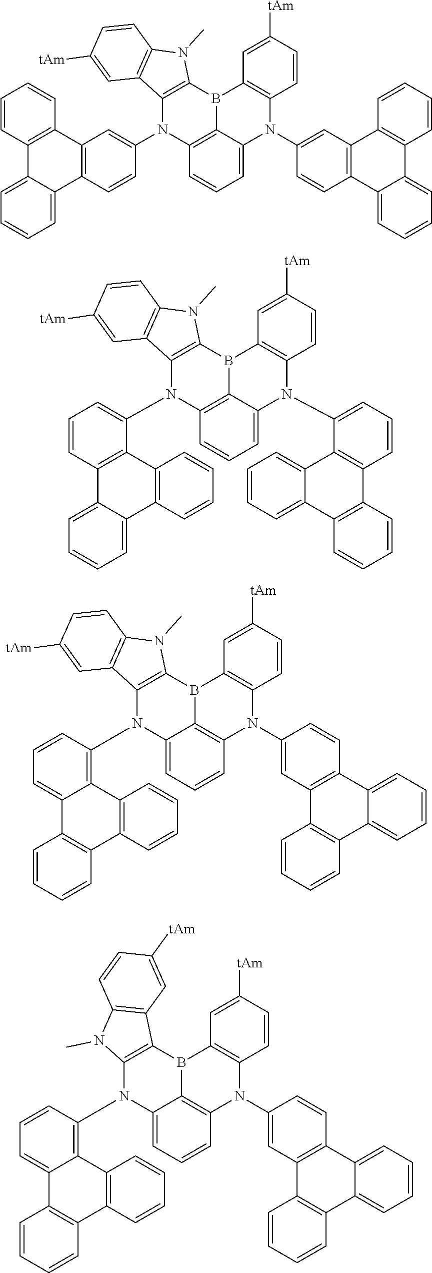

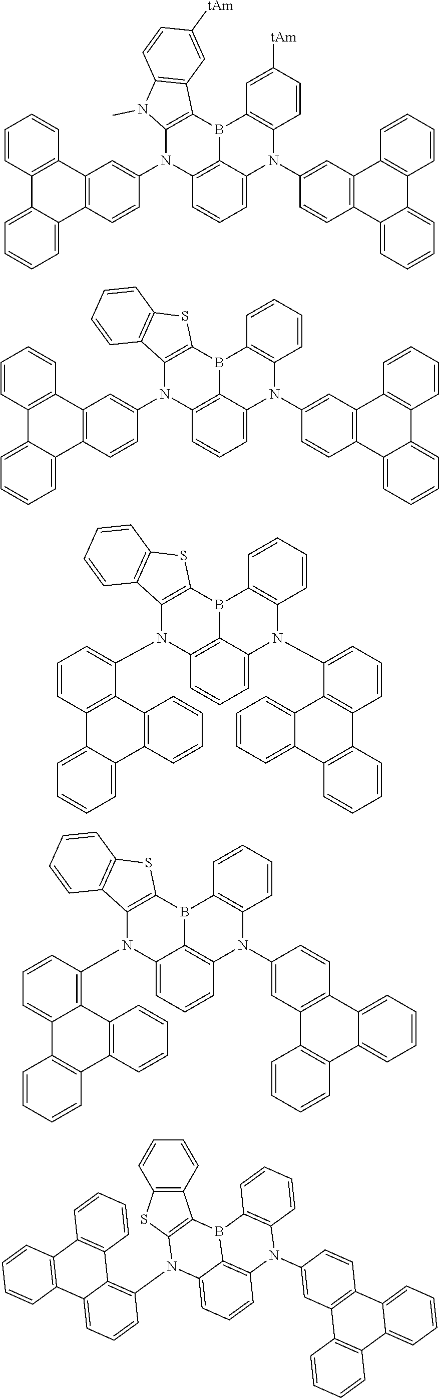

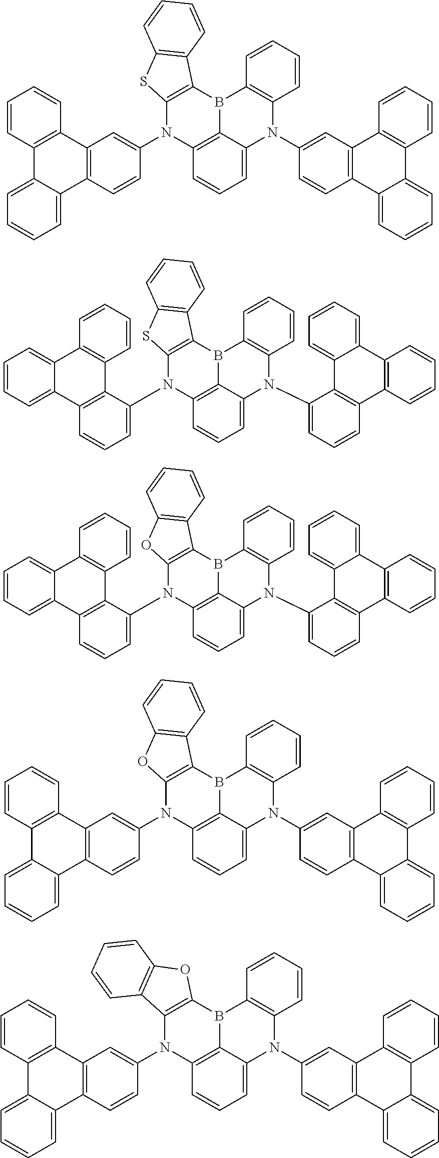

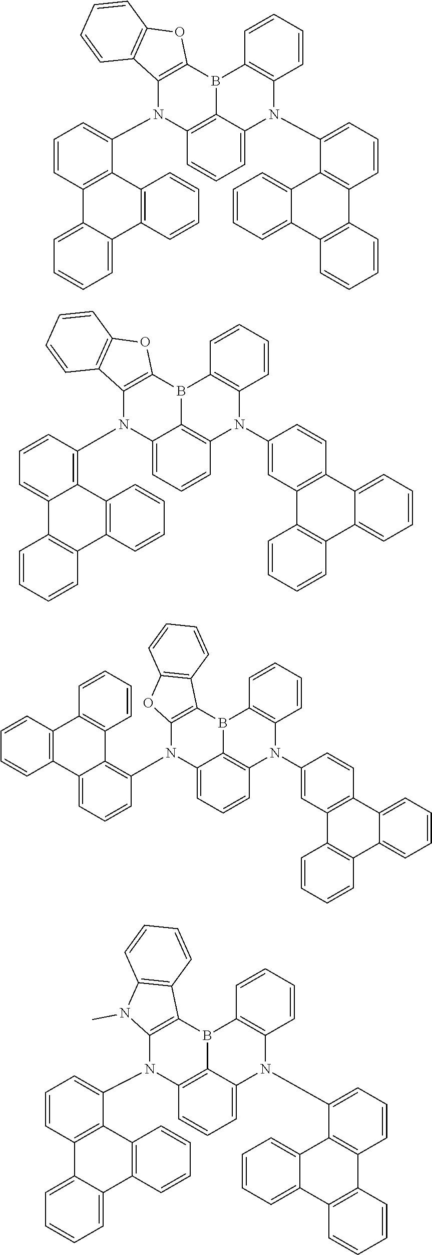

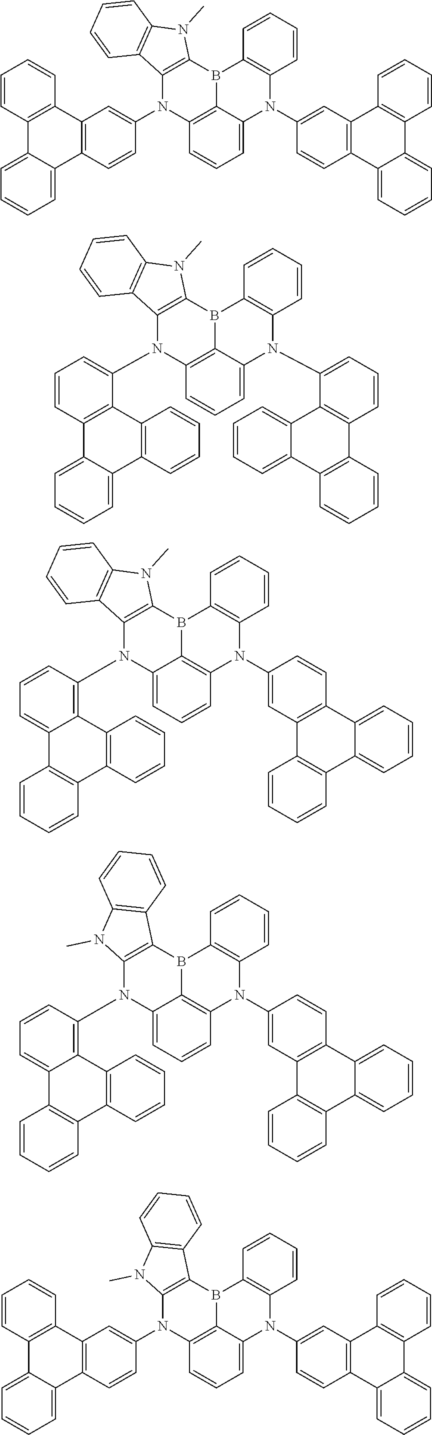

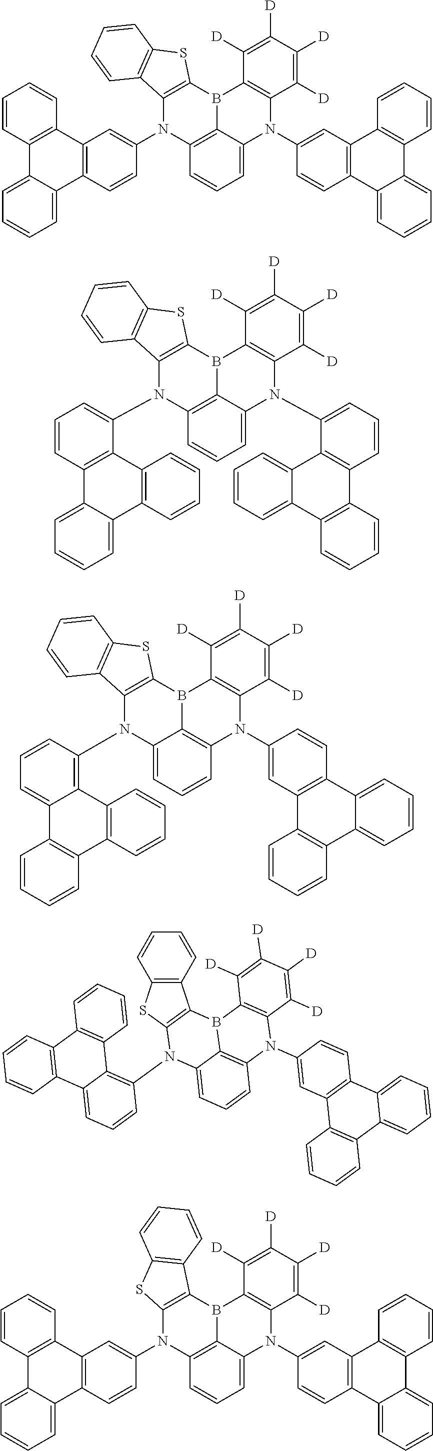

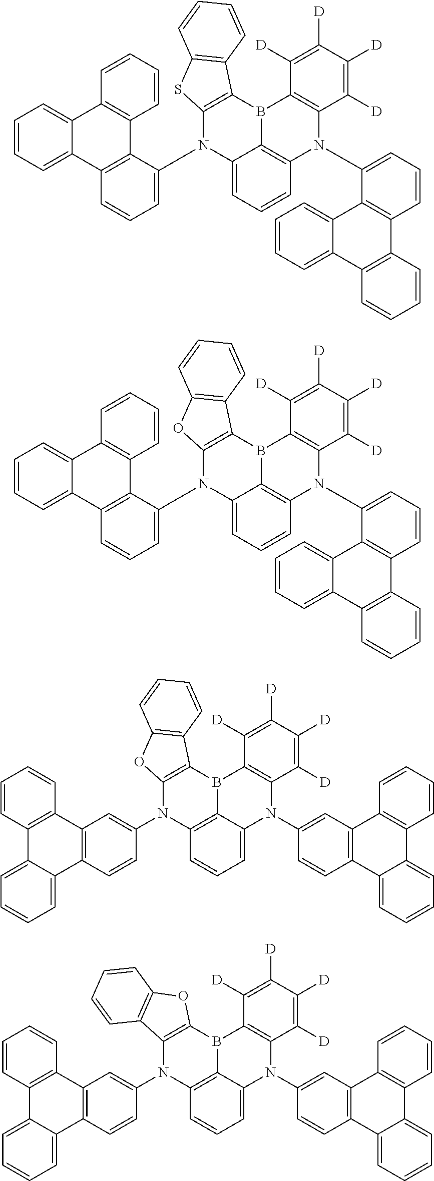 [SMILES: [2H]c1c([2H])c([2H])c2c(c1[2H])B1c3c(cccc3N2c2cccc3c4ccccc4c4ccccc4c23)N(c2cccc3c4ccccc4c4ccccc4c23)c2sc3ccccc3c21 ; [2H]c1c([2H])c([2H])c2c(c1[2H])B1c3c(cccc3N2c2cccc3c4ccccc4c4ccccc4c23)N(c2cccc3c4ccccc4c4ccccc4c23)c2oc3ccccc3c21 ; [2H]c1c([2H])c([2H])c2c(c1[2H])B1c3c(cccc3N2c2ccc3c4ccccc4c4ccccc4c3c2)N(c2ccc3c4ccccc4c4ccccc4c3c2)c2oc3ccccc3c21 ; [2H]c1c([2H])c([2H])c2c(c1[2H])B1c3oc4ccccc4c3N(c3ccc4c5ccccc5c5ccccc5c4c3)c3cccc(c31)N2c1ccc2c3ccccc3c3ccccc3c2c1]

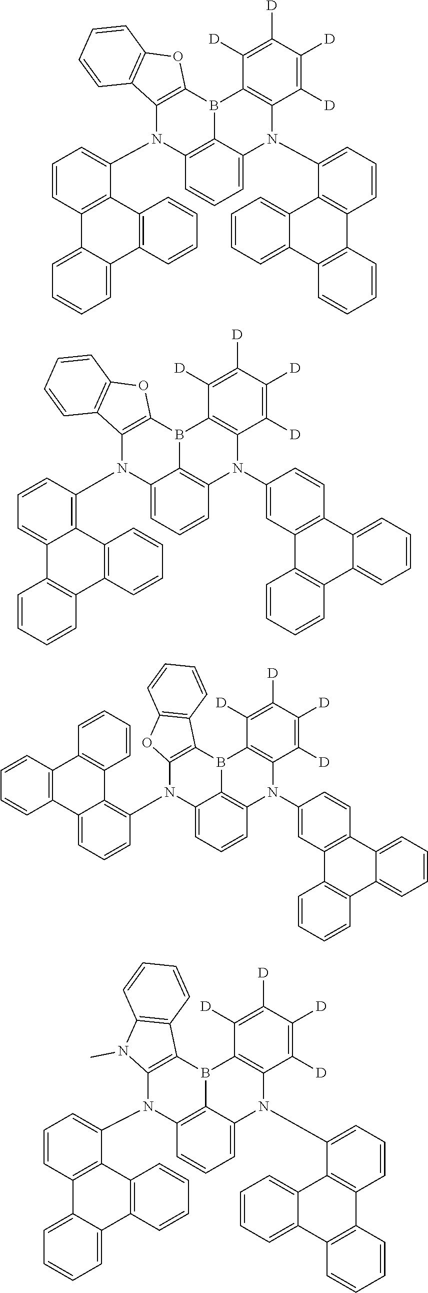

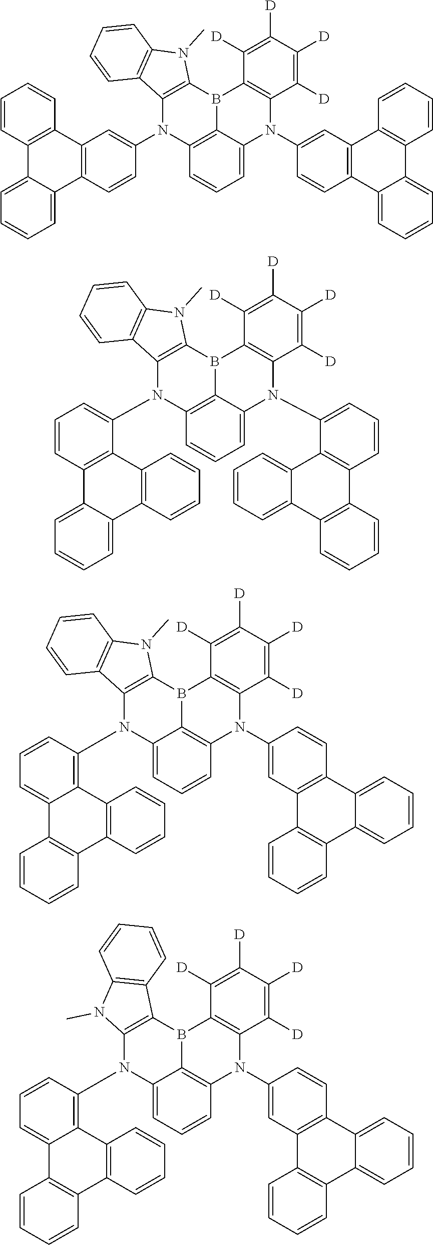

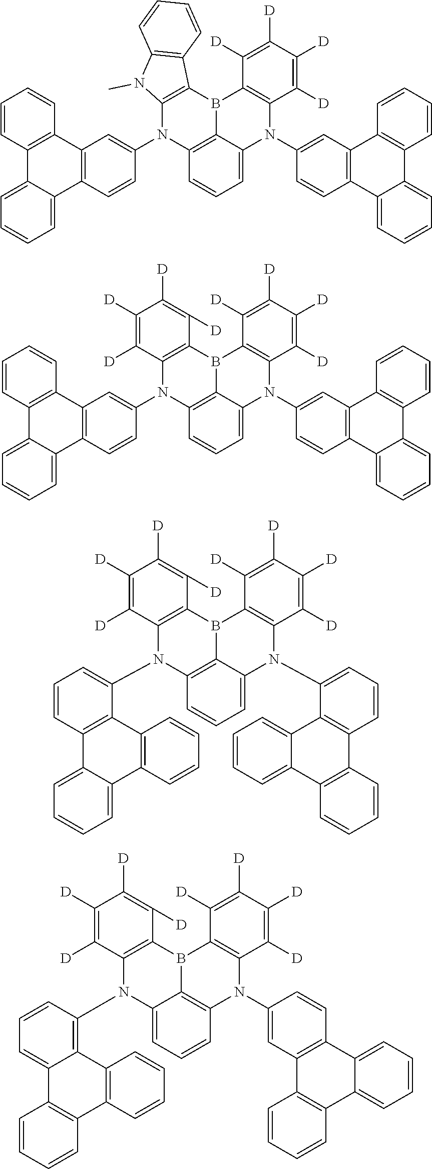

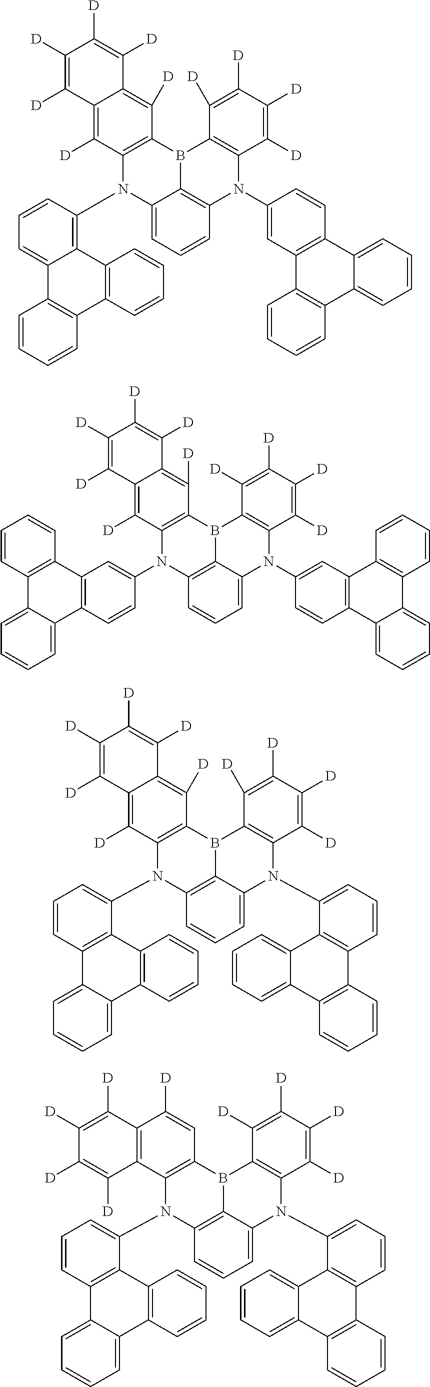

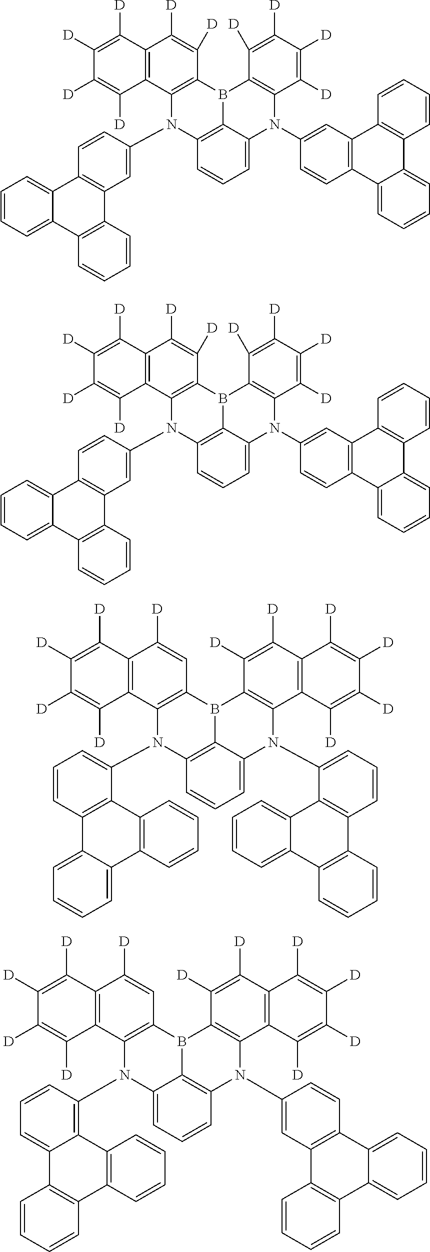

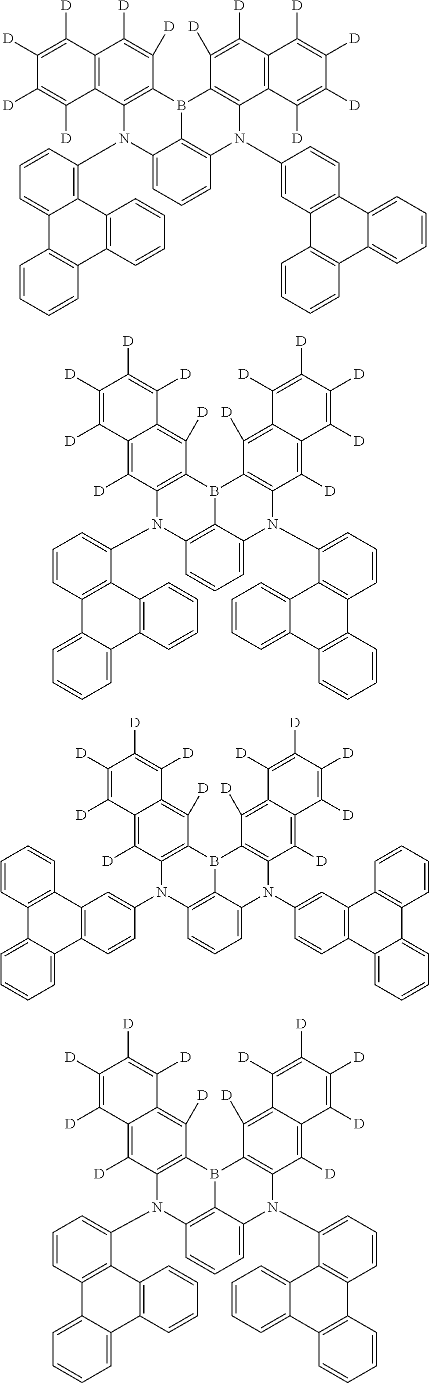

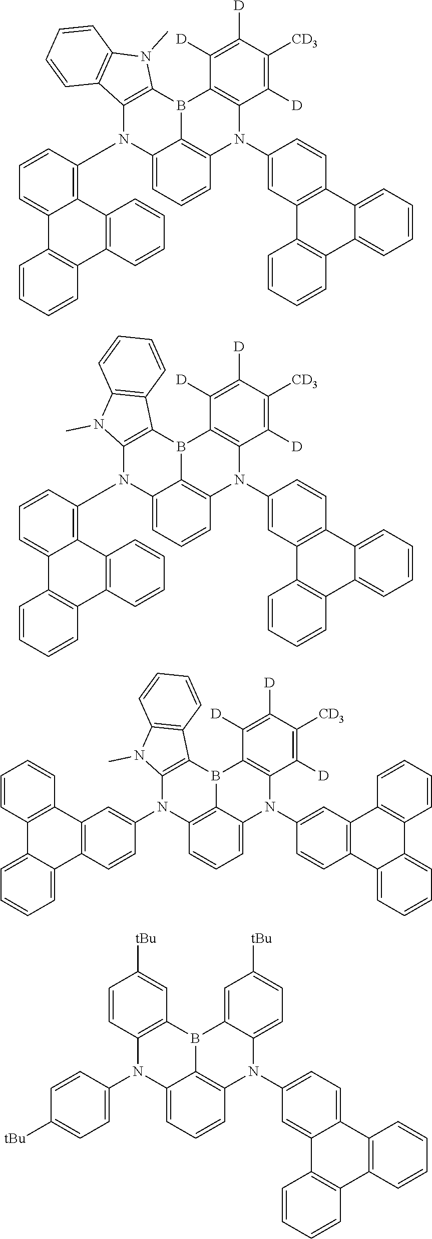

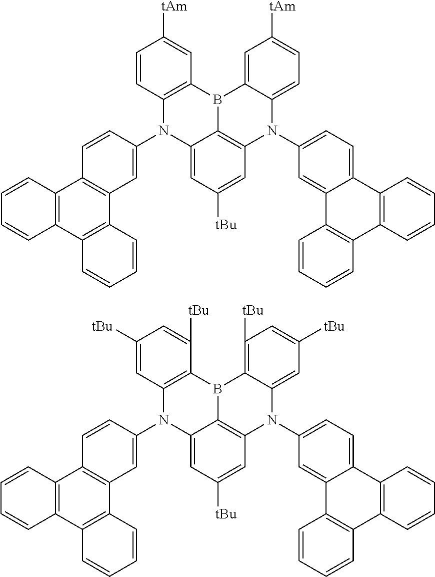

11. A composition comprising a boron-containing triphenylene compound and an organic solvent, wherein the boron-containing triphenylene compound has a structure represented by formula (1): 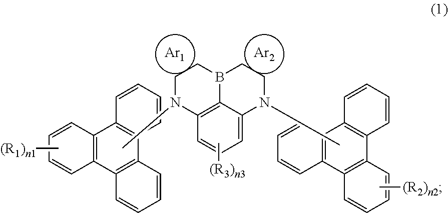
wherein Ar₁ and Ar₂ are each independently selected from any one of formula (A-1) to formula (A-5): 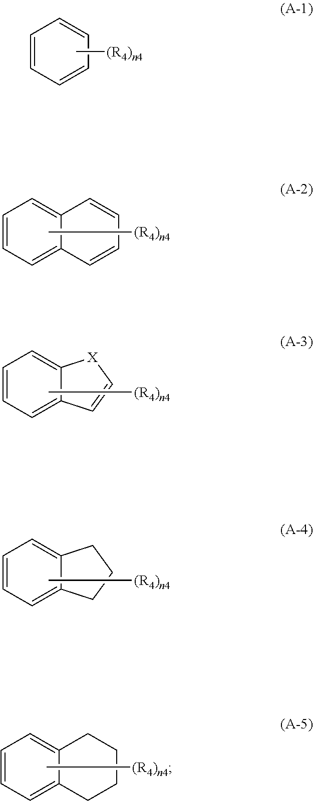
X is selected from O, S, CR₅R₆, or NR₇;
R₁-R₇ are each independently selected from H, D, a C₁₋₂₀ linear alkyl group, a C₁₋₂₀ linear alkoxyl group, a C₁₋₂₀ linear thioalkoxyl group, a C₃₋₂₀ branched alkyl group, a C₃₋₂₀ cyclic alkyl group, a C₃₋₂₀ branched alkoxyl group, a C₃₋₂₀ cyclic alkoxyl group, a C₃₋₂₀ branched thioalkoxyl group, a C₃₋₂₀ cyclic thioalkoxyl group, silyl, a ketone group containing 1-20 carbon atoms, an alkoxycarbonyl group containing 2-20 carbon atoms, an aryloxycarbonyl group containing 7-20 carbon atoms, an alkenyl group containing 1-20 carbon atoms, a cyanoyl group, a carbamoyl group, a haloformyl group, a formyl group, an isocyanoyl group, an isocyanate group, a thiocyanate group, an isothiocyanate group, a hydroxyl group, a nitro group, CF₃, Cl, Br, F, a substituted or unsubstituted aromatic group containing 6-30 ring atoms, a substituted or unsubstituted heteroaromatic group containing 5-30 ring atoms, a substituted or unsubstituted aryloxy group containing 6-30 ring atoms, a substituted or unsubstituted heteroaryloxy group containing 5-30 ring atoms, or combinations thereof at each occurrence; and
n1-n4 are each independently selected from 0, 1, 2, or 3.

12. The composition of claim 11, wherein the boron-containing triphenylene compound is selected from any one of formula (2-1) to formula (2-8):

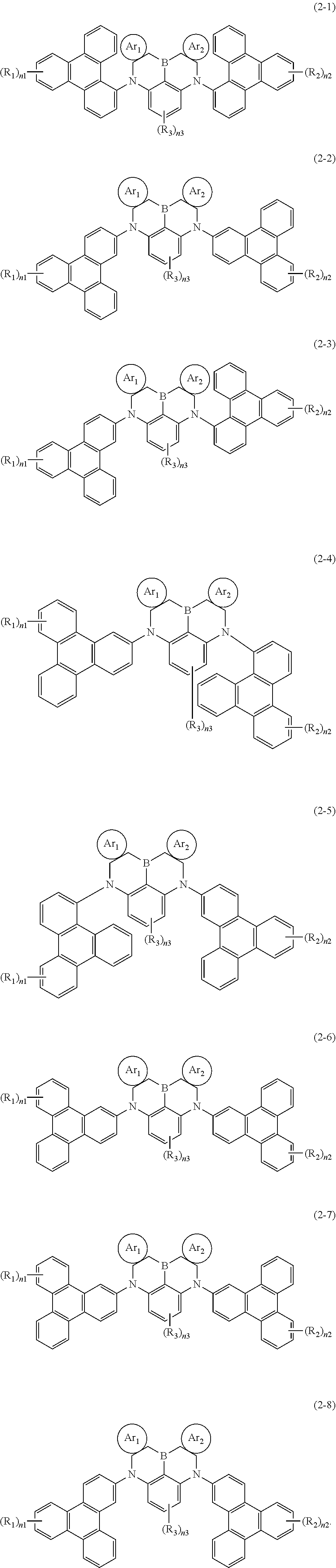

13. The composition of claim 11, wherein the boron-containing triphenylene compound is selected from any one of formula (3-1) to formula (3-22):

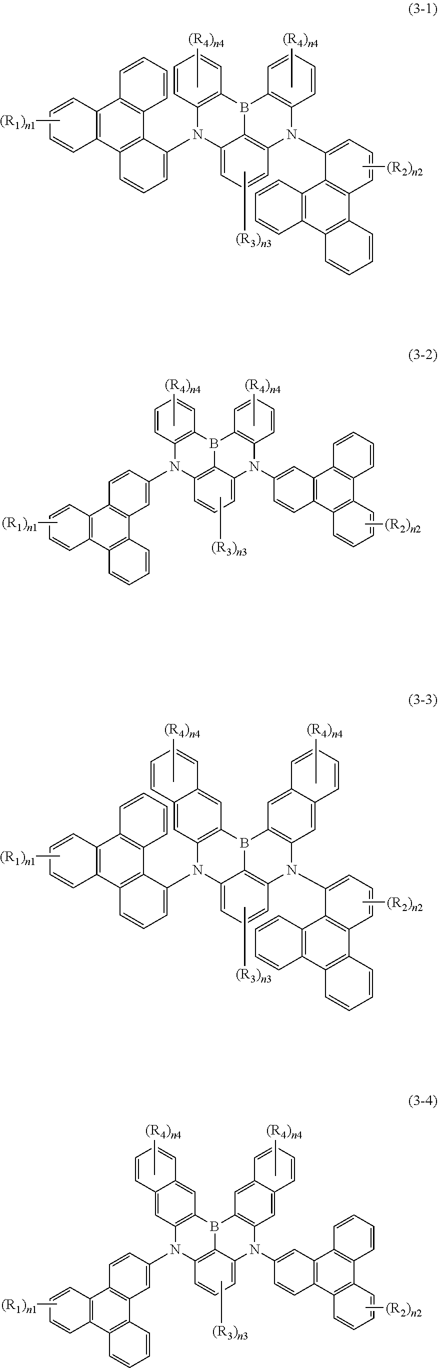

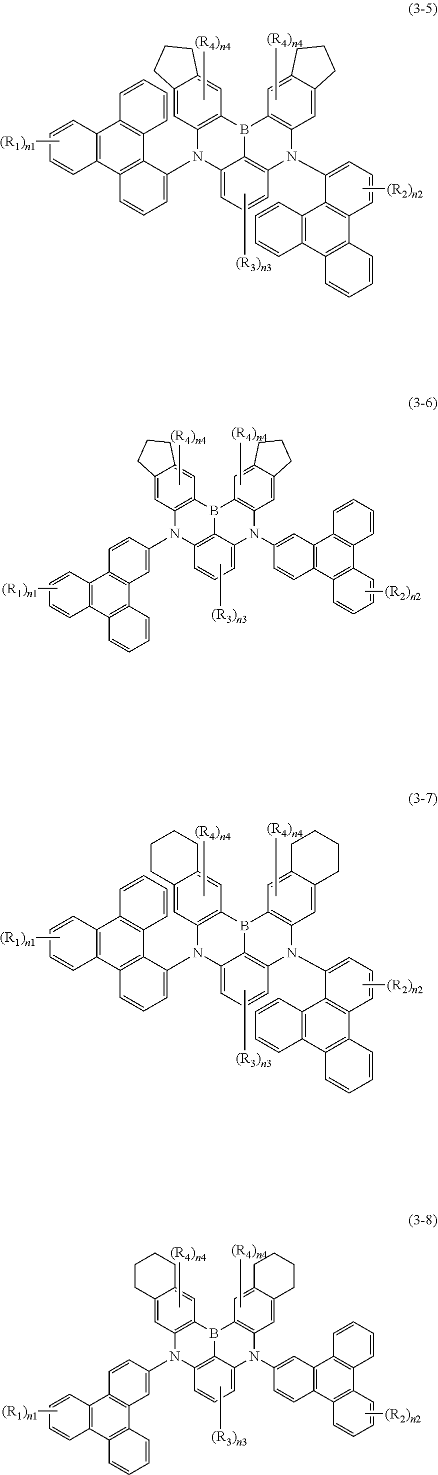

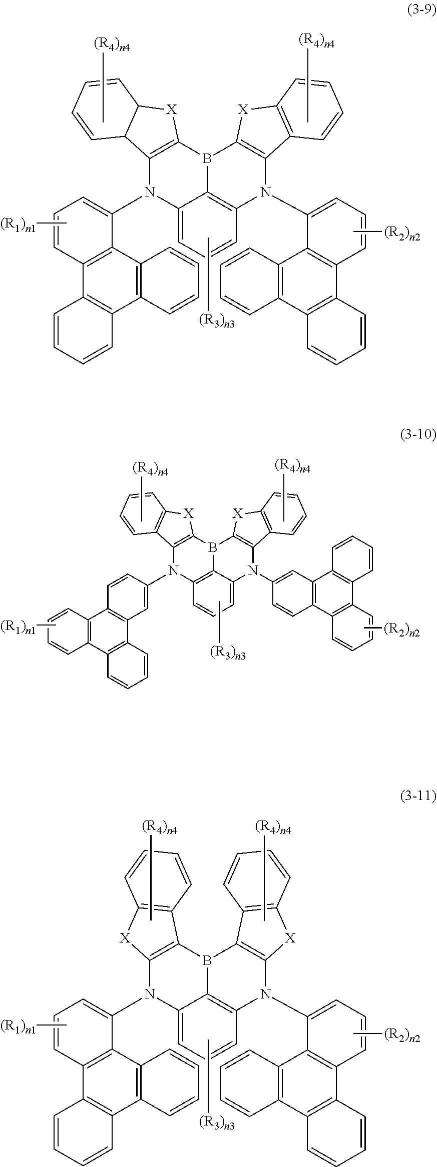

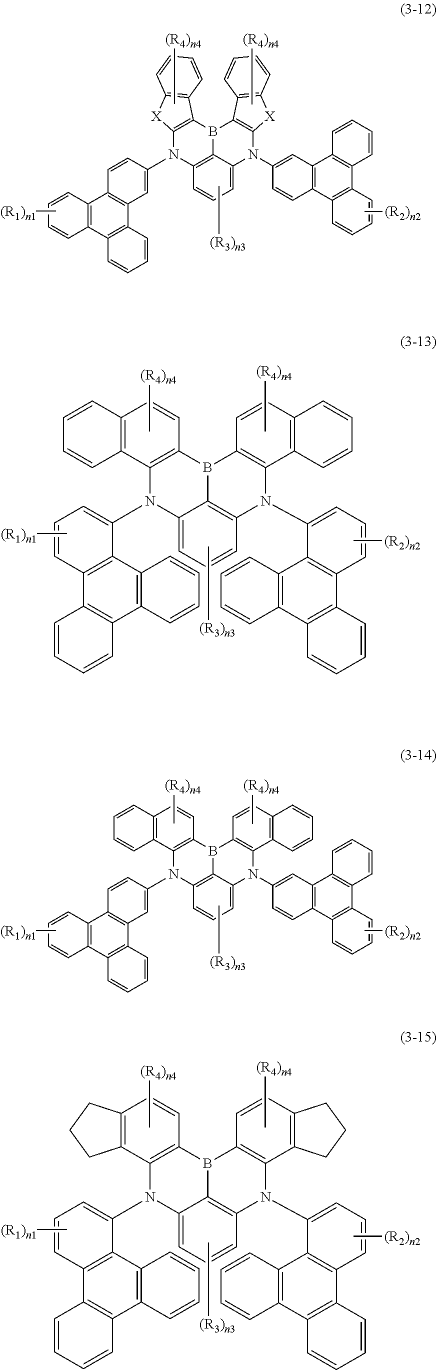

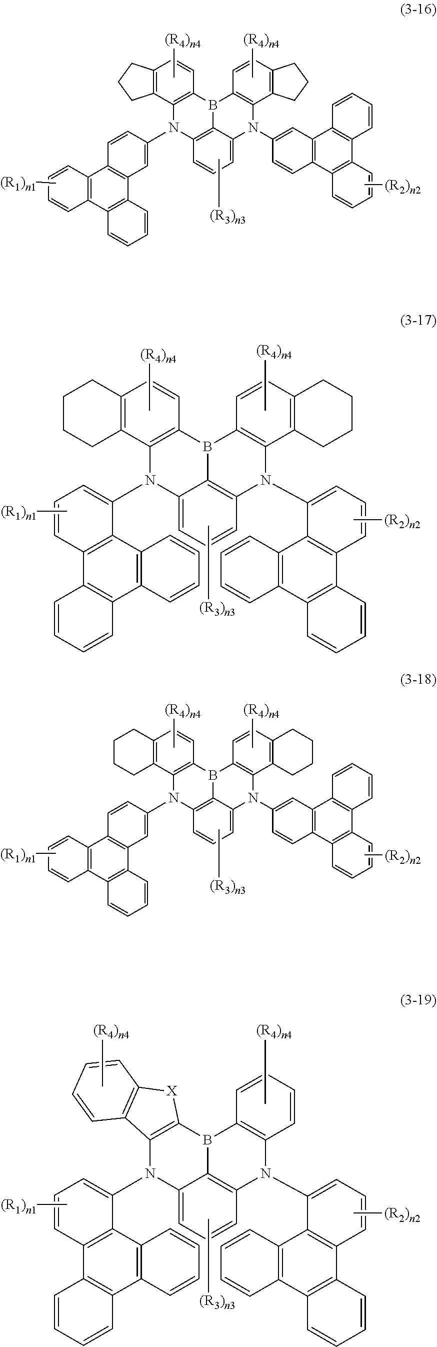

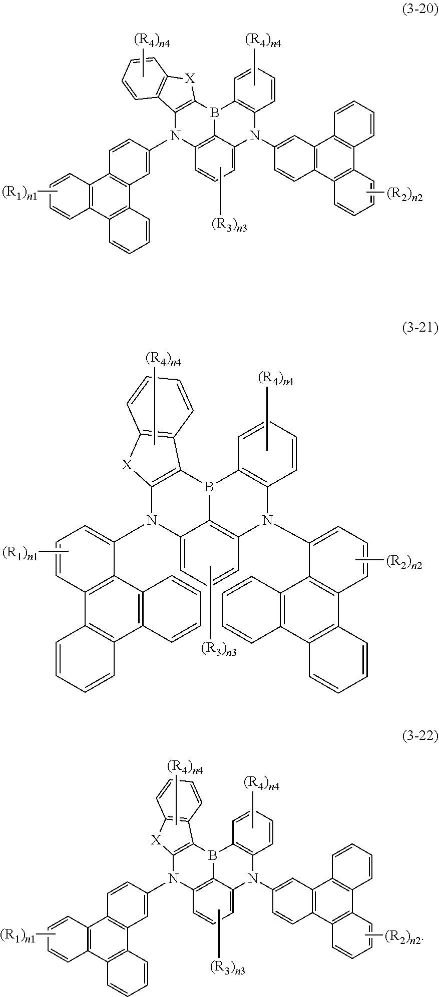

14. The composition of claim 11, wherein Ar₁ and Ar₂ are each independently selected from any one of formula (B-1) to formula (B-8): 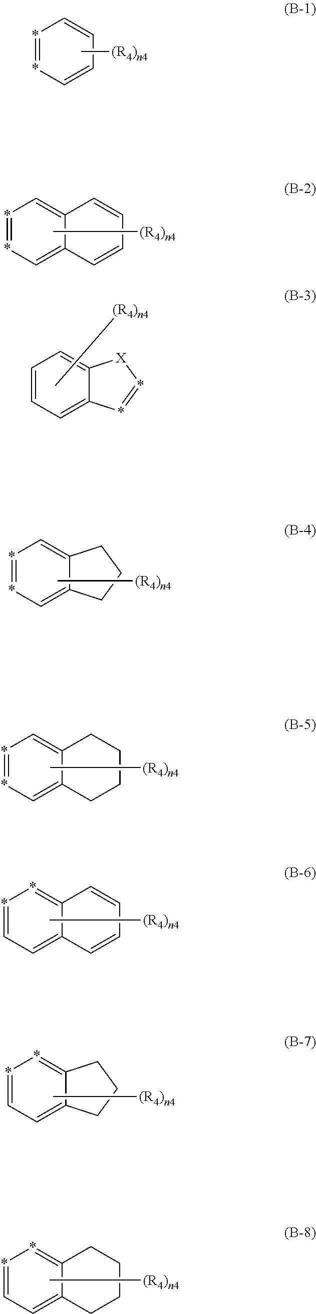
wherein “*” indicates a fused site.

15. The composition of claim 11, wherein two adjacent R₁ groups do not form a ring with each other, and R₁ is independently selected from H, D, a C₁₋₄ linear alkyl group, or a C₃₋₅ branched alkyl group at each occurrence; or
two adjacent R₁ groups form 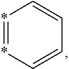 [SMILES: *1:*cccc1]
and “*” indicates a linking site.

16. The composition of claim 11, wherein two adjacent R₂ groups do not form a ring with each other, and R₂ is independently selected from H, D, a C₁₋₄ linear alkyl group, or a C₃₋₅ branched alkyl group at each occurrence; or
two adjacent R₂ groups form 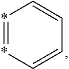 [SMILES: *1:*cccc1]
and “*” indicates a linking site.

17. The composition of claim 11, wherein two adjacent R₃ groups do not form a ring with each other, and R₃ is independently selected from H, D, a C₁₋₄ linear alkyl group, or a C₃₋₅ branched alkyl group at each occurrence; or
two adjacent R₃ groups form an aromatic ring containing six ring atoms or an aliphatic ring with each other.

18. The composition of claim 11, wherein R₄ is independently selected from H, D, a C₁₋₄ linear alkyl group, or a C₃₋₅ branched alkyl group at each occurrence.

19. The composition of claim 11, wherein X is selected from O, S, N—CH₃, N-Ph, or C(CH₃)₂, wherein Ph indicates benzene.

20. An organic electronic device comprising an organic functional layer, wherein the organic functional layer comprises a boron-containing triphenylene compound having a structure represented by formula (1): 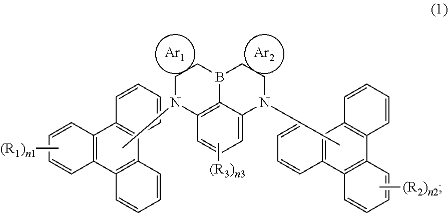
wherein Ar₁ and Ar₂ are each independently selected from any one of formula (A-1) to formula (A-5): 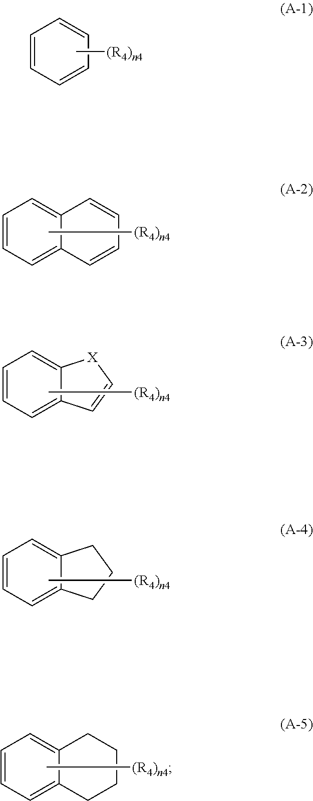
X is selected from O, S, CR₅R₆, or NR₇;
R₁-R₇ are each independently selected from H, D, a C₁₋₂₀ linear alkyl group, a C₁₋₂₀ linear alkoxyl group, a C₁₋₂₀ linear thioalkoxyl group, a C₃₋₂₀ branched alkyl group, a C₃₋₂₀ cyclic alkyl group, a C₃₋₂₀ branched alkoxyl group, a C₃₋₂₀ cyclic alkoxyl group, a C₃₋₂₀ branched thioalkoxyl group, a C₃₋₂₀ cyclic thioalkoxyl group, silyl, a ketone group containing 1-20 carbon atoms, an alkoxycarbonyl group containing 2-20 carbon atoms, an aryloxycarbonyl group containing 7-20 carbon atoms, an alkenyl group containing 1-20 carbon atoms, a cyanoyl group, a carbamoyl group, a haloformyl group, a formyl group, an isocyanoyl group, an isocyanate group, a thiocyanate group, an isothiocyanate group, a hydroxyl group, a nitro group, CF₃, Cl, Br, F, a substituted or unsubstituted aromatic group containing 6-30 ring atoms, a substituted or unsubstituted heteroaromatic group containing 5-30 ring atoms, a substituted or unsubstituted aryloxy group containing 6-30 ring atoms, a substituted or unsubstituted heteroaryloxy group containing 5-30 ring atoms, or combinations thereof at each occurrence; and
n1-n4 are each independently selected from 0, 1, 2, or 3.
